(19) United States
(12) Patent Application Publication
(10) Pub. No.: US 2026/0173635 A1
(43) Pub. Date: Jun. 18, 2026

(54) ORGANIC COMPOUND, OPTOELECTRONIC DEVICE INCLUDING THE SAME, AND ELECTRONIC APPARATUS INCLUDING THE OPTOELECTRONIC DEVICE

(71) Applicants: Samsung Display Co., Ltd., Yongin-si (KR); Korea University Research And Business Foundation, Seoul (KR)

(72) Inventors: Youngeun Choi, Yongin-si (KR); Han Young Woo, Seoul (KR); Hwasook Ryu, Yongin-si (KR); Chaeyeon Park, Seoul (KR); Seokgyu Yoon, Yongin-si (KR); Minyoung Lim, Seoul (KR); Hyejin Jung, Yongin-si (KR); Min Hun Jee, Seoul (KR)

(73) Assignees: Samsung Display Co., Ltd., Yongin-si (KR); Korea University Research And Business Foundation, Seoul (KR)

(21) Appl. No.: 19/324,306

(22) Filed: Sep. 10, 2025

(30) Foreign Application Priority Data
Dec. 16, 2024 (KR) 10-2024-0187462

(51) Int. Cl. H10K 30/20; H10K 50/11; H10K 65/00

(52) U.S. Cl. CPC H10K 30/20; H10K 65/00; H10K 50/11

(57) ABSTRACT

Embodiments provide an optoelectronic device that includes an organic compound, an electronic apparatus including the optoelectronic device, an electronic equipment including the electronic apparatus, and the organic compound. The optoelectronic device includes a first electrode, a second electrode facing the first electrode, an optical activation layer between the first electrode and the second electrode, and the organic compound. The organic compound is represented by Formula 1, which is explained in the specification:

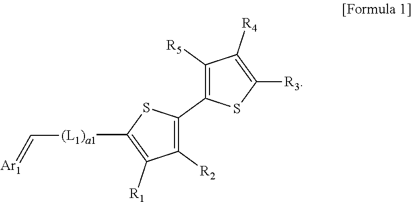

### CROSS-REFERENCE TO RELATED APPLICATION(S)

This application claims priority to and benefits of Korean Patent Application No. 10-2024-0187462 under 35 U.S.C. § 119, filed on Dec. 16, 2024, in the Korean Intellectual Property Office, the entire contents of which are incorporated herein by reference.

### BACKGROUND

### 1. Technical Field

Embodiments relate to an organic compound, an optoelectronic device including the same, and an electronic apparatus including the optoelectronic device.

### 2. Description of the Related Art

Optoelectronic devices are devices that convert optical energy or optical signals into electrical energy or electrical signals. Examples of an optoelectronic device may include an optical or solar cell, which converts optical energy into electrical energy, an optical detector or sensor, which detects and converts optical energy into electrical signals, and the like. An optoelectronic device may include a p-type semiconductor compound that serves as a donor that supplies electrons, and an n-type semiconductor compound that serves as an acceptor that receives electrons.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments include an organic compound having excellent thermal stability and capable of being uniformly deposited to manufacture an optoelectronic device having excellent external quantum efficiency through a deposition process, an optoelectronic device manufactured through a deposition process and having excellent external quantum efficiency, including the organic compound, and an electronic apparatus that absorbs a wide range of light to generate electrical signals, including the optoelectronic device.

Additional aspects will be set forth in part in the description which follows and, in part, will be apparent from the description, or may be learned by practice of the embodiments of the disclosure.

According to embodiments, an optoelectronic device may include a first electrode, a second electrode facing the first electrode, an optical activation layer between the first electrode and the second electrode, and an organic compound represented by Formula 1:

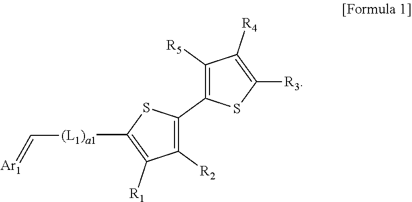

In Formula 1,
R₁ to R₅ may each independently be hydrogen, deuterium, a C₁-C₁₅ alkyl group unsubstituted or substituted with at least one R₀, a C₁-C₁₅ alkoxy group unsubstituted or substituted with at least one R₀, or a C₆-C₁₅ aryl group unsubstituted or substituted with at least one R₀,
R₀ may be deuterium, a C₁-C₁₅ alkyl group, a C₁-C₁₅ alkoxy group, or a C₆-C₁₅ aryl group,
L₁ may be a C₃-C₁₅ carbocyclic group unsubstituted or substituted with at least one R₁₀ₐ or a C₁-C₁₅ heterocyclic group unsubstituted or substituted with at least one R₁₀ₐ,
a1 may be an integer from 0 to 2, wherein when a1 is 0, (L₁)ₐ₁ may be a single bond, and when a1 is 2, two of L₁ may be identical to or different from each other, and
Ar₁ may be a group represented by one of Formulae A1 to A3:

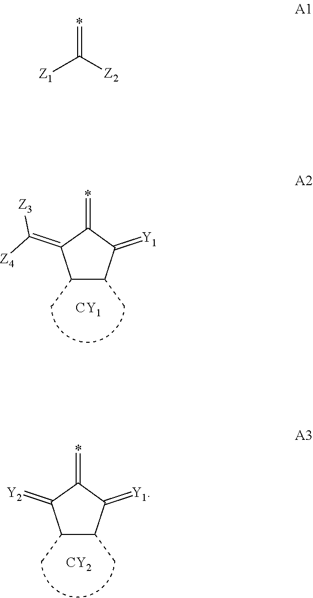

In Formulae A1 to A3,
ring CY₁ and ring CY₂ may each independently be a C₃-C₁₅ carbocyclic group unsubstituted or substituted with at least one R₁₀ₐ or a C₁-C₁ heterocyclic group unsubstituted or substituted with at least one R₁₀ₐ,
Z₁ to Z₄ may each independently be a cyano group, —F, —Cl, —Br, or —I,
Y₁ to Y₃ may each independently be O or S,
* indicates a binding site to a neighboring atom, and
R₁₀ₐ may be:
deuterium, —F, —Cl, —Br, —I, a hydroxyl group, a cyano group, or a nitro group;
a C₁-C₁ alkyl group, a C₂-C₁₅ alkenyl group, a C₂-C₁₅ alkynyl group, or a C₁-C₁₅ alkoxy group, each unsubstituted or substituted with deuterium, —F, —Cl, —Br, —I, a hydroxyl group, a cyano group, a nitro group, a C₃-C₁₅ carbocyclic group, a C₁-C₁₅ heterocyclic group, a C₆-C₁₅ aryloxy group, a C₆-C₁₅ arylthio group, a C₇-C₁₅ arylalkyl group, a C₂₋₁₅ heteroarylalkyl group, or any combination thereof; or
a C₃-C₁₅ carbocyclic group, a C₁-C₁₅ heterocyclic group, a C₆-C₁₅ aryloxy group, a C₆-C₁₅ arylthio group, a C₇-C₁₅ arylalkyl group, or a C₂-C₁₅ heteroarylalkyl group, each unsubstituted or substituted with deuterium, —F, —Cl, —Br, —I, a hydroxyl group, a cyano group, a nitro group, a C₁-C₁₅ alkyl group, a C₂-C₁₅ alkenyl group, a C₂-C₁₅ alkynyl group, a C₁-C₁₅ alkoxy group, a C₃-C₁₅ carbocyclic group, a C₁-C₁₅ heterocyclic group, a C₆-C₁₅ aryloxy group, a C₆-C₁₅ arylthio group, a C₇-C₁₅ arylalkyl group, a C₂-C₁₅ heteroarylalkyl group, or any combination thereof.

In an embodiment, the optoelectronic device may further include a first compound that is different from the organic compound, wherein the first compound may not be a fullerene-based compound.

In an embodiment, the optical activation layer may include the organic compound and the first compound.

In an embodiment, the optical activation layer may include a first layer adjacent to the first electrode and a second layer adjacent to the second electrode, wherein the first layer may include the organic compound, and the second layer may include the first compound.

In an embodiment, the optical activation layer may absorb light having a wavelength in a range of about 400 nm to about 1000 nm.

In an embodiment, the first compound may be represented by one of Formulae 2-1 to 2-6, which are explained below.

In an embodiment, the first compound may be one of Compounds N1 to N43, which are explained below.

According to embodiments, an electronic apparatus may include the optoelectronic device, and a light-emitting device including an emission layer that does not overlap the optical activation layer.

According to embodiments, an electronic equipment may include the electronic apparatus, and a processor for transmitting a signal to the electronic apparatus.

In an embodiment, the electronic equipment may be a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, smart glasses, a head-mounted display, a smart watch, a laser printer, a telephone, a mobile phone, a tablet computer, a phablet, a personal digital assistant (PDA), a wearable device, a laptop computer, a digital camera, a camcorder, a viewfinder, a micro display, a three-dimensional (3D) display, a virtual reality display, an augmented-reality display, a vehicle, a vehicle dashboard, a center information display (CID) for a vehicle, a head-up display for a vehicle, a rearview mirror display, a video wall with multiple displays tiled together, a theater screen, a stadium screen, a phototherapy device, or a signboard.

According to embodiments, an organic compound may be represented by Formula 1, which is explained herein.

In an embodiment, a molecular weight of the organic compound may be equal to or less than about 1,000 g/mol.

In an embodiment, a decomposition temperature of the organic compound may be equal to or greater than about 200° C.

In an embodiment, in Formula 1, R₁ to R₅ may each independently be:
hydrogen, deuterium, a C₁-C₄ alkyl group, a C₁-C₄ alkoxy group, a phenyl group, or a naphthyl group;
a C₁-C₄ alkyl group substituted with at least one deuterium;
a C₁-C₄ alkoxy group substituted with at least one deuterium; or
a phenyl group or a naphthyl group, each unsubstituted or substituted with deuterium, a C₁-C₄ alkyl group, a C₁-C₄ alkoxy group, or any combination thereof.

In an embodiment, in Formula 1, at least one of R₁ to R₅ may each independently be a C₆-C₁₅ aryl group unsubstituted or substituted with at least one R₀.

In an embodiment, the organic compound may be represented by Formula 1-1:

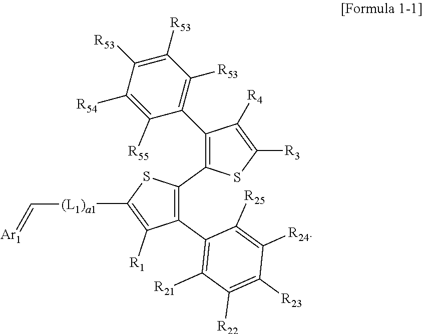

In Formula 1-1,
R₁, R₃, R₄, L₁, a1, and Ar₁ may each be the same as defined in Formula 1,
R₂₁ to R₂₅ may each independently be the same as described in connection with R₂ in Formula 1, and
R₅₁ to R₅₅ may each independently be the same as described in connection with R₅ in Formula 1.

In an embodiment, a1 may be 0; or a1 may be 1, and L₁ may be a benzene group unsubstituted or substituted with at least one R₁₀ₐ, a pyrrole group unsubstituted or substituted with at least one R₁₀ₐ, a furan group unsubstituted or substituted with at least one R₁₀ₐ, a thiophene group unsubstituted or substituted with at least one R₁₀ₐ, or a selenophene group unsubstituted or substituted with at least one R₁₀ₐ.

In an embodiment, in Formulae A2 and A3,
ring CY₁ and ring CY₂ may each independently be a substituted or unsubstituted 5-membered ring, a substituted or unsubstituted 6-membered ring, a substituted or unsubstituted condensed ring in which two 5-membered rings are condensed with each other, a condensed ring in which a 5-membered ring and a 6-membered ring are condensed with each other, or a substituted or unsubstituted condensed ring in which two 6-membered rings are condensed with each other;
the 5-membered ring may be a pyrrole group, a furan group, a thiophene group, an imidazole group, a pyrazole group, an oxazole group, an isoxazole group, or a thiazole group; and
the 6-membered ring may be a benzene group, a pyridine group, a pyrimidine group, or a triazine group.

In an embodiment, in Formulae A2 and A3, ring CY₁ and ring CY₂ may each independently be a group represented by one of Formulae R1 to R5, which are explained below.

In an embodiment, the organic compound may be one of Compounds 1 to 84, which are explained below.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic cross-sectional view of an optoelectronic device according to an embodiment;

FIG. 2 is a schematic cross-sectional view of an optoelectronic device according to an embodiment;

FIG. 3 is a schematic cross-sectional view of an optoelectronic device according to an embodiment;

FIG. 4 is a schematic cross-sectional view of a light-emitting device according to an embodiment;

FIG. 5 is a schematic cross-sectional view of an electronic apparatus according to an embodiment.

FIG. 6 is a schematic cross-sectional view of an electronic apparatus according to another embodiment;

FIG. 7 is a block diagram of an electronic equipment including an electronic apparatus according to an embodiment;

FIG. 8 is a schematic diagram of an electronic equipment according to embodiments;

FIG. 9 is a schematic perspective view of an electronic equipment according to an embodiment;

FIG. 10 is a schematic perspective view of an exterior of a vehicle according to an embodiment;

FIGS. 11A to 11C are each a schematic diagram of an interior of a vehicle according to embodiments;

FIG. 12A is a schematic planar view of the structure of Comparative Compound CE3; and

FIG. 12B is a schematic profile view of the structure of Comparative Compound CE3.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and/or like reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on”, “directly connected to”, or “directly coupled to” another element, there are no intervening elements present. For example, “directly on” may mean that two layers or two elements are disposed without an additional element such as an adhesion element therebetween.

In the specification, the expressions used in the singular such as “a”, “an”, and “the” are intended to include the plural forms as well, unless the context clearly indicates otherwise.

In the specification, the term “and/or” includes any and all combinations of one or more of the associated listed items. For example, “A and/or B” may be understood to mean “A, B, or A and B”. The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of”, modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises”, “comprising”, “includes”, “including”, “have”, “having”, “contains”, “containing”, and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

An optoelectronic device may be employed with a light-emitting device. For example, when an object (for example, a body part of a user of an electronic apparatus) comes into contact with or approaches an electronic apparatus that includes both an optoelectronic device and a light-emitting device, light emitted from the light-emitting device may be reflected from the object and incident onto the optoelectronic device, and the optoelectronic device may absorb the light to generate an electrical signal. Components of the light-emitting device may be formed through a deposition process, and some components of the light-emitting device (for example, common layers such as a hole transport region, an electron transport region, etc.) may be formed with some components of the optoelectronic device by using a substantially same material and a same manufacturing method. Therefore, it is desirable to form an optical activation layer that is included in the optoelectronic device through a deposition process rather than a solution process. However, when the molecular weight of a material for forming components of the optoelectronic device (for example, an optical activation layer) is relatively high, deposition temperature may become excessively high, so that the material may decompose at that deposition temperature.

Therefore, there is a need for materials that exhibit excellent optoelectronic device efficiency while also having high thermal stability during deposition and are thus suitable for use in deposition processes.

### [Optoelectronic Device]

According to an embodiment, an optoelectronic device may include: a first electrode; a second electrode facing the first electrode; an optical activation layer between the first electrode and the second electrode; and an organic compound represented by Formula 1, which will be described below. The optoelectronic device may include a hole transport region between the first electrode and the optical activation layer and an electron transport region between the optical activation layer and the second electrode.

The optoelectronic device may have an excellent level of external quantum efficiency by including the organic compound, absorbs a relatively wide range of light (for example, light having a wavelength in a range of about 400 nm to about 1000 nm), and may be stably, readily, and quickly manufactured through a deposition process.

According to an embodiment, the optical activation layer may include the organic compound. The optical activation layer may include a first compound described below, and the first compound may be different from the organic compound and may not be a fullerene-based compound.

In the specification, the term “fullerene-based compound” refers to any compound that is derived from fullerene or that includes a fullerene group.

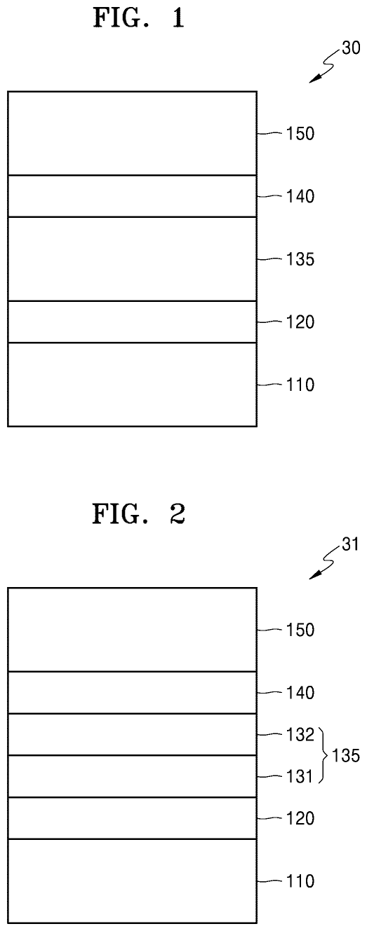

FIG. 1 is a schematic cross-sectional view of an optoelectronic device according to an embodiment.

Referring to FIG. 1, the optoelectronic device 30 may include a first electrode 110, a hole transport region 120 arranged on the first electrode 110, an optical activation layer 135 arranged on the hole transport region 120, an electron transport region 140 arranged on the optical activation layer 135, and a second electrode 150 arranged on the electron transport region 140. The optical activation layer 135 may contact (e.g., directly contact) both the hole transport region 120 and the electron transport region 140. The optical activation layer 135 may be single-layered, and the organic compound and the first compound may be mixed and present in the optical activation layer 135.

FIG. 2 is a schematic cross-sectional view of an optoelectronic device according to an embodiment.

Referring to FIG. 2, the optical activation layer 135 may include a first layer 131 adjacent to the first electrode 110 and a second layer 132 adjacent to the second electrode 150. The first layer 131 may be between the first electrode 110 and the second electrode 150, and the second layer 132 may be between the first layer 131 and the second electrode 150. The first layer 131 may contact (e.g., directly contact) the second layer 132. For example, the optoelectronic device 31 may include a first electrode 110, a hole transport region 120, a first layer 131, a second layer 132, an electron transport region 140, and a second electrode 150, which may be stacked in this stated order. The first layer 131 may include the organic compound and may be referred to as a p-type optical activation layer. The first layer 131 may consist of the organic compound. The second layer 132 may include the first compound and may be referred to as an n-type optical activation layer. The second layer 132 may consist of the first compound. In an embodiment, the optical activation layer 135 may have a two-layered structure in which a p-type optical activation layer 131 including the organic compound and an n-type optical activation layer 132 including the first compound are provided as distinct layers.

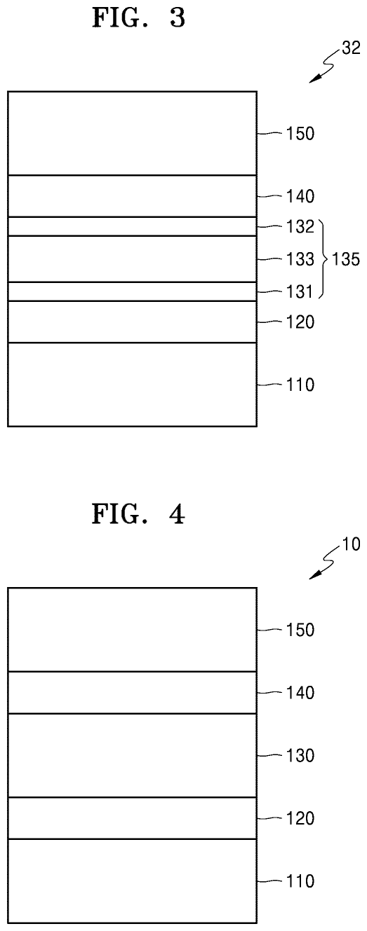

FIG. 3 is a schematic cross-sectional view of an optoelectronic device according to an embodiment.

Referring to FIG. 3, the optical activation layer 135 may include a first layer 131 adjacent to the first electrode 110, a second layer 132 adjacent to the second electrode 150, and a third layer 133 between the first layer 131 and the second layer 132. The third layer 133 may contact (e.g., directly contact) both the first layer 131 and the second layer 132. For example, the optoelectronic device 32 may include a first electrode 110, a hole transport region 120, a first layer 131, a third layer 133, a second layer 132, an electron transport region 140, and a second electrode 150, which may be stacked in this stated order. The organic compound may be present in the first layer 131 and the third layer 133, and the first compound may be present in the second layer 132 and the third layer 133. In an embodiment, the optical activation layer 135 may have a three-layered structure in which a first layer 131 includes the organic compound, a third layer 133 in which the organic compound and the first compound are mixed and present, and a second layer 132 includes the first compound, which are distinct from each other. The third layer 133 may also be referred to as a mixing layer.

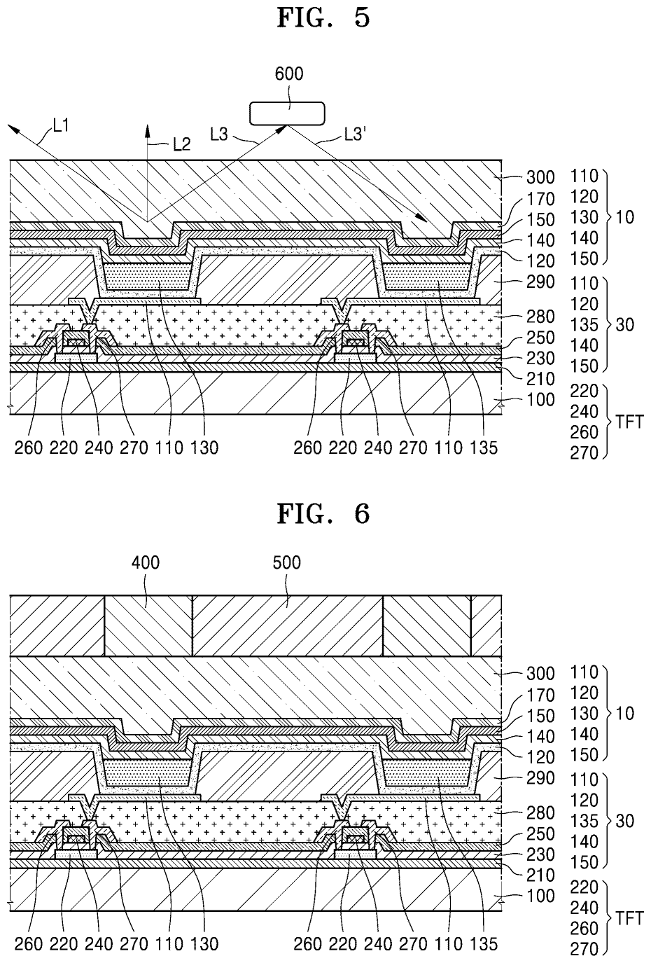

The optical activation layer 135 included in the optoelectronic device 30, 31, and 32 may absorb incident light, thereby generating excitons. The excitons may generate holes and electrons. The holes generated by the optical activation layer 135 may move to the first electrode 110 through the hole transport region 120. The electrons generated by the optical activation layer 135 may move to the second electrode 150 through the electron transport region 140. For example, the optical activation layer 135 may absorb light to generate an electrical signal. For example, the organic compound included in the optical activation layer 135 may serve as a donor that supplies electrons, and the first compound included in the optical activation layer 135 may serve as an acceptor that receives electrons. Therefore, the optoelectronic device 30, 31, and 32 including the optical activation layer 135 may serve as an optical sensor. For example, the optoelectronic device 30, 31, and 32 may serve as fingerprint recognition sensors, which will be described below with reference to FIG. 5.

### [Electronic Apparatus]

According to embodiments, an electronic apparatus may include the above-described optoelectronic device. The electronic apparatus may further include, in addition to the optoelectronic device, a light-emitting device including an emission layer that does not overlap the optical activation layer. For example, the electronic apparatus may be a light-emitting apparatus, an authentication apparatus, or the like.

FIG. 4 is a schematic cross-sectional view of a light-emitting device included in an electronic apparatus according to an embodiment.

The light-emitting device 10 may include a first electrode 110, a hole transport region 120 arranged on the first electrode 110, an emission layer 130 arranged on the hole transport region 120, an electron transport region 140 arranged on the emission layer 130, and a second electrode 150 arranged on the electron transport region 140. The emission layer 130 may not overlap the optical activation layer 135 of FIGS. 1 to 3. Some or all of the hole transport region 120 may be a common layer in the light-emitting device 10 and the optoelectronic device 30, 31, and 32. Some or all of the electron transport region 140 may be a common layer in the light-emitting device 10 and the optoelectronic device 30, 31, and 32.

When the light-emitting device 10 converts an electrical signal into an optical signal and the light emitted from the emission layer 130 is incident onto the optoelectronic device 30, 31, and 32, the optical activation layer 135 may convert the optical signal into an electrical signal. For example, the electronic apparatus may convert electrical signals into optical signals, and may convert optical signals into electrical signals.

[Organic Compound (p-Type Compound)]

According to embodiments, an organic compound may be represented by Formula 1:

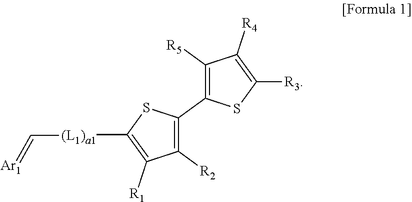

In Formula 1,
R₁ to R₅ may each independently be hydrogen, deuterium, a C₁-C₁₅ alkyl group unsubstituted or substituted with at least one R₀, a C₁-C₁₅ alkoxy group unsubstituted or substituted with at least one R₀, or a C₆-C₁₅ aryl group unsubstituted or substituted with at least one R₀,
R₀ may be deuterium, a C₁-C₁₅ alkyl group, a C₁-C₁₅ alkoxy group, or a C₆-C₁₅ aryl group,
L₁ may be a C₃-C₁₅ carbocyclic group unsubstituted or substituted with at least one R₁₀ₐ or a C₁-C₁ heterocyclic group unsubstituted or substituted with at least one R₁₀ₐ,
a1 may be an integer from 0 to 2, wherein when a1 is 0, (L₁)ₐ₁ may be a single bond, and when a1 is 2, two of L₁ may be identical to or different from each other, and
Ar₁ may be a group represented by one of Formulae A1 to A3:

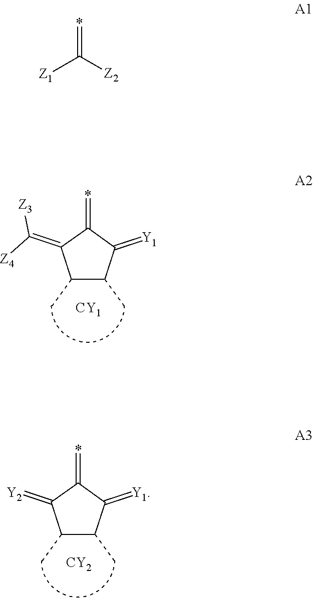

In Formulae A1 to A3,
ring CY₁ and ring CY₂ may each independently be a C₃-C₁₅ carbocyclic group unsubstituted or substituted with at least one R₁₀ₐ or a C₁-C₁₅ heterocyclic group unsubstituted or substituted with at least one R₁₀ₐ,
Z₁ to Z₄ may each independently be a cyano group, —F, —Cl, —Br, or —I,
Y₁ to Y₃ may each independently be O or S,
* indicates a binding site to a neighboring atom, and
R₁₀ₐ may be:
deuterium, —F, —Cl, —Br, —I, a hydroxyl group, a cyano group, or a nitro group;
a C₁-C₁₅ alkyl group, a C₂-C₁₅ alkenyl group, a C₂-C₁₅ alkynyl group, or a C₁-C₁₅ alkoxy group, each unsubstituted or substituted with deuterium, —F, —Cl, —Br, —I, a hydroxyl group, a cyano group, a nitro group, a C₃-C₁₅ carbocyclic group, a C₁-C₁₅ heterocyclic group, a C₆-C₁₅ aryloxy group, a C₆-C₁₅ arylthio group, a C₇-C₁₅ arylalkyl group, a C₂₋₁₅ heteroarylalkyl group, or any combination thereof; or
a C₃-C₁₅ carbocyclic group, a C₁-C₁₅ heterocyclic group, a C₆-C₁₅ aryloxy group, a C₆-C₁₅ arylthio group, a C₇-C₁₅ arylalkyl group, or a C₂-C₁₅ heteroarylalkyl group, each unsubstituted or substituted with deuterium, —F, —Cl, —Br, —I, a hydroxyl group, a cyano group, a nitro group, a C₁-C₁₅ alkyl group, a C₂-C₁₅ alkenyl group, a C₂-C₁₅ alkynyl group, a C₁-C₁₅ alkoxy group, a C₃-C₁₅ carbocyclic group, a C₁-C₁₅ heterocyclic group, a C₆-C₁₅ aryloxy group, a C₆-C₁₅ arylthio group, a C₇-C₁₅ arylalkyl group, a C₂-C₁₅ heteroarylalkyl group, or any combination thereof.

The organic compound may have a structure of donor-spacer-acceptor that are interconnected as shown below, and when a1 is 0, (L₁)ₐ₁ may be a single bond, so that the organic compound has a structure of donor-acceptor:

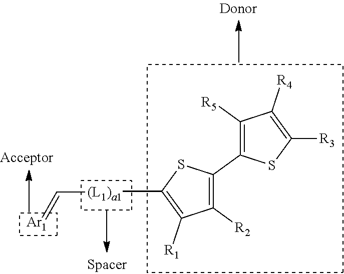

For example, the organic compound may have a structure of donor-(spacer)-acceptor (D-A) that includes an acceptor, which is an Ar group represented by one of Formulae A1 to A3, and may not have a structure of acceptor-(spacer)-donor-(spacer)-acceptor (A-D-A) that includes two acceptors. For example, the organic compound is clearly different from a compound in which at least one of R₁ to R₅ in Formula 1 is a group represented by one of Formulae A1 to A3. The organic compound having a structure of donor-acceptor (D-A) may have a smaller molecular weight than a compound having a structure of acceptor-donor-acceptor (A-D-A).

According to an embodiment, a molecular weight of the organic compound may be equal to or less than about 1,000 g/mol. For example, the molecular weight of the organic compound may be in a range about 400 g/mol to about 1,000 g, in a range of about 450 g/mol to about 1000 g/mol, in a range of about 400 g/mol to about 950 g/mol, in a range of about 400 g/mol to about 900 g/mol, in a range of about 400 g/mol to about 850 g/mol, in a range of about 400 g/mol to about 800 g/mol, or in a range of about 450 g/mol to about 800 g/mol.

According to an embodiment, in Formula 1, R₁ to R₅ may each independently be:
hydrogen, deuterium, a C₁-C₄ alkyl group, a C₁-C₄ alkoxy group, a phenyl group, or a naphthyl group;
a C₁-C₄ alkyl group substituted with at least one deuterium;
a C₁-C₄ alkoxy group substituted with at least one deuterium; and
a phenyl group or a naphthyl group, each unsubstituted or substituted with deuterium, a C₁-C₄ alkyl group, a C₁-C₄ alkoxy group, or any combination thereof.

According to an embodiment, at least one of R₁ to R₅ may each independently be a C₆-C₁₅ aryl group unsubstituted or substituted with at least one R₀.

According to an embodiment, in Formula 1, R₂ and R₅ may each independently be a C₆-C₁₅ aryl group unsubstituted or substituted with at least one R₀, and R₀ may be a C₁-C₁₅ alkyl group. For example, R₂ and R₅ may each independently be a phenyl group substituted with at least one C₁-C₄ alkyl group.

According to an embodiment, the organic compound may be represented by Formula 1-1:

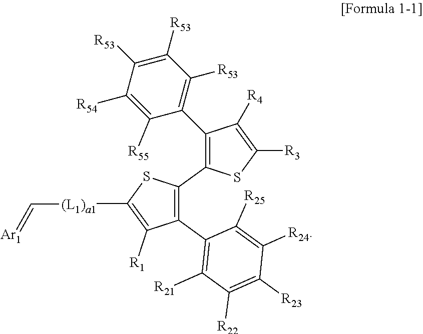

In Formula 1-1,
R₁, R₃, R₄, L₁, a1, and Ar₁ may each be the same as defined in Formula 1,
R₂₁ to R₂₅ may each independently be the same as described in connection with R₂ in Formula 1, and
R₅₁ to R₅₅ may each independently be the same as described in connection with R₅ in Formula 1.

According to an embodiment, the organic compound may be represented by Formula 1-1-1 or Formula 1-1-2:

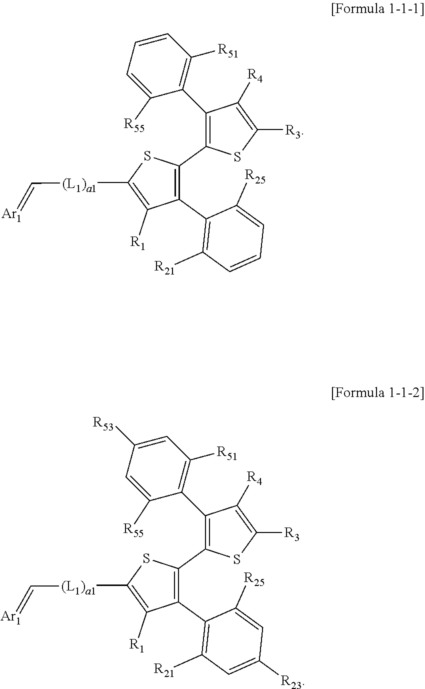

In Formulae 1-1-1 and 1-1-2,
R₁, R₂₁, R₂₃, R₂₅, R₃, R₄, R₅₁, R₅₃, R₅₅, L₁, a1, and Ar₁ may each be the same as defined in Formula 1-1.

According to an embodiment, in Formulae 1, 1-1-1, and 1-1-2,
R₁, R₂₁, R₂₃, R₂₅, R₃, R₄, R₅₁, R₅₃, and R₅₅ may each independently be hydrogen, deuterium, or a C₁-C₄ alkyl group.

According to an embodiment, the donor in the structure of the donor-(spacer)-acceptor (D-A) of Formula 1 may be 3,3′-bis(2,6-dimethylphenyl)-2,2′-bithiophene (i.e., R₁, R₃, and R₄ may each be hydrogen, and R₂ and R₅ may each be a dimethylphenyl group).

According to an embodiment, in Formulae 1, 1-1, 1-1-1, and 1-1-2, a1 may be 0 or 1.

According to an embodiment, in Formulae 1, 1-1, 1-1-1, and 1-1-2,
a1 may be 0; or
a1 may be 1, and L₁ may be a benzene group unsubstituted or substituted with at least one R₁₀ₐ, a pyrrole group unsubstituted or substituted with at least one R₁₀ₐ, a furan group unsubstituted or substituted with at least one R₁₀ₐ, a thiophene group unsubstituted or substituted with at least one R₁₀ₐ, or a selenophene group unsubstituted or substituted with at least one R₁₀ₐ.

According to an embodiment, in Formulae 1, 1-1, 1-1-1, and 1-1-2, L₁ may be a thiophene group unsubstituted or substituted with at least one R₁₀ₐ or a selenophene group unsubstituted or substituted with at least one R₁₀ₐ.

According to an embodiment, in Formulae 1, 1-1, 1-1-1, and 1-1-2, L₁ may be represented by Formula S1 or S2:

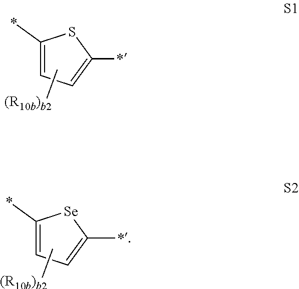

In Formulae S1 and S2,
R_{10b} may be deuterium, a C₁-C₄ alkyl group, or a C₁-C₄ alkoxy group,
b2 may be an integer from 0 to 2, and
* and *′ each indicate a binding site to a neighboring atom.

According to an embodiment, when L₁ is represented by Formula S1, at least one R_{10b} may be a C₁-C₄ alkoxy group.

According to an embodiment, when L₁ is represented by Formula S2, b2 may be 0.

According to an embodiment, in Formula A1, at least one of Z₁ and Z₂ may be a cyano group. For example, Z₁ and Z₂ may each be a cyano group.

According to an embodiment, in Formula A2, at least one of Z₃ and Z₄ may be a cyano group. For example, Z₃ and Z₄ may each be a cyano group.

According to an embodiment, in Formula A2, Y₁ may be O.

According to an embodiment, in Formula A3, at least one of Y₂ and Y₃ may be O.

According to an embodiment, in Formulae A2 and A3, ring CY₁ and ring CY₂ may each independently be:
a substituted or unsubstituted 5-membered ring;
a substituted or unsubstituted 6-membered ring;
a substituted or unsubstituted condensed ring in which two 5-membered rings are condensed with each other;
a substituted or unsubstituted condensed ring in which a 5-membered ring and a 6-membered ring are condensed with each other; or
a substituted or unsubstituted condensed ring in which two 6-membered rings are condensed with each other, wherein each ring is substituted or unsubstituted, wherein
the 5-membered ring may be a pyrrole group, a furan group, a thiophene group, an imidazole group, a pyrazole group, an oxazole group, an isoxazole group, or a thiazole group, and
the 6-membered ring may be a benzene group, a pyridine group, a pyrimidine group, or a triazine group.

According to an embodiment, ring CY₁ and ring CY₂ may each independently include at least one of a benzene group and a thiophene group.

According to an embodiment, in Formulae A2 and A3, ring CY₁ and ring CY₂ may each independently be a group represented by one of Formulae R1 to R5:

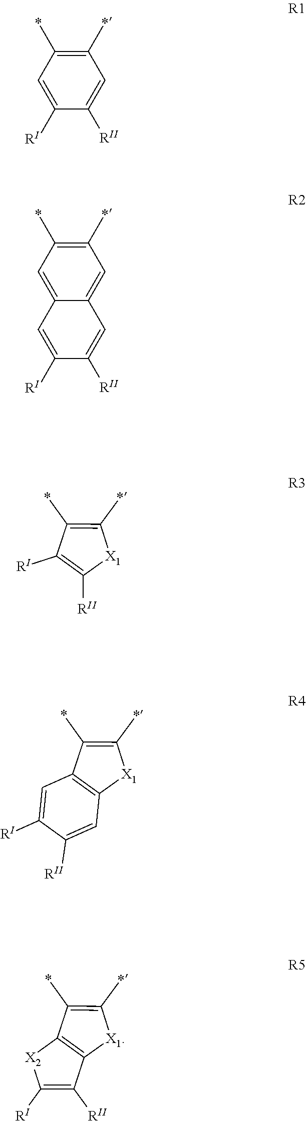

In Formulae R1 to R5,
X₁ may be O, S, N(R^{III}), or C(R^{III})(R^{IV}),
X₂ may be O, S, N(R^{V}), or C(R^{V})(R^{VI}),
R^{I} to R^{VI} may each independently be hydrogen, deuterium, —F, —Cl, —Br, —I, or a cyano group,
* and *′ each indicate a binding site that is condensed with a moiety excluding ring CY₁ and ring CY₂ in Formulae A2 and A3.

According to an embodiment, the optical activation layer may absorb light having a wavelength in a range of about 400 nm to about 1,000 nm. For example, the organic compound may absorb light in a blue wavelength spectrum, a green wavelength spectrum, a red wavelength spectrum, a near-infrared wavelength spectrum, or any combination thereof.

According to an embodiment, a decomposition temperature of the organic compound may be greater than or equal to about be 200° C. For example, the decomposition temperature of the organic compound may be in a range of about 200° C. to about 1,000° C., in a range of about 200° C. to about 900° C., in a range of about 200° C. to about 800° C., in a range of about 200° C. to about 700° C., in a range of about 200° C. to about 600° C., in a range of about 200° C. to about 500° C., in a range of about 250° C. to about 1,000° C., in a range of about 250° C. to about 900° C., in a range of about 250° C. to about 800° C., in a range of about 250° C. to about 700° C., in a range of about 250° C. to about 600° C., in a range of about 250° C. to about 500° C., in a range of about 300° C. to about 1,000° C., in a range of about 300° C. to about 900° C., in a range of about 300° C. to about 800° C., in a range of about 300° C. to about 700° C., in a range of about 300° C. to about 600° C., or in a range of about 300° C. to about 500° C. When the decomposition temperature is within any of these ranges, the organic compound may have excellent thermal stability without being decomposed at a deposition temperature.

According to an embodiment, a highest occupied molecular orbital (HOMO) energy level of the organic compound may be in a range of about −6.5 eV to about −5.0 eV. For example, the HOMO energy level of the organic compound may be in a range of about −6.5 eV to about −5.5 eV. For example, the HOMO energy level of the organic compound may be in a range of about −6.0 eV to about −5.0 eV. For example, the HOMO energy level of the organic compound may be in a range of about −6.0 eV to about −5.5 eV.

According to an embodiment, a lowest unoccupied molecular orbital (LUMO) energy level of the organic compound may be in a range of about −4.5 eV to about −3.0 eV. For example, the LUMO energy level of the organic compound may be in a range of about −4.5 eV to about −3.1 eV. For example, the LUMO energy level of the organic compound may be in a range of about −4.5 eV to about −3.2 eV. For example, the LUMO energy level of the organic compound may be in a range of about −4.3 eV to about −3.0 eV. For example, the LUMO energy level of the organic compound may be in a range of about −4.1 eV to about −3.0 eV.

According to an embodiment, an optical band gap of the organic compound may be in a range of about 1.0 eV to about 4.0 eV. For example, the optical band gap of the organic compound may be in a range of about 1.0 eV to about 3.5 eV, in a range of about 1.0 eV to about 3.0 eV, in a range of about 1.0 eV to about 2.7 eV, in a range of about 1.0 eV to about 2.5 eV, in a range of about 1.0 eV to about 2.4 eV, in a range of about 1.5 eV to about 3.0 eV, in a range of about 1.5 eV to about 2.7 eV, in a range of about 1.5 eV to about 2.5 eV, or in a range of about 1.5 eV to about 2.4 eV.

By satisfying each of the above-described ranges of the HOMO energy level, the LUMO energy level, and the optical band gap, the organic compound may have excellent absorbance and effectively form excitons, and may have excellent compatibility with the first compound represented by any one of Formulae 2-1 to 2-6 for effectively transferring electrons.

According to an embodiment, the organic compound may be one of Compounds 1 to 84:

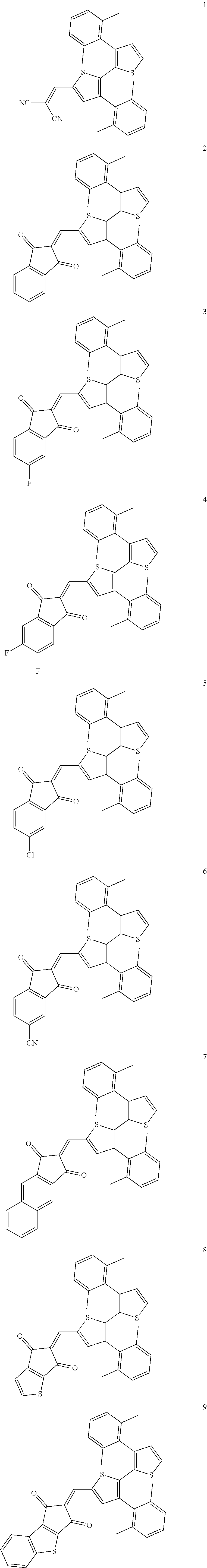

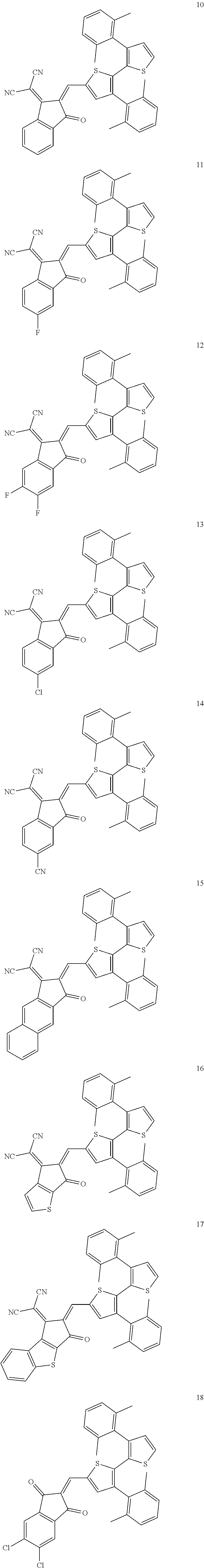

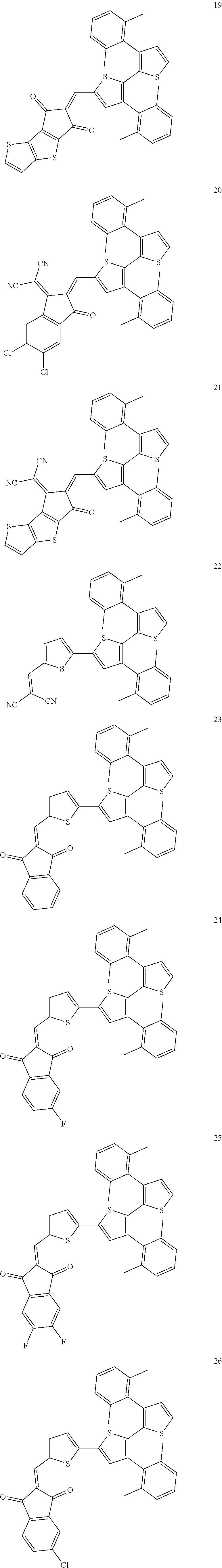

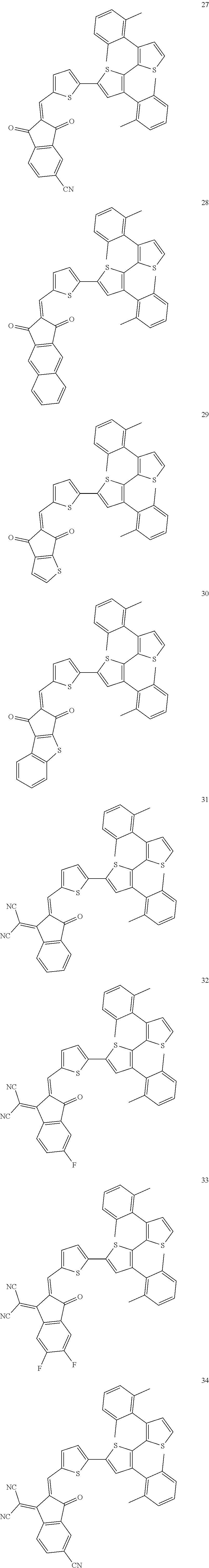

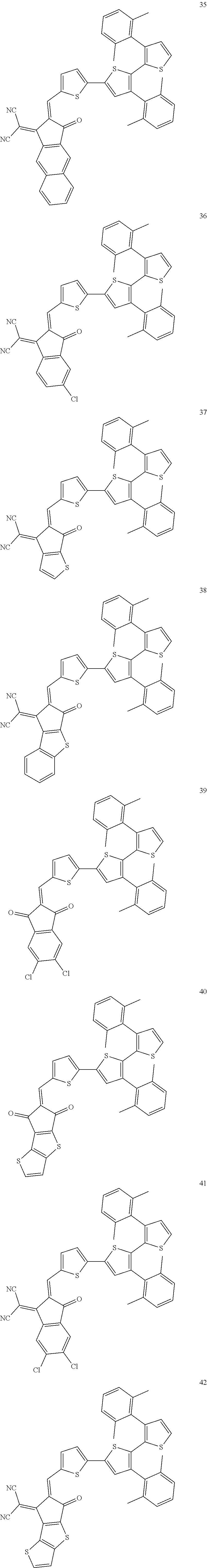

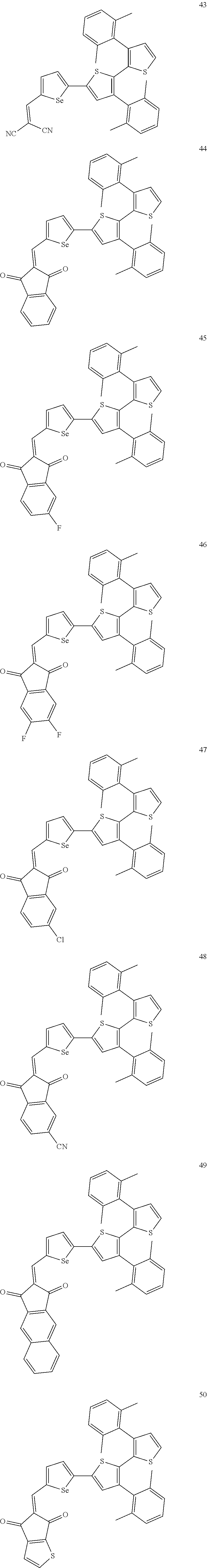

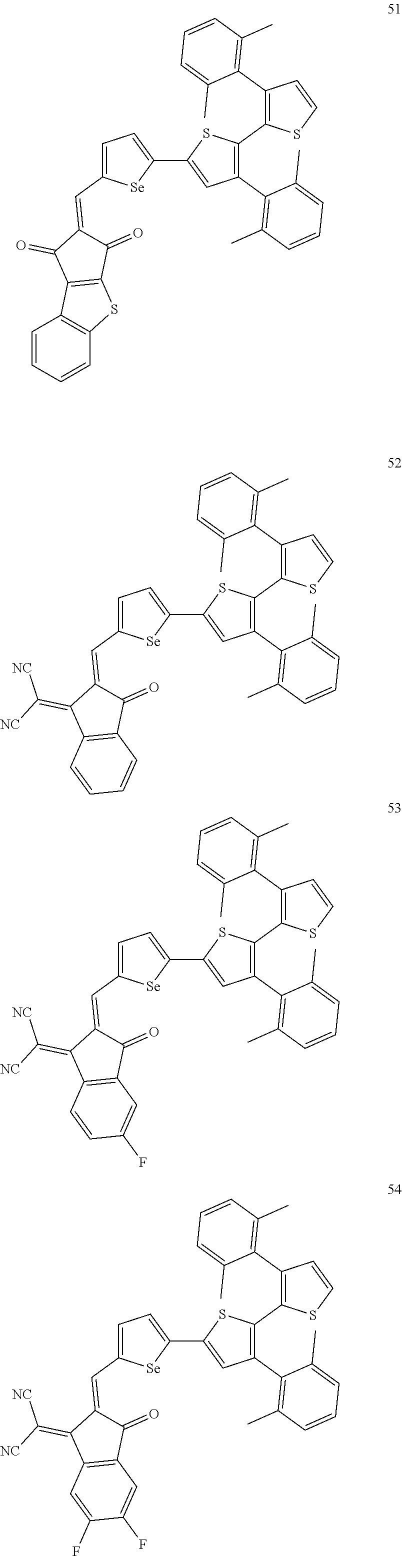 [SMILES: Cc1cccc(C)c1-c1ccsc1-c1sc(-c2ccc(/C=C3\C(=O)c4sc5ccccc5c4C3=O)[se]2)cc1-c1c(C)cccc1C ; Cc1cccc(C)c1-c1ccsc1-c1sc(-c2ccc(/C=C3\C(=O)c4ccccc4C3=C(C#N)C#N)[se]2)cc1-c1c(C)cccc1C ; Cc1cccc(C)c1-c1ccsc1-c1sc(-c2ccc(/C=C3\C(=O)c4cc(F)ccc4C3=C(C#N)C#N)[se]2)cc1-c1c(C)cccc1C ; Cc1cccc(C)c1-c1ccsc1-c1sc(-c2ccc(/C=C3\C(=O)c4cc(F)c(F)cc4C3=C(C#N)C#N)[se]2)cc1-c1c(C)cccc1C]

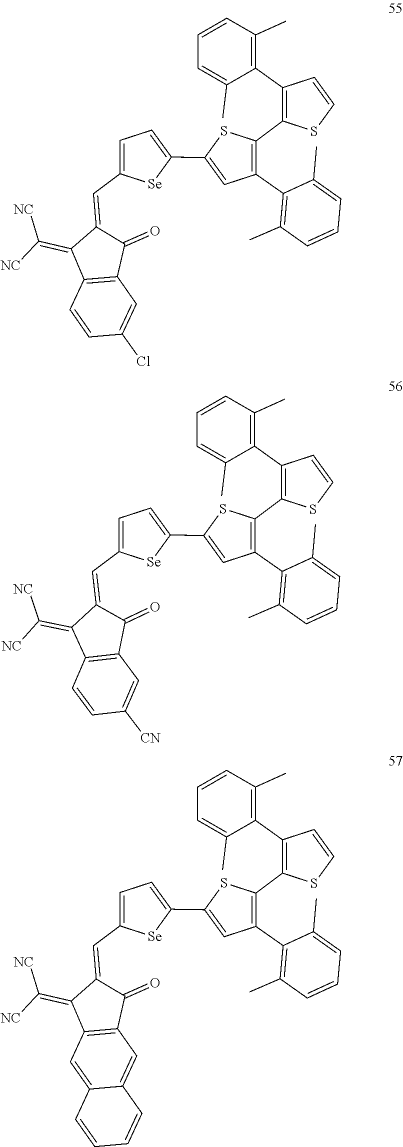 [SMILES: Cc1cccc(C)c1-c1ccsc1-c1sc(-c2ccc(/C=C3\C(=O)c4cc(Cl)ccc4C3=C(C#N)C#N)[se]2)cc1-c1c(C)cccc1C ; Cc1cccc(C)c1-c1ccsc1-c1sc(-c2ccc(/C=C3\C(=O)c4cc(C#N)ccc4C3=C(C#N)C#N)[se]2)cc1-c1c(C)cccc1C ; Cc1cccc(C)c1-c1ccsc1-c1sc(-c2ccc(/C=C3\C(=O)c4cc5ccccc5cc4C3=C(C#N)C#N)[se]2)cc1-c1c(C)cccc1C]

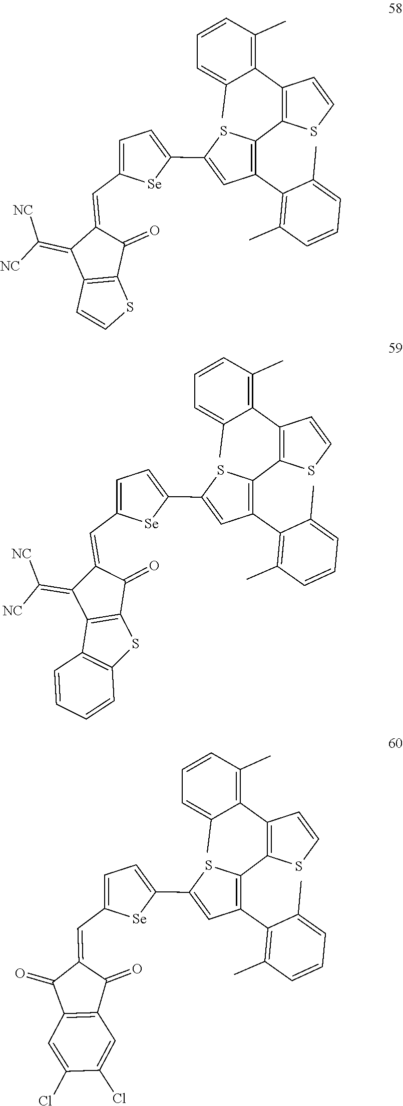 [SMILES: Cc1cccc(C)c1-c1ccsc1-c1sc(-c2ccc(/C=C3\C(=O)c4sccc4C3=C(C#N)C#N)[se]2)cc1-c1c(C)cccc1C ; Cc1cccc(C)c1-c1ccsc1-c1sc(-c2ccc(/C=C3\C(=O)c4sc5ccccc5c4C3=C(C#N)C#N)[se]2)cc1-c1c(C)cccc1C ; Cc1cccc(C)c1-c1ccsc1-c1sc(-c2ccc(C=C3C(=O)c4cc(Cl)c(Cl)cc4C3=O)[se]2)cc1-c1c(C)cccc1C]

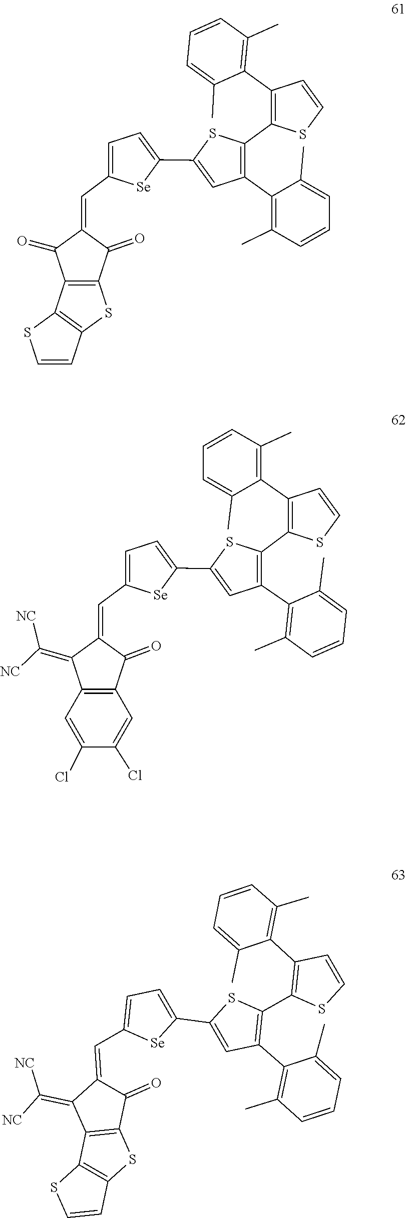 [SMILES: Cc1cccc(C)c1-c1ccsc1-c1sc(-c2ccc(/C=C3\C(=O)c4sc5ccsc5c4C3=O)[se]2)cc1-c1c(C)cccc1C ; Cc1cccc(C)c1-c1ccsc1-c1sc(-c2ccc(/C=C3\C(=O)c4cc(Cl)c(Cl)cc4C3=C(C#N)C#N)[se]2)cc1-c1c(C)cccc1C ; Cc1cccc(C)c1-c1ccsc1-c1sc(-c2ccc(/C=C3\C(=O)c4sc5ccsc5c4C3=C(C#N)C#N)[se]2)cc1-c1c(C)cccc1C]

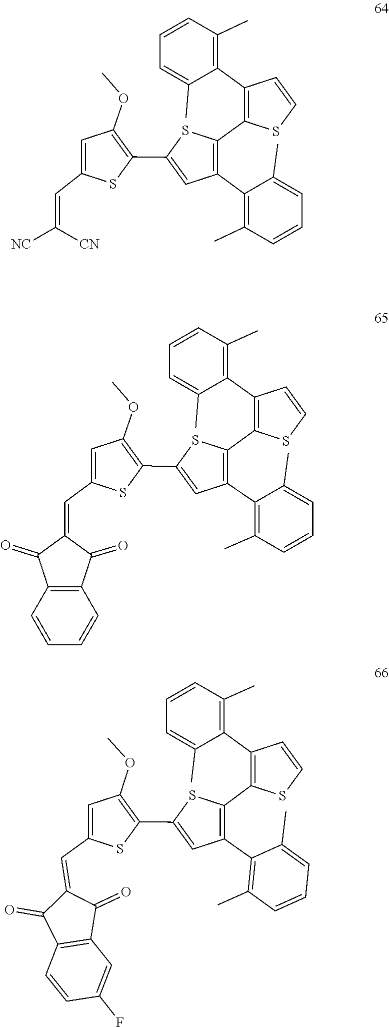 [SMILES: COc1cc(C=C(C#N)C#N)sc1-c1cc(-c2c(C)cccc2C)c(-c2sccc2-c2c(C)cccc2C)s1 ; COc1cc(C=C2C(=O)c3ccccc3C2=O)sc1-c1cc(-c2c(C)cccc2C)c(-c2sccc2-c2c(C)cccc2C)s1 ; COc1cc(/C=C2/C(=O)c3ccc(F)cc3C2=O)sc1-c1cc(-c2c(C)cccc2C)c(-c2sccc2-c2c(C)cccc2C)s1]

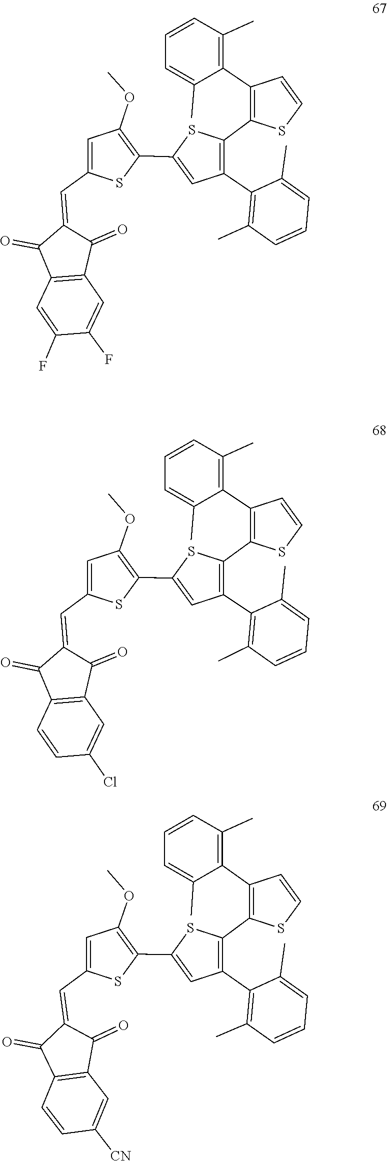 [SMILES: COc1cc(C=C2C(=O)c3cc(F)c(F)cc3C2=O)sc1-c1cc(-c2c(C)cccc2C)c(-c2sccc2-c2c(C)cccc2C)s1 ; COc1cc(/C=C2/C(=O)c3ccc(Cl)cc3C2=O)sc1-c1cc(-c2c(C)cccc2C)c(-c2sccc2-c2c(C)cccc2C)s1 ; COc1cc(/C=C2/C(=O)c3ccc(C#N)cc3C2=O)sc1-c1cc(-c2c(C)cccc2C)c(-c2sccc2-c2c(C)cccc2C)s1]

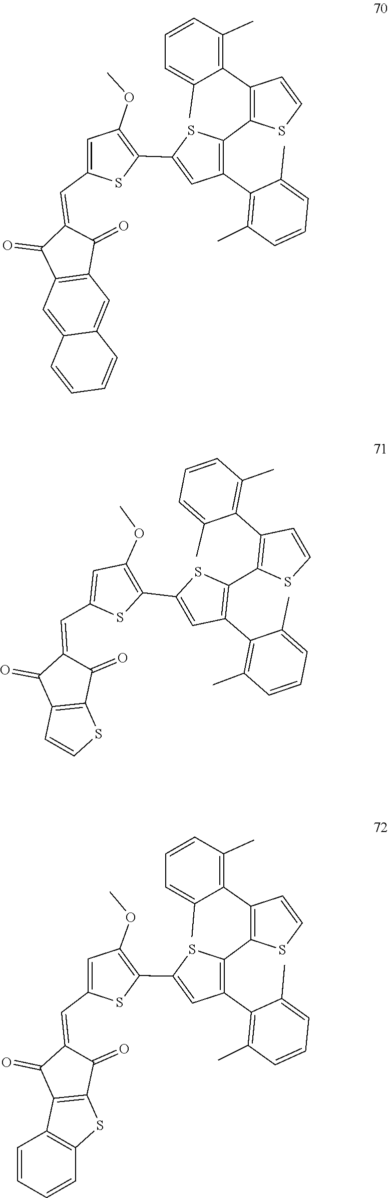 [SMILES: COc1cc(C=C2C(=O)c3cc4ccccc4cc3C2=O)sc1-c1cc(-c2c(C)cccc2C)c(-c2sccc2-c2c(C)cccc2C)s1 ; COc1cc(/C=C2/C(=O)c3ccsc3C2=O)sc1-c1cc(-c2c(C)cccc2C)c(-c2sccc2-c2c(C)cccc2C)s1 ; COc1cc(/C=C2\C(=O)c3sc4ccccc4c3C2=O)sc1-c1cc(-c2c(C)cccc2C)c(-c2sccc2-c2c(C)cccc2C)s1]

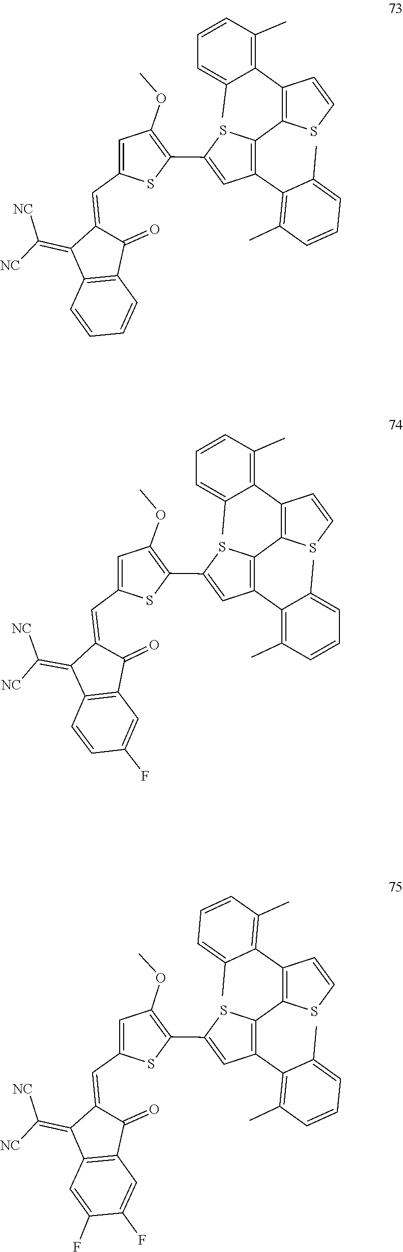 [SMILES: COc1cc(/C=C2\C(=O)c3ccccc3C2=C(C#N)C#N)sc1-c1cc(-c2c(C)cccc2C)c(-c2sccc2-c2c(C)cccc2C)s1 ; COc1cc(/C=C2\C(=O)c3cc(F)ccc3C2=C(C#N)C#N)sc1-c1cc(-c2c(C)cccc2C)c(-c2sccc2-c2c(C)cccc2C)s1 ; COc1cc(/C=C2\C(=O)c3cc(F)c(F)cc3C2=C(C#N)C#N)sc1-c1cc(-c2c(C)cccc2C)c(-c2sccc2-c2c(C)cccc2C)s1]

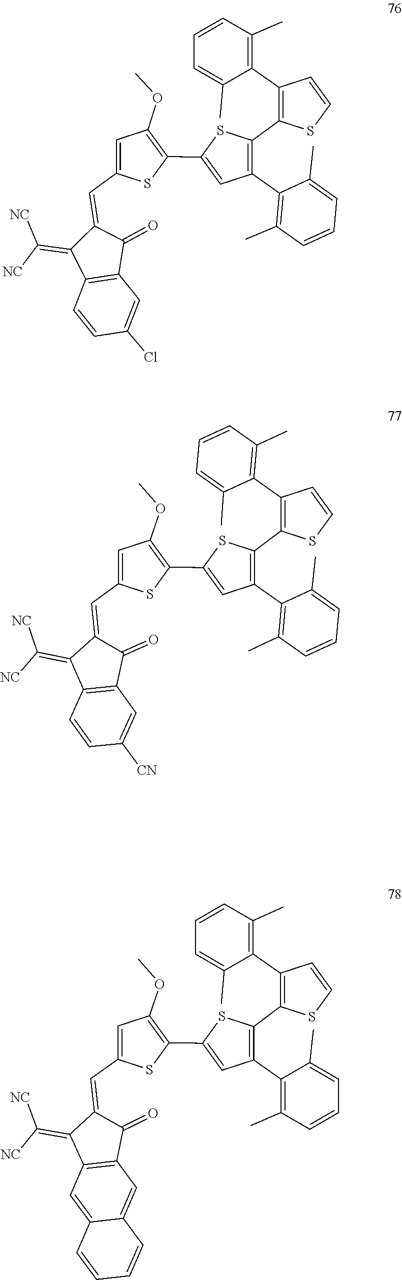 [SMILES: COc1cc(/C=C2\C(=O)c3cc(Cl)ccc3C2=C(C#N)C#N)sc1-c1cc(-c2c(C)cccc2C)c(-c2sccc2-c2c(C)cccc2C)s1 ; COc1cc(/C=C2\C(=O)c3cc(C#N)ccc3C2=C(C#N)C#N)sc1-c1cc(-c2c(C)cccc2C)c(-c2sccc2-c2c(C)cccc2C)s1 ; COc1cc(/C=C2\C(=O)c3cc4ccccc4cc3C2=C(C#N)C#N)sc1-c1cc(-c2c(C)cccc2C)c(-c2sccc2-c2c(C)cccc2C)s1]

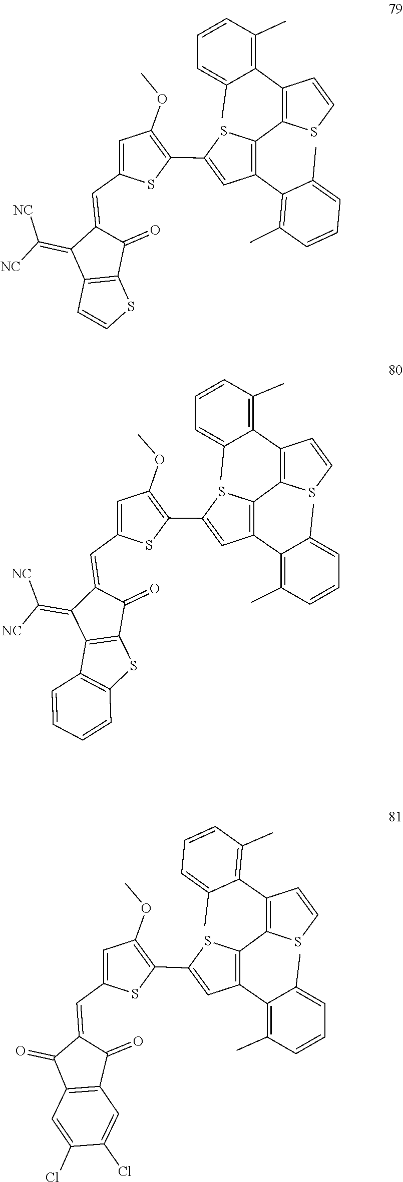 [SMILES: COc1cc(/C=C2\C(=O)c3sccc3C2=C(C#N)C#N)sc1-c1cc(-c2c(C)cccc2C)c(-c2sccc2-c2c(C)cccc2C)s1 ; COc1cc(/C=C2\C(=O)c3sc4ccccc4c3C2=C(C#N)C#N)sc1-c1cc(-c2c(C)cccc2C)c(-c2sccc2-c2c(C)cccc2C)s1 ; COc1cc(C=C2C(=O)c3cc(Cl)c(Cl)cc3C2=O)sc1-c1cc(-c2c(C)cccc2C)c(-c2sccc2-c2c(C)cccc2C)s1]

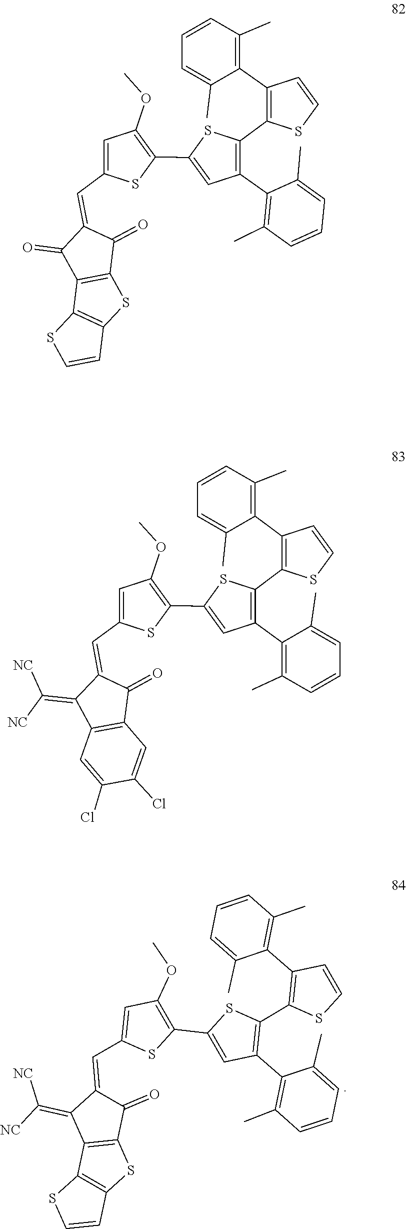 [SMILES: COc1cc(/C=C2\C(=O)c3sc4ccsc4c3C2=O)sc1-c1cc(-c2c(C)cccc2C)c(-c2sccc2-c2c(C)cccc2C)s1 ; COc1cc(/C=C2\C(=O)c3cc(Cl)c(Cl)cc3C2=C(C#N)C#N)sc1-c1cc(-c2c(C)cccc2C)c(-c2sccc2-c2c(C)cccc2C)s1 ; COc1cc(/C=C2\C(=O)c3sc4ccsc4c3C2=C(C#N)C#N)sc1-c1cc(-c2c(C)cccc2C)c(-c2sccc2-c2c(C)cccc2C)s1]

Since the above-described organic compound has a structure of donor-(spacer)-acceptor, the organic compound may have a molecular weight smaller than that of a compound having a structure of acceptor-(spacer)-donor-(spacer)-acceptor. Since the organic compound includes only one acceptor and accordingly has a small molecular weight, the deposition temperature may be low and thus thermal stability may be high during deposition. Therefore, the optical activation layer including the organic compound may be readily and quickly manufactured through a deposition process without having to perform a solution process. The organic compound may be referred to as an organic compound for thin film deposition.

Since the organic compound has a skeleton combining the above-described structure of the donor, the above-described structure of the spacer, and the above-described structure of the acceptor, the organic compound may absorb light in a blue wavelength spectrum, a green wavelength spectrum, a red wavelength spectrum, a near-infrared wavelength spectrum, or any combination spectrum thereof, and may have an excellent level of external quantum efficiency (FOE).

In an embodiment, when the planarity of a compound included in the optical activation layer manufactured through a deposition process is high, the compounds may aggregate with each other and accordingly the optical activation layer may not be uniformly deposited, so that the layer arranged above and the layer arranged below the optical activation layer may come into contact with each other. For example, in an optoelectronic device having a stacked structure of hole transport layer/p-type optical activation layer/n-type optical activation layer/electron transport layer, when a compound with high planarity is used during a deposition process of the p-type optical activation layer, the hole transport layer and the n-type optical activation layer may contact each other, thereby lowering EQE. Therefore, when a compound with high planarity is applied, it may be useful to form an optical activation layer with a large thickness so that the upper and lower layers do not come into contact.

According to an embodiment, since R₁ to R₅ in Formula 1 may be selected from the group described above, the planarity of the organic compound may be lowered, so that a degree of aggregation between the organic compounds may be reduced, and thus an optoelectronic device having an excellent level of EQE may be manufactured with a relatively small thickness.

[First Compound (n-Type Compound)]

According to embodiments, the first compound described above may be represented by one of Formulae 2-1 to 2-6:

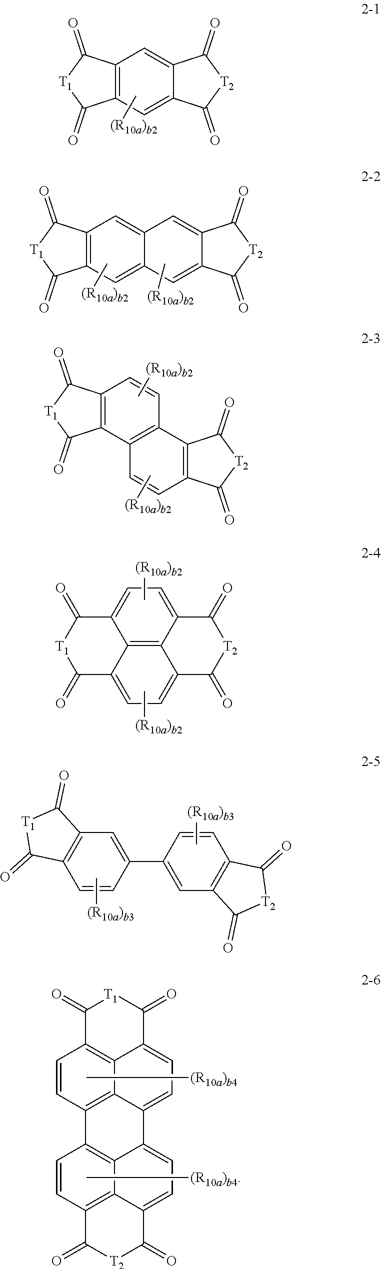

In Formulae 2-1 to 2-6,
T₁ may be O, S, N(R₆₁), C(R₆₁)(R₆₂), C(═O), C(═S), or C═C(R₆₁)(R₆₂),
T₂ may be O, S, N(R₆₃), C(R₆₃)(R₆₄), C(═O), C(═S), or C═C(R₆₃)(R₆₄),
R₆₁ to R₆₄ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ arylalkyl group, a C₂-C₆₀ heteroarylalkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
R₁₀ₐ may be the same as described herein,
Q₁ to Q₃ may each independently be:
hydrogen, deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, or a C₁-C₆₀ alkoxy group; or
a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or any combination thereof,
b2 may be an integer from 0 to 2,
b3 may be an integer from 0 to 3, and
b4 may be an integer from 0 to 4.

Thus, the first compound may be clearly different from a fullerene-based compound.

According to an embodiment, R₆₁ to R₆₄ may each independently be a C₁-C₆₀ alkyl group, a C₃-C₁₀ cycloalkyl group, a C₆-C₆₀ aryl group, or a C₁-C₆₀ heteroaryl group, each unsubstituted or substituted with deuterium, —F, —Cl, —Br, —I, a cyano group, a C₁-C₆₀ alkyl group, a C₁-C₆₀ alkoxy group, or any combination thereof.

According to an embodiment, the first compound may be one of Compounds N1 to N43:

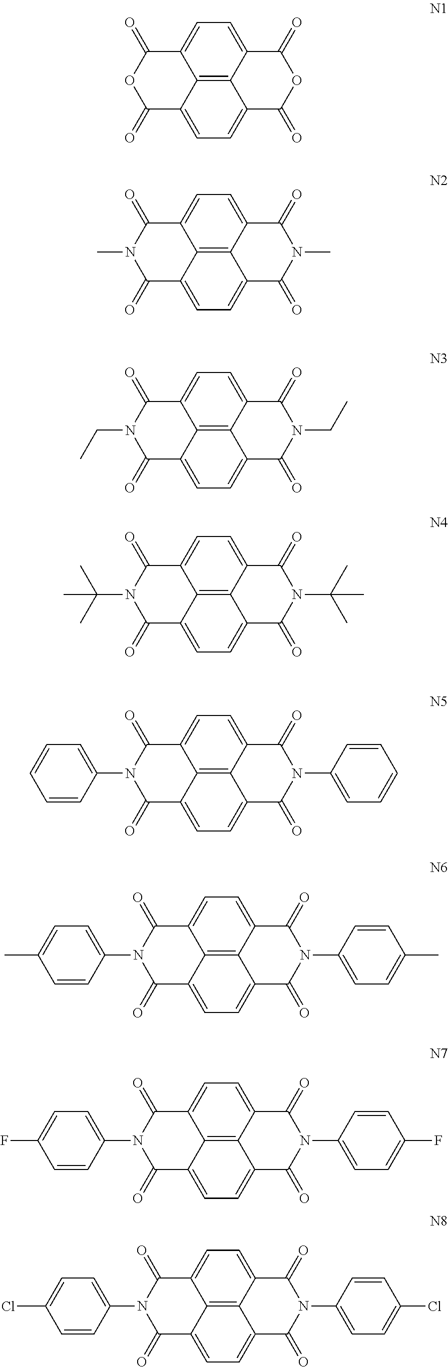

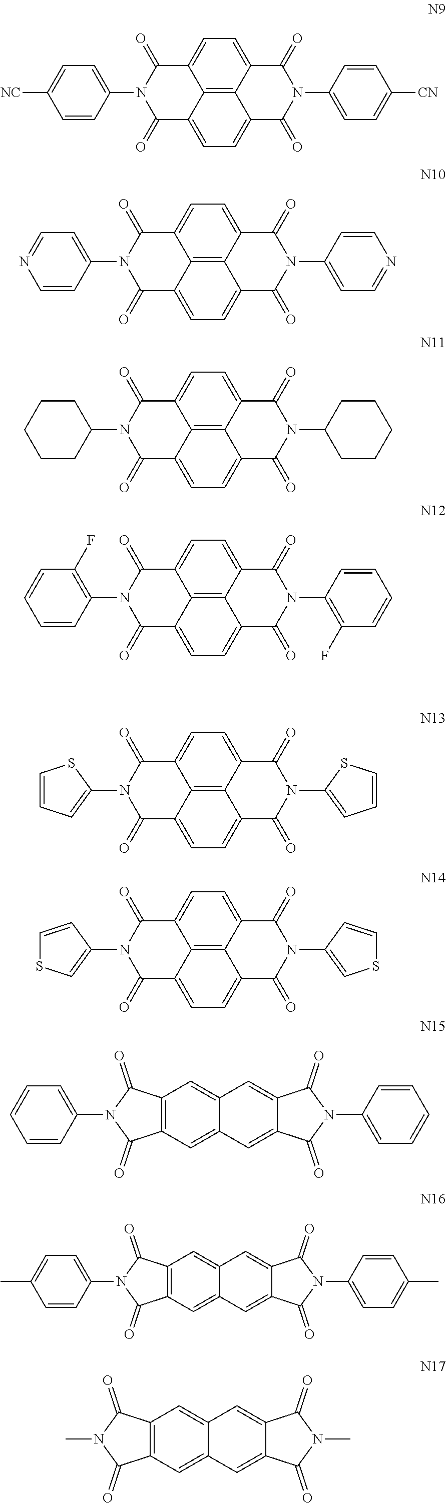

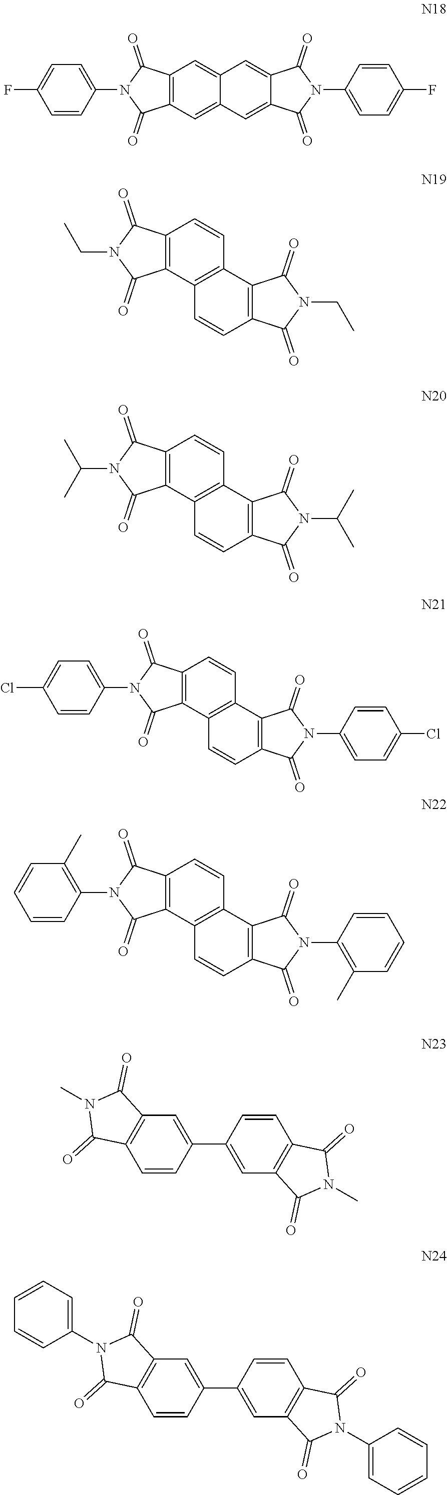

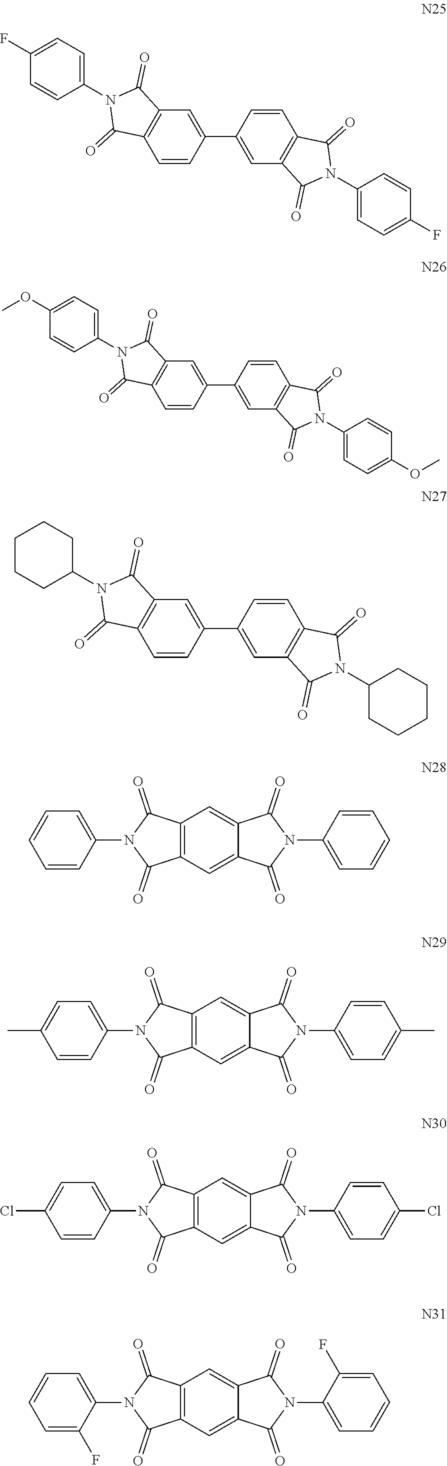

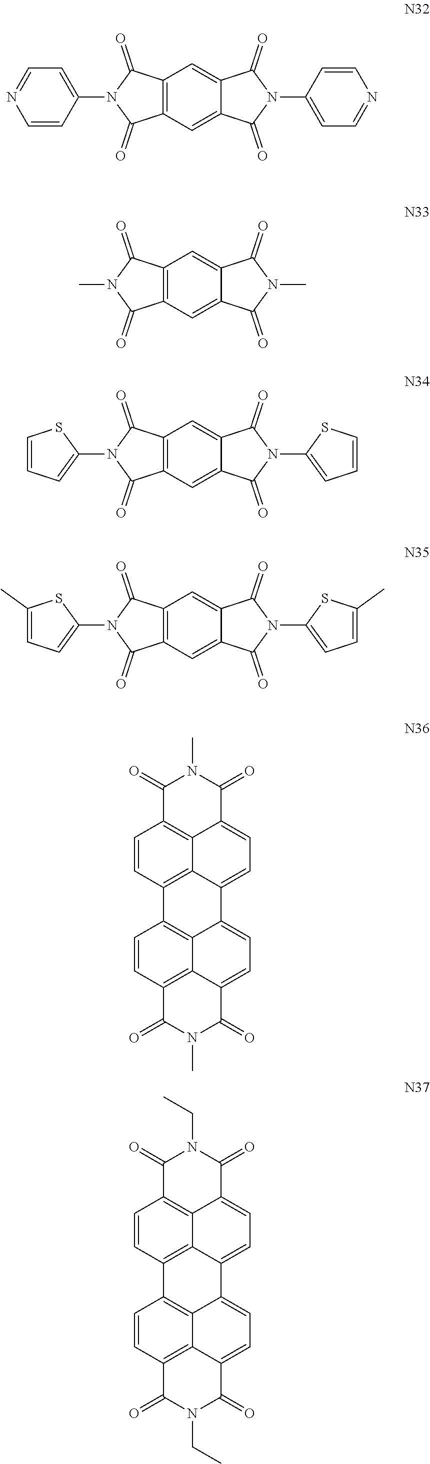

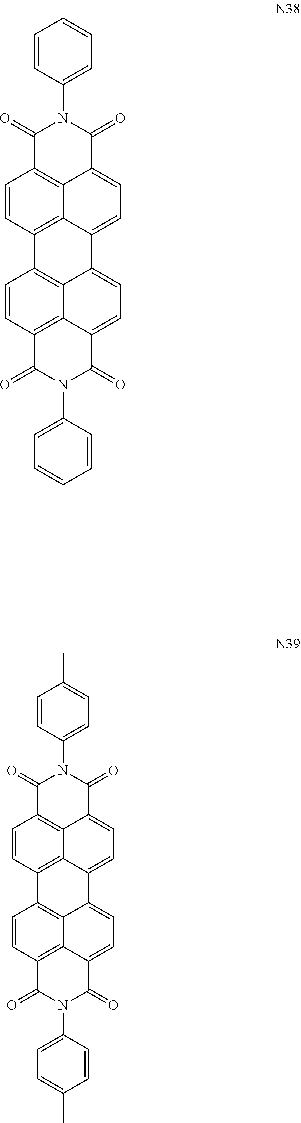 [SMILES: O=C1c2ccc3c4ccc5c6c(ccc(c7ccc(c2c37)C(=O)N1c1ccccc1)c64)C(=O)N(c1ccccc1)C5=O ; Cc1ccc(N2C(=O)c3ccc4c5ccc6c7c(ccc(c8ccc(c3c48)C2=O)c75)C(=O)N(c2ccc(C)cc2)C6=O)cc1]

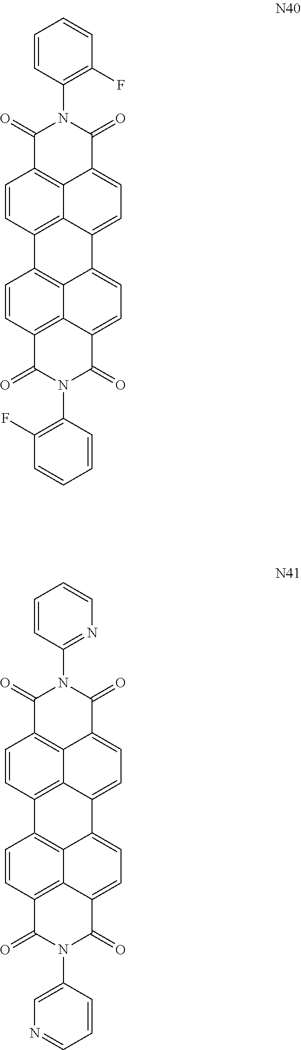 [SMILES: O=C1c2ccc3c4ccc5c6c(ccc(c7ccc(c2c37)C(=O)N1c1ccccc1F)c64)C(=O)N(c1ccccc1F)C5=O ; O=C1c2ccc3c4ccc5c6c(ccc(c7ccc(c2c37)C(=O)N1c1cccnc1)c64)C(=O)N(c1ccccn1)C5=O]

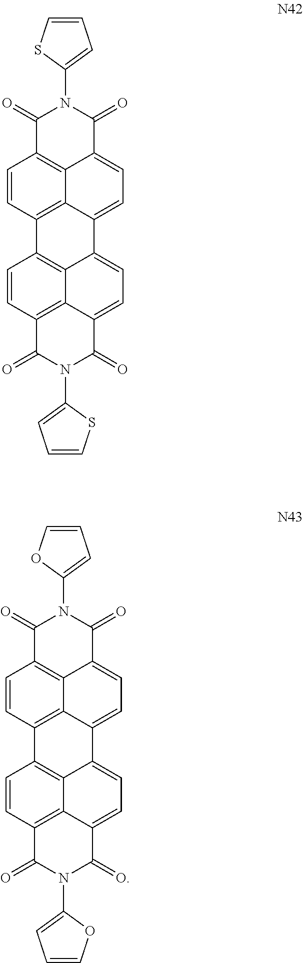 [SMILES: O=C1c2ccc3c4ccc5c6c(ccc(c7ccc(c2c37)C(=O)N1c1cccs1)c64)C(=O)N(c1cccs1)C5=O ; O=C1c2ccc3c4ccc5c6c(ccc(c7ccc(c2c37)C(=O)N1c1ccco1)c64)C(=O)N(c1ccco1)C5=O]

### [First Electrode 110]

In FIGS. 1 to 4, a substrate may be further included under the first electrode 110 or on the second electrode 120. The substrate may be a glass substrate or a plastic substrate. The substrate may be a flexible substrate. For example, the substrate may include plastics with excellent heat resistance and durability, such as polyimide, polyethylene terephthalate (PET), polycarbonate, polyethylene naphthalate, polyarylate (PAR), polyetherimide, or any combination thereof.

The first electrode 110 may be formed by, for example, depositing or sputtering a material for forming the first electrode 110 on the substrate. When the first electrode 110 is an anode, a material for forming the first electrode 110 may be a high work function material to facilitate injection of holes.

The first electrode 110 may be a reflective electrode, a transflective electrode, or a transmissive electrode. When the first electrode 110 is a transmissive electrode, a material for forming the first electrode 110 may include indium tin oxide (ITO), indium zinc oxide (IZO), tin oxide (SnO₂), zinc oxide (ZnO), or any combination thereof. In embodiments, when the first electrode 110 is a transflective electrode or a reflective electrode, a material for forming the first electrode 110 may include magnesium (Mg), silver (Ag), aluminum (Al), aluminum-lithium (Al—Li), calcium (Ca), magnesium-indium (Mg—In), magnesium-silver (Mg—Ag), or any combination thereof.

The first electrode 110 may have a structure consisting of a single layer or a structure including multiple layers. In an embodiment, the first electrode 110 may have a three-layered structure of ITO/Ag/ITO.

### [Hole Transport Region 120]

The hole transport region 120 may have a structure consisting of a layer consisting of a single material, a structure consisting of a layer including different materials, or a structure including multiple layers including different materials.

The hole transport region 120 may include a hole injection layer, a hole transport layer, an emission auxiliary layer, an electron-blocking layer, or any combination thereof.

In embodiments, the hole transport region 120 may have a multi-layered structure, such as a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron-blocking layer structure, wherein the layers of each structure may be stacked from the first electrode 110 in its respective stated order, but the structure of the hole transport region 120 is not limited thereto.

In embodiments, the hole transport region 120 may include a compound represented by Formula 201, a compound represented by Formula 202, or any combination thereof:

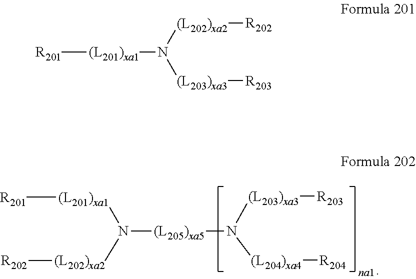

In Formulae 201 and 202,
L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—*′, *—S—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
R₂₀₁ and R₂₀₂ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group (for example, a carbazole group, etc.) unsubstituted or substituted with at least one R₁₀ₐ (for example, Compound HT16, etc.),
R₂₀₃ and R₂₀₄ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and
na1 may be an integer from 1 to 4.

In an embodiment, the compound represented by Formula 201 and the compound represented by Formula 202 may each independently include at least one of groups represented by Formulae CY201 to CY217:

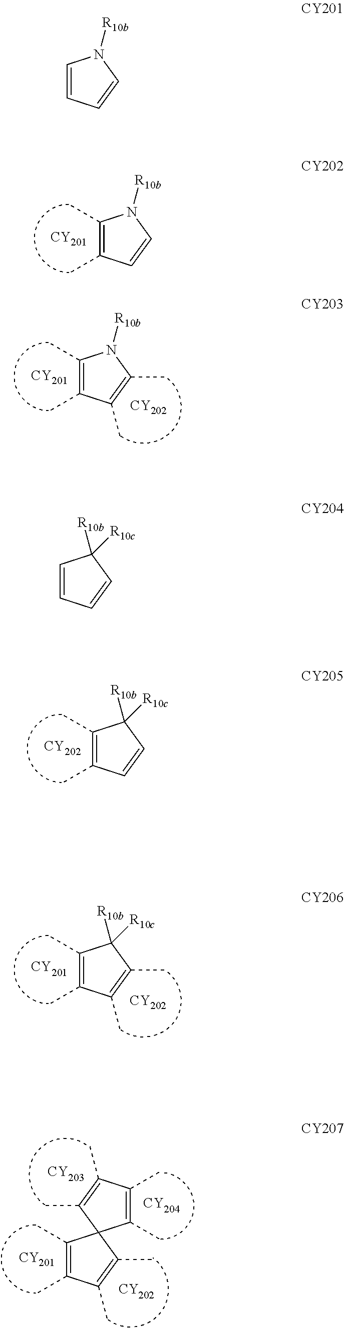

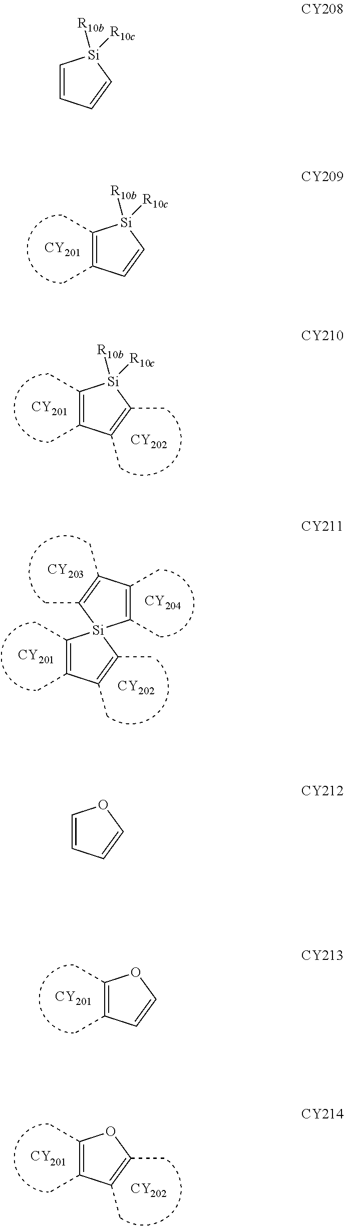

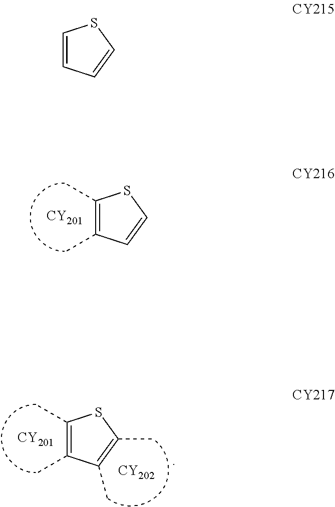

In Formulae CY201 to CY217, R_{10b} and R_{10c} may each independently be the same as described in connection with R₁₀ₐ, ring CY₂₀₁ to ring CY₂₀₄ may each independently be a C₃-C₂₀ carbocyclic group or a C₁-C₂₀ heterocyclic group, and at least one hydrogen in Formulae CY201 to CY217 may be unsubstituted or substituted with R₁₀ₐ.

According to an embodiment, in Formulae CY201 to CY217, ring CY₂₀₁ to ring CY₂₀₄ may each independently be a benzene group, a naphthalene group, a phenanthrene group, or an anthracene group.

According to embodiments, the compound represented by Formula 201 and the compound represented by Formula 202 may each independently include at least one of groups represented by Formulae CY201 to CY203.

According to embodiments, the compound represented by Formula 201 may include at least one of groups represented by Formulae CY201 to CY203 and at least one of groups represented by Formulae CY204 to CY217.

According to embodiments, in Formula 201, xa1 may be 1, R₂₀₁ may be a group represented by one of Formulae CY201 to CY203, xa2 may be 0, and R₂₀₂ may be a group represented by one of Formulae CY204 to CY207.

According to embodiments, the compound represented by Formula 201 and the compound represented by Formula 202 may each not include groups represented by Formulae CY201 to CY203.

According to embodiments, the compound represented by Formula 201 and the compound represented by Formula 202 may each not include groups represented by Formulae CY201 to CY203, and may each independently include at least one of groups represented by Formulae CY204 to CY217.

In an embodiment, the compound represented by Formula 201 and the compound represented by Formula 202 may each not include groups represented by Formulae CY201 to CY217.

In an embodiment, the hole transport region 120 may include one of Compounds HT1 to HT46, m-MTDATA, TDATA, 2-TNATA, NPB (NPD), p-NPB, TPD, Spiro-TPD, Spiro-NPB, methylated NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), or any combination thereof:

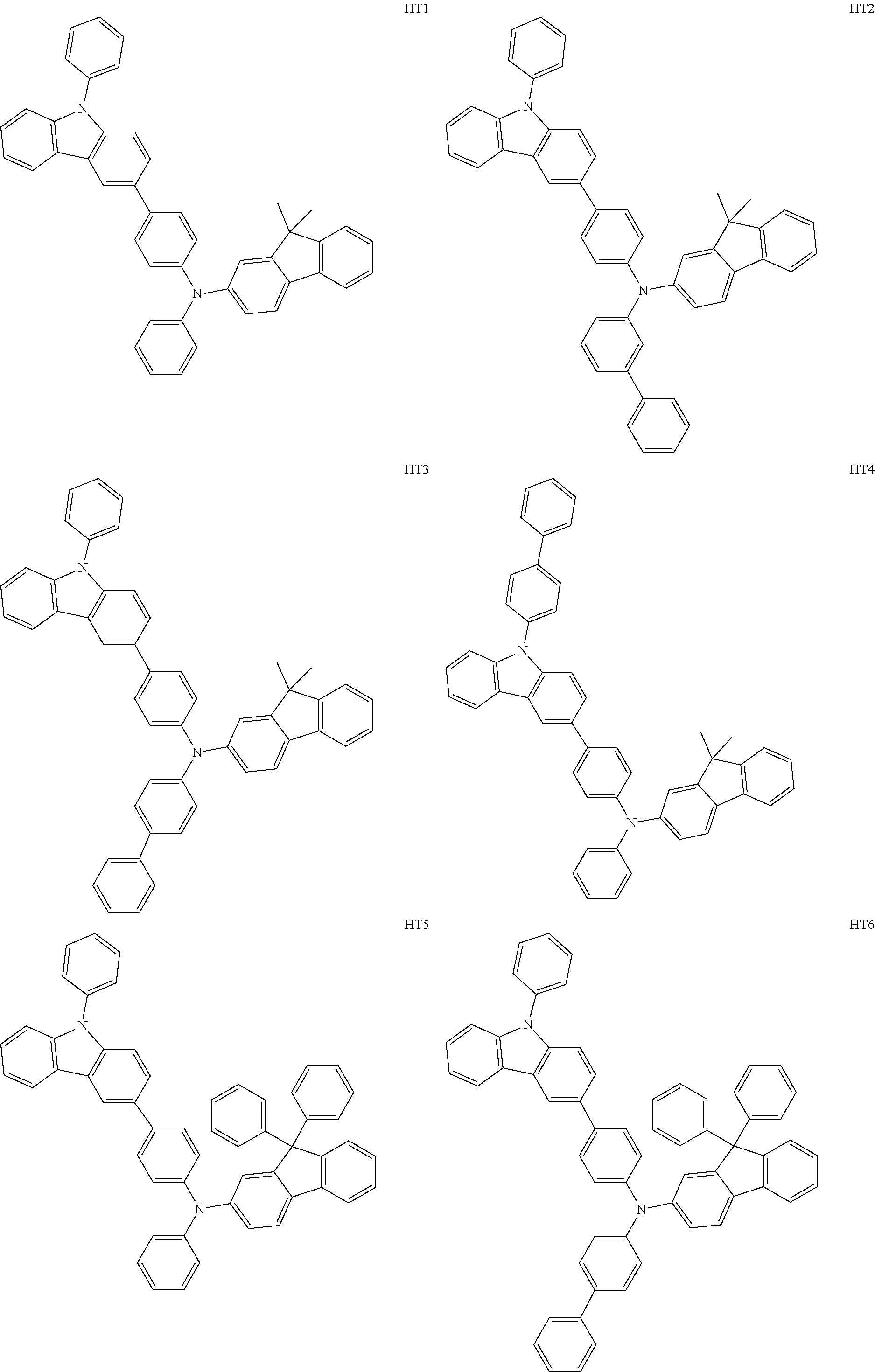

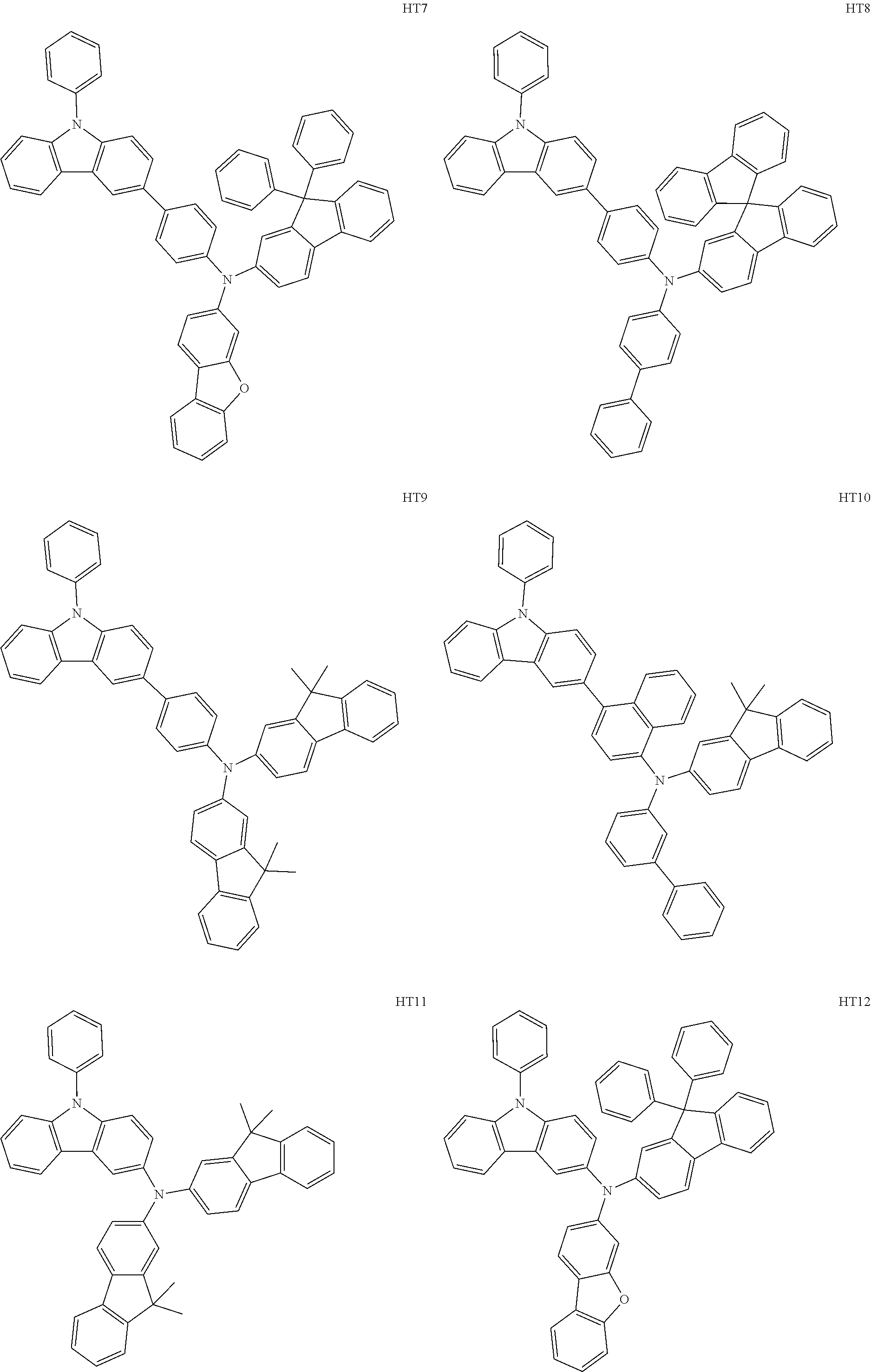

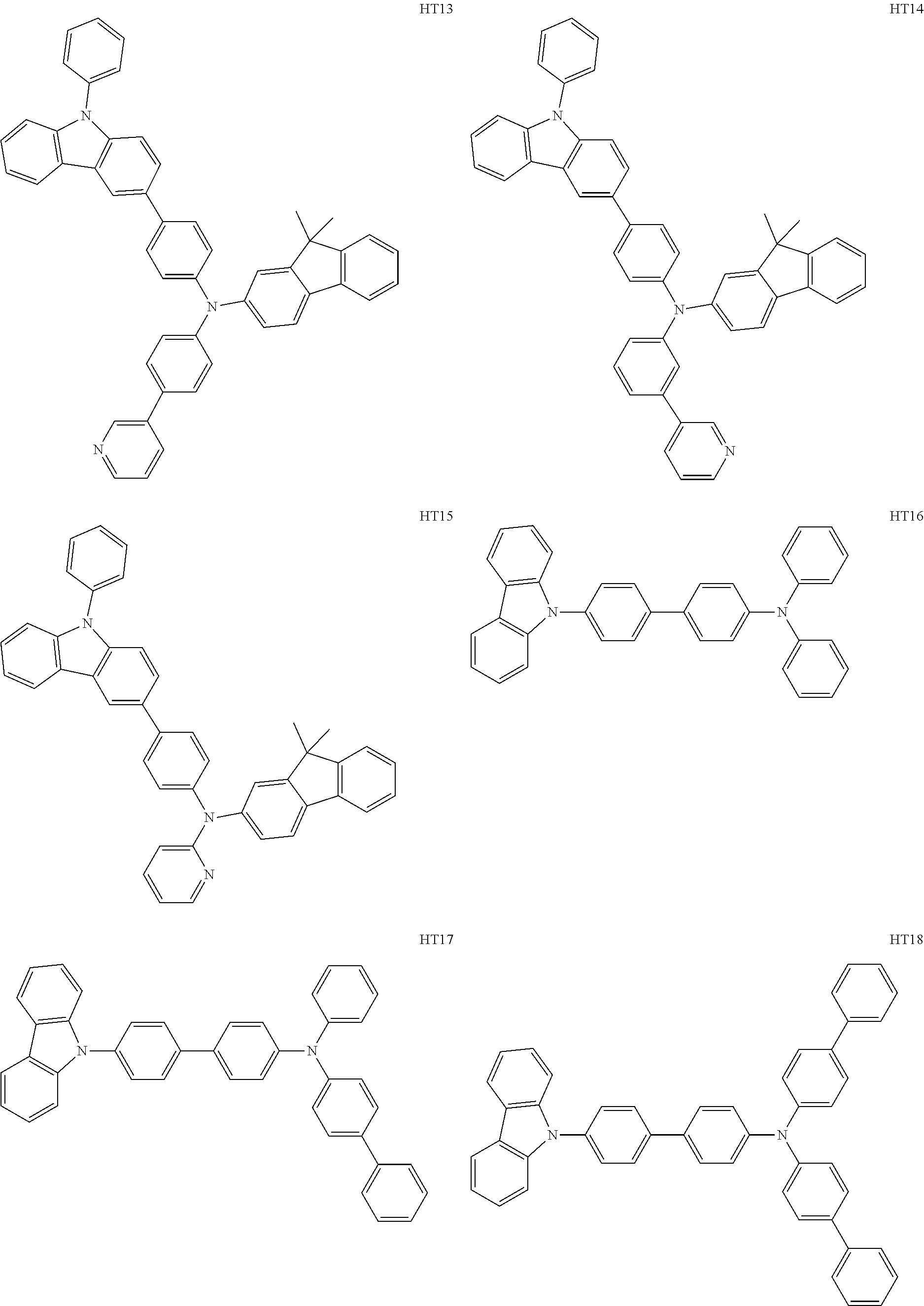

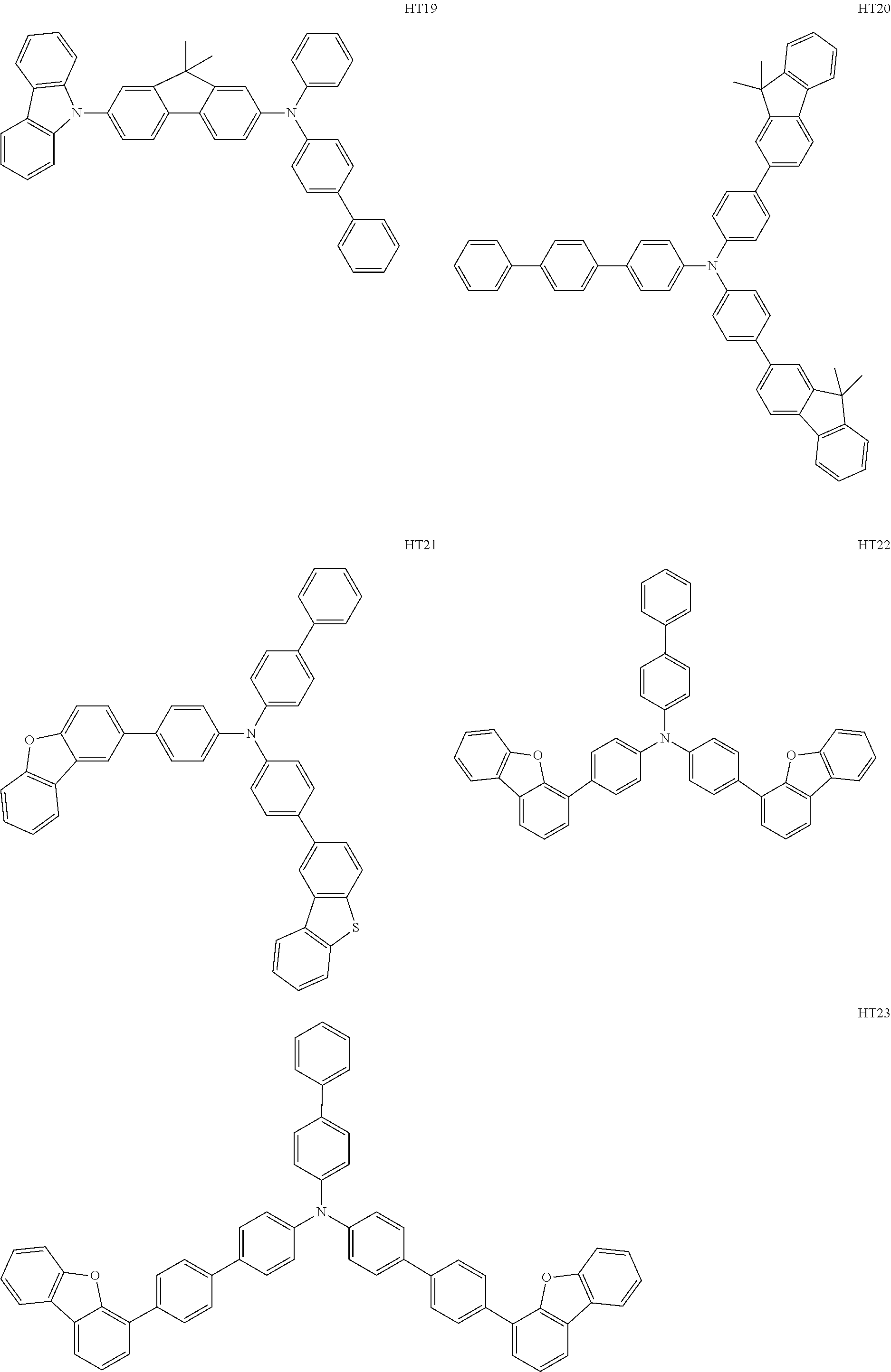

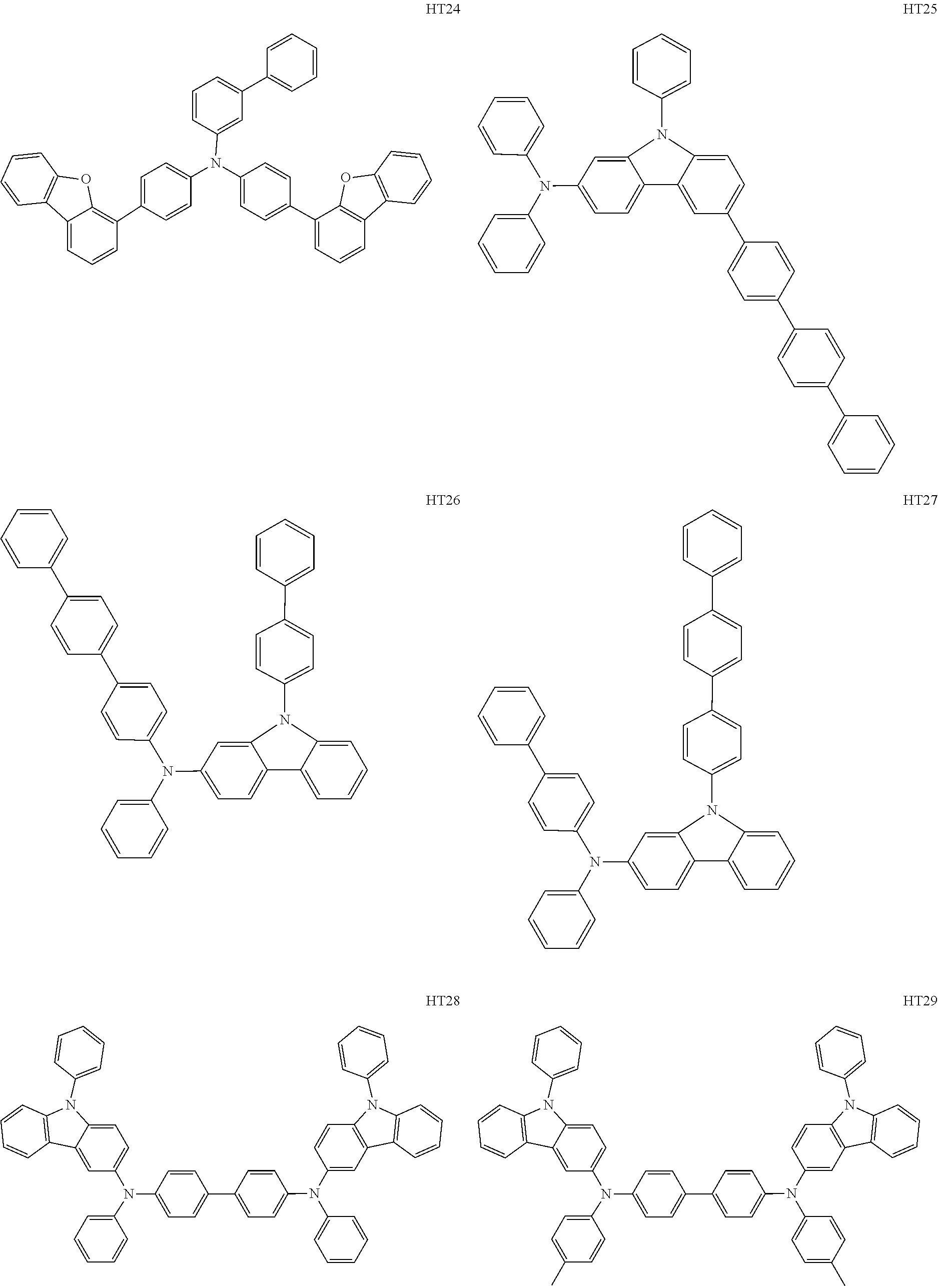

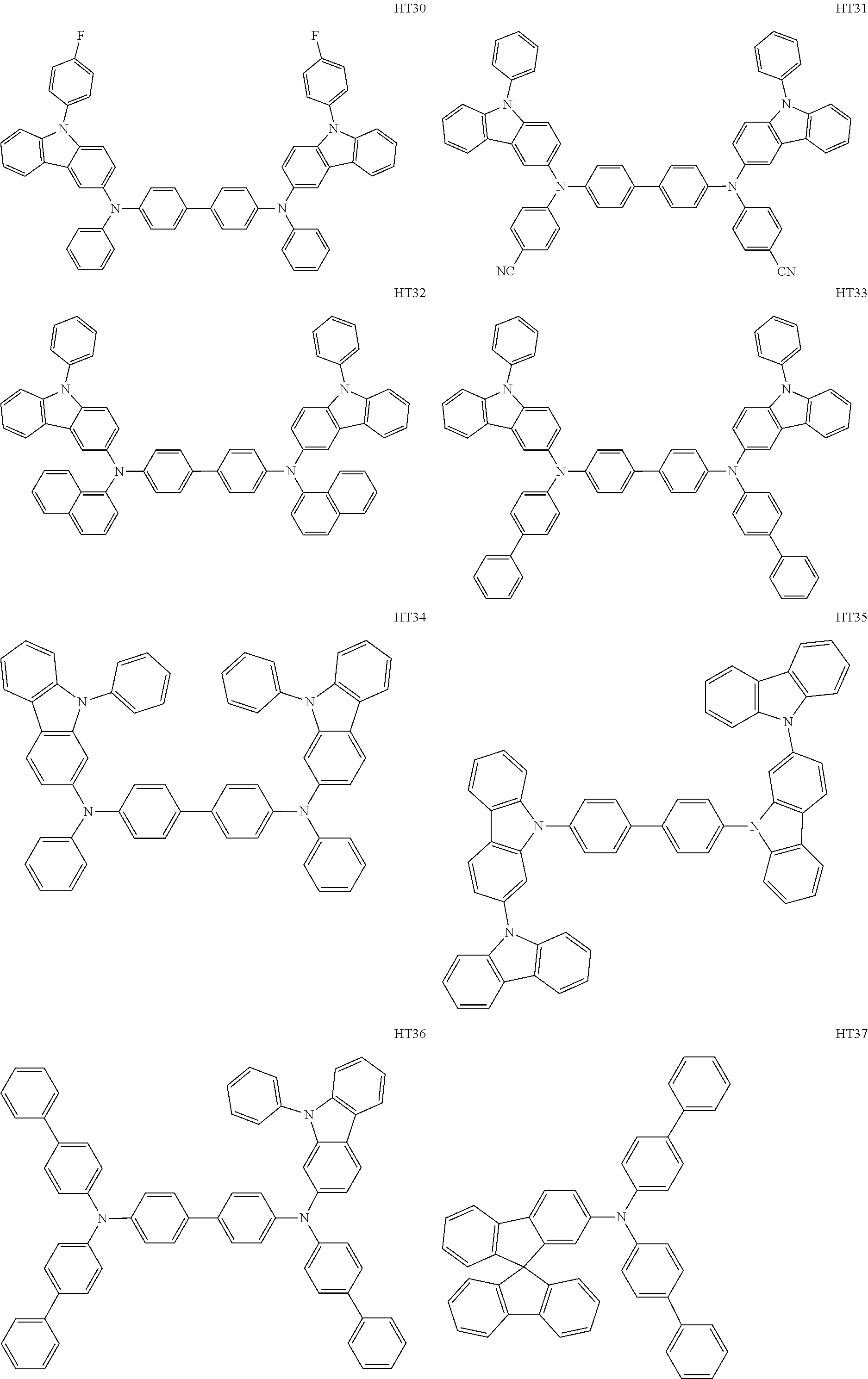

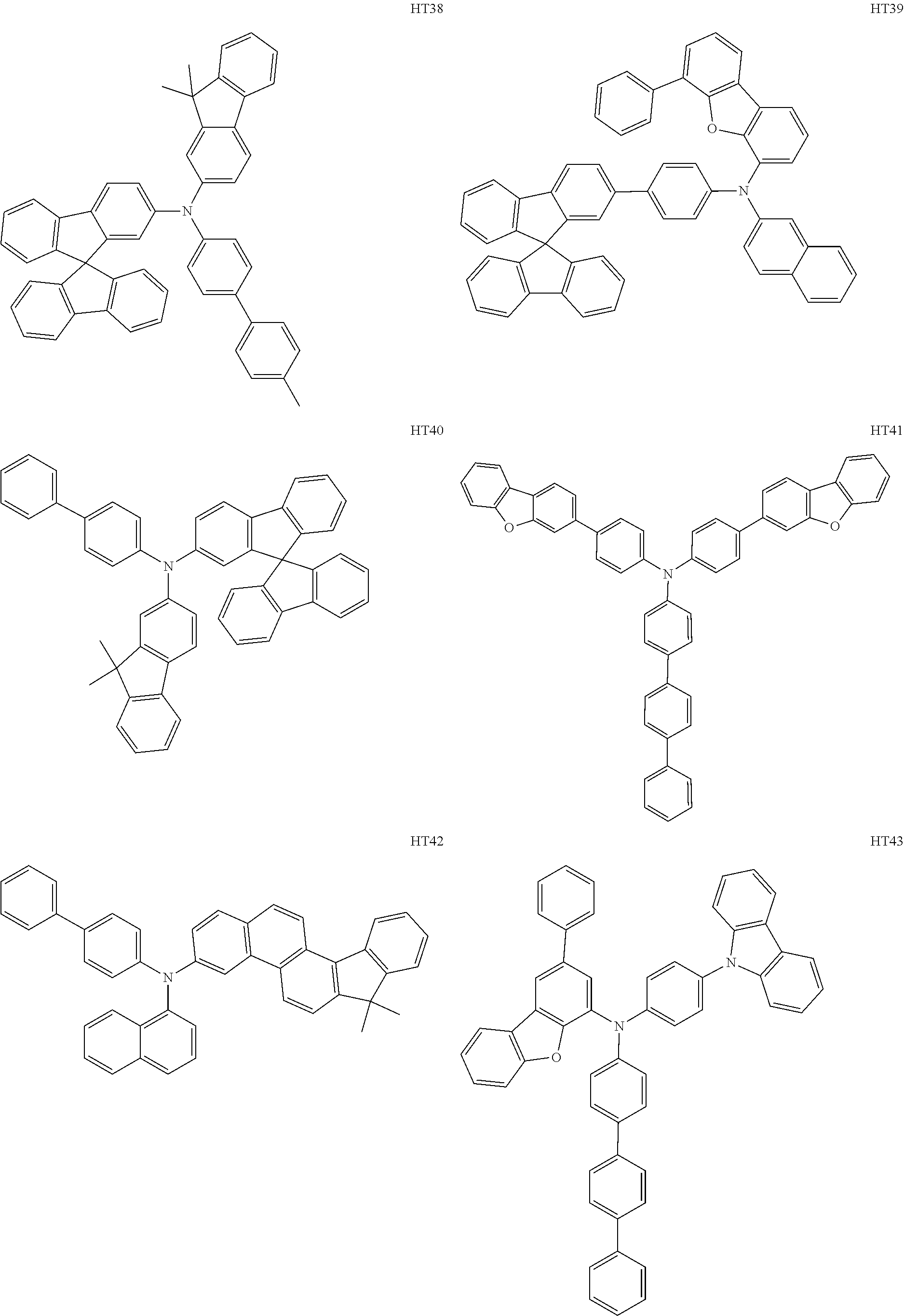

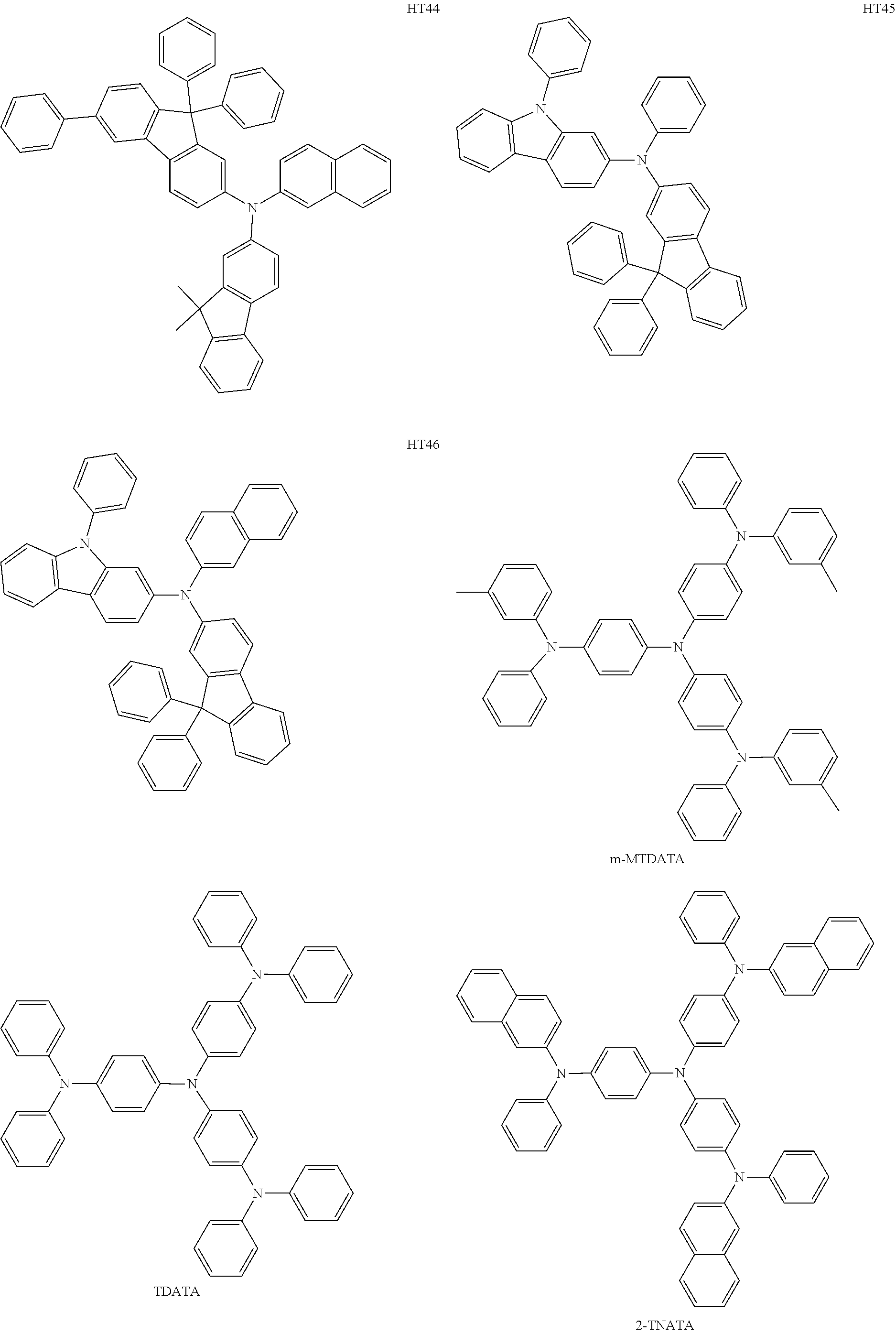

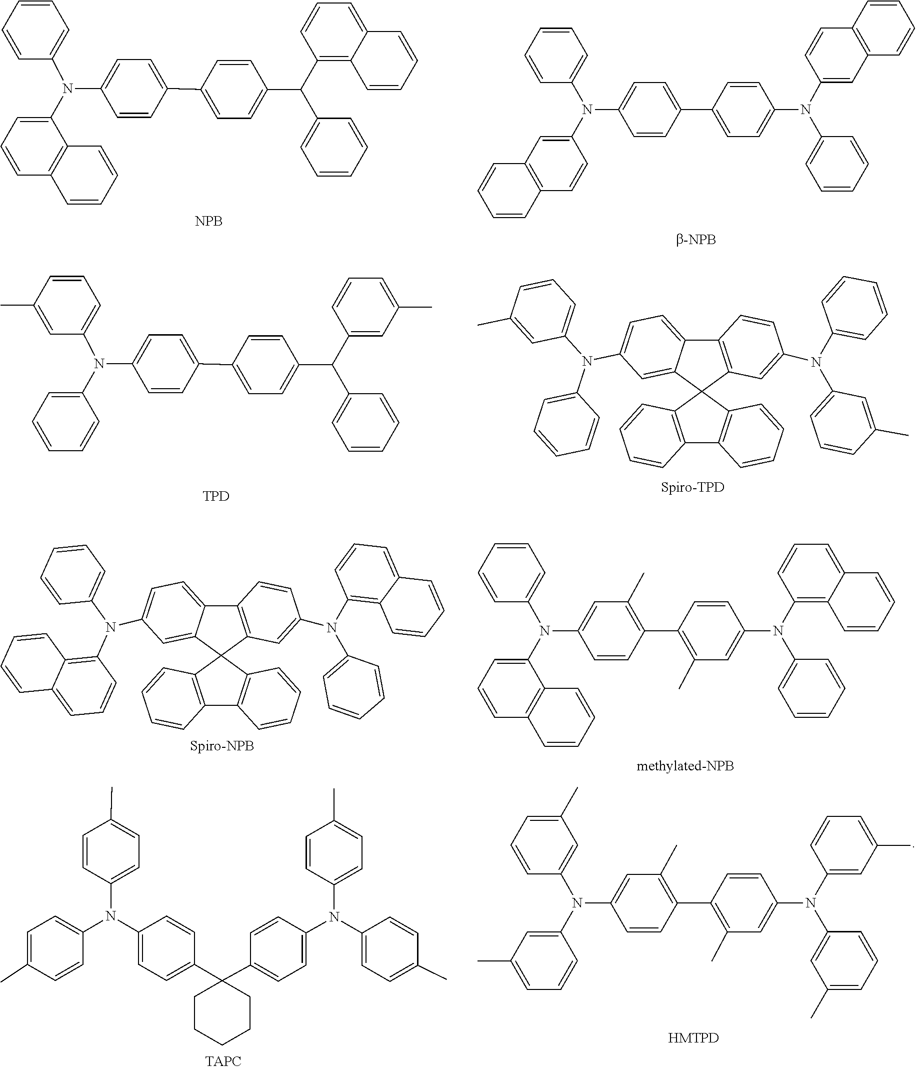

A thickness of the hole transport region 120 may be in a range of about 50 Å to about 10,000 Å. For example, the thickness of the hole transport region 120 may be in a range of about 100 Å to about 4,000 Å. When the hole transport region 120 includes a hole injection layer, a hole transport layer, or any combination thereof, a thickness of the hole injection layer may be in a range of about 100 Å to about 9,000 Å, and a thickness of the hole transport layer may be in a range of about 50 Å to about 2,000 Å. For example, the thickness of the hole injection layer may be in a range of about 100 Å to about 1,000 Å. For example, the thickness of the hole transport layer may be in a range of about 100 Å to about 1,500 Å. When the thicknesses of the hole transport region 120, the hole injection layer, and the hole transport layer are within these ranges, satisfactory hole-transporting characteristics may be obtained without a substantial increase in driving voltage.

The emission auxiliary layer may increase light-emission efficiency by compensating for an optical resonance distance according to a wavelength of light emitted by the emission layer 130, and the electron-blocking layer may block the leakage of electrons from the emission layer 130 to the hole transport region 120. Materials that may be included in the hole transport region 120 may be included in the emission auxiliary layer and the electron-blocking layer.

[p-Dopant]

The hole transport region 120 may further include, in addition to the above-described materials, a charge-generation material for the improvement of conductive properties. The charge-generating material may be substantially homogeneously or non-homogeneously dispersed (for example, as a single layer consisting of charge-generating material) in the hole transport region 120.

The charge-generation material may be, for example, a p-dopant.

For example, a lowest unoccupied molecular orbital (LUMO) energy level of the p-dopant may be equal to or less than about −3.5 eV.

According to an embodiment, the p-dopant may include a quinone derivative, a cyano group-containing compound, a compound including element EL1 and element EL2, or any combination thereof.

Examples of a quinone derivative may include TCNQ, F4-TCNQ, and the like.

Examples of a cyano group-containing compound may include HAT-CN, a compound represented by Formula 221, and the like:

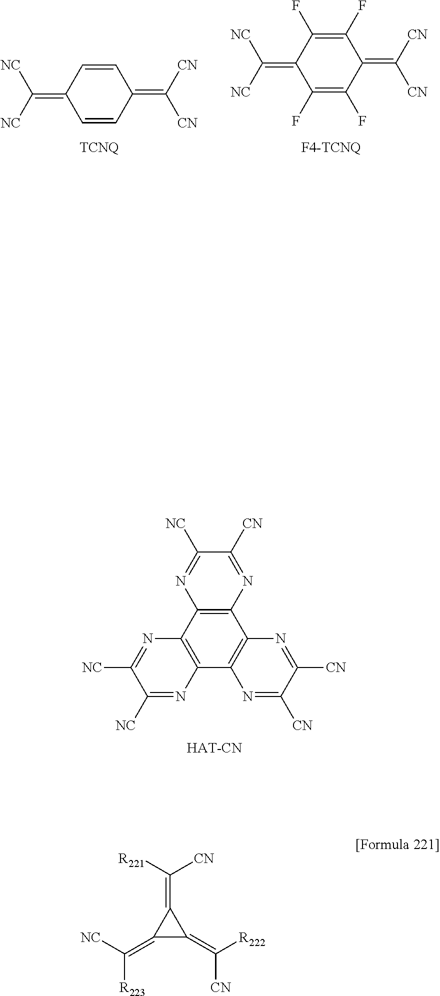

In Formula 221,
R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and
at least one of R₂₂₁ to R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, or any combination thereof; or any combination thereof.

In the compound including element EL1 and element EL2, element EL1 may be a metal, a metalloid, or any combination thereof, and element EL2 may be a non-metal, a metalloid, or any combination thereof.

Examples of a metal may include: an alkali metal (for example, lithium (Li), sodium (Na), potassium (K), rubidium (Rb), cesium (Cs), etc.); an alkaline earth metal (for example, beryllium (Be), magnesium (Mg), calcium (Ca), strontium (Sr), barium (Ba), etc.); a transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), etc.); a post-transition metal (for example, zinc (Zn), indium (In), tin (Sn), etc.); and a lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), etc.).

Examples of a metalloid may include silicon (Si), antimony (Sb), tellurium (Te), and the like.

Examples of a non-metal may include oxygen (O), a halogen (for example, F, Cl, Br, I, etc.), and the like.

Examples of a compound including element EL1 and element EL2 may include a metal oxide, a metal halide (for example, a metal fluoride, a metal chloride, a metal bromide, a metal iodide, etc.), a metalloid halide (for example, a metalloid fluoride, a metalloid chloride, a metalloid bromide, a metalloid iodide, etc.), a metal telluride, or any combination thereof.

Examples of a metal oxide may include a tungsten oxide (for example, WO, W₂O₃, WO₂, WO₃, W₂O₅, etc.), a vanadium oxide (for example, VO, V₂O₃, VO₂, V₂O₅, etc.), a molybdenum oxide (for example, MoO, Mo₂O₃, MoO₂, MoO₃, Mo₂O₅, etc.), a rhenium oxide (for example, ReO₃, etc.), and the like.

Examples of a metal halide may include an alkali metal halide, an alkaline earth metal halide, a transition metal halide, a post-transition metal halide, a lanthanide metal halide, and the like.

Examples of an alkali metal halide may include LiF, NaF, KF, RbF, CsF, LiCl, NaCl, KCl, RbCl, CsCl, LiBr, NaBr, KBr, RbBr, CsBr, LiI, NaI, KI, RbI, CsI, and the like.

Examples of an alkaline earth metal halide may include BeF₂, MgF₂, CaF₂, SrF₂, BaF₂, BeCl₂, MgCl₂, CaCl₂), SrCl₂, BaCl₂, BeBr₂, MgBr₂, CaBr₂, SrBr₂, BaBr₂, BeI₂, MgI₂, CaI₂, SrI₂, BaI₂, and the like.

Examples of a transition metal halide may include a titanium halide (for example, TiF₄, TiCl₄, TiBr₄, TiI₄, etc.), a zirconium halide (for example, ZrF₄, ZrCl₄, ZrBr₄, ZrI₄, etc.), a hafnium halide (for example, HfF₄, HfCl₄, HfBr₄, HfI₄, etc.), a vanadium halide (for example, VF₃, VCl₃, VBr₃, VI₃, etc.), a niobium halide (for example, NbF₃, NbCl₃, NbBr₃, NbI₃, etc.), a tantalum halide (for example, TaF₃, TaCl₃, TaBr₃, TaI₃, etc.), a chromium halide (for example, CrF₃, CrO₃, CrBr₃, CrI₃, etc.), a molybdenum halide (for example, MoF₃, MoCl₃, MoBr₃, MoI₃, etc.), a tungsten halide (for example, WF₃, WCl₃, WBr₃, WI₃, etc.), a manganese halide (for example, MnF₂, MnCl₂, MnBr₂, MnI₂, etc.), a technetium halide (for example, TcF₂, TcCl₂, TcBr₂, TcI₂, etc.), a rhenium halide (for example, ReF₂, ReCl₂, ReBr₂, ReI₂, etc.), an iron halide (for example, FeF₂, FeCl₂, FeBr₂, FeI₂, etc.), a ruthenium halide (for example, RuF₂, RuCl₂, RuBr₂, RuI₂, etc.), an osmium halide (for example, OsF₂, OsCl₂, OsBr₂, OsI₂, etc.), a cobalt halide (for example, CoF₂, CoCl₂, CoBr₂, CoI₂, etc.), a rhodium halide (for example, RhF₂, RhCl₂, RhBr₂, RhI₂, etc.), an iridium halide (for example, IrF₂, IrCl₂, IrBr₂, IrI₂, etc.), a nickel halide (for example, NiF₂, NiCl₂, NiBr₂, NiI₂, etc.), a palladium halide (for example, PdF₂, PdCl₂, PdBr₂, PdI₂, etc.), a platinum halide (for example, PtF₂, PtCl₂, PtBr₂, PtI₂, etc.), a copper halide (for example, CuF, CuCl, CuBr, CuI, etc.), a silver halide (for example, AgF, AgCl, AgBr, AgI, etc.), a gold halide (for example, AuF, AuCl, AuBr, AuI, etc.), and the like.

Examples of a post-transition metal halide may include a zinc halide (for example, ZnF₂, ZnCl₂, ZnBr₂, ZnI₂, etc.), an indium halide (for example, InI₃, etc.), a tin halide (for example, Sn₁₂, etc.), and the like.

Examples of a lanthanide metal halide may include YbF, YbF₂, YbF₃, SmF₃, YbCl, YbCl₂, YbCl₃, SmCl₃, YbBr, YbBr₂, YbBr₃, SmBr₃, YbI, YbI₂, YbI₃, SmI₃, and the like.

Examples of a metalloid halide may include an antimony halide (for example, SbCl₅, etc.).

Examples of a metal telluride may include an alkali metal telluride (for example, Li₂Te, Na₂Te, K₂Te, Rb₂Te, Cs₂Te, etc.), an alkaline earth metal telluride (for example, BeTe, MgTe, CaTe, SrTe, BaTe, etc.), a transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, etc.), a post-transition metal telluride (for example, ZnTe, etc.), a lanthanide metal telluride (for example, LaTe, CeTe, PrTe, NdTe, PmTe, EuTe, GdTe, TbTe, DyTe, HoTe, ErTe, TmTe, YbTe, LuTe, etc.), and the like.

### [Emission Layer 130]

The light-emitting device 10 may include an emission layer 130 on the hole transport region 120.

In an embodiment, the emission layer 130 may further include, in addition to various organic materials, a metal-containing compound such as an organometallic compound, an inorganic material such as a quantum dot, and the like.

In an embodiment, the emission layer 130 may include two or more emitting units stacked between the first electrode 110 and the second electrode 150, and at least one charge generation layer arranged, each between adjacent units among the two or more emitting units. When the emission layer 130 includes the two or more light-emitting units and the at least one charge generation layer as described above, the light-emitting device 10 may be a tandem light-emitting device.

When the light-emitting device 10 is a full-color light-emitting device, the emission layer 130 may be patterned into a red emission layer, a green emission layer, and/or a blue emission layer, according to a subpixel. In embodiments, the emission layer 130 may have a stacked structure of two or more layers among a red emission layer, a green emission layer, and a blue emission layer, in which the two or more layers may contact each other or may be separated from each other, to emit white light. In embodiments, the emission layer 130 may include two or more materials among a red light-emitting material, a green light-emitting material, and a blue light-emitting material, in which the two or more materials may be mixed with each other in a single layer, to emit white light.

The emission layer 130 may include a host and a dopant. The dopant may include a phosphorescent dopant, a fluorescent dopant, or any combination thereof.

An amount of the dopant in the emission layer 130 may be in a range of about 0.01 parts by weight to about 15 parts by weight, with respect to 100 parts by weight of the host.

In embodiments, the emission layer 130 may include a quantum dot.

In embodiments, the emission layer 130 may include a delayed fluorescence material. The delayed fluorescence material may serve as a host or as dopant in the emission layer 130.

A thickness of the emission layer 130 may be in a range of about 100 Å to about 1,000 Å. For example, the thickness of the emission layer 130 may be in a range of about 200 Å to about 600 Å. When the thickness of the emission layer 130 is within any of these ranges, excellent luminescence characteristics may be obtained without a substantial increase in driving voltage.

### [Host]

In an embodiment, the host may include a compound represented by Formula 301:

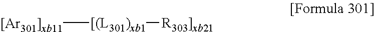

In Formula 301,
Ar₃₀₁ and L₃₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xb11 may be 1, 2, or 3,
xb1 may be an integer from 0 to 5,
R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),
xb21 may be an integer from 1 to 5, and
Q₃₀₁ to Q₃₀₃ may each independently be the same as described in connection with Q₁.

In an embodiment, in Formula 301, when xb11 is 2 or more, two or more of Ar₃₀₁ may be linked to each other via a single bond.

In embodiments, the host may include a compound represented by Formula 301-1, a compound represented by Formula 301-2, or any combination thereof:

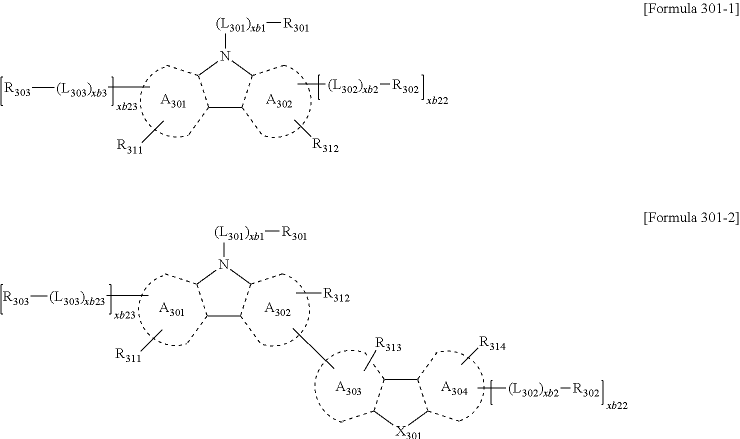

In Formulae 301-1 and 301-2,
ring A₃₀₁ to ring A₃₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
X₃₀₁ may be O, S, N[(L₃₀₄)_{xb4}-R₃₀₄], C(R₃₀₄)(R₃₀₅), or Si(R₃₀₄)(R₃₀₅),
xb22 and xb23 may each independently be 0, 1, or 2,
L₃₀₁, xb1, and R₃₀₁ may each be the same as described herein,
L₃₀₂ to L₃₀₄ may each independently be the same as described in connection with L₃₀₁,
xb2 to xb4 may each independently be the same as described in connection with xb1, and
R₃₀₂ to R₃₀₅ and R₃₁₁ to R₃₁₄ may each independently be the same as described in connection with R₃₀₁.

In embodiments, the host may include an alkali earth metal complex, a post-transition metal complex, or any combination thereof. For example, the host may include a Be complex (for example, Compound H55), an Mg complex, a Zn complex, or any combination thereof.

In embodiments, the host may include one of Compounds H1 to H128, 9,10-di(2-naphthyl)anthracene (ADN), 2-methyl-9,10-bis(naphthalen-2-yl)anthracene (MADN), 9,10-di-(2-naphthyl)-2-t-butyl-anthracene (TBADN); 4,4′-bis(N-carbazolyl)-1,1′-biphenyl (CBP), 1,3-di(carbazol-9-yl)benzene (mCP); 1,3,5-tri(carbazol-9-yl)benzene (TCP), or any combination thereof:

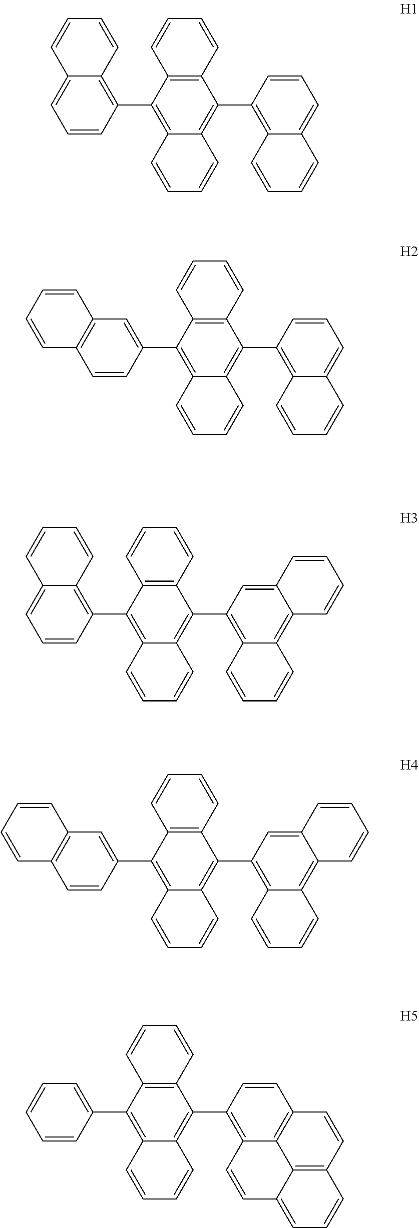

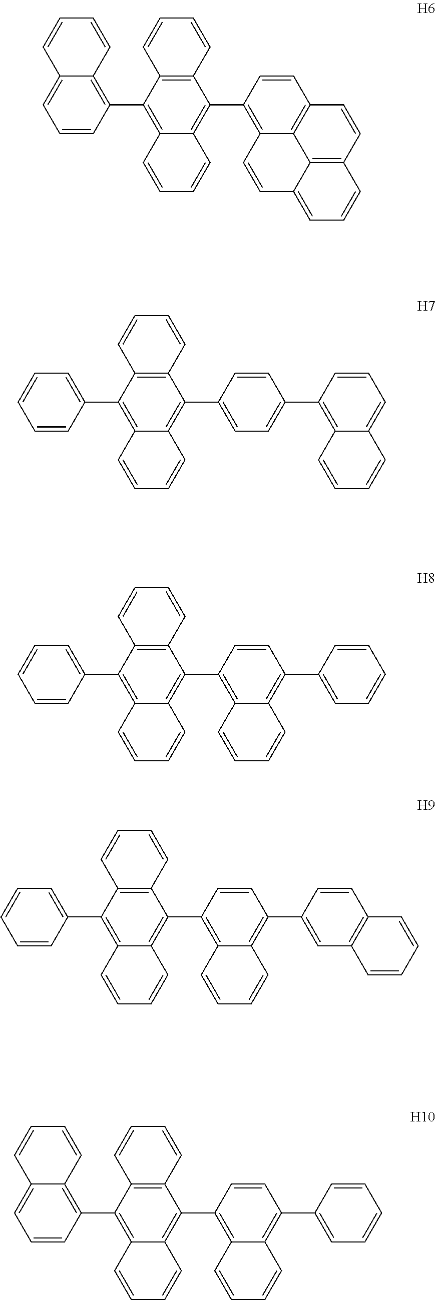

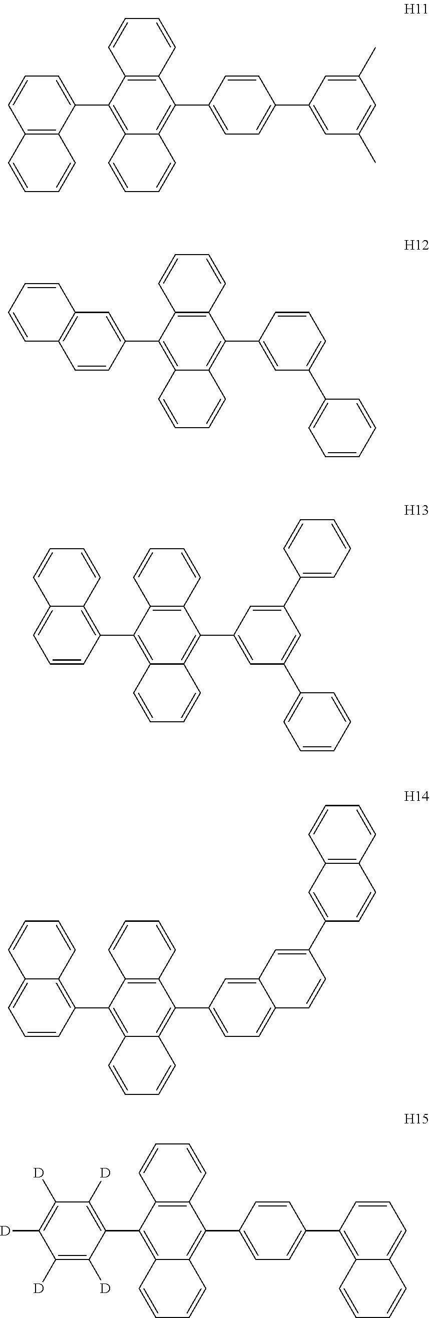

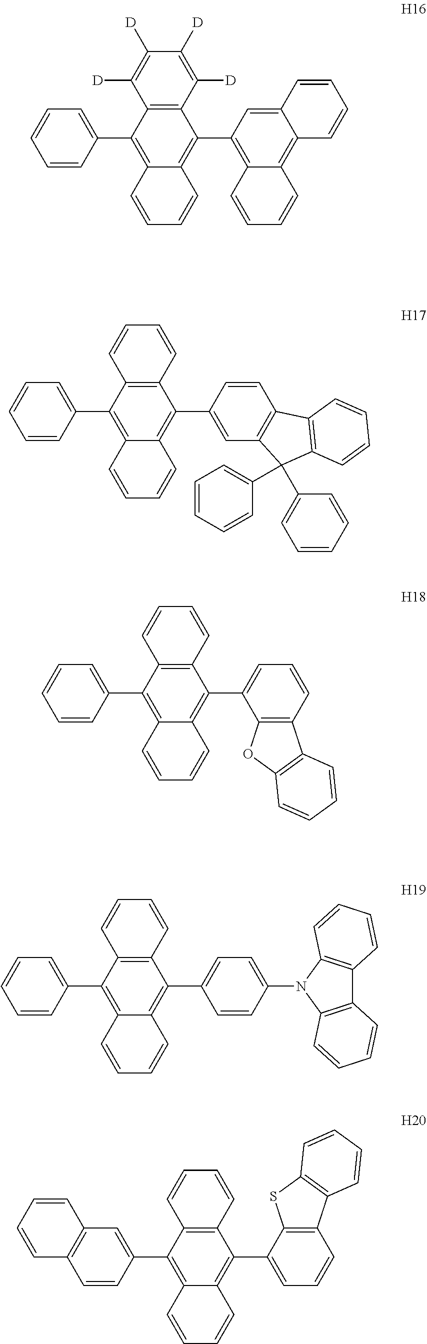

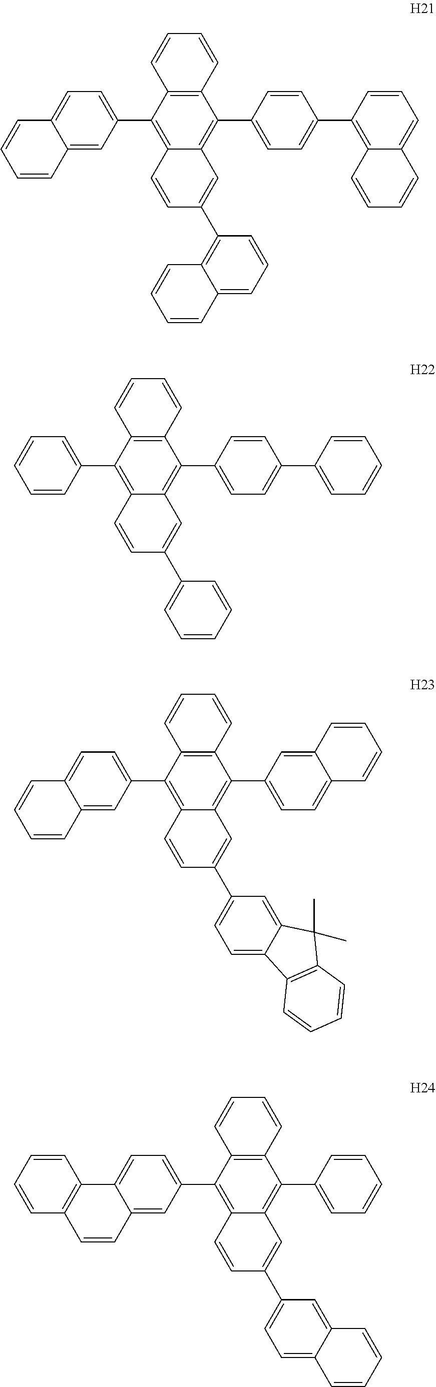

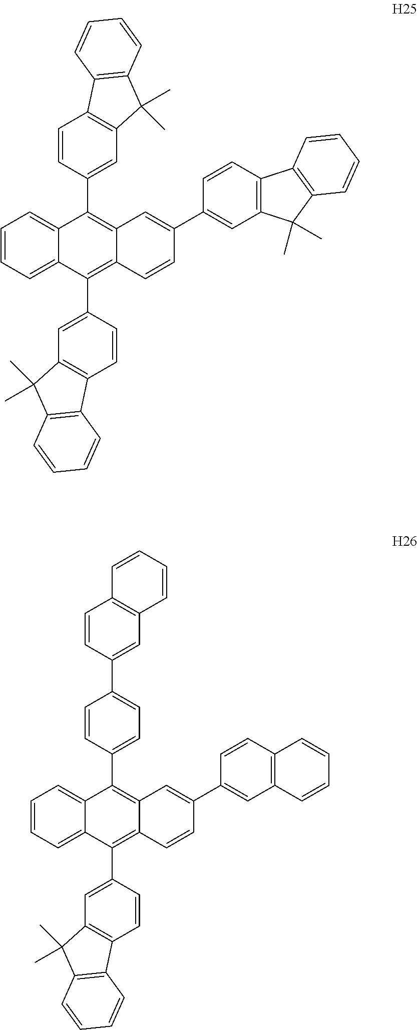

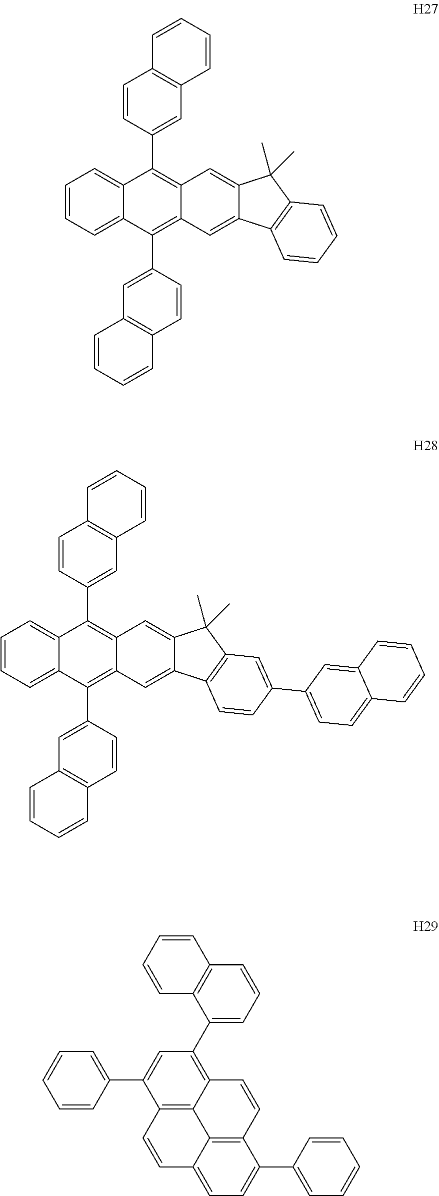

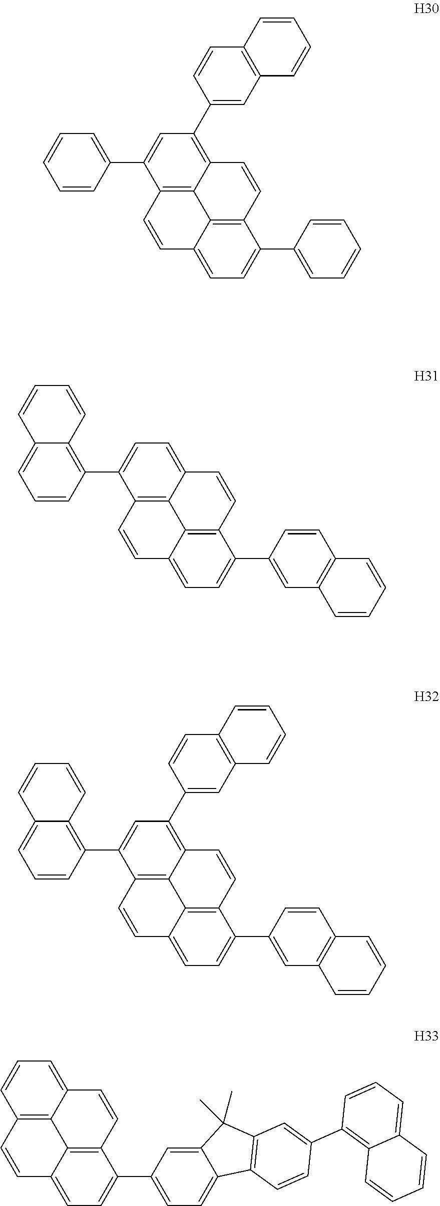

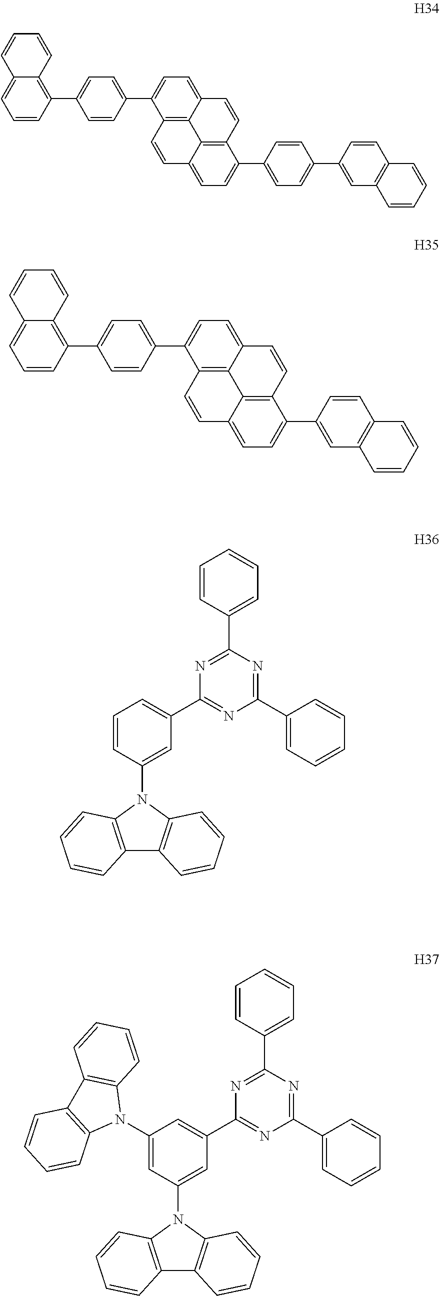

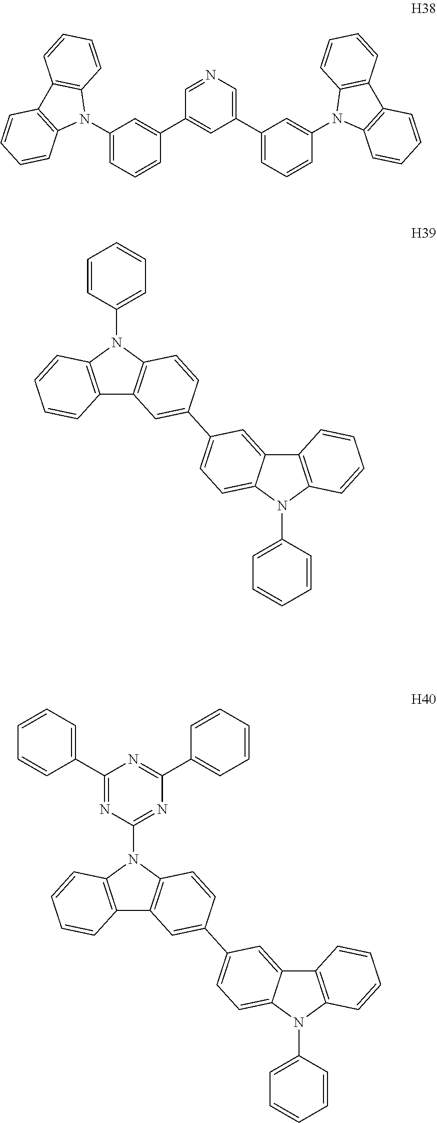 [SMILES: c1cc(-c2cncc(-c3cccc(-n4c5ccccc5c5ccccc54)c3)c2)cc(-n2c3ccccc3c3ccccc32)c1 ; c1ccc(-n2c3ccccc3c3cc(-c4ccc5c(c4)c4ccccc4n5-c4ccccc4)ccc32)cc1 ; c1ccc(-c2nc(-c3ccccc3)nc(-n3c4ccccc4c4cc(-c5ccc6c(c5)c5ccccc5n6-c5ccccc5)ccc43)n2)cc1]

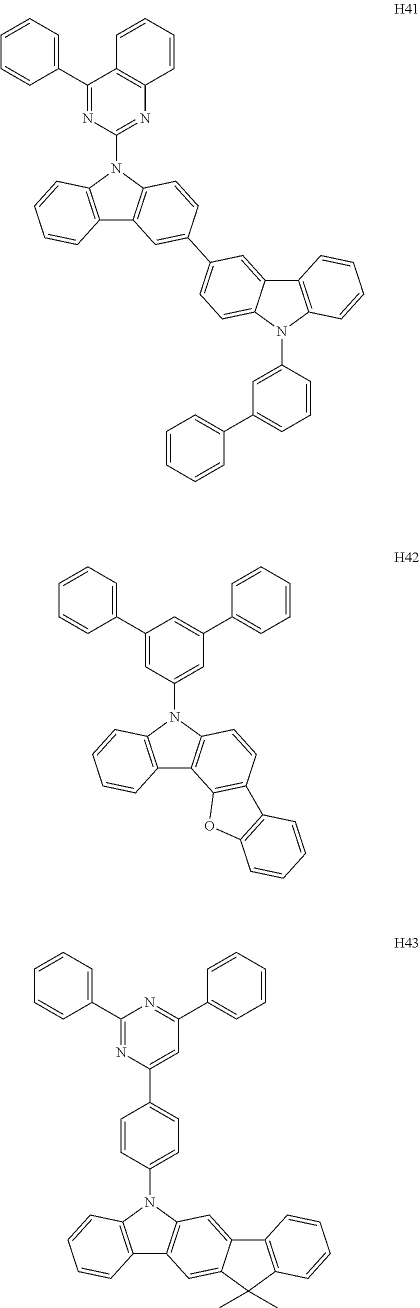 [SMILES: c1ccc(-c2cccc(-n3c4ccccc4c4cc(-c5ccc6c(c5)c5ccccc5n6-c5nc(-c6ccccc6)c6ccccc6n5)ccc43)c2)cc1 ; c1ccc(-c2cc(-c3ccccc3)cc(-n3c4ccccc4c4c5oc6ccccc6c5ccc43)c2)cc1 ; CC1(C)c2ccccc2-c2cc3c(cc21)c1ccccc1n3-c1ccc(-c2cc(-c3ccccc3)nc(-c3ccccc3)n2)cc1]

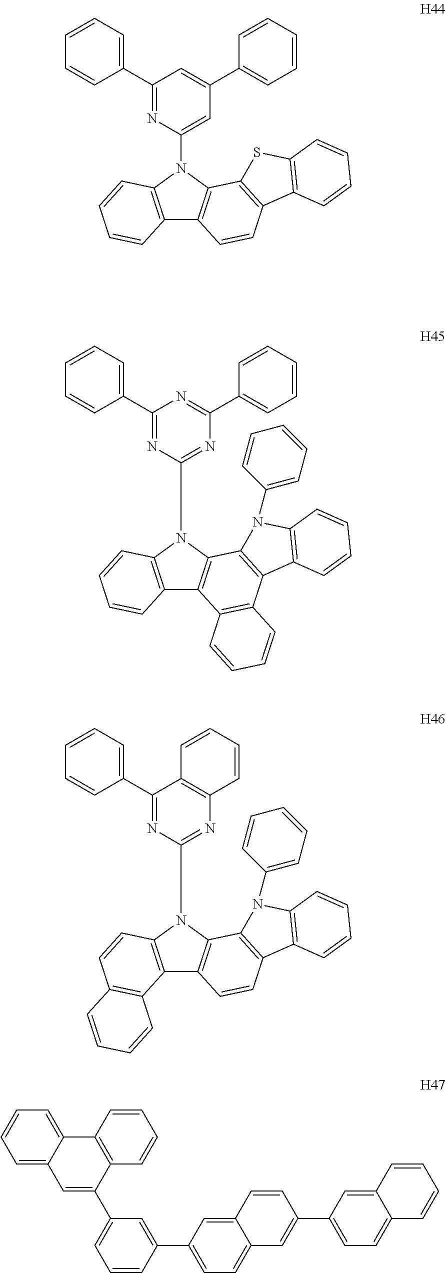

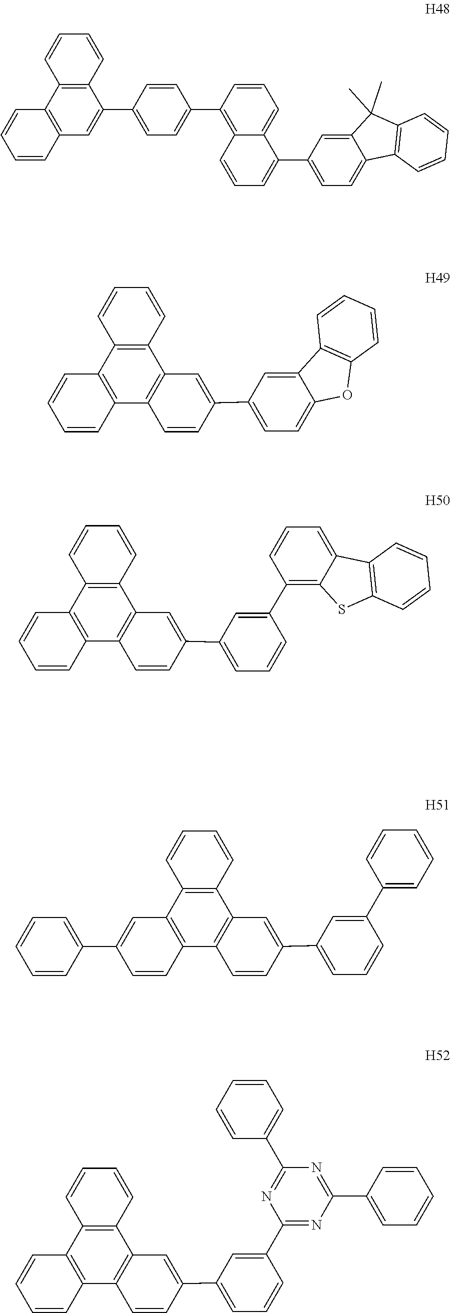

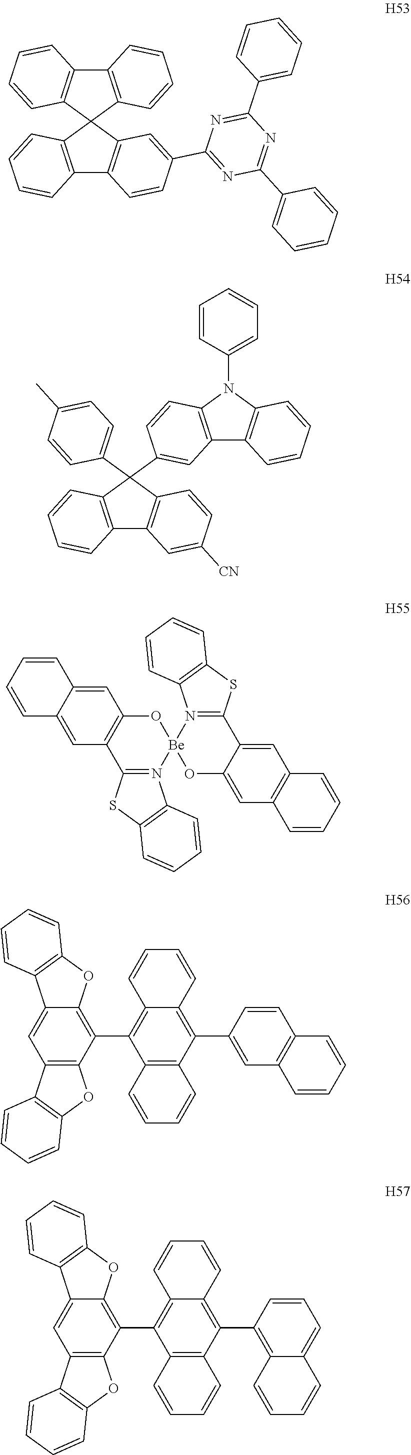

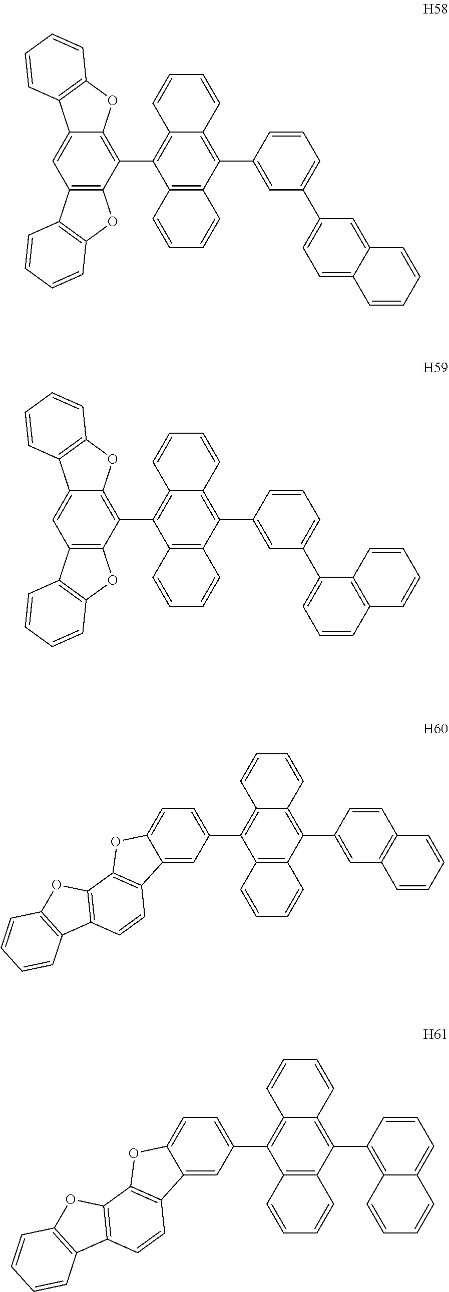 [SMILES: c1cc(-c2ccc3ccccc3c2)cc(-c2c3ccccc3c(-c3c4oc5ccccc5c4cc4c3oc3ccccc34)c3ccccc23)c1 ; c1cc(-c2cccc3ccccc23)cc(-c2c3ccccc3c(-c3c4oc5ccccc5c4cc4c3oc3ccccc34)c3ccccc23)c1 ; c1ccc2cc(-c3c4ccccc4c(-c4ccc5oc6c(ccc7c8ccccc8oc76)c5c4)c4ccccc34)ccc2c1 ; c1ccc2c(-c3c4ccccc4c(-c4ccc5oc6c(ccc7c8ccccc8oc76)c5c4)c4ccccc34)cccc2c1]

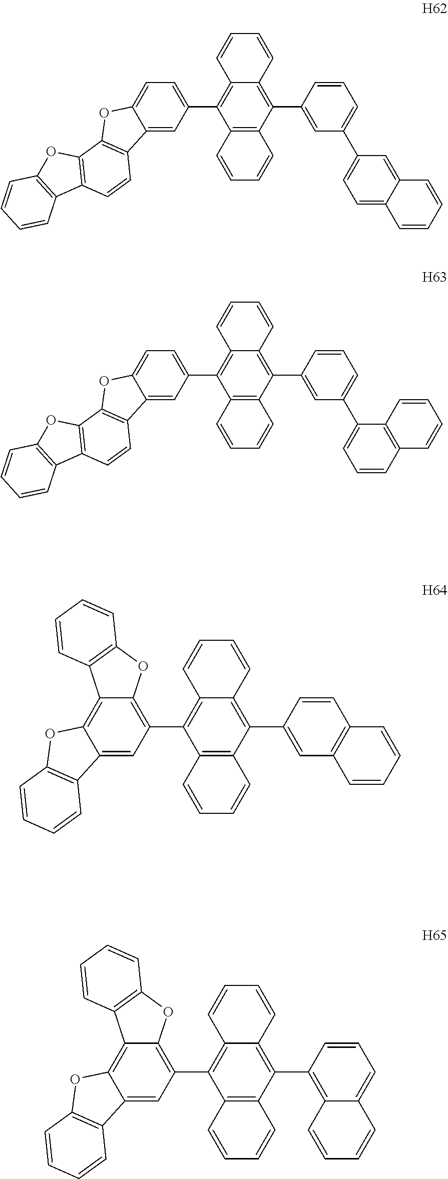 [SMILES: c1cc(-c2ccc3ccccc3c2)cc(-c2c3ccccc3c(-c3ccc4oc5c(ccc6c7ccccc7oc65)c4c3)c3ccccc23)c1 ; c1cc(-c2cccc3ccccc23)cc(-c2c3ccccc3c(-c3ccc4oc5c(ccc6c7ccccc7oc65)c4c3)c3ccccc23)c1 ; c1ccc2cc(-c3c4ccccc4c(-c4cc5c6ccccc6oc5c5c4oc4ccccc45)c4ccccc34)ccc2c1 ; c1ccc2c(-c3c4ccccc4c(-c4cc5c6ccccc6oc5c5c4oc4ccccc45)c4ccccc34)cccc2c1]

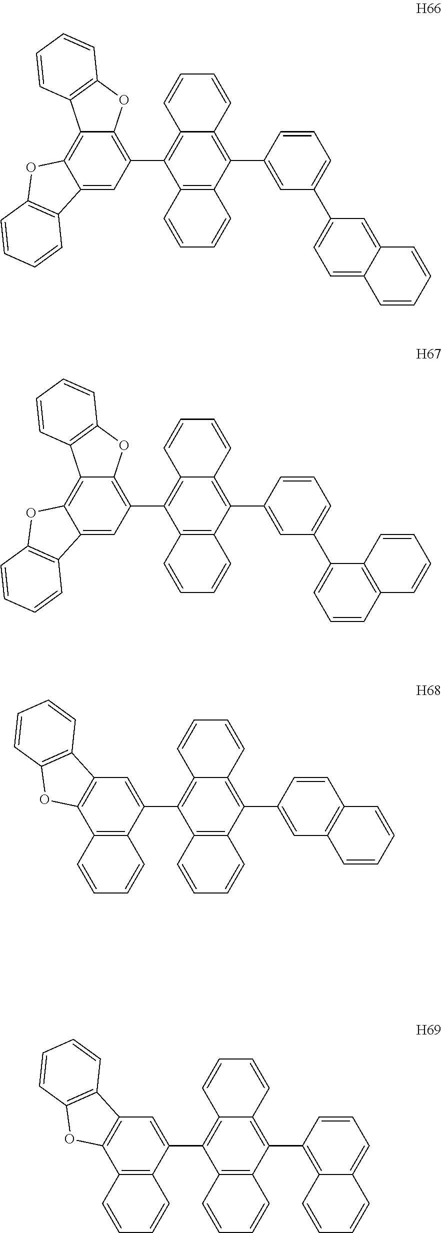 [SMILES: c1cc(-c2ccc3ccccc3c2)cc(-c2c3ccccc3c(-c3cc4c5ccccc5oc4c4c3oc3ccccc34)c3ccccc23)c1 ; c1cc(-c2cccc3ccccc23)cc(-c2c3ccccc3c(-c3cc4c5ccccc5oc4c4c3oc3ccccc34)c3ccccc23)c1 ; c1ccc2cc(-c3c4ccccc4c(-c4cc5c6ccccc6oc5c5ccccc45)c4ccccc34)ccc2c1 ; c1ccc2c(-c3c4ccccc4c(-c4cc5c6ccccc6oc5c5ccccc45)c4ccccc34)cccc2c1]

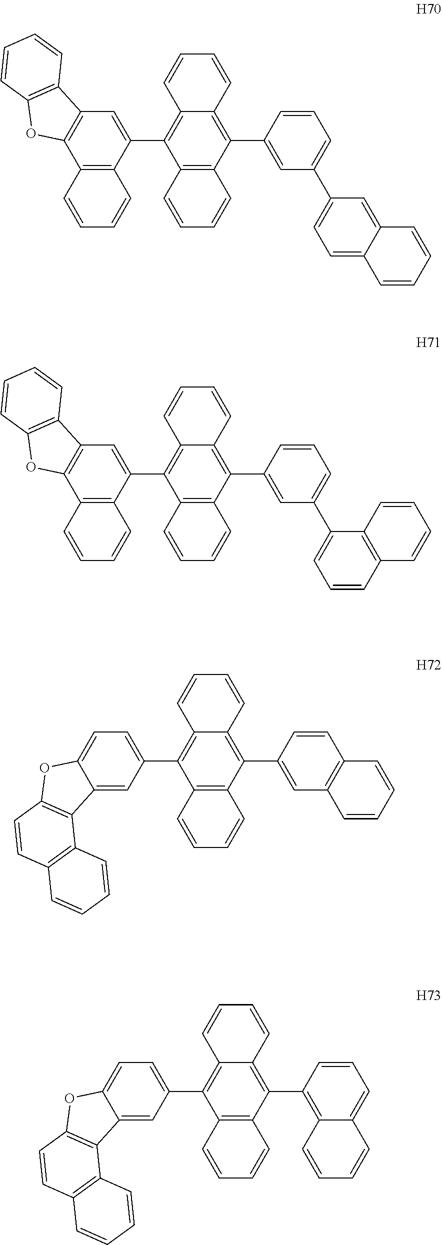 [SMILES: c1cc(-c2ccc3ccccc3c2)cc(-c2c3ccccc3c(-c3cc4c5ccccc5oc4c4ccccc34)c3ccccc23)c1 ; c1cc(-c2cccc3ccccc23)cc(-c2c3ccccc3c(-c3cc4c5ccccc5oc4c4ccccc34)c3ccccc23)c1 ; c1ccc2cc(-c3c4ccccc4c(-c4ccc5oc6ccc7ccccc7c6c5c4)c4ccccc34)ccc2c1 ; c1ccc2c(-c3c4ccccc4c(-c4ccc5oc6ccc7ccccc7c6c5c4)c4ccccc34)cccc2c1]

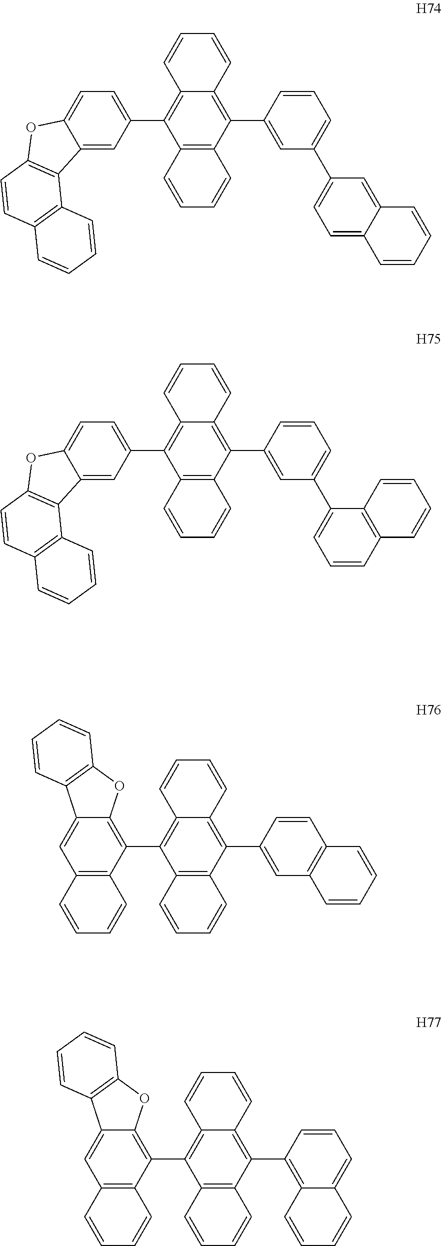 [SMILES: c1cc(-c2ccc3ccccc3c2)cc(-c2c3ccccc3c(-c3ccc4oc5ccc6ccccc6c5c4c3)c3ccccc23)c1 ; c1cc(-c2cccc3ccccc23)cc(-c2c3ccccc3c(-c3ccc4oc5ccc6ccccc6c5c4c3)c3ccccc23)c1 ; c1ccc2cc(-c3c4ccccc4c(-c4c5ccccc5cc5c4oc4ccccc45)c4ccccc34)ccc2c1 ; c1ccc2c(-c3c4ccccc4c(-c4c5ccccc5cc5c4oc4ccccc45)c4ccccc34)cccc2c1]

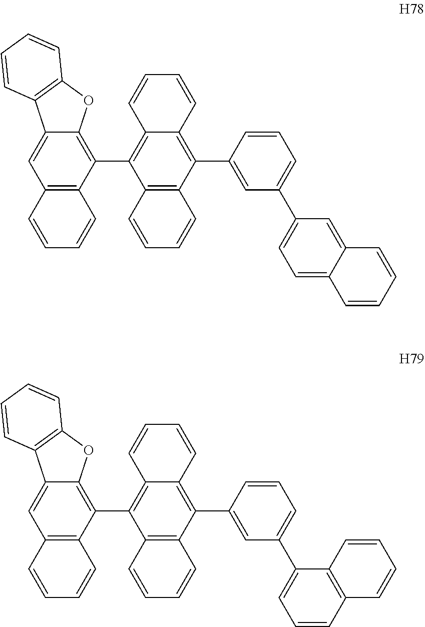 [SMILES: c1cc(-c2ccc3ccccc3c2)cc(-c2c3ccccc3c(-c3c4ccccc4cc4c3oc3ccccc34)c3ccccc23)c1 ; c1cc(-c2cccc3ccccc23)cc(-c2c3ccccc3c(-c3c4ccccc4cc4c3oc3ccccc34)c3ccccc23)c1]

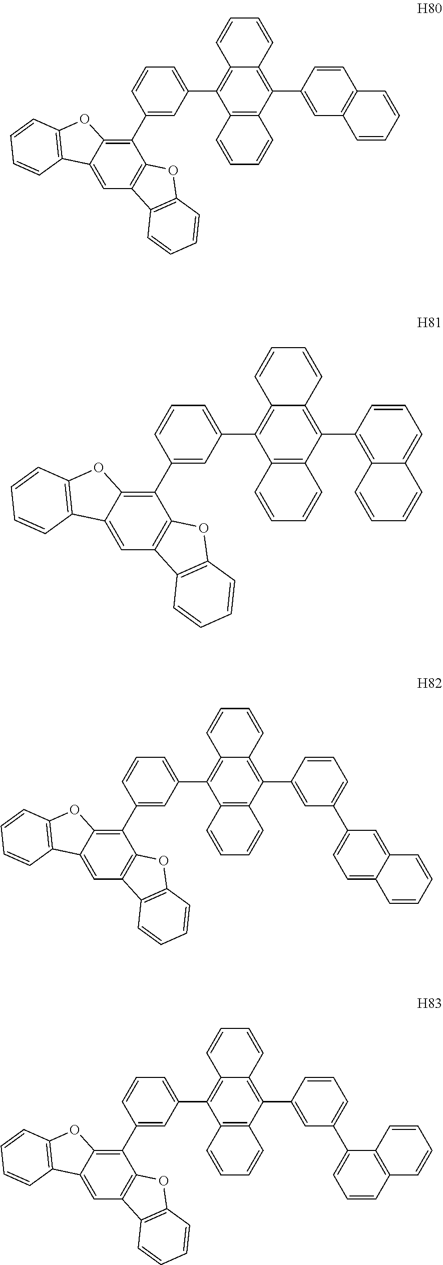 [SMILES: c1cc(-c2c3ccccc3c(-c3ccc4ccccc4c3)c3ccccc23)cc(-c2c3oc4ccccc4c3cc3c2oc2ccccc23)c1 ; c1cc(-c2c3ccccc3c(-c3cccc4ccccc34)c3ccccc23)cc(-c2c3oc4ccccc4c3cc3c2oc2ccccc23)c1 ; c1cc(-c2ccc3ccccc3c2)cc(-c2c3ccccc3c(-c3cccc(-c4c5oc6ccccc6c5cc5c4oc4ccccc45)c3)c3ccccc23)c1 ; c1cc(-c2cccc3ccccc23)cc(-c2c3ccccc3c(-c3cccc(-c4c5oc6ccccc6c5cc5c4oc4ccccc45)c3)c3ccccc23)c1]

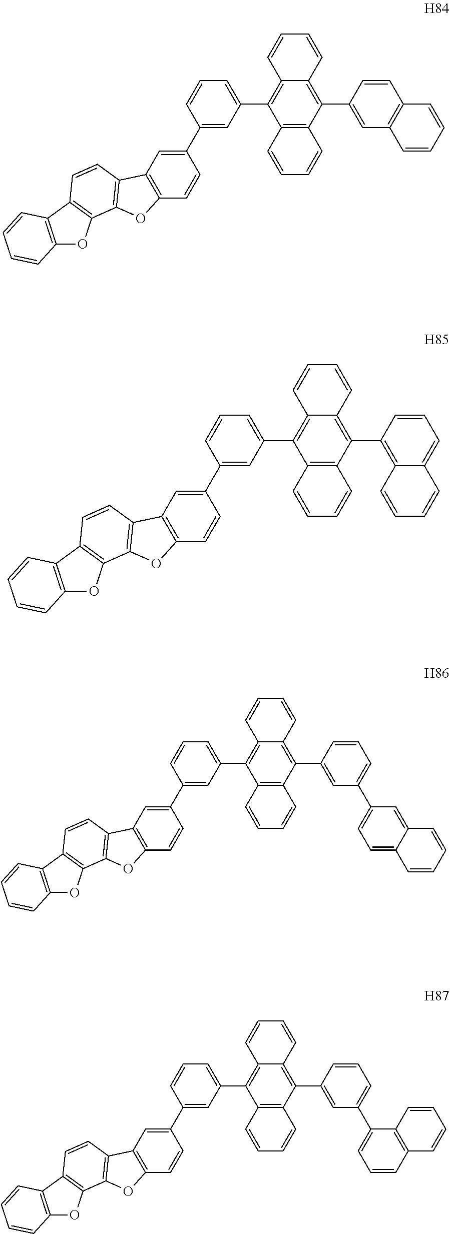 [SMILES: c1cc(-c2ccc3oc4c(ccc5c6ccccc6oc54)c3c2)cc(-c2c3ccccc3c(-c3ccc4ccccc4c3)c3ccccc23)c1 ; c1cc(-c2ccc3oc4c(ccc5c6ccccc6oc54)c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6c(ccc7c8ccccc8oc76)c5c4)c3)c3ccccc23)c1 ; c1cc(-c2ccc3oc4c(ccc5c6ccccc6oc54)c3c2)cc(-c2c3ccccc3c(-c3cccc(-c4cccc5ccccc45)c3)c3ccccc23)c1]

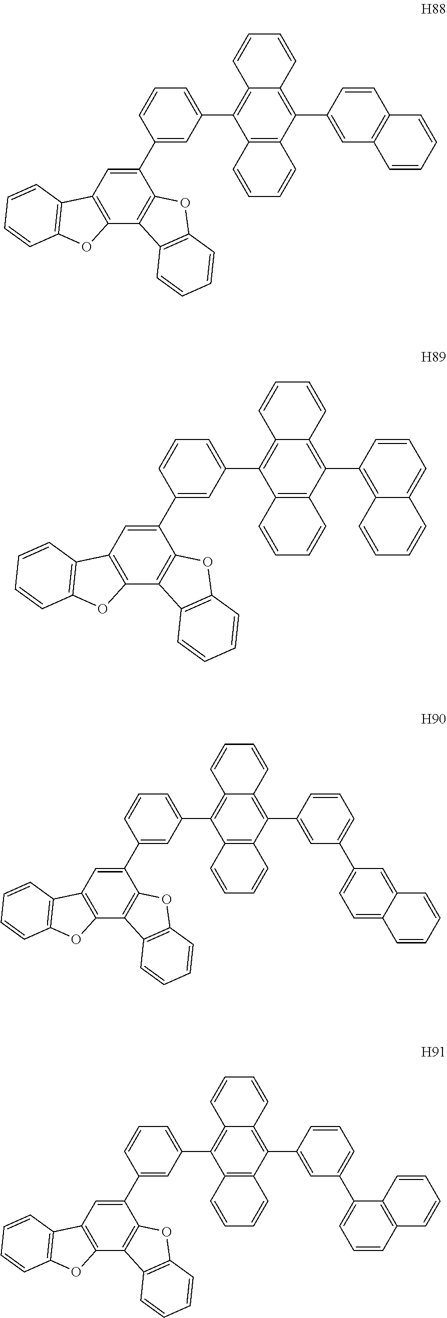 [SMILES: c1cc(-c2c3ccccc3c(-c3ccc4ccccc4c3)c3ccccc23)cc(-c2cc3c4ccccc4oc3c3c2oc2ccccc23)c1 ; c1cc(-c2c3ccccc3c(-c3cccc4ccccc34)c3ccccc23)cc(-c2cc3c4ccccc4oc3c3c2oc2ccccc23)c1 ; c1cc(-c2ccc3ccccc3c2)cc(-c2c3ccccc3c(-c3cccc(-c4cc5c6ccccc6oc5c5c4oc4ccccc45)c3)c3ccccc23)c1 ; c1cc(-c2cccc3ccccc23)cc(-c2c3ccccc3c(-c3cccc(-c4cc5c6ccccc6oc5c5c4oc4ccccc45)c3)c3ccccc23)c1]

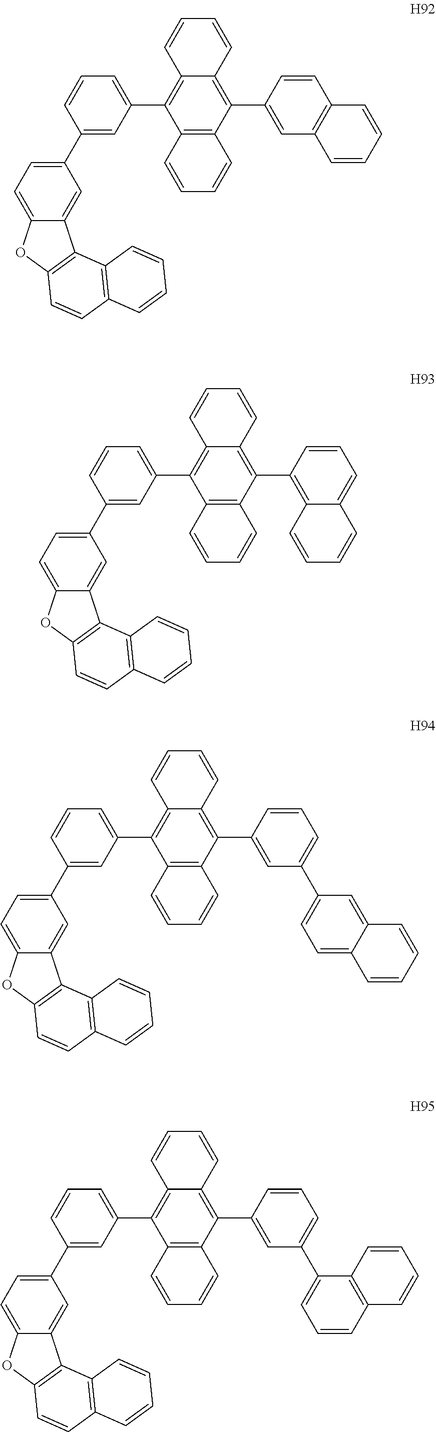 [SMILES: c1cc(-c2ccc3oc4ccc5ccccc5c4c3c2)cc(-c2c3ccccc3c(-c3ccc4ccccc4c3)c3ccccc23)c1 ; c1cc(-c2ccc3oc4ccc5ccccc5c4c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6ccc7ccccc7c6c5c4)c3)c3ccccc23)c1 ; c1cc(-c2ccc3oc4ccc5ccccc5c4c3c2)cc(-c2c3ccccc3c(-c3cccc(-c4cccc5ccccc45)c3)c3ccccc23)c1]

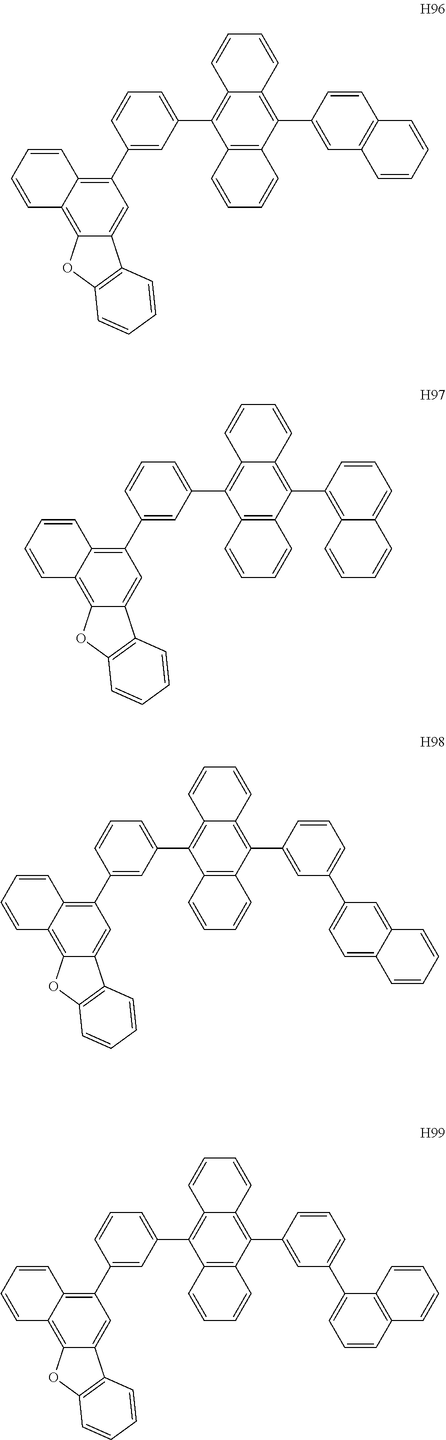 [SMILES: c1cc(-c2c3ccccc3c(-c3ccc4ccccc4c3)c3ccccc23)cc(-c2cc3c4ccccc4oc3c3ccccc23)c1 ; c1cc(-c2c3ccccc3c(-c3cccc4ccccc34)c3ccccc23)cc(-c2cc3c4ccccc4oc3c3ccccc23)c1 ; c1cc(-c2ccc3ccccc3c2)cc(-c2c3ccccc3c(-c3cccc(-c4cc5c6ccccc6oc5c5ccccc45)c3)c3ccccc23)c1 ; c1cc(-c2cccc3ccccc23)cc(-c2c3ccccc3c(-c3cccc(-c4cc5c6ccccc6oc5c5ccccc45)c3)c3ccccc23)c1]

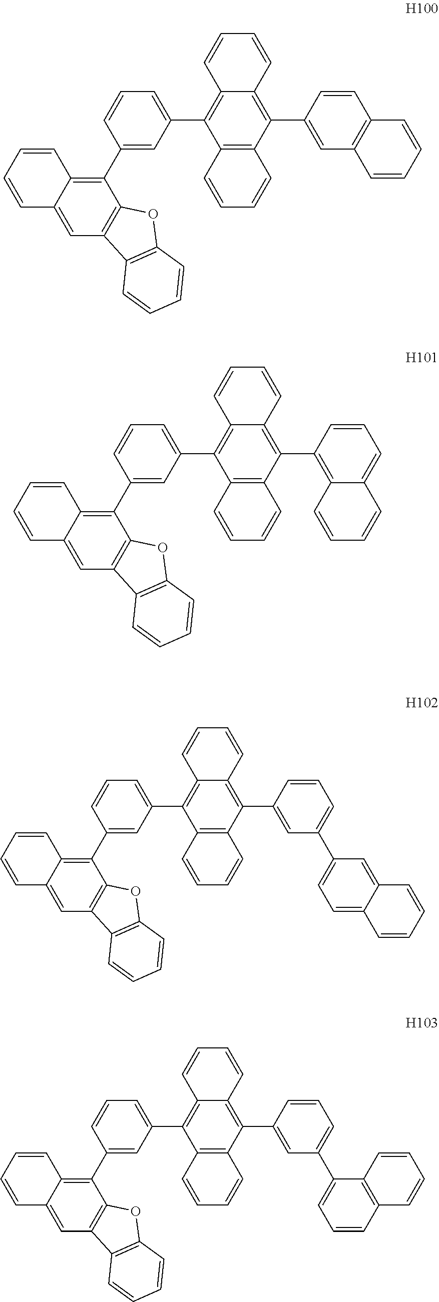 [SMILES: c1cc(-c2c3ccccc3c(-c3ccc4ccccc4c3)c3ccccc23)cc(-c2c3ccccc3cc3c2oc2ccccc23)c1 ; c1cc(-c2c3ccccc3c(-c3cccc4ccccc34)c3ccccc23)cc(-c2c3ccccc3cc3c2oc2ccccc23)c1 ; c1cc(-c2ccc3ccccc3c2)cc(-c2c3ccccc3c(-c3cccc(-c4c5ccccc5cc5c4oc4ccccc45)c3)c3ccccc23)c1 ; c1cc(-c2cccc3ccccc23)cc(-c2c3ccccc3c(-c3cccc(-c4c5ccccc5cc5c4oc4ccccc45)c3)c3ccccc23)c1]

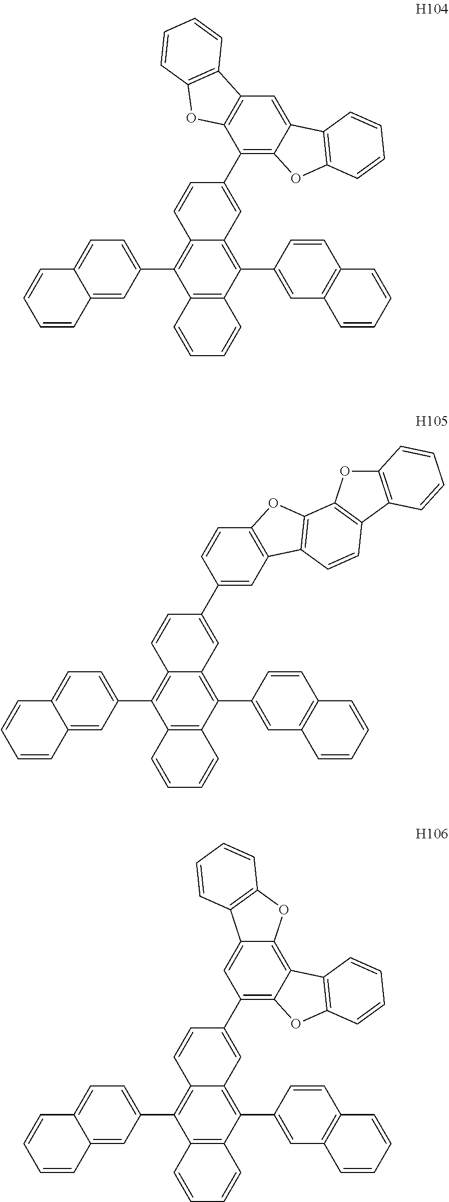 [SMILES: c1ccc2cc(-c3c4ccccc4c(-c4ccc5ccccc5c4)c4cc(-c5c6oc7ccccc7c6cc6c5oc5ccccc56)ccc34)ccc2c1 ; c1ccc2cc(-c3c4ccccc4c(-c4ccc5ccccc5c4)c4cc(-c5ccc6oc7c(ccc8c9ccccc9oc87)c6c5)ccc34)ccc2c1 ; c1ccc2cc(-c3c4ccccc4c(-c4ccc5ccccc5c4)c4cc(-c5cc6c7ccccc7oc6c6c5oc5ccccc56)ccc34)ccc2c1]

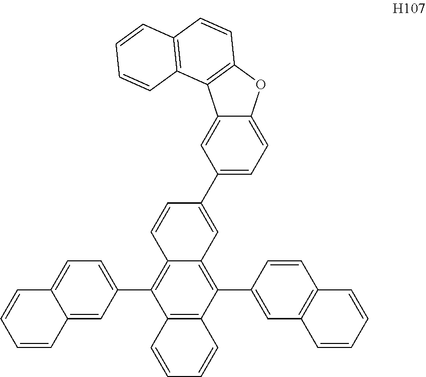 [SMILES: c1ccc2cc(-c3c4ccccc4c(-c4ccc5ccccc5c4)c4cc(-c5ccc6oc7ccc8ccccc8c7c6c5)ccc34)ccc2c1]

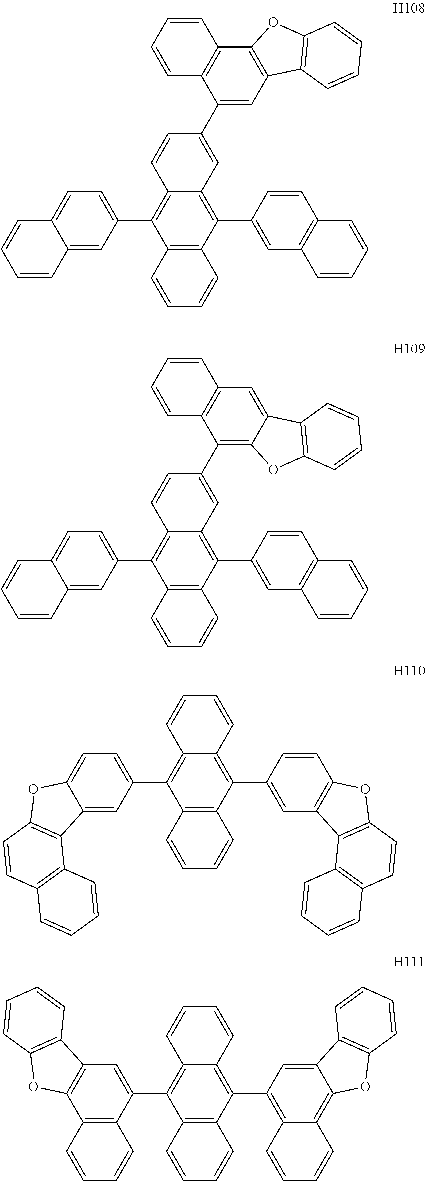 [SMILES: c1ccc2cc(-c3c4ccccc4c(-c4ccc5ccccc5c4)c4cc(-c5cc6c7ccccc7oc6c6ccccc56)ccc34)ccc2c1 ; c1ccc2cc(-c3c4ccccc4c(-c4ccc5ccccc5c4)c4cc(-c5c6ccccc6cc6c5oc5ccccc56)ccc34)ccc2c1 ; c1ccc2c(c1)ccc1oc3ccc(-c4c5ccccc5c(-c5ccc6oc7ccc8ccccc8c7c6c5)c5ccccc45)cc3c12 ; c1ccc2c(c1)oc1c3ccccc3c(-c3c4ccccc4c(-c4cc5c6ccccc6oc5c5ccccc45)c4ccccc34)cc21]

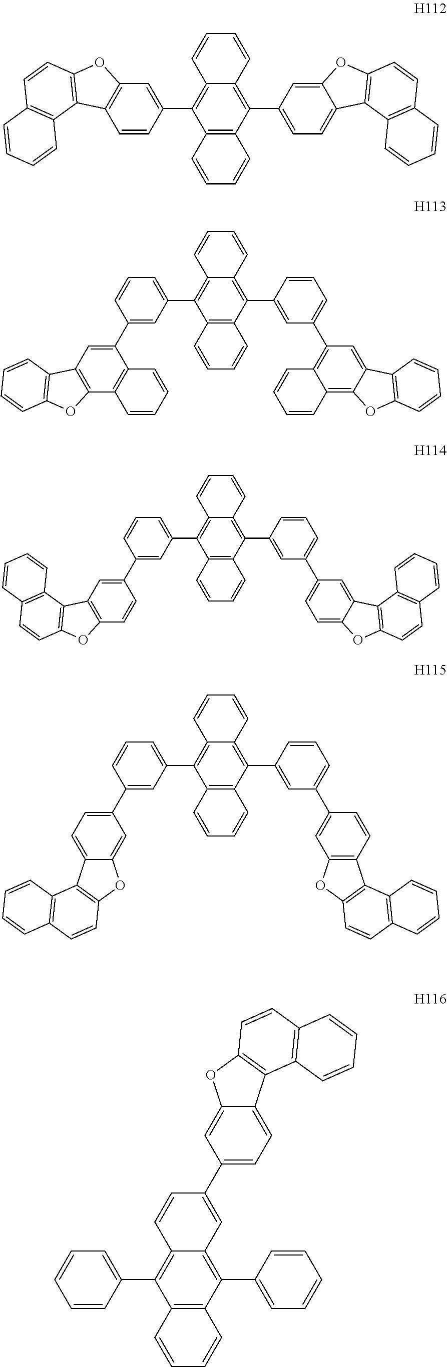 [SMILES: c1ccc2c(c1)ccc1oc3cc(-c4c5ccccc5c(-c5ccc6c(c5)oc5ccc7ccccc7c56)c5ccccc45)ccc3c12 ; c1cc(-c2c3ccccc3c(-c3cccc(-c4cc5c6ccccc6oc5c5ccccc45)c3)c3ccccc23)cc(-c2cc3c4ccccc4oc3c3ccccc23)c1 ; c1cc(-c2ccc3oc4ccc5ccccc5c4c3c2)cc(-c2c3ccccc3c(-c3cccc(-c4ccc5oc6ccc7ccccc7c6c5c4)c3)c3ccccc23)c1 ; c1cc(-c2ccc3c(c2)oc2ccc4ccccc4c23)cc(-c2c3ccccc3c(-c3cccc(-c4ccc5c(c4)oc4ccc6ccccc6c45)c3)c3ccccc23)c1 ; c1ccc(-c2c3ccccc3c(-c3ccccc3)c3cc(-c4ccc5c(c4)oc4ccc6ccccc6c45)ccc23)cc1]

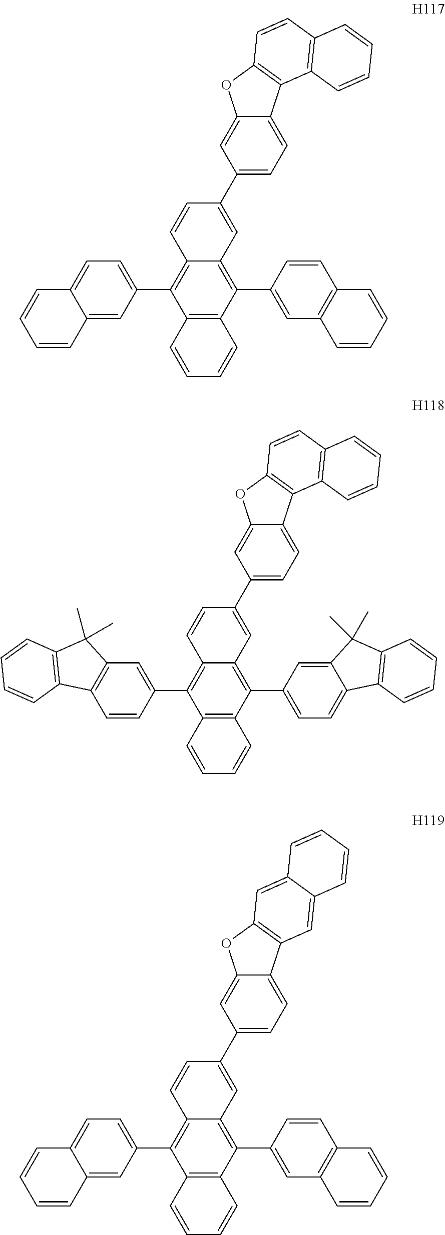 [SMILES: c1ccc2cc(-c3c4ccccc4c(-c4ccc5ccccc5c4)c4cc(-c5ccc6c(c5)oc5ccc7ccccc7c56)ccc34)ccc2c1 ; CC1(C)c2ccccc2-c2ccc(-c3c4ccccc4c(-c4ccc5c(c4)C(C)(C)c4ccccc4-5)c4cc(-c5ccc6c(c5)oc5ccc7ccccc7c56)ccc34)cc21 ; c1ccc2cc(-c3c4ccccc4c(-c4ccc5ccccc5c4)c4cc(-c5ccc6c(c5)oc5cc7ccccc7cc56)ccc34)ccc2c1]

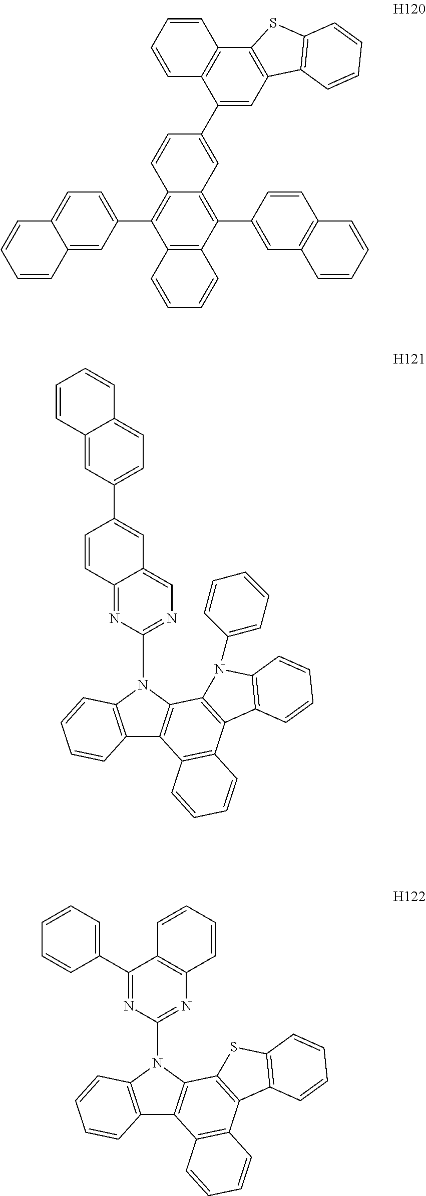 [SMILES: c1ccc2cc(-c3c4ccccc4c(-c4ccc5ccccc5c4)c4cc(-c5cc6c7ccccc7sc6c6ccccc56)ccc34)ccc2c1 ; c1ccc(-n2c3ccccc3c3c4ccccc4c4c5ccccc5n(-c5ncc6cc(-c7ccc8ccccc8c7)ccc6n5)c4c32)cc1 ; c1ccc(-c2nc(-n3c4ccccc4c4c5ccccc5c5c6ccccc6sc5c43)nc3ccccc23)cc1]

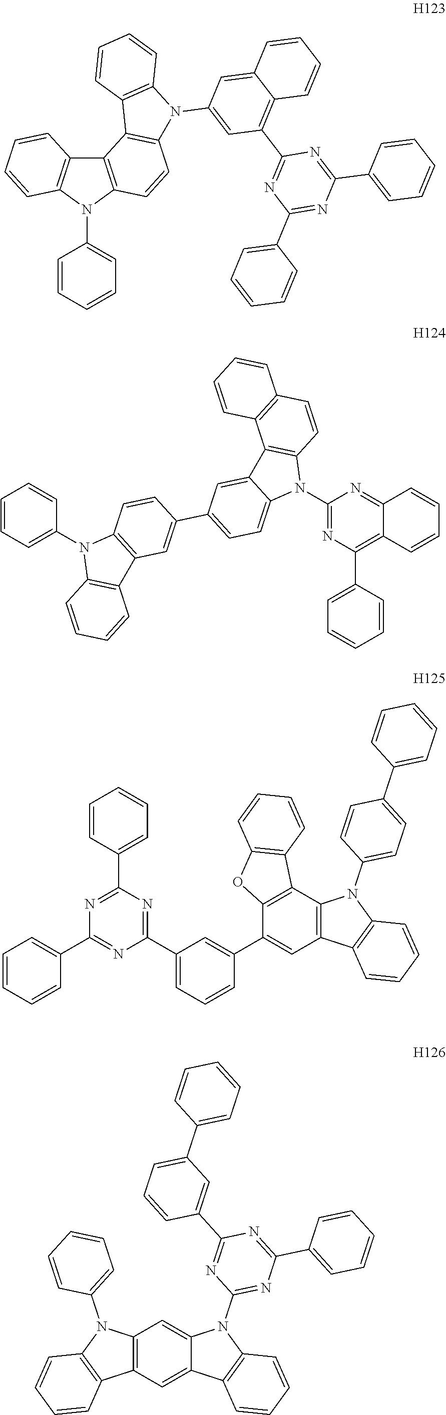 [SMILES: c1ccc(-c2nc(-c3ccccc3)nc(-c3cc(-n4c5ccccc5c5c6c7ccccc7n(-c7ccccc7)c6ccc54)cc4ccccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-c2cccc(-c3nc(-c4ccccc4)nc(-n4c5ccccc5c5cc6c7ccccc7n(-c7ccccc7)c6cc54)n3)c2)cc1]

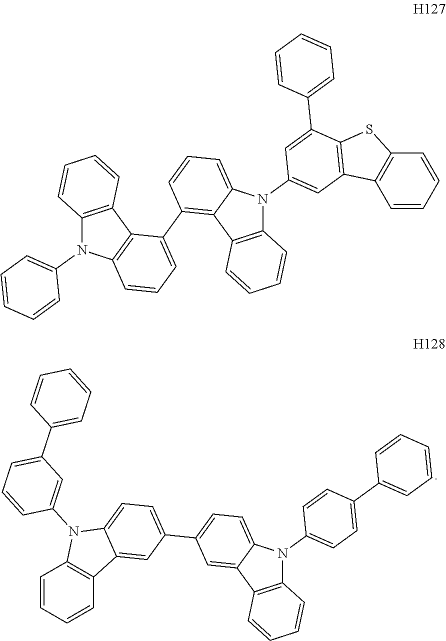 [SMILES: c1ccc(-c2cc(-n3c4ccccc4c4c(-c5cccc6c5c5ccccc5n6-c5ccccc5)cccc43)cc3c2sc2ccccc23)cc1 ; c1ccc(-c2ccc(-n3c4ccccc4c4cc(-c5ccc6c(c5)c5ccccc5n6-c5cccc(-c6ccccc6)c5)ccc43)cc2)cc1]

### [Phosphorescent Dopant]

In an embodiment, the phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

In an embodiment, the phosphorescent dopant may include an organometallic compound represented by Formula 401:

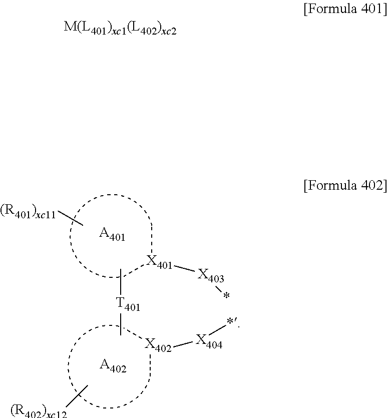

In Formulae 401 and 402,
M may be a transition metal (for example, iridium (Ir), platinum (Pt), palladium (Pd), osmium (Os), titanium (Ti), gold (Au), hafnium (Hf), europium (Eu), terbium (Tb), rhodium (Rh), rhenium (Re), or thulium (Tm)),
L₄₀₁ may be a ligand represented by Formula 402, and xc1 may be 1, 2, or 3, wherein when xc1 is 2 or more, two or more of L₄₀₁ may be identical to or different from each other,
L₄₀₂ may be an organic ligand, and xc2 may be 0, 1, 2, 3, or 4, wherein when xc2 is 2 or more, two or more of L₄₀₂ may be identical to or different from each other,
X₄₀₁ and X₄₀₂ may each independently be nitrogen or carbon,
ring A₄₀₁ and ring A₄₀₂ may each independently be a C₃-C₆₀ carbocyclic group or a C₁-C₆₀ heterocyclic group,
T₄₀₁ may be a single bond, *—O—*′, *—S—*′, *—C(═O)—*′, *—N(Q₄₁₁)-*′, *—C(Q₄₁₁)(Q₄₁₂)-*′, *—C(Q₄₁₁)=C(Q₄₁₂)-*′, *—C(Q₄₁₁)=*′, or *═C═*′,
X₄₀₃ and X₄₀₄ may each independently be a chemical bond (for example, a covalent bond or a coordinate bond), O, S, N(Q₄₁₃), B(Q₄₁₃), P(Q₄₁₃), C(Q₄₁₃)(Q₄₁₄), or Si(Q₄₁₃)(Q₄₁₄),
Q₄₁₁ to Q₄₁₄ may each independently be the same as described in connection with Q₁,
R₄₀₁ and R₄₀₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
Q₄₀₁ to Q₄₀₃ may independently each be the same as described in connection with Q₁,
xc11 and xc12 may each independently be an integer from 0 to 10, and
* and *′ in Formula 402 each indicate a binding site to M in Formula 401.

In an embodiment, in Formula 402, X₄₀₁ may be nitrogen and X₄₀₂ may be carbon, or X₄₀₁ and X₄₀₂ may each be nitrogen.

In embodiments, in Formula 401, when xc1 is 2 or more, two ring A₄₀₁(s) among two or more L₄₀₁(s) may optionally be linked to each other via T₄₀₂, which is a linking group, and two ring A₄₀₂(s) among two or more L₄₀₁(s) may optionally be linked to each other via T₄₀₃, which is a linking group (see Compounds PD1 to PD4 and PD7). T₄₀₂ and T₄₀₃ may each independently be the same as described in connection with T₄₀₁.

In Formula 401, L₄₀₂ may be an organic ligand. In an embodiment, L₄₀₂ may include a halogen group, a diketone group (for example, an acetylacetonate group), a carboxylic acid group (for example, a picolinate group), —C(═O), an isonitrile group, —CN group, a phosphorus group (for example, a phosphine group, a phosphite group, etc.), or any combination thereof.

In an embodiment, the phosphorescent dopant may include, for example, one of Compounds PD1 to PD39, or any combination thereof:

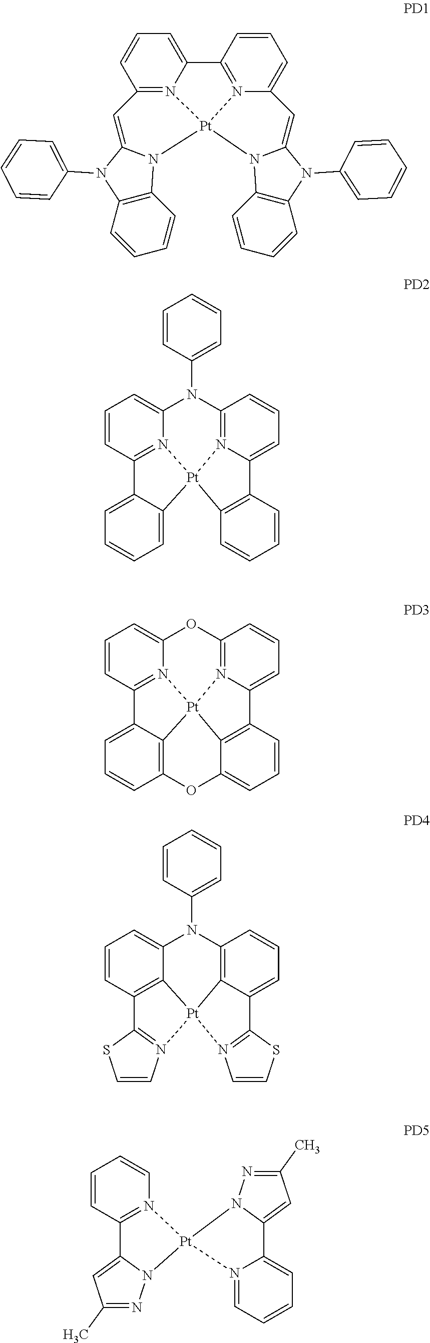

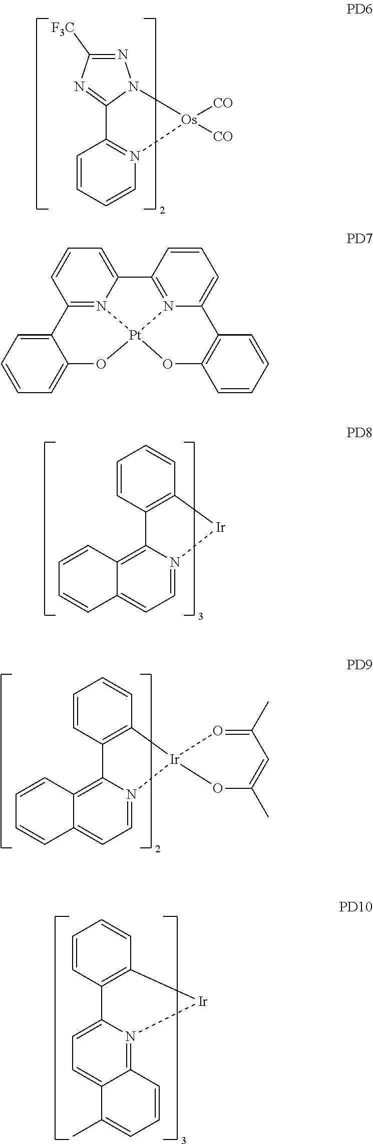

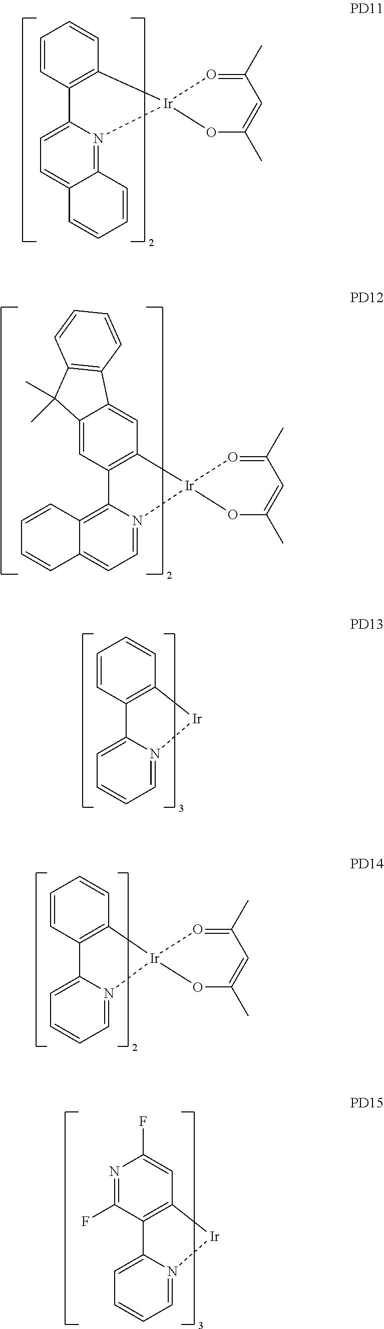

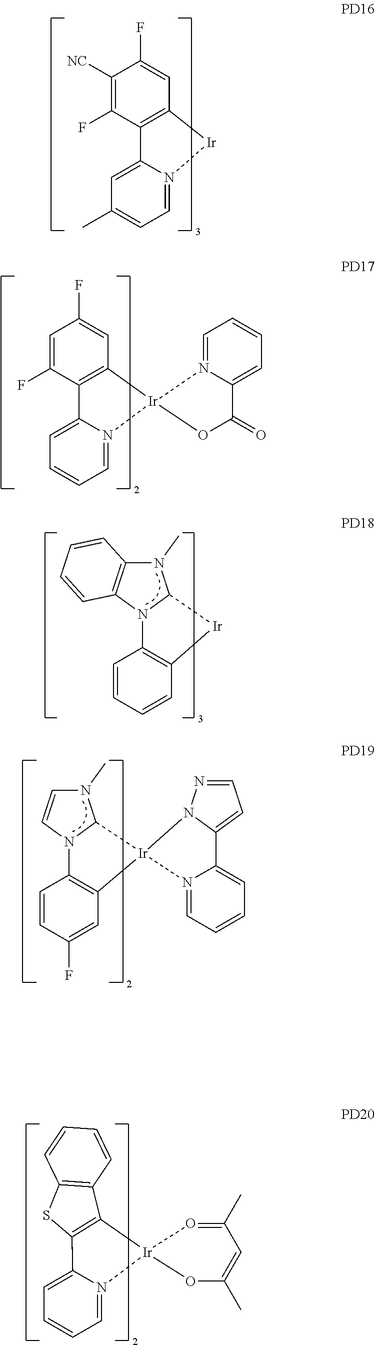

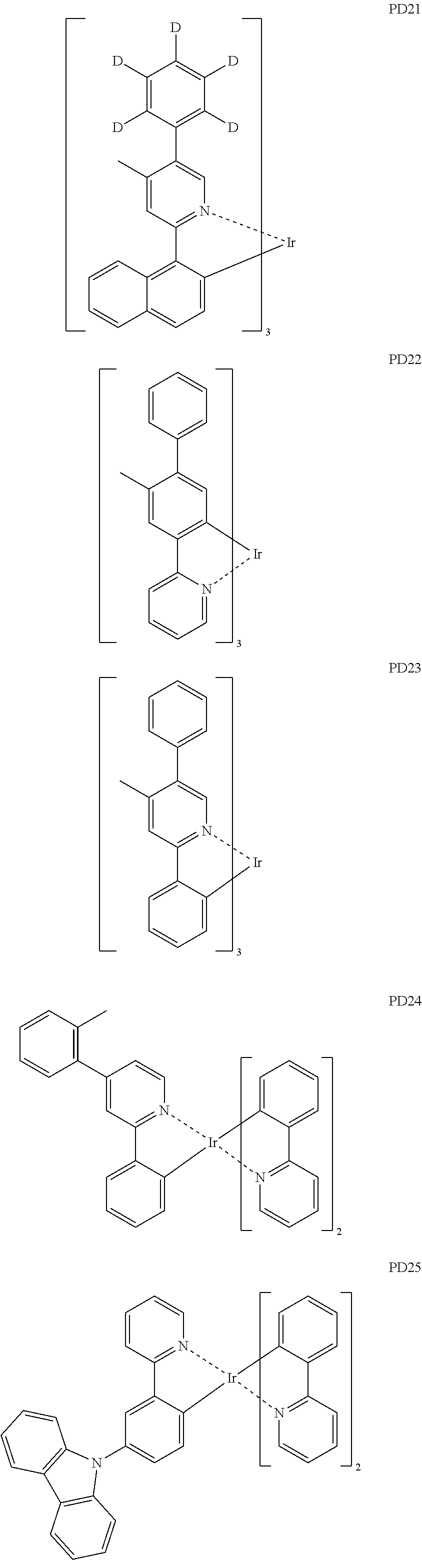

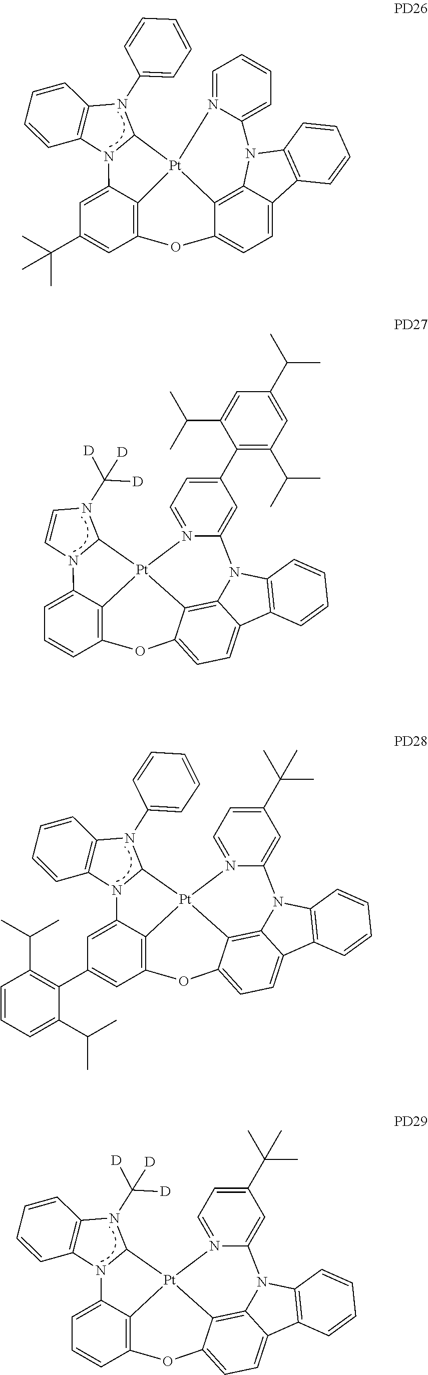

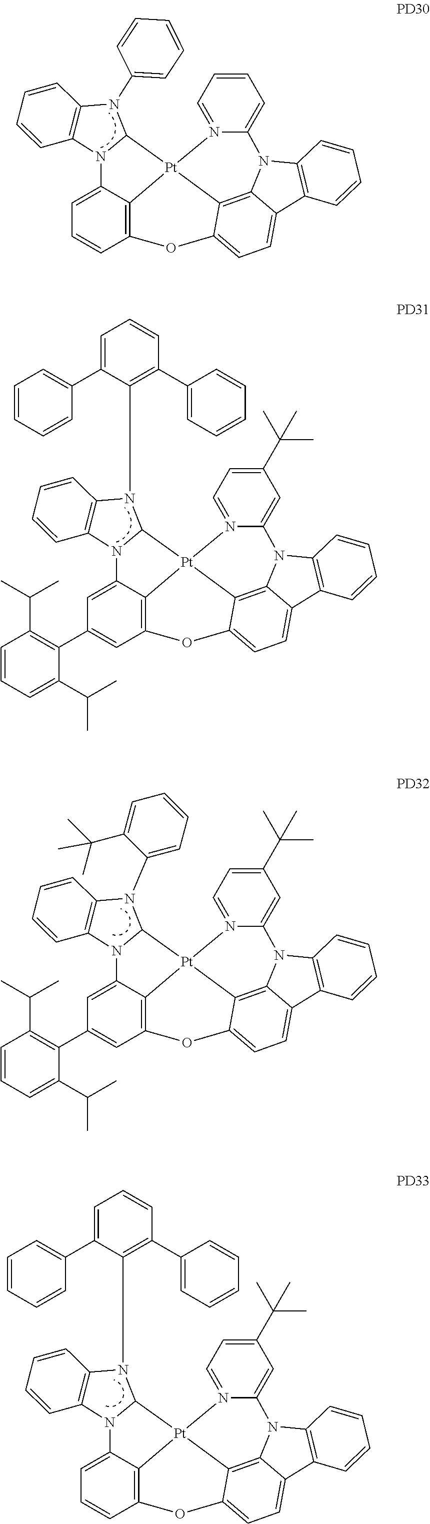

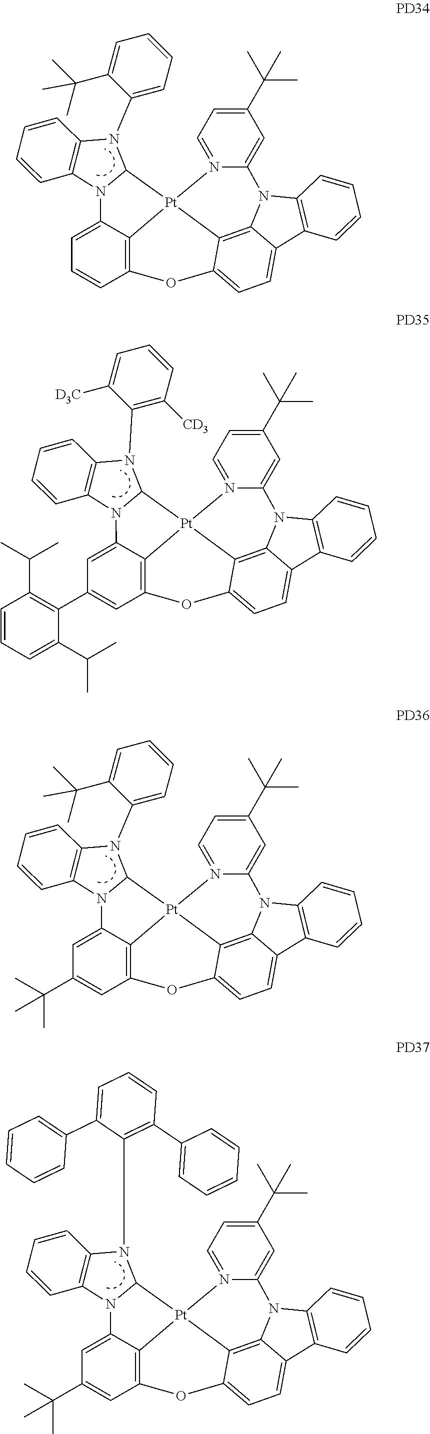

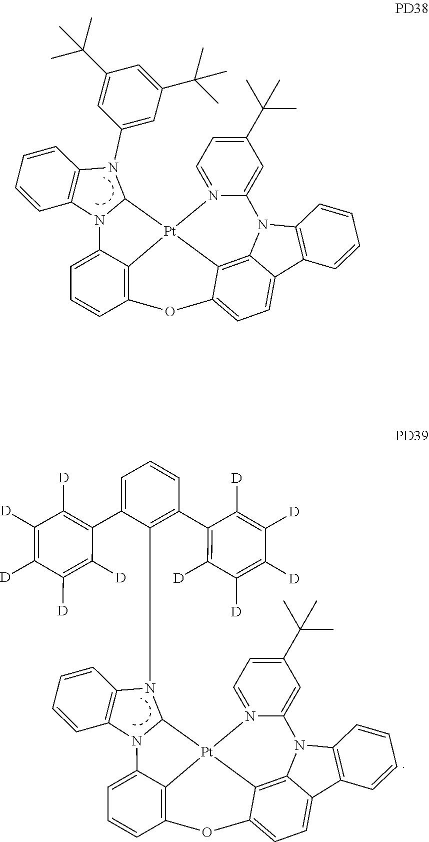

### [Fluorescent Dopant]

In an embodiment, the fluorescent dopant may include an amine group-containing compound, a styryl group-containing compound, or any combination thereof.

In an embodiment, the fluorescent dopant may include a compound represented by Formula 501:

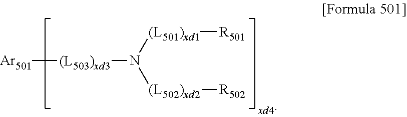

In Formula 501,
Ar₅₀₁, L₅₀₁ to L₅₀₃, R₅₀₁, and R₅₀₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xd1 to xd3 may each independently be 0, 1, 2, or 3, and
xd4 may be 1, 2, 3, 4, 5, or 6.

In an embodiment, in Formula 501, Ar₅₀₁ may be a condensed cyclic group (for example, an anthracene group, a chrysene group, a pyrene group, etc.) in which three or more monocyclic groups are condensed together.

In embodiments, in Formula 501, xd4 may be 2.

In an embodiment, the fluorescent dopant may include one of Compounds FD1 to FD37, DPVBi, DPAVBi, or any combination thereof:

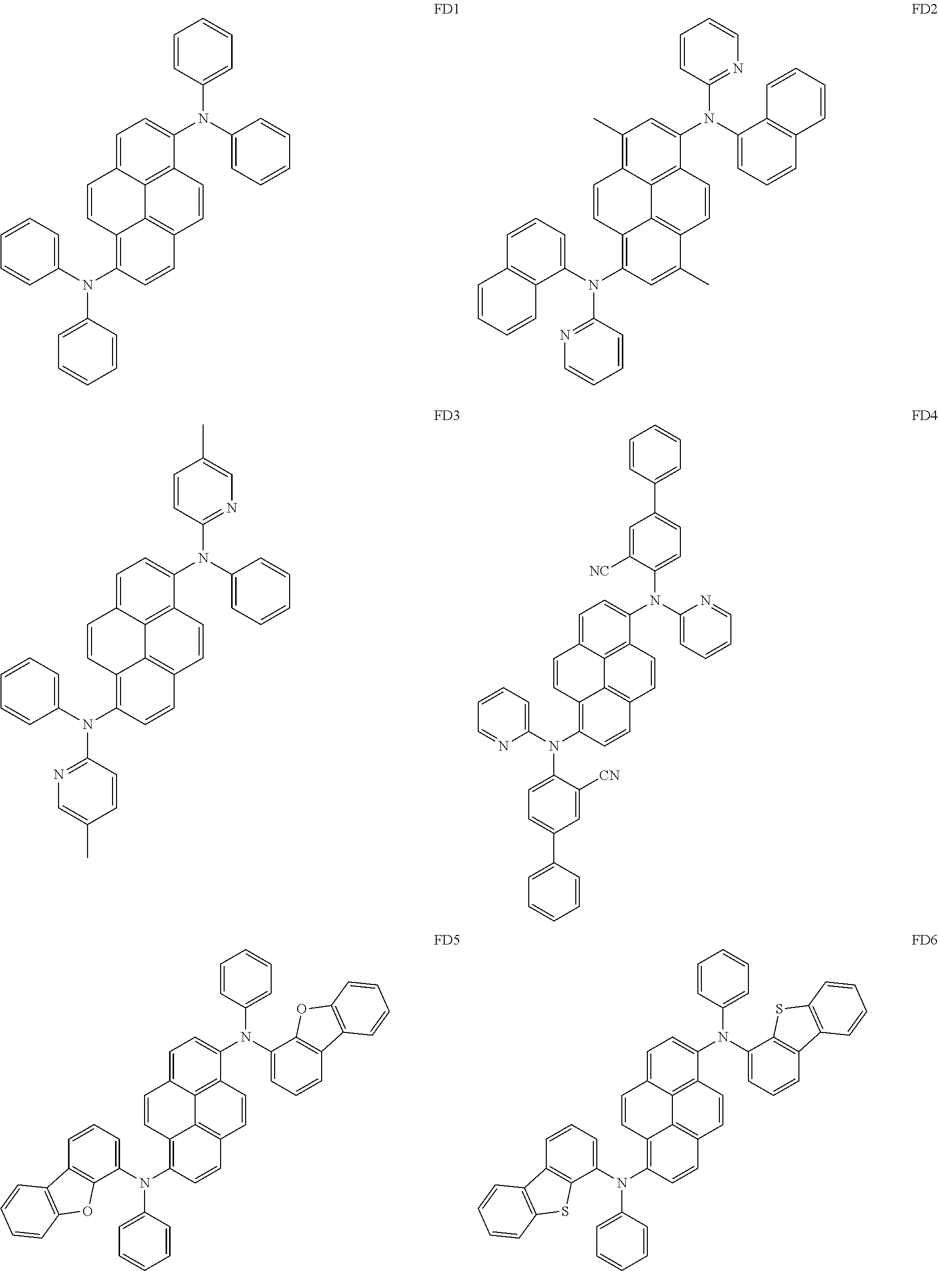

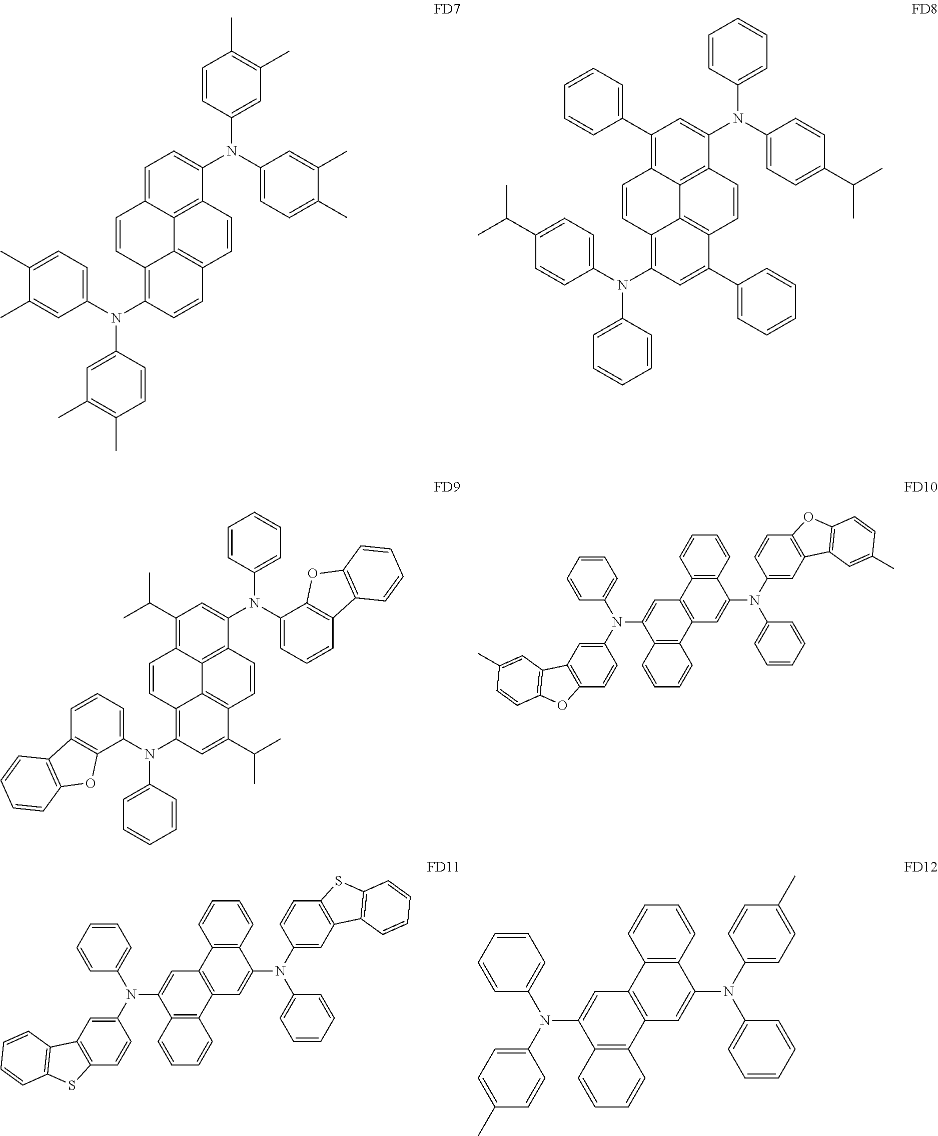

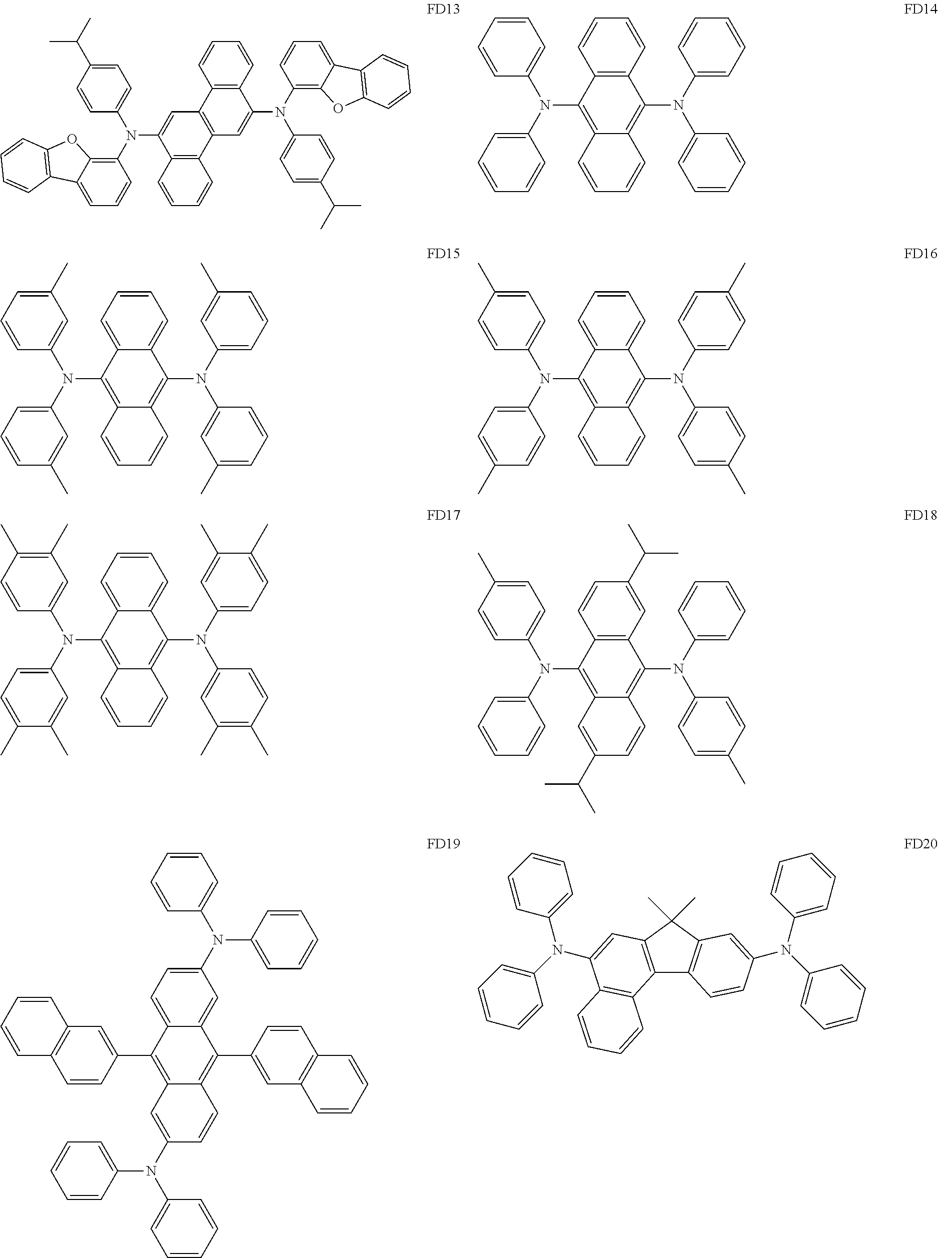

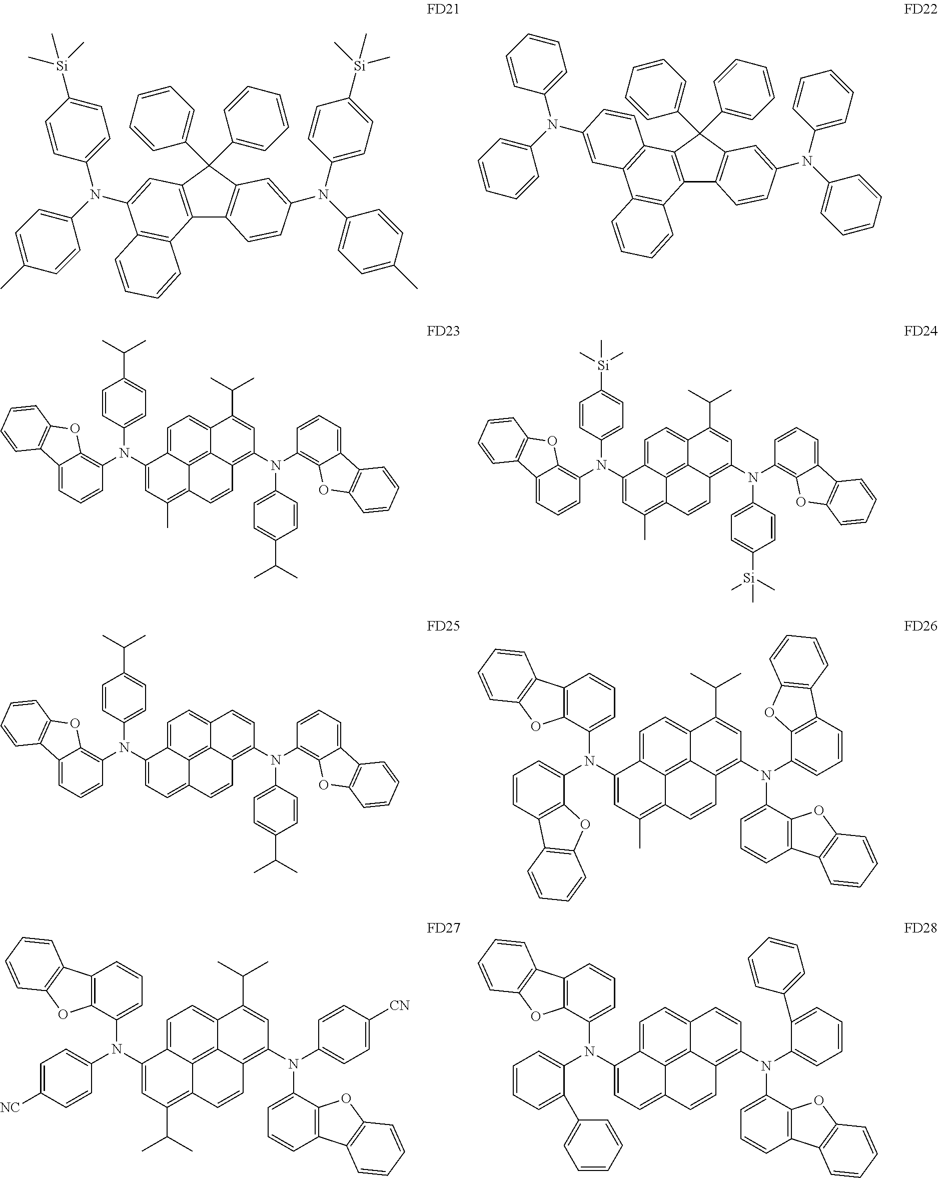

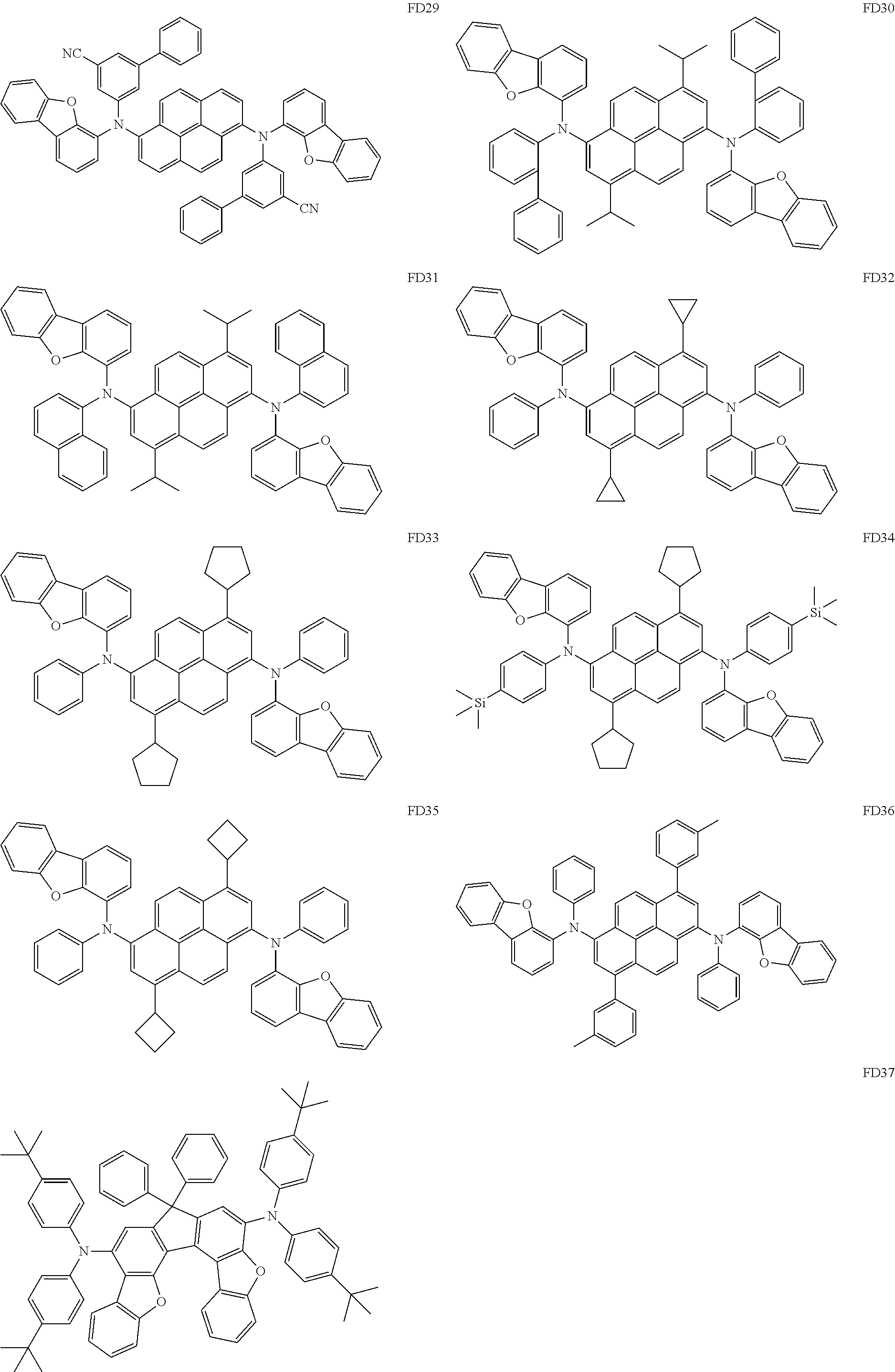

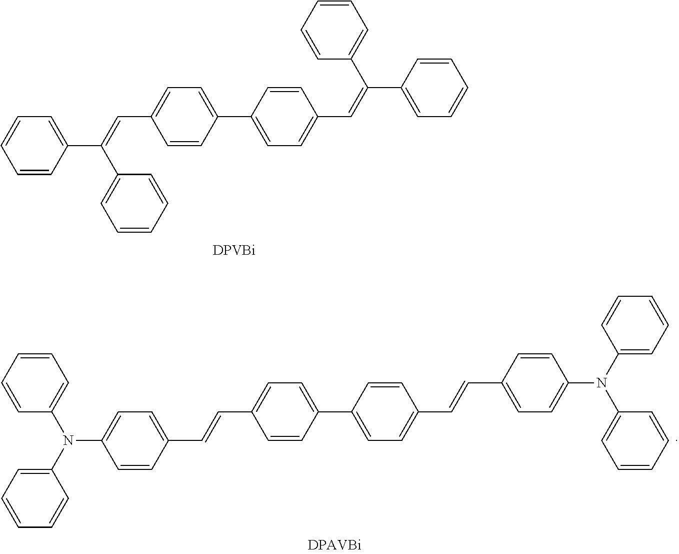

### [Delayed Fluorescence Material]

In an embodiment, the emission layer 130 may include a delayed fluorescence material.

In the specification, a delayed fluorescence material may be any compound that is capable of emitting delayed fluorescence, based on a delayed fluorescence emission mechanism.

The delayed fluorescence material included in the emission layer 130 may serve as a host or as a dopant, depending on the types of other materials included in the emission layer 130.

According to an embodiment, a difference between a triplet energy level (eV) of the delayed fluorescence material and a singlet energy level (eV) of the delayed fluorescence material may be in a range of about 0 eV to about 0.5 eV. When a difference between a triplet energy level (eV) of the delayed fluorescence material and a singlet energy level (eV) of the delayed fluorescence material is within the range described above, up-conversion from the triplet state to the singlet state of the delayed fluorescence material may effectively occur, and thus, the light-emitting device 10 may have improved luminescence efficiency.

In an embodiment, the delayed fluorescence material may include: a material including at least one electron donor (for example, a π electron-rich C₃-C₆₀ cyclic group, such as a carbazole group) and at least one electron acceptor (for example, a sulfoxide group, a cyano group, or a π electron-deficient nitrogen-containing C₁-C₆₀ cyclic group); or a material including a C₈-C₆₀ polycyclic group in which two or more cyclic groups are condensed while sharing boron (B).

In an embodiment, the delayed fluorescence material may include, for example, at least one of Compounds DF1 to DF14:

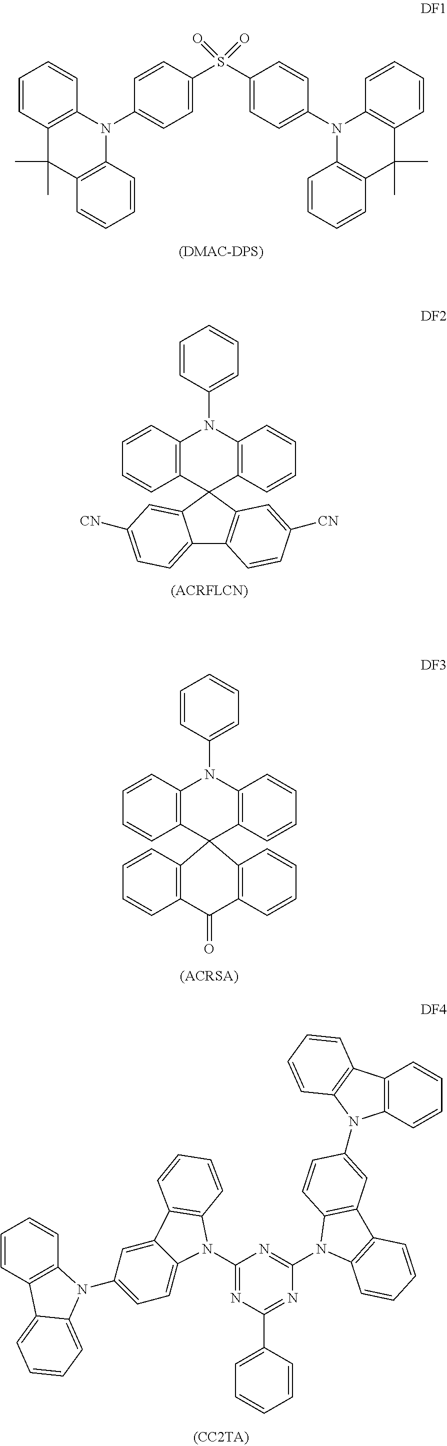

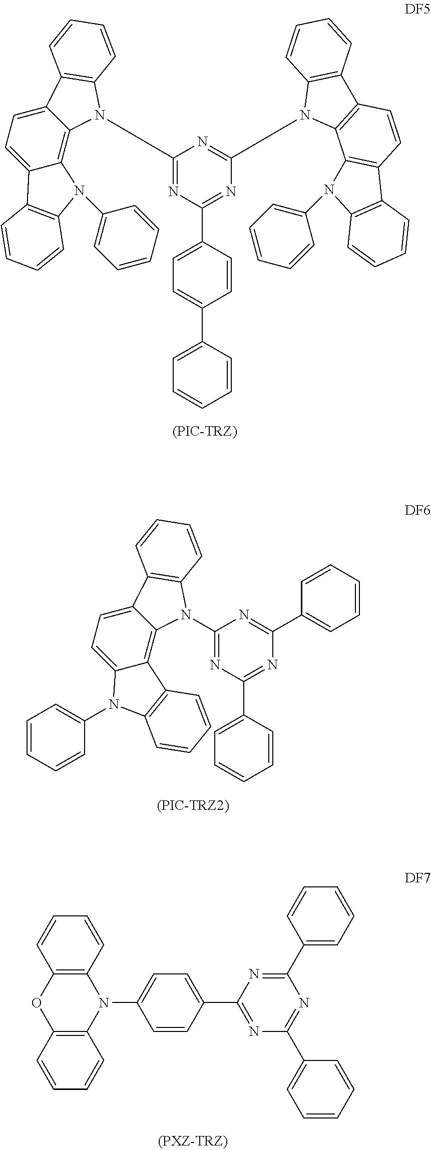 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-n3c4ccccc4c4ccc5c(c6ccccc6n5-c5ccccc5)c43)n2)cc1 ; c1ccc(-c2nc(-c3ccccc3)nc(-c3ccc(N4c5ccccc5Oc5ccccc54)cc3)n2)cc1]

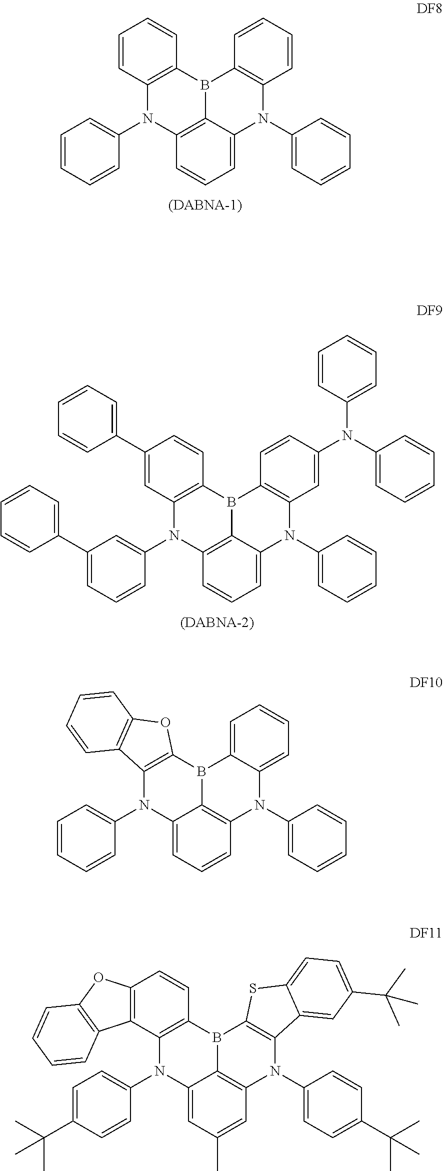

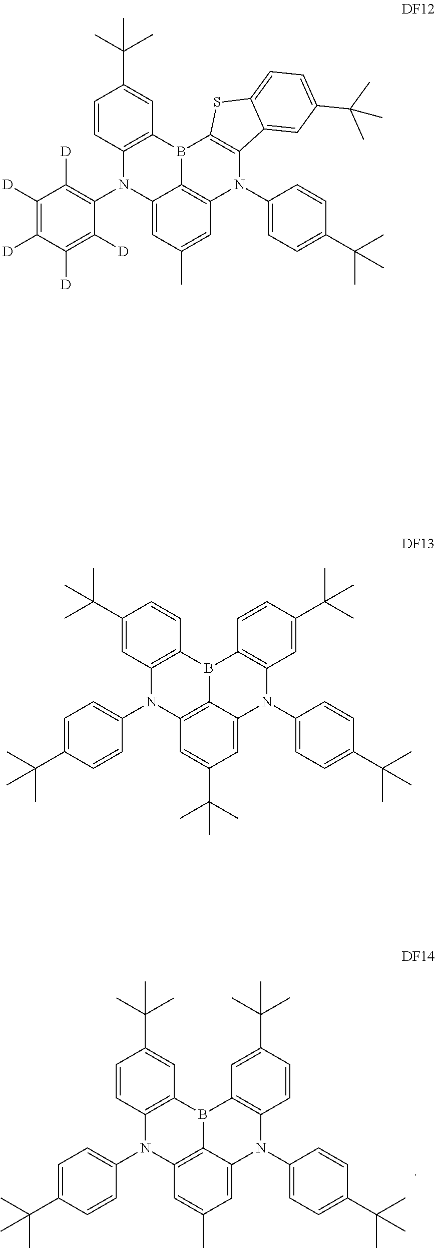

### [Quantum Dot]

The emission layer 130 may include a quantum dot.

In the specification, a quantum dot may be a crystal of a semiconductor compound, and may include any material capable of emitting light of various emission wavelengths according to a size of the crystal.

A diameter of the quantum dot may be, for example, in a range of about 1 nm to about 10 nm.

The quantum dot may be synthesized by a wet chemical process, a metal organic chemical vapor deposition process, a molecular beam epitaxy process, or any process similar thereto.

The wet chemical process is a method that includes mixing a precursor material with an organic solvent and growing a quantum dot particle crystal. When the crystals grow, the organic solvent naturally serves as a dispersant coordinated on the surface of the quantum dot crystals and controls the growth of the crystals so that the growth of quantum dot particles may be controlled through a process which costs less and may be more readily performed than vapor deposition methods, such as metal organic chemical vapor deposition (MOCVD) or molecular beam epitaxy (MBE).

The quantum dot may include a Group II-VI semiconductor compound, a Group III-V semiconductor compound, a Group III-VI semiconductor compound, a Group I-III-VI semiconductor compound, a Group IV-VI semiconductor compound, a Group IV element or compound, or any combination thereof.

Examples of a Group II-VI semiconductor compound may include: a binary compound, such as CdS, CdSe, CdTe, ZnS, ZnSe, ZnTe, ZnO, HgS, HgSe, HgTe, MgSe, MgS, etc.; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, etc.; a quaternary compound, such as CdZnSeS, CdZnSeTe, CdZnSTe, CdHgSeS, CdHgSeTe, CdHgSTe, HgZnSeS, HgZnSeTe, HgZnSTe, etc.; and any combination thereof.

Examples of a Group III-V semiconductor compound may include: a binary compound, such as GaN, GaP, GaAs, GaSb, AlN, AlP, AlAs, AlSb, InN, InP, InAs, InSb, etc.; a ternary compound, such as GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, etc.; a quaternary compound, such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, etc.; and any combination thereof. In embodiments, a Group III-V semiconductor compound may further include a Group II element. Examples of a Group III-V semiconductor compound further including a Group II element may include InZnP, InGaZnP, InAlZnP, etc.

Examples of a Group III-VI semiconductor compound may include: a binary compound, such as GaS, GaSe, Ga₂Se₃, GaTe, InS, InSe, In₂S₃, In₂Se₃, InTe, etc.; a ternary compound, such as InGaS₃, InGaSe₃, etc.; and any combination thereof.

Examples of a Group I-III-VI semiconductor compound may include: a ternary compound, such as AgInS, AgInS₂, CuInS, CuInS₂, CuGaO₂, AgGaO₂, AgAlO₂, etc.; a quaternary compound, such as CuInGaS, CulnGaS₂, AgInGaS, AgInGaS₂, AgInGaSe, AgInGaS₂, etc.; and any combination thereof.

Examples of a Group IV-VI semiconductor compound may include: a binary compound, such as SnS, SnSe, SnTe, PbS, PbSe, PbTe, or the like; a ternary compound, such as SnSeS, SnSeTe, SnSTe, PbSeS, PbSeTe, PbSTe, SnPbS, SnPbSe, SnPbTe, or the like; a quaternary compound, such as SnPbSSe, SnPbSeTe, SnPbSTe, or the like; and any combination thereof.

Examples of a Group IV element or compound may include: a single element material, such as Si, Ge, etc.; a binary compound, such as SiC, SiGe, etc.; and any combination thereof.

Each element included in a compound such as a binary compound, a ternary compound, or a quaternary compound may be present in a particle at a uniform concentration or at a non-uniform concentration.

In embodiments, the quantum dots may have a single structure, in which the concentration of each element in the quantum dots is uniform, or the quantum dot may have a core-shell structure. In an embodiment, in case that the quantum dot has a core-shell structure, a material included in the core and a material included in the shell may be different from each other.

The shell of a quantum dot may serve as a protective layer that prevents chemical degeneration of the core to maintain semiconductor characteristics, and/or may serve as a charging layer that imparts electrophoretic characteristics to the quantum dot. The shell may be single-layered or multilayered. An interface between the core and the shell may have a concentration gradient in which the concentration of a material that is present in the shell decreases toward the core.

Examples of a shell of a quantum dot may include a metal oxide, a metalloid oxide, a non-metal oxide, a semiconductor compound, and any combination thereof. Examples of a metal oxide, a metalloid oxide, or a non-metal oxide may include: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, etc.; a ternary compound, such as MgAl₂O₄, CoFe₂O₄, NiFe₂O₄, CoMn₂O₄, etc.; and any combination thereof.

Examples of a semiconductor compound may include, as described above: a Group II-VI semiconductor compound; a Group III-V semiconductor compound; a Group III-VI semiconductor compound; a Group I-III-VI semiconductor compound; a Group IV-VI semiconductor compound; and any combination thereof. In an embodiment, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or any combination thereof.

A full width at half maximum (FWHM) of an emission wavelength spectrum of the quantum dot may be less than or equal to about 45 nm. For example, an FWHM of an emission wavelength spectrum of the quantum dot may be less than or equal to about 40 nm. For example, an FWHM of an emission wavelength spectrum of the quantum dot may be less than or equal to about 30 nm. When the FWHM is within any of these ranges, color purity or color reproducibility may be increased. Light emitted through a quantum dot may be emitted in all directions, so that a wide viewing angle may be improved.

In an embodiment, the quantum dot may be in the form of a spherical particle, a pyramidal particle, a multi-arm particle, a cubic nanoparticle, a nanotube particle, a nanowire particle, a nanofiber particle, or a nanoplate particle.

Since an energy band gap may be adjusted by controlling the size of the quantum dot, light having various wavelength bands may be obtained from a quantum dot emission layer. Accordingly, by using quantum dots of different sizes, a light-emitting device that emits light of various wavelengths may be implemented. In an embodiment, the size of the quantum dot may be selected to emit red light, green light, and/or blue light. The size of the quantum dot may be configured to emit white light by combining light of various colors.

### [Electron Transport Region 140]

The electron transport region 140 may have a structure consisting of a layer consisting of a single material, a structure consisting of a layer including different materials, or a structure consisting of multiple layers including different materials.

The electron transport region 140 may include a buffer layer, a hole-blocking layer, an electron control layer, an electron transport layer, an electron injection layer, or any combination thereof.

In embodiments, the electron transport region 140 may have an electron transport layer/electron injection layer structure, a hole-blocking layer/electron transport layer/electron injection layer structure, an electron control layer/electron transport layer/electron injection layer structure, or a buffer layer/electron transport layer/electron injection layer structure, wherein the layers of each structure may be stacked from the emission layer 130 in its respective stated order, but the structure of the electron transport region 140 is not limited thereto.

In an embodiment, the electron transport region 140 (for example, a buffer layer, a hole-blocking layer, an electron control layer, or an electron transport layer in the electron transport region 140) may include a metal-free compound including at least one π electron-deficient nitrogen-containing C₁-C₆₀ cyclic group.

In an embodiment, the electron transport region 140 may include a compound represented by Formula 601:

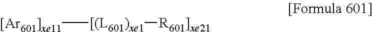

In Formula 601,
Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each independently be the same as described in connection with Q₁,
xe21 may be 1, 2, 3, 4, or 5, and
at least one of Ar₆₀₁, L₆₀₁, and R₆₀₁ may each independently be a π electron-deficient nitrogen-containing C₁-C₆₀ cyclic group unsubstituted or substituted with at least one R₁₀ₐ.

In an embodiment, in Formula 601, when xe11 is 2 or more, two or more of Ar₆₀₁ may be linked to each other via a single bond.

In embodiments, in Formula 601, Ar₆₀₁ may be an anthracene group unsubstituted or substituted with at least one R₁₀ₐ.

In embodiments, the electron transport region 140 may include a compound represented by Formula 601-1:

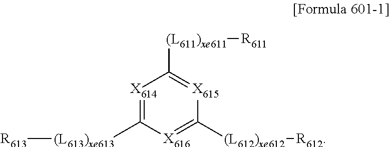

In Formula 601-1,
X₆₁₄ may be N or C(R₆₁₄), X₆₁₅ may be N or C(R₆₁₅), X₆₁₆ may be N or C(R₆₁₆), and at least one of X₆₁₄ to X₆₁₆ may each be N,
L₆₁₁ to L₆₁₃ may each independently be the same as described in connection with L₆₀₁,
xe611 to xe613 may each independently be the same as described in connection with xe1,
R₆₁₁ to R₆₁₃ may each independently be the same as described in connection with R₆₀₁, and
R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

In an embodiment, in Formulae 601 and 601-1, xe1 and xe611 to xe613 may each independently be 0, 1, or 2.

In an embodiment, the electron transport region 140 may include one of Compounds ET1 to ET45, 2,9-dimethyl-4,7-diphenyl-1,10-phenanthroline (BCP), 4,7-diphenyl-1,10-phenanthroline (Bphen), Alq₃, BAlq, TAZ, NTAZ, or any combination thereof:

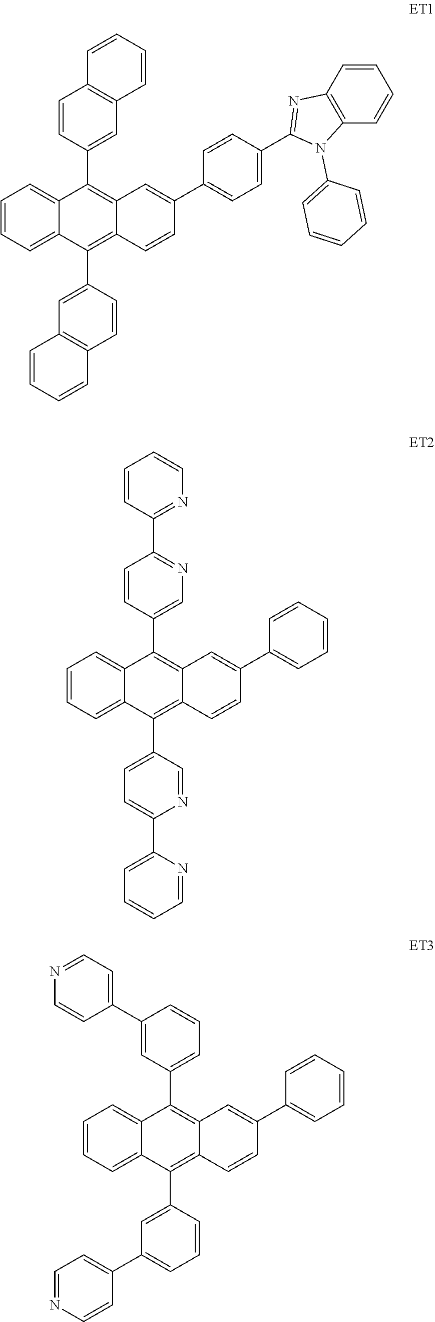 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

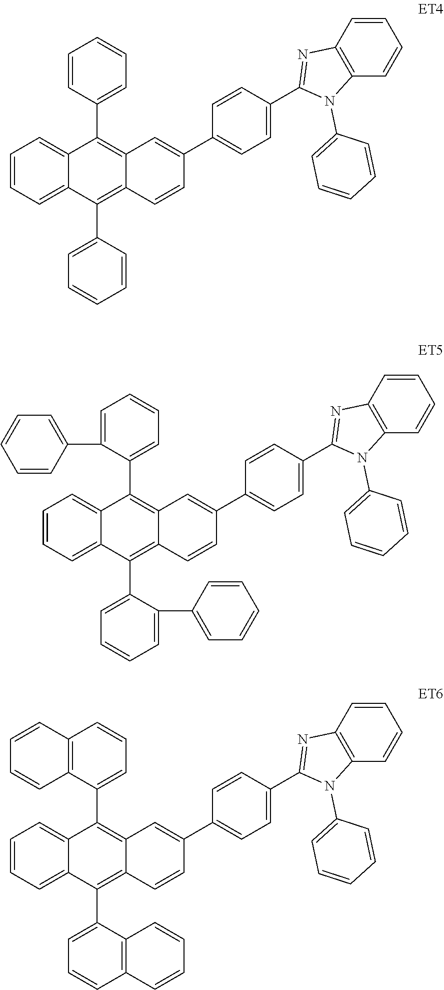 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

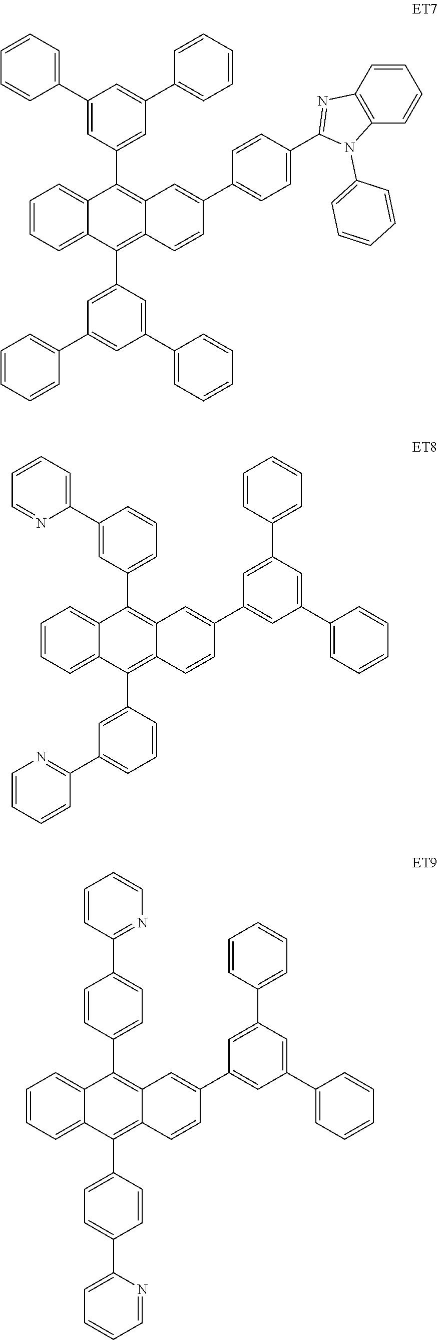 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

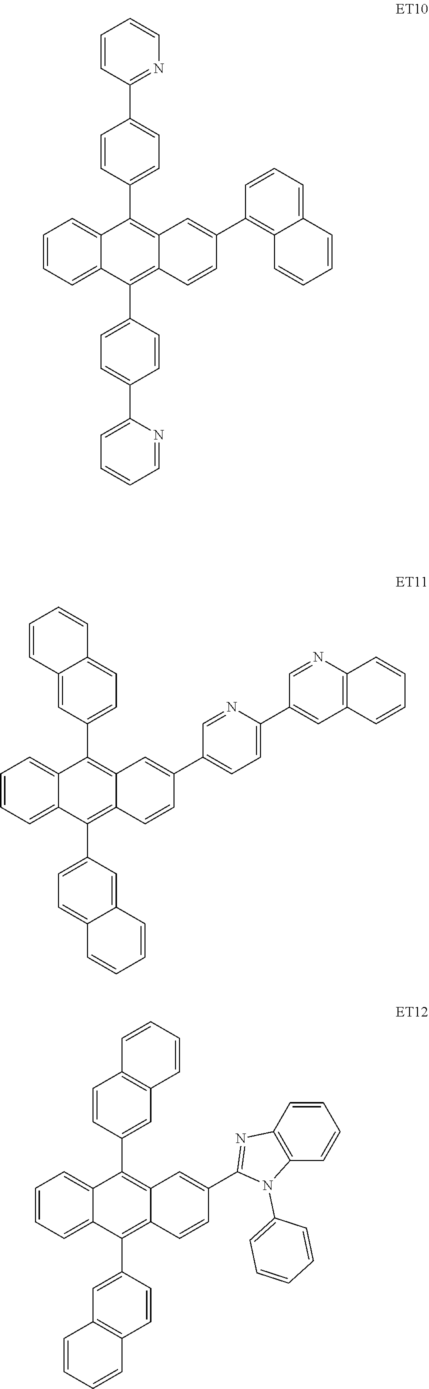 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

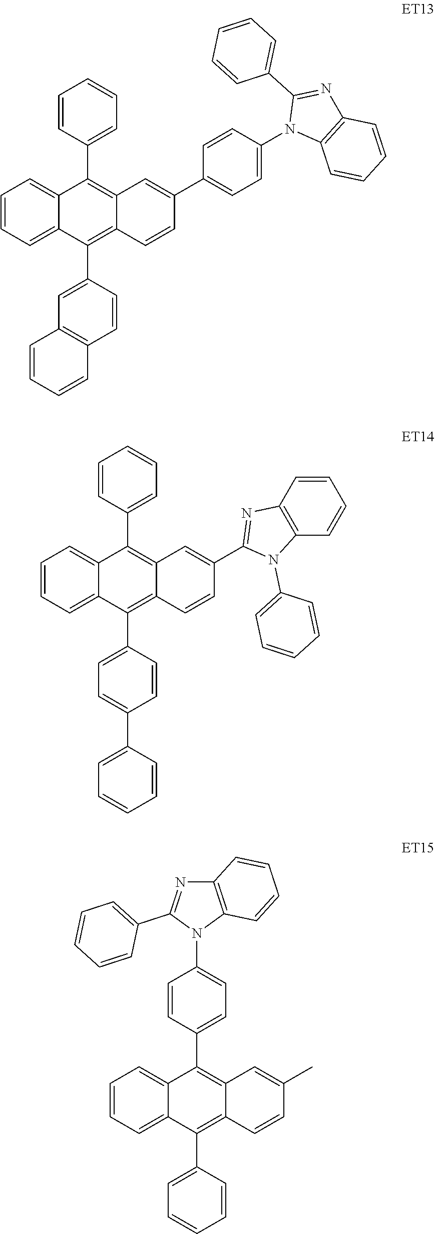 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

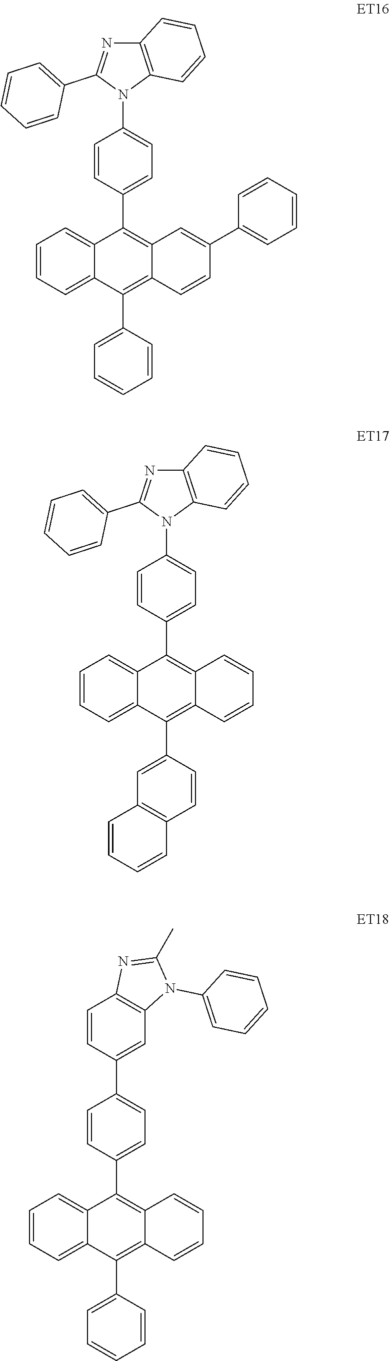 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

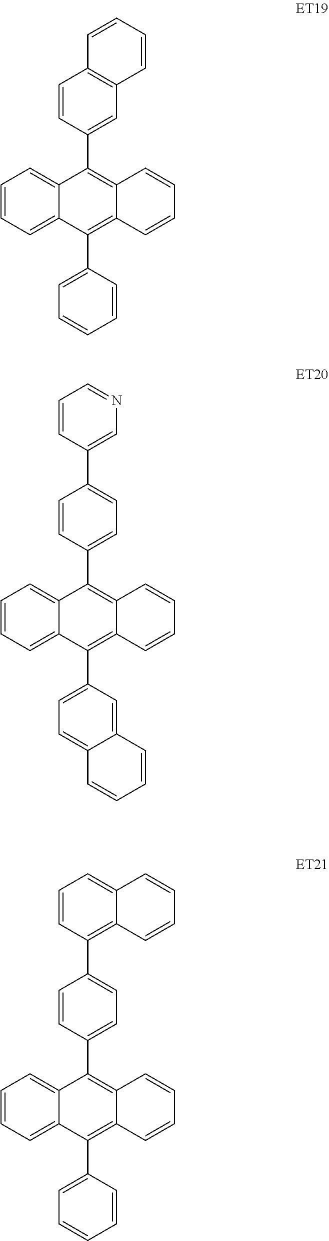

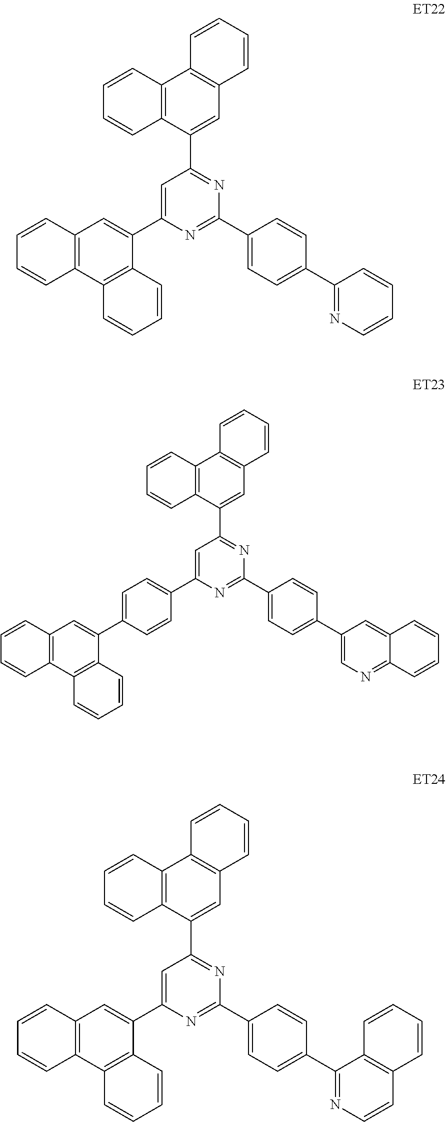 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

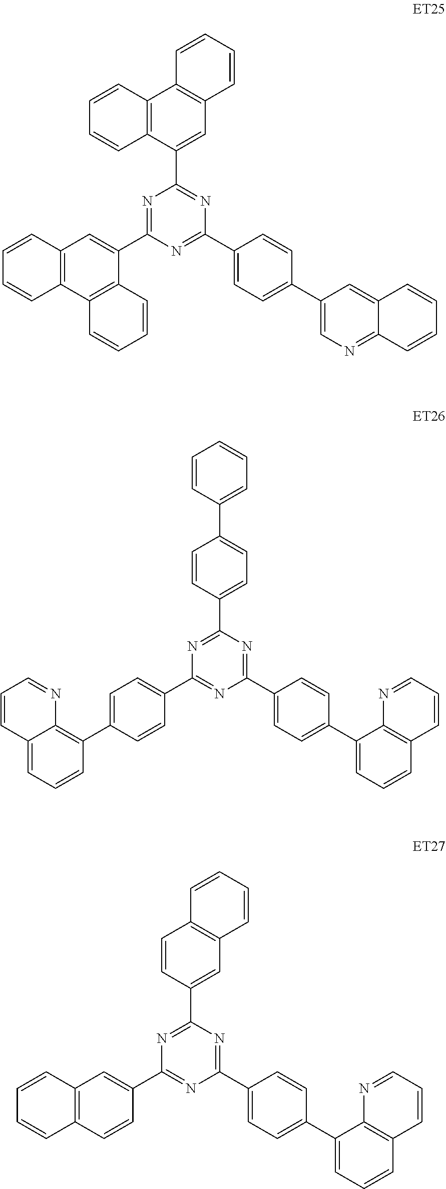 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

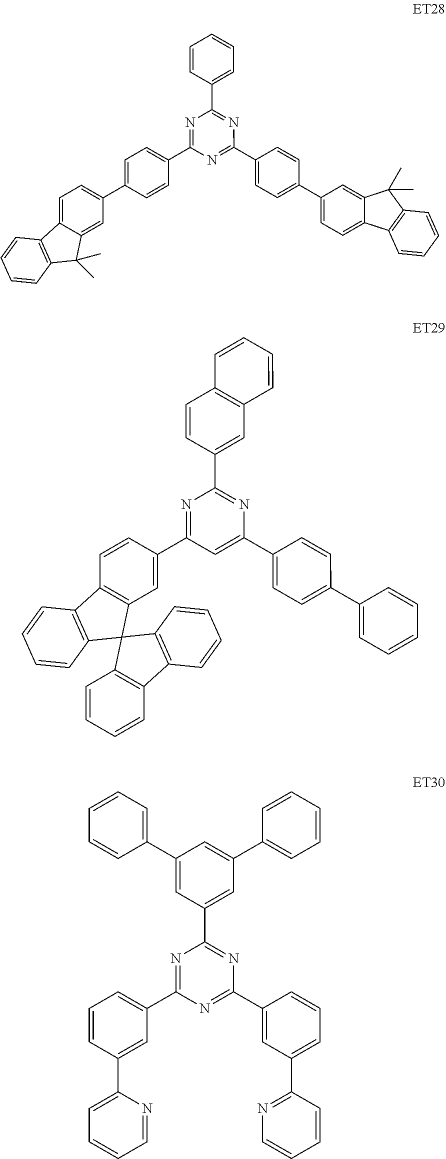 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

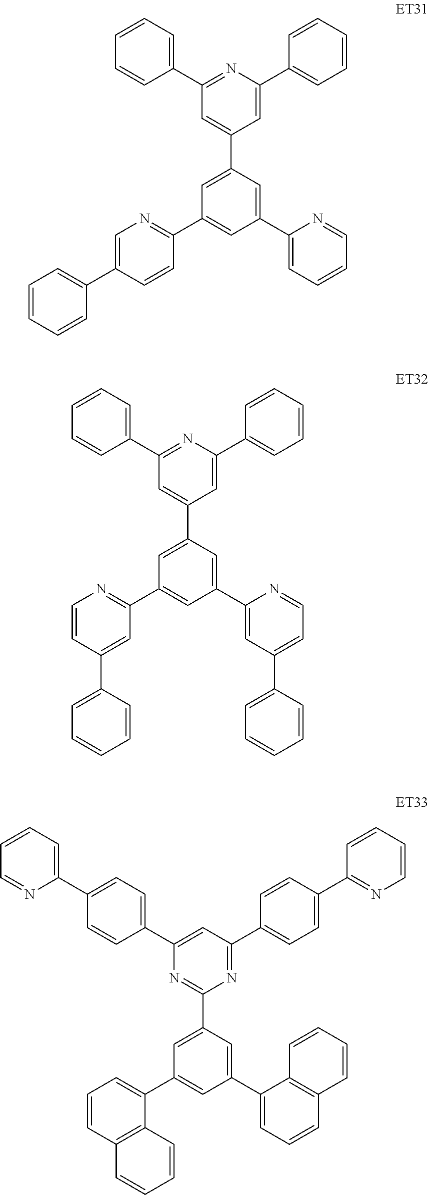 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

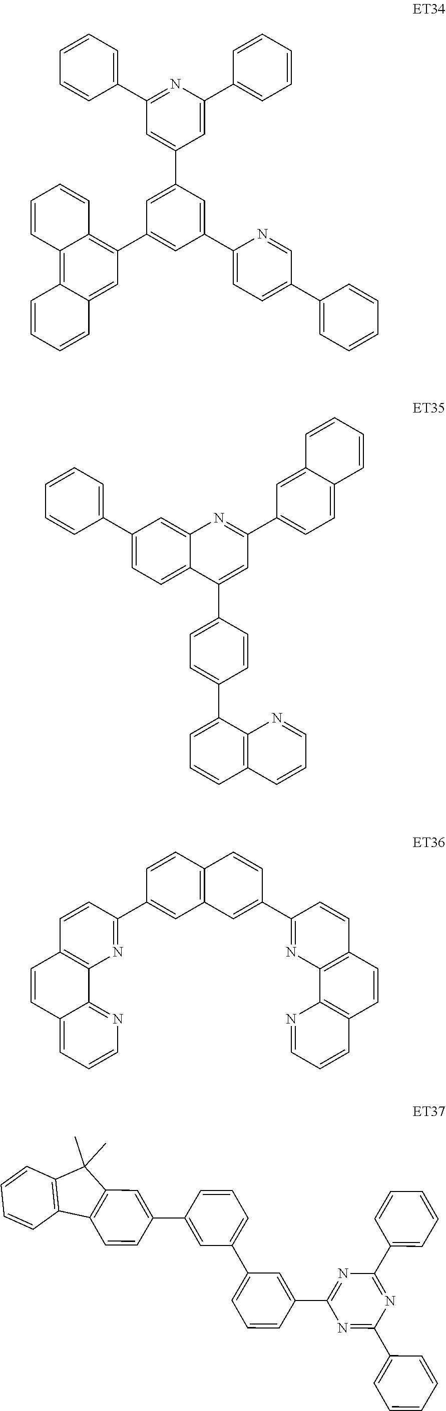 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12 ; CC1(C)c2ccccc2-c2ccc(-c3cccc(-c4cccc(-c5nc(-c6ccccc6)nc(-c6ccccc6)n5)c4)c3)cc21]

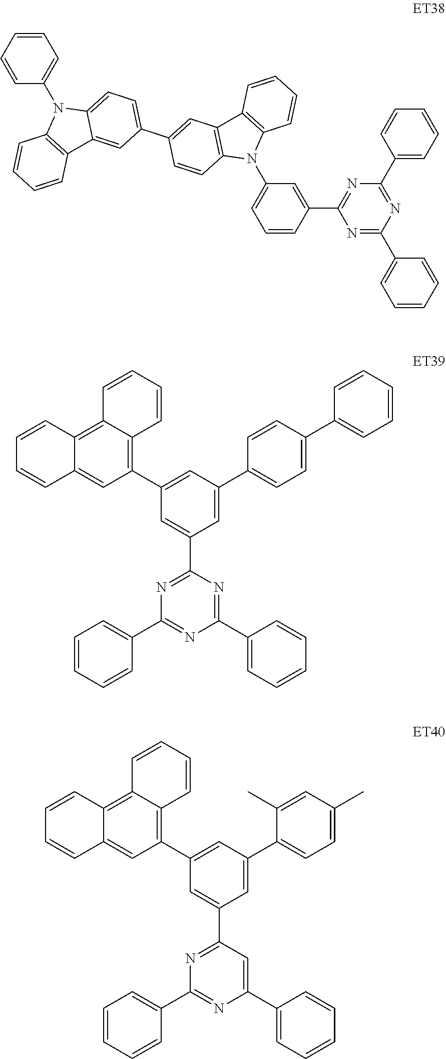 [SMILES: c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2ccc(-c3cc(-c4nc(-c5ccccc5)nc(-c5ccccc5)n4)cc(-c4cc5ccccc5c5ccccc45)c3)cc2)cc1 ; Cc1ccc(-c2cc(-c3cc(-c4ccccc4)nc(-c4ccccc4)n3)cc(-c3cc4ccccc4c4ccccc34)c2)c(C)c1]

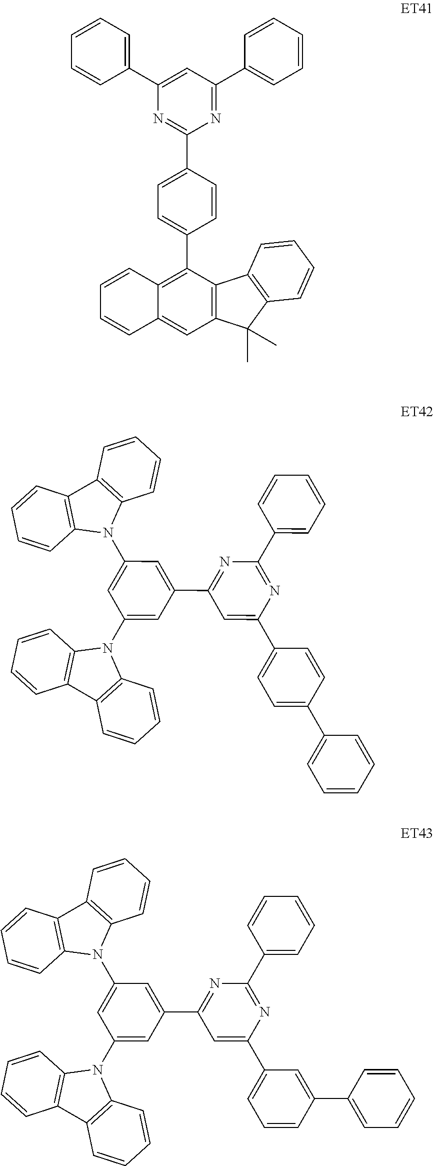 [SMILES: CC1(C)c2ccccc2-c2c1cc1ccccc1c2-c1ccc(-c2nc(-c3ccccc3)cc(-c3ccccc3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1]

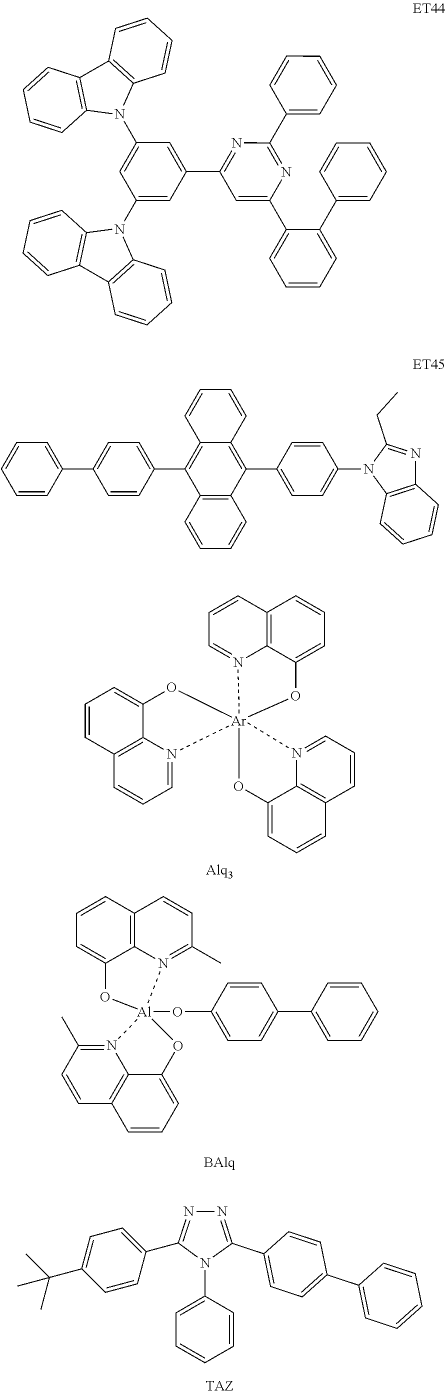

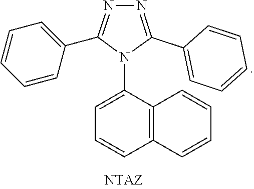 [SMILES: c1ccc(-c2nnc(-c3ccccc3)n2-c2cccc3ccccc23)cc1]

A thickness of the electron transport region 140 may be in a range of about 100 Å to about 5,000 Å. For example, the thickness of the electron transport region 140 may be in a range of about 160 Å to about 4,000 Å. When the electron transport region 140 includes a buffer layer, a hole-blocking layer, an electron control layer, an electron transport layer, or any combination thereof, a thickness of the buffer layer, the hole-blocking layer, or the electron control layer may each independently be in a range of about 20 Å to about 1,000 Å, and a thickness of the electron transport layer may be in a range of about 100 Å to about 1,000 Å. For example, the thickness of the buffer layer, the hole-blocking layer, or the electron control layer may each independently be in a range of about 30 Å to about 300 Å. For example, the thickness of the electron transport layer may be in a range of about 150 Å to about 500 Å. When the thicknesses of the buffer layer, the hole-blocking layer, the electron control layer, the electron transport layer, and/or the electron transport region are within the ranges described above, satisfactory electron transporting characteristics may be obtained without a substantial increase in driving voltage.

The electron transport region 140 (for example, an electron transport layer in the electron transport region 140) may further include, in addition to the aforementioned materials, a metal-containing material.

The metal-containing material may include an alkali metal complex, an alkaline earth metal complex, or any combination thereof. A metal ion of the alkali metal complex may be a Li ion, a Na ion, a K ion, a Rb ion, or a Cs ion, and a metal ion of the alkaline earth metal complex may be a Be ion, a Mg ion, a Ca ion, a Sr ion, or a Ba ion. A ligand coordinated with a metal ion of an alkali metal complex or an alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

In an embodiment, the metal-containing material may include a Li complex. The Li complex may include, for example, Compound ET-D1 (LiQ) or Compound ET-D2:

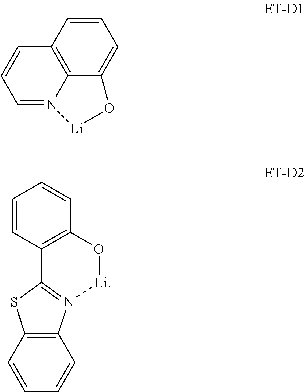

The electron transport region 140 may include an electron injection layer that facilitates the injection of electrons from the second electrode 150. The electron injection layer may contact (e.g., directly contact) the second electrode 150, but embodiments are not limited thereto.

The electron injection layer may have a structure consisting of a layer consisting of a single material, a structure consisting of a layer including different materials, or a structure including multiple layers including different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may include oxides, halides (for example, fluorides, chlorides, bromides, iodides, etc.), or tellurides of the alkali metal, the alkaline earth metal, and the rare earth metal, or any combination thereof.

The alkali metal-containing compound may include: an alkali metal oxide, such as Li₂O, Cs₂O, K₂O, etc.; an alkali metal halide, such as LiF, NaF, CsF, KF, LiI, NaI, CsI, KI, etc.; or any combination thereof. The alkaline earth metal-containing compound may include an alkaline earth metal compound, such as BaO, SrO, CaO, BaₓSr₁₋ₓO (wherein x is a real number satisfying 0<x<1), BaₓCa₁₋ₓO (wherein x is a real number satisfying 0<x<1), and the like. The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. In embodiments, the rare earth metal-including compound may include a lanthanide metal telluride. Examples of a lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, Lu₂Te₃, and the like.

The alkali metal complex, the alkaline earth-metal complex, and the rare earth metal complex may include an alkali metal ion, an alkaline earth metal ion, or a rare earth metal ion; and a ligand bonded to the metal ion (for example, a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenyl benzimidazole, a hydroxyphenylbenzothiazole, a bipyridine, a phenanthroline, a cyclopentadiene, or any combination thereof).

In an embodiment, the electron injection layer may consist of an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In an embodiment, the electron injection layer may further include an organic material (for example, a compound represented by Formula 601).

According to an embodiment, the electron injection layer may consist of an alkali metal-containing compound (for example, an alkali metal halide); or the electron injection layer may consist of an alkali metal-containing compound (for example, alkali metal halide), and an alkali metal, an alkaline earth metal, a rare earth metal, or any combination thereof. For example, the electron injection layer may be a KI:Yb co-deposited layer, an RbI:Yb co-deposited layer, a LiF:Yb co-deposited layer, and the like.

When the electron injection layer further includes an organic material, an alkali metal, an alkaline earth metal, a rare earth metal, an alkali metal-containing compound, a alkaline earth metal-containing compound, a rare earth metal-containing compound, an alkali metal complex, an alkaline earth-metal complex, a rare earth metal complex, or any combination thereof may be uniformly or non-uniformly dispersed in a matrix including the organic material.

A thickness of the electron injection layer may be in a range of about 1 Å to about 100 Å. For example, the thickness of the electron injection layer may be in a range of about 3 Å to about 90 Å. When the thickness of the electron injection layer is within any of the ranges as described above, satisfactory electron injection characteristics may be obtained without a substantial increase in driving voltage.

### [Second Electrode 150]

The second electrode 150 may be arranged on the electron transport region 140. The second electrode 150 may be a cathode, which is an electron injection electrode. When the second electrode 150 is a cathode, a material for forming the second electrode may include a material having a low-work function such as a metal, an alloy, an electrically conductive compound, or any combination thereof.

The second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 150 may be a transmissive electrode, a transflective electrode, or a reflective electrode.

The second electrode 150 may have a single-layered structure or a multilayered structure.

### [Capping Layer]

The optoelectronic device 30, 31, and 32 and the light-emitting device 10 may include a first capping layer outside the first electrode 110, and/or a second capping layer outside the second electrode 150.

In an embodiment, the light-emitting device 10 may have a structure in which a first capping layer, a first electrode 110, an emission layer 130, and a second electrode 150 are stacked in this stated order.

In embodiments, the light-emitting device 10 may have a structure in which a first electrode 110, an emission layer 130, a second electrode 150, and a second capping layer are stacked in this stated order.

In embodiments, the light-emitting device 10 may have a structure in which a first capping layer, a first electrode 110, an emission layer 130, a second electrode 150, and a second capping layer are stacked in this stated order.

Light generated in the emission layer 130 of the light-emitting device 10 may pass through the first electrode 110, which may be a transflective electrode or a transmissive electrode, and through the first capping layer to the outside. Light generated in the emission layer 130 of the light-emitting device 10 may pass through the second electrode 150, which may be a transflective electrode or a transmissive electrode, and through the second capping layer to the outside.

The first capping layer and the second capping layer may each increase external emission efficiency according to the principle of constructive interference. Accordingly, the light extraction efficiency of the light-emitting device 10 may be increased, such that the luminescence efficiency of the light-emitting device 10 may be improved.

The first capping layer and the second capping layer may each include a material having a refractive index equal to or greater than about 1.6 (with respect to a wavelength in a range of about 520 nm to about 630 nm).

The first capping layer and the second capping layer may each independently be an organic capping layer including an organic material, an inorganic capping layer including an inorganic material, or an organic-inorganic composite capping layer including an organic material and an inorganic material.

At least one of the first capping layer and the second capping layer may each independently include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may optionally be substituted with a substituent including O, N, S, Se, Si, F, Cl, Br, I, or any combination thereof. According to an embodiment, at least one of the first capping layer and the second capping layer may each independently include an amine group-containing compound.

In an embodiment, at least one of the first capping layer and the second capping layer may each independently include a compound represented by Formula 201, a compound represented by Formula 202, or any combination thereof.

According to embodiments, at least one of the first capping layer and the second capping layer may each independently include one of Compounds HT28 to HT33, one of Compounds CP1 to CP6, β-NPB, or any combination thereof:

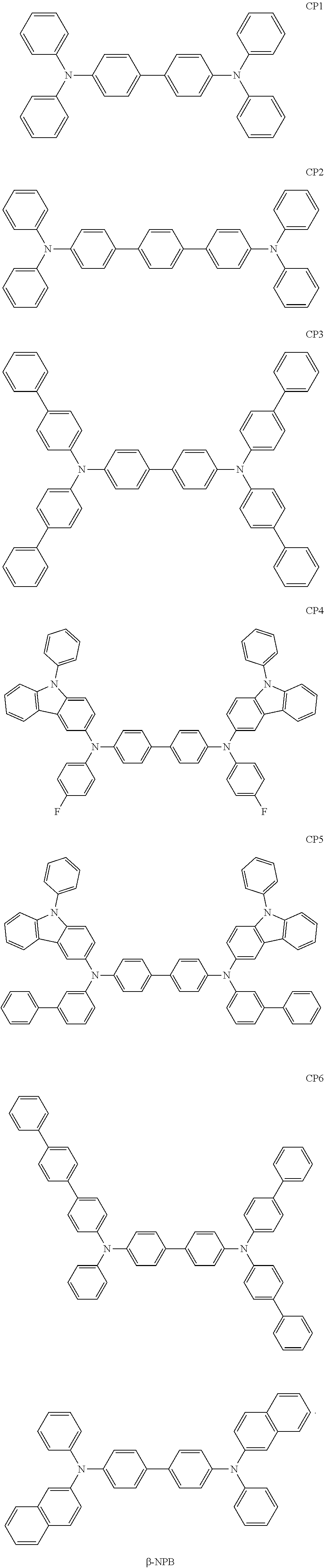

### [Film]

In an embodiment, the electronic apparatus may further include a film. The film may be, for example, an optical member (or a light control means) (for example, a color filter, a color conversion member, a capping layer, a light extraction efficiency enhancement layer, a selective light absorbing layer, a polarizing layer, a quantum dot-containing layer, etc.), a light blocking member (for example, a light reflective layer, a light absorbing layer, etc.), a protective member (for example, an insulating layer, a dielectric layer, etc.).

### [Electronic Apparatus]

The light-emitting device 10 and the optoelectronic device 30, 31, and 32 may be included in various electronic apparatuses.

The electronic apparatus (for example, light-emitting device) may further include, in addition to the light-emitting device 10 and the optoelectronic device 30, 31, and 32, a color filter, a color conversion layer, or a color filter and a color conversion layer. The color filter and/or the color-conversion layer may be arranged in at least one direction in which light emitted from the light-emitting device 10 travels. For example, the light emitted from the light-emitting device 10 may be blue light or white light. The light-emitting device 10 may be the same as described herein. The color conversion layer may include quantum dots. The quantum dot may be, for example, a quantum dot as described herein.

The electronic apparatus may include a substrate. The substrate may include subpixels, the color filter may include color filter areas respectively corresponding to the subpixels, and the color conversion layer may include color conversion areas respectively corresponding to the subpixels.

A pixel-defining film may be arranged between the subpixels to define each subpixel.

The color filter may further include color filter areas and light-shielding patterns arranged between the color filter areas, and the color conversion layer may further include color conversion areas and light-shielding patterns arranged between the color conversion areas.

The color filter areas (or the color conversion areas) may include a first area emitting first color light, a second area emitting second color light, and/or a third area emitting third color light, wherein the first color light, the second color light, and/or the third color light may have different maximum emission wavelengths from one another. In an embodiment, the first color light may be red light, the second color light may be green light, and the third color light may be blue light. In an embodiment, the color filter areas (or the color conversion areas) may include quantum dots. In an embodiment, the first area may include red quantum dots, the second area may include green quantum dots, and the third area may not include quantum dots. The quantum dot may be the same as described herein. The first area, the second area, and/or the third area may each further include a scatterer.

In an embodiment, the light-emitting device 10 may emit first light, the first area may absorb the first light to emit first-first color light, the second area may absorb the first light to emit second-first color light, and the third area may absorb the first light to emit third-first color light. In an embodiment, the first-first color light, the second-first color light, and the third-first color light may have different maximum emission wavelengths. For example, the first light may be blue light, the first-first color light may be red light, the second-first color light may be green light, and the third-first color light may be blue light.

The electronic apparatus may further include a thin-film transistor, in addition to the optoelectronic device 30, 31, and 32, and the light-emitting device 10 as described above. The thin-film transistor may include a source electrode, a drain electrode, and an active layer, wherein any one of the source electrode and the drain electrode may be electrically connected to any one of the first electrode 110 and the second electrode 150 of the light-emitting device 10.

The thin-film transistor may further include a gate electrode, a gate insulating film, and the like.

The active layer may include crystalline silicon, amorphous silicon, an organic semiconductor, an oxide semiconductor, and the like.

The electronic apparatus may further include a sealing portion that seals the optoelectronic device 30, 31, and 32, and the light-emitting device 10. The sealing portion may be arranged between the color filter and/or the color conversion layer and the optoelectronic device 30, 31, and 32, and/or the light-emitting device 10. The sealing portion may allow light from the light-emitting device 10 to be extracted to the outside, and may prevent ambient air and moisture from penetrating into the optoelectronic device 30, 31, and 32, and the light-emitting device 10. The sealing portion may be a sealing substrate including a transparent glass substrate or a plastic substrate. The sealing portion may be a thin-film encapsulation layer that includes at least one of an organic layer and/or an inorganic layer. When the sealing portion is a thin-film encapsulation layer, the electronic apparatus may be flexible.

Various functional layers may be further included on the sealing portion, in addition to the color filter and/or the color conversion layer, according to the use of the electronic apparatus. Examples of the functional layers may include a touch screen layer and a polarizing layer. The touch screen layer may be a pressure-sensitive touch screen layer, a capacitive touch screen layer, or an infrared touch screen layer. The authentication apparatus may be, for example, a biometric authentication apparatus that authenticates an individual by using biometric information of a living body (for example, fingertips, pupils, etc.).

The authentication apparatus may further include a biometric information collection means, in addition to the optoelectronic device 30, 31, and 32, and the light-emitting device 10 as described above.

The electronic apparatus may be applied to various displays, light sources, lighting, personal computers (for example, mobile personal computers), mobile phones, digital cameras, electronic organizers, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, or endoscope displays), fish finders, various measuring instruments, meters (for example, meters for a vehicle, an aircraft, and a vessel), projectors, sensors (for example, automobile sensors and household sensors), solar cells, and the like.

Since the optoelectronic device 30, 31, and 32 has excellent optoelectronic characteristics, the electronic apparatus including the optoelectronic device 30, 31, and 32 may have a function of an optical sensor such as a fingerprint recognition sensor.

### [Description of FIGS. 5 and 6]

FIG. 5 is a schematic cross-sectional view of an electronic apparatus according to an embodiment.

The electronic apparatus of FIG. 5 may include a substrate 100, a thin-film transistor (TFT), a light-emitting device 10, an optoelectronic device 30, and a sealing portion 300. The optoelectronic device 30 of FIG. 5 may be the optoelectronic device 30 described with reference to FIG. 1, but is not limited thereto. For example, the optoelectronic device 30 of FIG. 5 may be the optoelectronic device 31 of FIG. 2 or the optoelectronic device 32 of FIG. 3.

The substrate 100 may be a flexible substrate, a glass substrate, or a metal substrate. A buffer layer 210 may be arranged on the substrate 100. The buffer layer 210 may prevent penetration of impurities through the substrate 100 and may provide a flat surface on the substrate 100.

The TFT may be arranged on the buffer layer 210. The TFT may include an active layer 220, a gate electrode 240, a source electrode 260, and a drain electrode 270.

The active layer 220 may include an inorganic semiconductor, such as silicon or polysilicon, an organic semiconductor, or an oxide semiconductor, and may include a source region, a drain region, and a channel region.

A gate insulating film 230 for insulating the active layer 220 from the gate electrode 240 may be arranged on the active layer 220, and the gate electrode 240 may be arranged on the gate insulating film 230.

An interlayer insulating film 250 may be arranged on the gate electrode 240. The interlayer insulating film 250 may be arranged between the gate electrode 240 and the source electrode 260 to insulate the gate electrode 240 from the source electrode 260, and between the gate electrode 240 and the drain electrode 270 to insulate the gate electrode 240 from the drain electrode 270.

The source electrode 260 and the drain electrode 270 may be arranged on the interlayer insulating film 250. The interlayer insulating film 250 and the gate insulating film 230 may be formed to expose a source region and a drain region of the active layer 220, and the source electrode 260 and the drain electrode 270 may respectively contact the exposed portions of the source region and the drain region of the active layer 220.

A light-emitting device 10 and an optoelectronic device 30 may be arranged on a thin-film transistor (TFT).

A thin-film transistor (TFT) electrically connected to the light-emitting device 10 may transmit an electrical signal that drives the light-emitting device 10. A thin-film transistor (TFT) electrically connected to the optoelectronic device 30 may transmit an electrical signal generated by the optoelectronic device 30. The thin-film transistor (TFT) may be covered and protected by a passivation layer 280. The passivation layer 280 may include an inorganic insulating film, an organic insulating film, or any combination thereof. The light-emitting device 10 and the optoelectronic device 30 may be arranged on the passivation layer 280.

The light-emitting device 10 may include the first electrode 110, a hole transport region 120, an emission layer 130, an electron transport region 140, and the second electrode 150. The optoelectronic device 30 may include a first electrode 110, a hole transport region 120, an optical activation layer 135, an electron transport region 140, and a second electrode 150. The first electrode 110 may be arranged on the passivation layer 280. The passivation layer 280 may not completely cover the source electrode 260 and the drain electrode 270 and may expose a portion of the source electrode 260 and the drain electrode 270. The first electrode 110 may be electrically connected to the exposed portion of the source electrode 260 and the drain electrode 270.

The pixel-defining film 290 including an insulating material may be arranged on the first electrode 110. The pixel-defining film 290 may expose an area of the first electrode 110. The pixel-defining film 290 may be a polyimide-based organic film or a polyacrylic organic film.

A hole transport region 120 may be arranged on the pixel-defining film 290. The hole transport region 120 included in the light-emitting device 10 and the hole transport region 120 included in the optoelectronic device 30 may be integrally formed. The hole transport region 120 included in the light-emitting device 10 and the hole transport region 120 included in the optoelectronic device 30 may be arranged on the pixel-defining film 290, may be connected to each other, may include substantially a same material, and may be formed substantially at about a same time.

The emission layer 130 and the optical activation layer 135 may each be arranged on the hole transport region 120. The emission layer 130 and the optical activation layer 135 may each overlap an area of the first electrode 110 that is exposed by the pixel-defining film 290.

An electron transport region 140 may be arranged on the emission layer 130 and the optical activation layer 135. The electron transport region 140 included in the light-emitting device 10 and the electron transport region 140 included in the optoelectronic device 30 may be integrally formed. The electron transport region 140 included in the light-emitting device 10 and the electron transport region 140 included in the optoelectronic device 30 may be arranged on the pixel-defining film 290, may be connected to each other, may include substantially a same material, and may be formed substantially at about a same time.

A second electrode 150 may be arranged on the electron transport region 140. The second electrode 150 included in the light-emitting device 10 and the second electrode 150 included in the optoelectronic device 30 may be integrally formed. The second electrode 150 included in the light-emitting device 10 and the second electrode 150 included in the optoelectronic device 30 may be arranged on the pixel-defining film 290, may be connected to each other, may include substantially a same material, and may be formed substantially at a same time.

A capping layer 170 may be further included on the second electrode 150. The capping layer 170 may cover the second electrode 150.

The encapsulation portion 300 may be arranged on the capping layer 170. The encapsulation portion 300 may be arranged on the light-emitting device 10 and the optoelectronic device 30 to protect the light-emitting device 10 and the optoelectronic device 30 from moisture and/or oxygen. The encapsulation portion 300 may include: an inorganic film including silicon nitride (SiNₓ), silicon oxide (SiOₓ), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (for example, polymethyl methacrylate, polyacrylic acid, or the like), an epoxy-based resin (for example, aliphatic glycidyl ether (AGE), or the like), or any combination thereof; or any combination of the inorganic film and the organic film.

In an embodiment, the light-emitting device 10 may emit light L1, light L2, and light L3. For example, the light L1, light L2, and light L3 may each independently be red light, green light, blue light, or near-infrared light.

For example, light L3, which may be emitted from the light-emitting device 10, may be incident onto an object 600 outside the electronic apparatus. For example, the object 600 may be a finger of a user of the electronic apparatus. Light L3′ reflected from the object 600 may be incident onto the optoelectronic device 30.

The optical activation layer 135 may absorb light L3′ to form excitons. The excitons may generate holes and electrons. For example, the optical activation layer 135 may absorb light to generate an electrical signal. In an embodiment, the organic compound included in the optical activation layer 135 may serve as a donor that supplies electrons, and the first compound included in the optical activation layer 135 may serve as an acceptor that receives electrons. For example, the optoelectronic device 30 may detect light L3′ and convert it into an electrical signal. Accordingly, the optoelectronic device 30 may recognize an object 600 that comes into contact with (or approaches) the electronic apparatus. Therefore, the optoelectronic device 30 including the optical activation layer 135 may serve as an optical sensor (for example, a fingerprint recognition sensor).

FIG. 6 is a schematic cross-sectional view of an electronic apparatus according to another embodiment.

The electronic apparatus of FIG. 6 may differ from the electronic apparatus of FIG. 5, at least in that a light-shielding pattern 500 and a functional region 400 are further included on the encapsulation portion 300. The functional region 400 may be a color filter area, a color conversion area, or a combination of the color filter area and the color conversion area. According to an embodiment, the light-emitting device included in the electronic apparatus of FIG. 6 may be a tandem light-emitting device.

### [Electronic Equipment]

According to embodiments, an electronic equipment may include the electronic apparatus as described above, and a processor for transmitting a signal to the electronic apparatus.

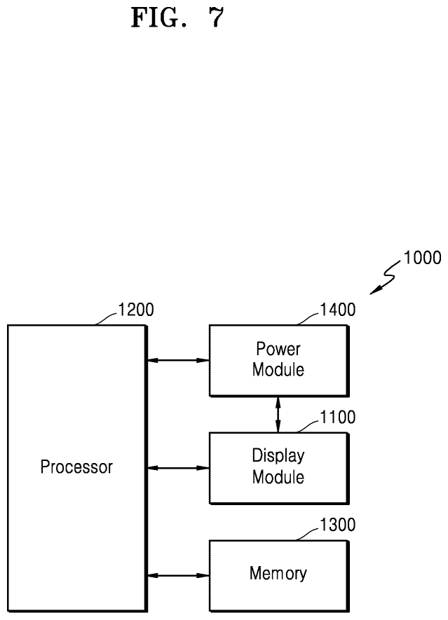

FIG. 7 is a block diagram of an electronic equipment including an electronic apparatus according to an embodiment.

The above-described electronic apparatus may be applied to various electronic equipment 1000. Electronic equipment 1000 according to an embodiment includes the electronic apparatus described above, and may further include a module or device having additional functions in addition to the electronic apparatus.

Referring to FIG. 7, an electronic equipment 1000 according to an embodiment may include a display module 1100, a processor 1200, a memory 1300, and a power module 1400.

The display module 1100 may emit light to display images such as moving images or still images, and may include, for example, an electronic apparatus as described above.

The processor 1200 may include at least one of a central processing unit (CPU), an application processor (AP), a graphic processing unit (GPU), a communication processor (CP), an image signal processor (ISP), and a controller.

Data for the operation of the processor 1200 or display module 1100 may be stored in the memory 1300. When the processor 1200 executes an application stored in the memory 1300, an image data signal and/or an input control signal is transmitted to the display module 1100, and the display module 1100 may process the received signal and output image information through a display screen.

The power module 1400 may include a power supply module, such as a power adapter and/or a battery device, and a power conversion module that converts power supplied by the power supply module to generate power required for the operation of the electronic equipment 1000.

At least one of the components of the above-described electronic equipment 1000 may be included in an electronic apparatus according to embodiments. In embodiments, one or more of the individual modules functionally included within one module may be included within the electronic apparatus while others may be provided separately from the electronic apparatus. For example, the electronic apparatus may include a display module 1100, and the processor 1200, memory 1300, and power module 1400 may be provided in the form of other devices within the electronic equipment 1000 other than the electronic apparatus.

According to an embodiment, the electronic equipment 1000 may be a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, smart glasses, a head-mounted display, a smart watch, a laser printer, a telephone, a mobile phone, a tablet computer, a phablet, a personal digital assistant (PDA), a wearable device, a laptop computer, a digital camera, a camcorder, a viewfinder, a micro display, a three-dimensional (3D) display, a virtual reality display, an augmented-reality display, a vehicle, a vehicle dashboard, a center information display (CID) for a vehicle, a head-up display for a vehicle, a rearview mirror display, a video wall with multiple displays tiled together, a theater screen, a stadium screen, a phototherapy device, or a signboard.

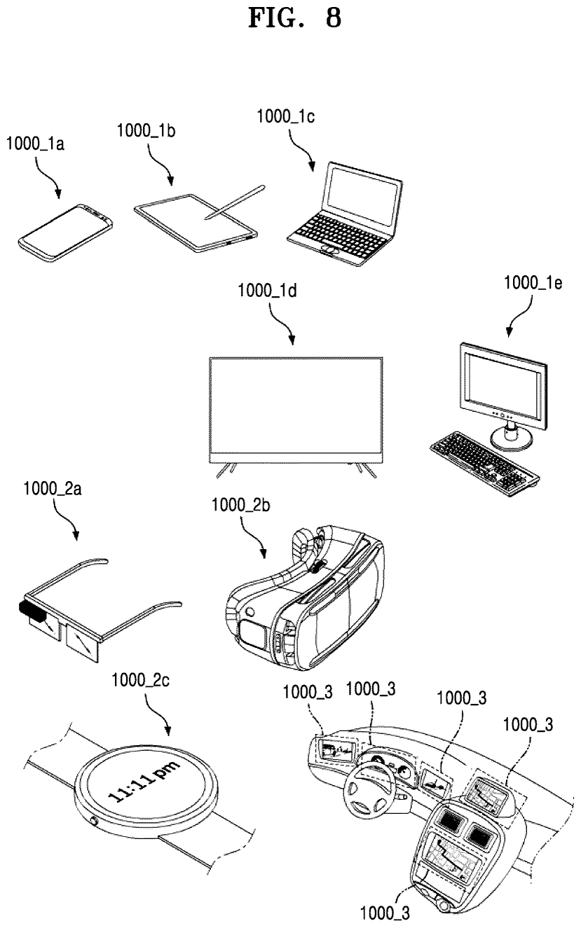

FIG. 8 is a schematic diagram of an electronic equipment 1000 according to embodiments.

Referring to FIG. 8, examples of electronic equipment 1000 to which the electronic apparatus according to embodiment are applied may include image display electronic equipment such as a smart phone 1000_1a, a tablet computer 1000_1b, a laptop computer 1000_1c, a television (TV) 1000_1d, and a desktop monitor 1000_1e, as well as wearable electronic equipment that include display modules such as smart glasses 1000_2a, a head mounted display 1000_2b, a smart watch 1000_2c, and vehicle electronic equipment 1000_3 that include display modules such as an instrument panel, a center fascia, a center information display (CID) disposed on a dashboard of a vehicle, and a room mirror display.

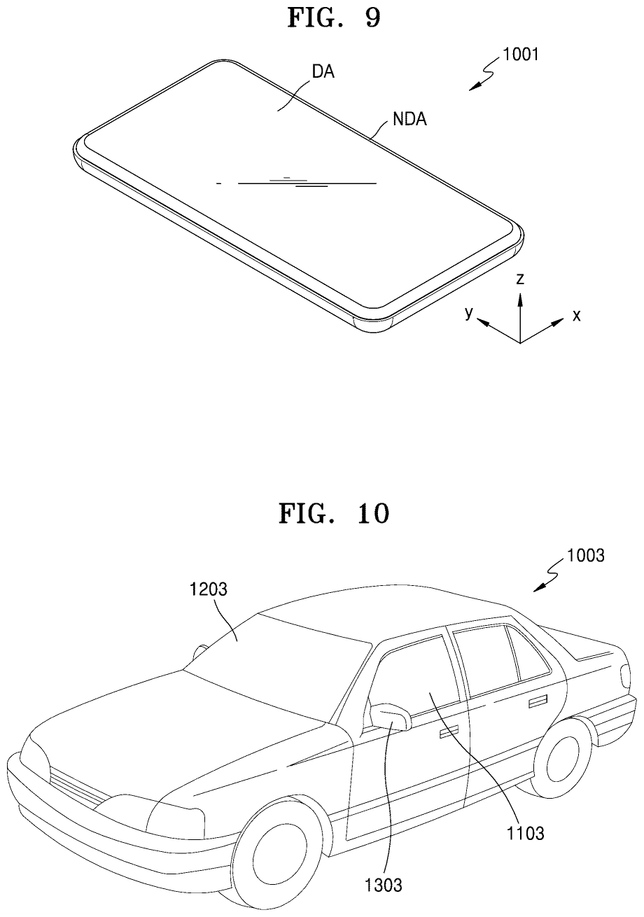

### [Description of FIG. 9]

FIG. 9 is a schematic perspective view of an electronic equipment 1001 including an optoelectronic device according to an embodiment.

The electronic equipment 1001, which may be as an apparatus that displays a moving image or a still image, may not only be a portable electronic equipment, such as a mobile phone, a smart phone, a tablet computer, a mobile communication terminal, an electronic notebook, an electronic book, a portable multimedia player (PMP), a navigation device, or an ultra-mobile personal computer (UMPC), but may also be various products, such as a television, a laptop computer, a monitor, a billboard, or an Internet of things (IoT) device. The electronic equipment 1001 may be any such product as described above or a part thereof.

In an embodiment, the electronic equipment 1001 may be a wearable device such as a smart watch, a watch phone, a glasses-type display, or a head mounted display (HMD), or a part of such a wearable device. However, embodiments are not limited thereto.

In an embodiment, examples of the electronic equipment 1001 may include a center information display (CID) on an instrument panel, a center fascia or dashboard of a vehicle, a room mirror display that replaces a side-view mirror of a vehicle, an entertainment display for a rear seat of a vehicle, a display arranged on the back of a front seat, a head up display (HUD) installed at the front of a vehicle or projected on a front window glass, or a computer generated hologram augmented reality head up display (CGH AR HUD). FIG. 9 illustrates an embodiment in which the electronic equipment 1001 is a smart phone for convenience of explanation.

The electronic equipment 1001 may include a display area DA and a non-display area NDA outside the display area DA. A display apparatus may implement an image through a two-dimensional array of pixels that are arranged in the display area DA.

The non-display area NDA may be an area that does not display an image, and may surround (e.g., entirely surround) the display area DA. A driver, which provides electrical signals or power to display devices arranged on the display area DA, may be arranged in the non-display area NDA. A pad, which is an area to which an electronic element or a printed circuit board may be electrically connected, may be arranged in the non-display area NDA.

In the electronic equipment 1001, a length in an x-axis direction and a length in a y-axis direction may be different from each other. For example, as shown in FIG. 9, a length in the x-axis direction may be shorter than a length in the y-axis direction. In embodiments, a length in the x-axis direction may be the same as a length in the y-axis direction. In embodiments, a length in the x-axis direction may be longer than a length in the y-axis direction.

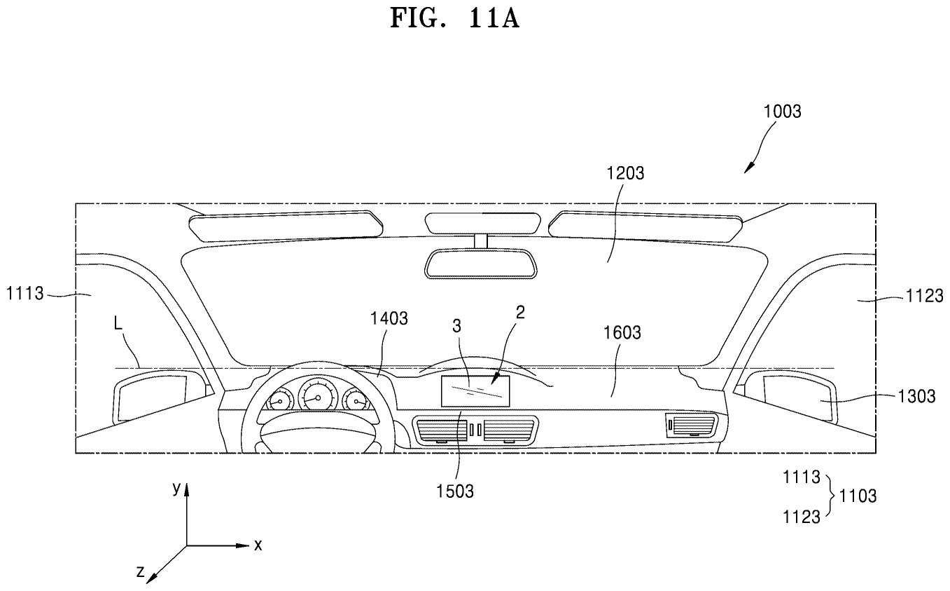

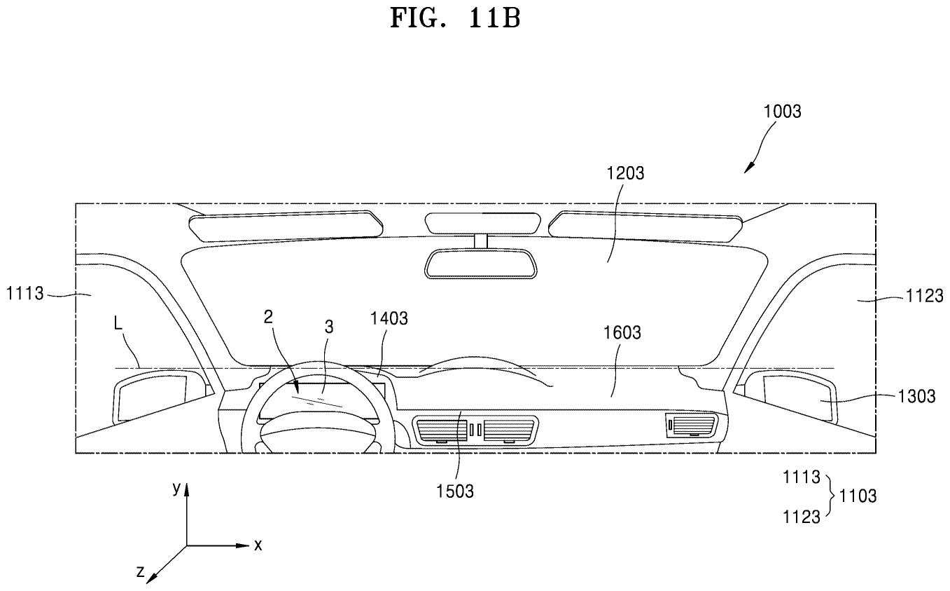

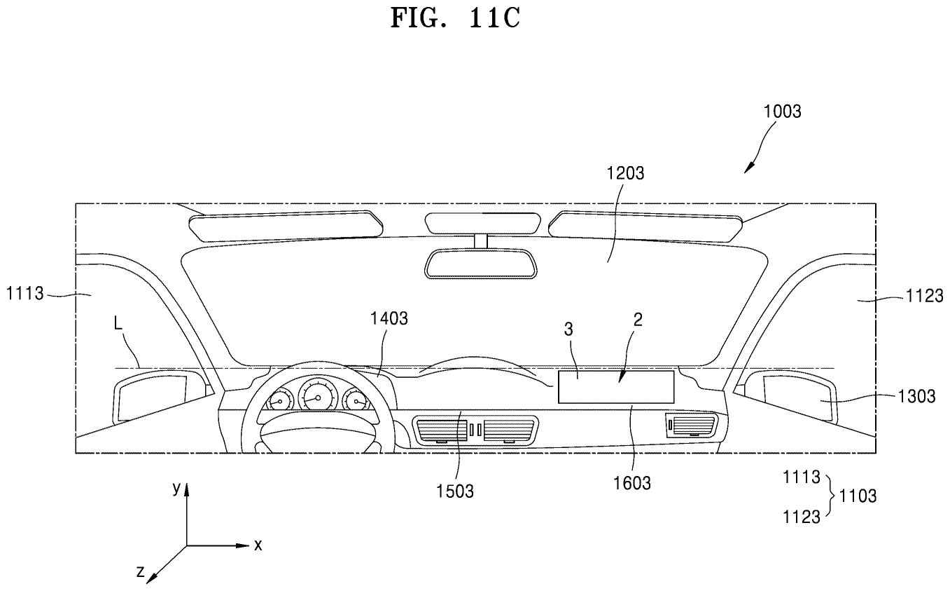

### [Descriptions of FIGS. 10 and 11A to 11C]

FIG. 10 is a schematic perspective view of an exterior of a vehicle 1003 as an electronic equipment including an optoelectronic device according to an embodiment. FIGS. 11A to 11C are each a schematic diagram of an interior of the vehicle 1003 according to embodiments.

Referring to FIGS. 10, 11A, 111B, and 11C, embodiments of a vehicle 1003 may include various apparatuses for moving a subject to be transported, such as a person, an object, or an animal, from a departure point to a destination. Examples of a vehicle 1003 may include a vehicle traveling on a road or a track, a vessel moving over a sea or a river, an airplane flying in the sky using the action of air, and the like.

The vehicle 1003 may travel on a road or a track. The vehicle 1003 may move in a selected or given direction according to the rotation of at least one wheel. Examples of the vehicle 1003 may include a three-wheeled or four-wheeled vehicle, a construction machine, a two-wheeled vehicle, a prime mover device, a bicycle, and a train running on a track.

The vehicle 1003 may include a body having an interior and an exterior, and a chassis that is a portion excluding the body in which mechanical apparatuses for operating the vehicle 1003 are installed. The exterior of the body of the vehicle 1003 may include a front panel, a bonnet, a roof panel, a rear panel, a trunk, a pillar provided at a boundary between doors, and the like. The chassis of the vehicle 1003 may include a power generating device, a power transmitting device, a driving device, a steering device, a braking device, a suspension device, a transmission device, a fuel device, front and rear wheels, left and right wheels, and the like.

The vehicle 1003 may include a side window glass 1103, a front window glass 1203, a side-view mirror 1303, a cluster 1403, a center fascia 1503, a passenger seat dashboard 1603, and a display apparatus 2.

The side window glass 1103 and the front window glass 1203 may be partitioned by a pillar arranged between the side window glass 1100 and the front window glass 1200.

The side window glass 1103 may be installed on a side of the vehicle 1003. In an embodiment, the side window glass 1103 may be installed on a door of the vehicle 1003. Multiple side window glasses 1103 may be provided and may face each other. In an embodiment, the side window glass 1103 may include a first side window glass 1113 and a second side window glass 1123. In an embodiment, the first side window glass 1113 may be arranged adjacent to the cluster 1403, and the second side window glass 1123 may be arranged adjacent to the passenger seat dashboard 1603.

In an embodiment, the side window glasses 1103 may be spaced apart from each other in the x-direction or the −x-direction. For example, the first side window glass 1113 and the second side window glass 1123 may be spaced apart from each other in the x direction or the −x direction. For example, a virtual straight line L connecting the side window glasses 1103 may extend in the x-direction or the −x-direction. For example, a virtual straight line L connecting the first side window glass 1113 and the second side window glass 1123 to each other may extend in the x direction or the −x direction.

The front window glass 1203 may be installed in front of the vehicle 1003. The front window glass 1203 may be arranged between the side window glasses 1103 facing each other.

The side-view mirror 1303 may provide a rear view of the vehicle 1003. The side-view mirror 1303 may be installed on the exterior of the body of the vehicle 1003. In an embodiment, multiple side-view mirrors 1303 may be provided. For example, one of the side-view mirrors 1303 may be arranged outside the first side window glass 1113, and another one of the side-view mirrors 1303 may be arranged outside the second side window glass 1123.

The cluster 1403 may be arranged in front of a steering wheel. The cluster 1403 may include a tachometer, a speedometer, a coolant thermometer, a fuel gauge, a turn signal indicator, a high beam indicator, a warning light, a seat belt warning light, an odometer, a tachograph, an automatic shift selector indicator, a door open warning light, an engine oil warning light, and/or a low fuel warning light.

The center fascia 1503 may include a control panel on which buttons for adjusting an audio device, an air conditioning device, and a seat heater are arranged. The center fascia 1503 may be arranged on a side of the cluster 1403.

The passenger seat dashboard 1603 may be spaced apart from the cluster 1403, and the center fascia 1503 may be arranged between the cluster 1403 and the passenger seat dashboard 1603. In an embodiment, the cluster 1403 may be arranged to correspond to a driver seat (not shown), and the passenger seat dashboard 1603 may be arranged to correspond to a passenger seat (not shown). In an embodiment, the cluster 1403 may be adjacent to the first side window glass 1113, and the passenger seat dashboard 1603 may be adjacent to the second side window glass 1123.

In an embodiment, the display apparatus 2 may include a display panel 3, and the display panel 3 may display an image. The display apparatus 2 may be arranged inside the vehicle 1003. In an embodiment, the display apparatus 2 may be arranged between the side window glasses 1103 facing each other. The display apparatus 2 may be arranged on at least one of the cluster 14030, the center fascia 1503, and the passenger seat dashboard 1603.

The display apparatus 2 may include an organic light emitting display, an inorganic light-emitting display, a quantum dot display, or the like. Hereinafter, an organic light emitting display including an optoelectronic device according to an embodiment will be described as an example of a display apparatus 2. However, various types of display apparatuses as described above may be used in embodiments.

Referring to FIG. 11A, the display apparatus 2 may be arranged on the center fascia 1503. In an embodiment, the display apparatus 2 may display navigation information. In an embodiment, the display apparatus 2 may display audio information, video information, or information about vehicle settings.

Referring to FIG. 6B, the display apparatus 2 may be arranged on the cluster 1403. In an embodiment, the cluster 1403 may display driving information and the like through the display apparatus 2. For example, the cluster 1403 may digitally implement driving information and the like. The cluster 1403 may digitally display vehicle information and driving information as images. For example, a needle and a gauge of a tachometer and various warning lights or icons may be displayed through a digital signal.

Referring to FIG. 6C, the display apparatus 2 may be arranged on the passenger seat dashboard 1603. The display apparatus 2 may be embedded in the passenger seat dashboard 1603 or arranged on the passenger seat dashboard 1603. In an embodiment, the display apparatus 2 arranged on the passenger seat dashboard 1603 may display an image that is related to information displayed on the cluster 1403 and/or information displayed on the center fascia 1503. In an embodiment, the display apparatus 2 arranged on the passenger seat dashboard 1603 may display information that is different from information displayed on the cluster 1403 and/or information displayed on the center fascia 1503.

### [Manufacturing Method]

Respective layers included in the hole transport region 120, the emission layer 130, the optical activation layer 135, and/or respective layers included in the electron transport region 140 may be formed in a selected region by using one or more suitable methods selected from a vacuum deposition method, a spin coating method, a casting method, a Langmuir-Blodgett (LB) method, an ink-jet printing method, a laser-printing method, and a laser-induced thermal imaging (LITI) method. According to an embodiment, both the emission layer 130 and the optical activation layer 135 may be formed by a vacuum deposition method.

When layers included in the hole transport region 120, the emission layer 130, the optical activation layer 135, and/or the layers included in the electron transport region 140 are formed by vacuum deposition, the deposition may be performed, for example, at a deposition temperature in a range of about 100° C. to about 500° C., a vacuum degree in a range of about 10⁻⁸ torr to about 10⁻³ torr, and a deposition speed in a range of about 0.01 Å/sec to about 100 Å/sec, depending on a material to be included in a layer to be formed and the structure of a layer to be formed.

### Definitions of Terms

The term “C₃-C₆₀ carbocyclic group” as used herein may be a cyclic group consisting of carbon atoms as the only ring-forming atoms and having 3 to 60 carbon atoms. The term “C₁-C₆₀ heterocyclic group” as used herein may be a cyclic group that has 1 to 60 carbon atoms and further includes, in addition to carbon atoms, at least one heteroatom as a ring-forming atom. The C₃-C₆₀ carbocyclic group and the C₁-C₆₀ heterocyclic group may each be a monocyclic group consisting of one ring or a polycyclic group in which two or more rings are condensed with each other. For example, the C₁-C₆₀ heterocyclic group may have 3 to 61 ring-forming atoms.

The term “cyclic group” may be a C₃-C₆₀ carbocyclic group or a C₁-C₆₀ heterocyclic group.

The term “π electron-rich C₃-C₆₀ cyclic group” as used herein may be a cyclic group that has 3 to 60 carbon atoms and may not include *—N═*′ as a ring-forming moiety.

The term “π electron-deficient nitrogen-containing C₁-C₆₀ cyclic group” as used herein may be a heterocyclic group that has 1 to 60 carbon atoms and may include *—N═*′ as a ring-forming moiety.

In embodiments,
a C₃-C₆₀ carbocyclic group may be a T1 group or a group in which two or more T1 groups are condensed with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
a C₁-C₆₀ heterocyclic group may be a T2 group, a group in which two or more T2 groups are condensed with each other, or a group in which at least one T2 group and at least one T1 group are condensed with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),
a π electron-rich C₃-C₆₀ cyclic group may be a T1 group, a group in which two or more T1 groups are condensed with each other, a T3 group, a group in which two or more T3 groups are condensed with each other, or a group in which at least one T3 group and at least one T1 group are condensed with each other (for example, a C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, etc.), and
a π electron-deficient nitrogen-containing C₁-C₆₀ cyclic group may be a T4 group, a group in which two or more T4 groups are condensed with each other, a group in which at least one T4 group and at least one T1 group are condensed with each other, a group in which at least one T4 group and at least one T3 group are condensed with each other, or a group in which at least one T4 group, at least one T1 group, and at least one T3 group are condensed with one another (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.).

A T1 group may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group.

A T2 group may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group.

A T3 group may be a furan group, a thiophene group, a 1H-pyrrole group, a silole group, or a borole group.

A T4 group may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “cyclic group”, “C₃-C₆₀ carbocyclic group”, “C₁-C₆₀ heterocyclic group”, “π electron-rich C₃-C₆₀ cyclic group”, or “π electron-deficient nitrogen-containing C₁-C₆₀ cyclic group” as used herein may each be a group condensed to any cyclic group, a monovalent group, or a polyvalent group (for example, a divalent group, a trivalent group, a tetravalent group, etc.) according to the structure of a formula for which the corresponding term is used.

For example, a “benzene group” may be a benzo group, a phenyl group, a phenylene group, or the like, which may be readily understood by one of ordinary skill in the art according to the structure of a formula including the “benzene group”.

Examples of a monovalent C₃-C₆₀ carbocyclic group or a monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group.

Examples of a divalent C₃-C₆₀ carbocyclic group or a divalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group.

The term “C₁-C₆₀ alkyl group” as used herein may be a linear or branched monovalent aliphatic hydrocarbon group that has 1 to 60 carbon atoms, and examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, and the like.

The term “C₁-C₆₀ alkylene group” as used herein may be a divalent group having a same structure as the C₁-C₆₀ alkyl group.

The term “C₂-C₆₀ alkenyl group” as used herein may be a monovalent hydrocarbon group having at least one carbon-carbon double bond in the middle or at a terminus of a C₂-C₆₀ alkyl group, and examples thereof may include an ethenyl group, a propenyl group, a butenyl group, and the like.

The term “C₂-C₆₀ alkenylene group” as used herein may be a divalent group having a same structure as the C₂-C₆₀ alkenyl group.

The term “C₂-C₆₀ alkynyl group” as used herein may be a monovalent hydrocarbon group having at least one carbon-carbon triple bond in the middle or at a terminus of a C₂-C₆₀ alkyl group, and examples thereof may include an ethynyl group, a propynyl group, and the like.

The term “C₂-C₆₀ alkynylene group” as used herein may be a divalent group having a same structure as the C₂-C₆₀ alkynyl group.

The term “C₁-C₆₀ alkoxy group” as used herein may be a monovalent group represented by —O(A₁₀₁) (wherein A₁₀₁ may be a C₁-C₆₀ alkyl group), and examples thereof may include a methoxy group, an ethoxy group, an isopropyloxy group, and the like.

The term “C₃-C₁₀ cycloalkyl group” as used herein may be a monovalent saturated hydrocarbon cyclic group that has 3 to 10 carbon atoms, and examples thereof may include a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, a bicyclo[2.2.2]octyl group, and the like.

The term “C₃-C₁₀ cycloalkylene group” as used herein may be a divalent group having a same structure as the C₃-C₁₀ cycloalkyl group.

The term “C₁-C₁₀ heterocycloalkyl group” as used herein may be a monovalent cyclic group that has 1 to 10 carbon atoms and further includes, in addition to the carbon atoms, at least one heteroatom as a ring-forming atom, and examples thereof may include a 1,2,3,4-oxatriazolidinyl group, a tetrahydrofuranyl group, a tetrahydrothiophenyl group, and the like.

The term “C₁-C₁₀ heterocycloalkylene group” as used herein may be a divalent group having a same structure as the C₁-C₁₀ heterocycloalkyl group.

The term “C₃-C₁₀ cycloalkenyl group” as used herein may be a monovalent cyclic group that has 3 to 10 carbon atoms and at least one carbon-carbon double bond in the cyclic structure thereof and no aromaticity, and examples thereof may include a cyclopentenyl group, a cyclohexenyl group, a cycloheptenyl group, and the like.

The term “C₃-C₁₀ cycloalkenylene group” as used herein may be a divalent group having a same structure as the C₃-C₁₀ cycloalkenyl group.

The term “C₁-C₁₀ heterocycloalkenyl group” as used herein may be a monovalent cyclic group that has 1 to 10 carbon atoms, further includes, in addition to the carbon atoms, at least one heteroatom as a ring-forming atom, and has at least one double bond in the cyclic structure thereof. Examples of a C₁-C₁₀ heterocycloalkenyl group may include a 4,5-dihydro-1,2,3,4-oxatriazolyl group, a 2,3-dihydrofuranyl group, a 2,3-dihydrothiophenyl group, and the like.

The term “C₁-C₁₀ heterocycloalkenylene group” as used herein may be a divalent group having a same structure as the C₁-C₁₀ heterocycloalkenyl group.

The term “C₆-C₆o aryl group” as used herein may be a monovalent group having a carbocyclic aromatic system of 6 to 60 carbon atoms.

The term “C₆-C₆₀ arylene group” as used herein may be a divalent group having a carbocyclic aromatic system of 6 to 60 carbon atoms.

Examples of a C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, an ovalenyl group, and the like.

When the C₆-C₆₀ aryl group and the C₆-C₆₀ arylene group each include two or more rings, the respective two or more rings may be condensed with each other.

The term “C₁-C₆₀ heteroaryl group” as used herein may be a monovalent group having a heterocyclic aromatic system of 1 to 60 carbon atoms, further including, in addition to carbon atoms, at least one heteroatom, as ring-forming atoms.

The term “C₁-C₆₀ heteroarylene group” as used herein may be a divalent group having a heterocyclic aromatic system of 1 to 60 carbon atoms, further including, in addition to carbon atoms, at least one heteroatom, as ring-forming atoms.

Examples of a C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a naphthyridinyl group, and the like.

When the C₁-C₆₀ heteroaryl group and the C₁-C₆₀ heteroarylene group each include two or more rings, the respective two or more rings may be condensed with each other.

The term “monovalent non-aromatic condensed polycyclic group” as used herein may be a monovalent group (for example, having 8 to 60 carbon atoms) having two or more rings condensed to each other, only carbon atoms as ring-forming atoms, and has no aromaticity in its molecular structure when considered as a whole. Examples of a monovalent non-aromatic condensed polycyclic group may include an indenyl group, a fluorenyl group, a spiro-bifluorenyl group, a benzofluorenyl group, an indenophenanthrenyl group, an indeno anthracenyl group, and the like.

The term “divalent non-aromatic condensed polycyclic group” as used herein may be a divalent group having a same structure as the monovalent non-aromatic condensed polycyclic group.

The term “monovalent non-aromatic condensed heteropolycyclic group” as used herein may be a monovalent group (for example, having 1 to 60 carbon atoms) having two or more rings condensed with each other, which further includes, in addition to carbon atoms, at least one heteroatom as ring-forming atoms, and has no aromaticity in its molecular structure when considered as a whole. Examples of a monovalent non-aromatic condensed heteropolycyclic group may include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, a benzothienodibenzothiophenyl group, and the like.

The term “divalent non-aromatic condensed heteropolycyclic group” as used herein may be a divalent group having a same structure as the monovalent non-aromatic condensed heteropolycyclic group.

The term “C₆-C₆₀ aryloxy group” as used herein may be a group represented by —O(A₁₀₂) (wherein A₁₀₂ may be a C₆-C₆₀ aryl group).

The term “C₆-C₆₀ arylthio group” as used herein may be a group represented by —S(A₁₀₃) (wherein A₁₀₃ may be a C₆-C₆₀ aryl group).

The term “C₇-C₆₀ arylalkyl group” as used herein may be a group represented by -(A₁₀₄)(A₁₀₅) (wherein A₁₀₄ may be a C₁-C₅₄ alkylene group, and A₁₀₅ may be a C₆-C₅₉ aryl group).

The term “C₂-C₆₀ heteroarylalkyl group” as used herein may be a group represented by -(A₁₀₆)(A₁₀₇) (wherein A₁₀₆ may be a C₁-C₅₉ alkylene group, and A₁₀₇ may be a C₁-C₅₉ heteroaryl group).

In the specification, the term “R₁₀ₐ” may be:
deuterium, —F, —Cl, —Br, —I, a hydroxyl group, a cyano group, or a nitro group;
a C₁-C₁₅ alkyl group, a C₂-C₁₅ alkenyl group, a C₂-C₁₅ alkynyl group, or a C₁-C₁₅ alkoxy group, each unsubstituted or substituted with deuterium, —F, —Cl, —Br, —I, a hydroxyl group, a cyano group, a nitro group, a C₃-C₁₅ carbocyclic group, a C₁-C₁₅ heterocyclic group, a C₆-C₁₅ aryloxy group, a C₆-C₁₅ arylthio group, a C₇-C₁₅ arylalkyl group, a C₂₋₁₅ heteroarylalkyl group, or any combination thereof; or
a C₃-C₁₅ carbocyclic group, a C₁-C₁₅ heterocyclic group, a C₆-C₁₅ aryloxy group, a C₆-C₁₅ arylthio group, a C₇-C₁₅ arylalkyl group, or a C₂-C₁₅ heteroarylalkyl group, each unsubstituted or substituted with deuterium, —F, —Cl, —Br, —I, a hydroxyl group, a cyano group, a nitro group, a C₁-C₁₅ alkyl group, a C₂-C₁₅ alkenyl group, a C₂-C₁₅ alkynyl group, a C₁-C₁₅ alkoxy group, a C₃-C₁₅ carbocyclic group, a C₁-C₁₅ heterocyclic group, a C₆-C₁₅ aryloxy group, a C₆-C₁₅ arylthio group, a C₇-C₁₅ arylalkyl group, a C₂-C₁₅ heteroarylalkyl group, or any combination thereof.

In the specification, Q₁ to Q₃ may each independently be:
hydrogen, deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, or a C₁-C₆₀ alkoxy group; or
a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

The term “heteroatom” as used herein may be any atom other than a carbon atom or a hydrogen atom. Examples of a heteroatom may include O, S, N, P, Si, B, Ge, Se, and any combination thereof.

In the specification, examples of a “transition metal” may include hafnium (Hf), tantalum (Ta), tungsten (W), rhenium (Re), osmium (Os), iridium (Ir), platinum (Pt), gold (Au), and the like.

The term “Ph” as used herein refers to a phenyl group, the term “Me” as used herein refers to a methyl group, the term “Et” as used herein refers to an ethyl group, the terms “ter-Bu” and “Bu^{t}” as used herein each refer to a tert-butyl group, and the term “OMe” as used herein refers to a methoxy group.

The term “biphenyl group” as used herein may be a “phenyl group substituted with a phenyl group”. For example, a “biphenyl group” may be a substituted phenyl group having a C₆-C₆₀ aryl group as a substituent.

The term “terphenyl group” as used herein may be a “phenyl group substituted with a biphenyl group”. For example, a “terphenyl group” may be a substituted phenyl group having, as a substituent, a C₆-C₆₀ aryl group substituted with a C₆-C₆₀ aryl group.

The symbols * and *′ as used herein, unless defined otherwise, each refer to a binding site with a neighboring atom in a corresponding formula or moiety.

In the specification, the terms “x-axis”, “y-axis”, and “z-axis” are not limited to three axes in an orthogonal coordinate system (for example, a Cartesian coordinate system), and may be interpreted in a broader sense than the aforementioned three axes in an orthogonal coordinate system. For example, the x-axis, y-axis, and z-axis may describe axes that are orthogonal to each other, or may describe axes that are in different directions that are not orthogonal to each other.

### EXAMPLES

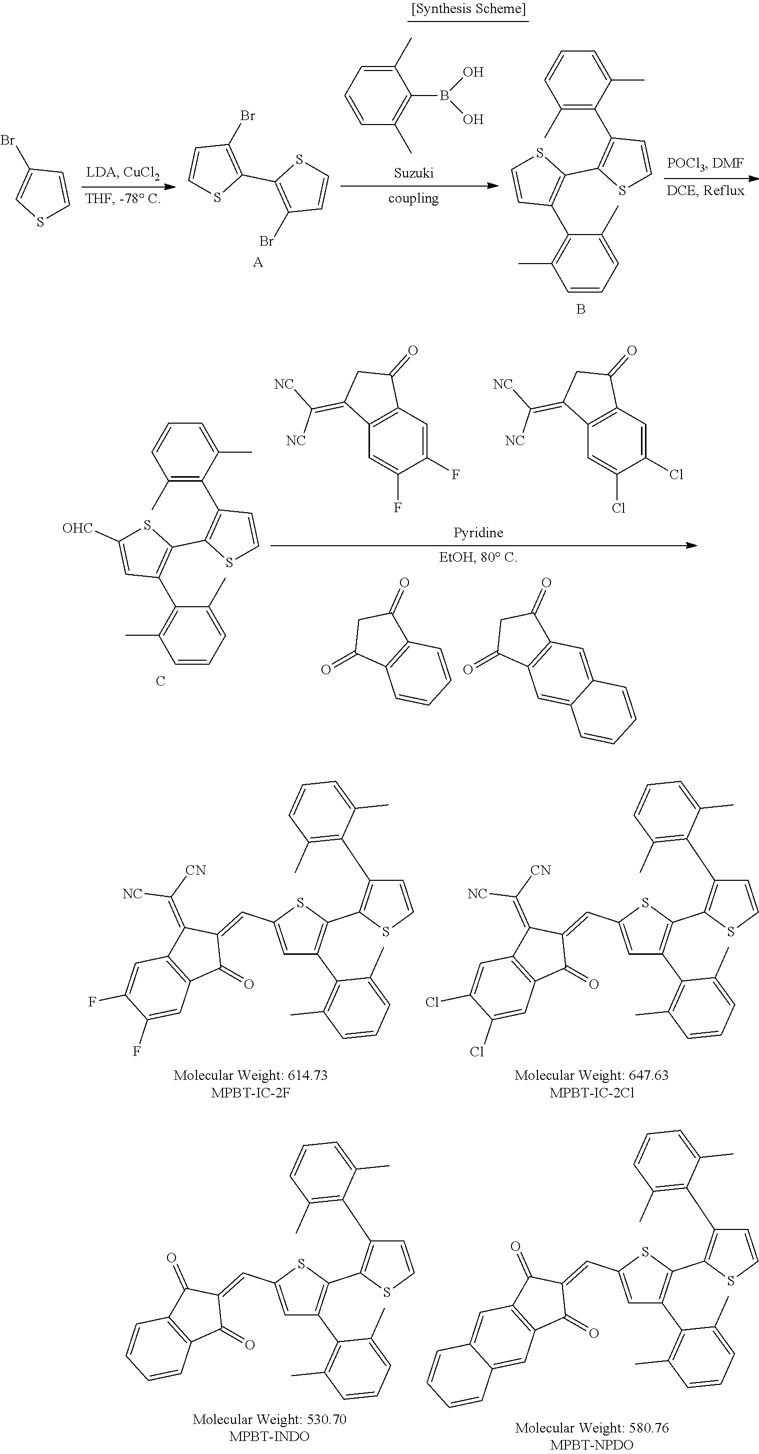

By referring to the synthesis route and materials according to the Synthesis Scheme, those skilled in the art may readily synthesize compounds according to embodiments.

Hereinafter, organic compounds and optoelectronic devices according to embodiments will be described in detail with reference to the Synthesis Examples and the Examples.

### Synthesis Example 1 (Synthesis of Compound 2)

### Synthesis of Intermediate 2-1 (3,3′-dibromo-2,2′-bithiophene)

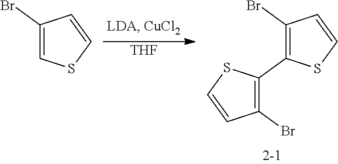 [SMILES: Brc1ccsc1 ; Brc1ccsc1-c1sccc1Br ; "THF"]

3-bromothiophene (30 g, 181.01 mmol) dissolved in tetrahydrofuran (THF, 150 mL) in a round-bottom flask was stirred at −78° C. for 15 minutes, and 1 M lithium diisopropylamide (LDA) (184.01 mL, 1.1 eq) was added dropwise thereto at the same temperature. The mixture was stirred for 1 hour after addition of LDA, CuCl₂ was added thereto, and the mixture was stirred for an additional 1 hour. The reaction was carried out at room temperature for 6 hours. After the reaction was completed, quenching was performed with an aqueous solution of ammonium chloride, and an extraction process was performed with dichloromethane (DCM) and water to separate the organic layer. MgSO₄ was added to the obtained organic layer to remove moisture therefrom and a rotary evaporator was used to remove DCM from the filtered solution. Column chromatography (hexane) was performed to obtain Intermediate 2-1 as a white solid (Yield=19%).

¹H NMR (500 Hz, CDCl₃) 7.42-7.40 (d, 2H), 7.09-7.08 (d, 2H).

### Synthesis of Intermediate 2-2 (3,3′-bis(2,6-dimethylphenyl)-2,2′-bithiophene)

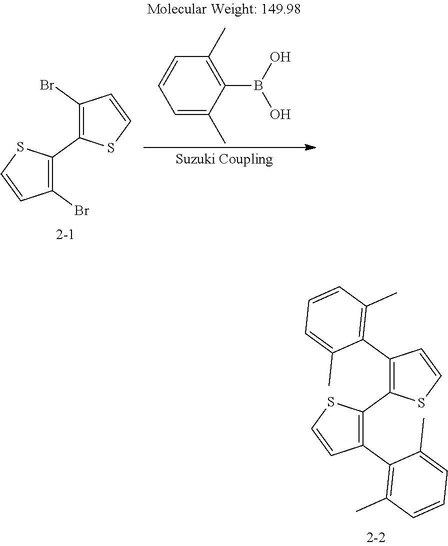

Intermediate 2-1 (100 mg, 0.308 mmol), (2,6-dimethylphenyl)boronic acid (184 mg, 4 eq), and 1 drop of Aliquat 336 were placed in a microwave vial, and Pd(PPh₃)₄ (42.64 mg, 0.12 eq) was added to the vial in a glovebox. Toluene (8 mL) and 2 M CsCO₃ (4 mL) were added thereto in a nitrogen environment, the reaction was carried out at 80° C. for 12 hours, and the resulting solution was cooled to room temperature. When the reaction was completed, an extraction process was performed with ether and water, and MgSO₄ was used to remove moisture from the organic layer. Column chromatography (hexane) was performed to obtain Intermediate 2-2 as a white solid (Yield=60%).

¹H NMR (500 MHz, (CD₃)₂CO) δ 7.33-7.32 (d, 2H), 7.26-7.23 (t, 2H), 7.14-7.13 (d, 4H), 6.72-6.71 (d, 2H), 1.96 (s, 12H)

### Synthesis of Intermediate 2-3 (3,3′-bis(2,6-dimethylphenyl)-[2,2′-bithiophene]-5-carbaldehyde)

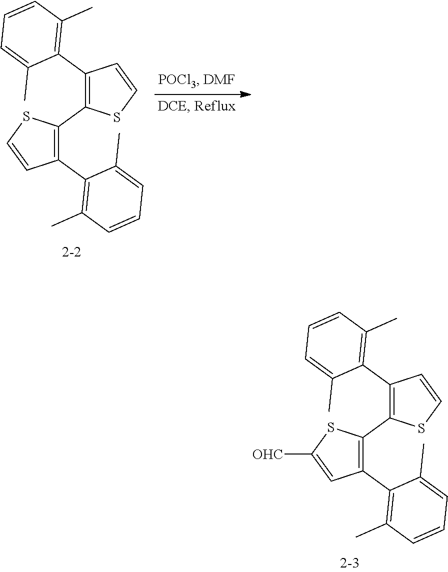 [SMILES: Cc1cccc(C)c1-c1ccsc1-c1sccc1-c1c(C)cccc1C ; Cc1cccc(C)c1-c1ccsc1-c1sc(C=O)cc1-c1c(C)cccc1C]

Intermediate 2-2 (0.79 g, 2.1 mmol) was placed in a flask which was connected to a condenser under nitrogen conditions. At 0° C., 1,2-dichloroethane (DCE, 50 mL), N,N-dimethylformamide (DMF, 6.50 mL, 40 eq), and phosphorus(V) oxychloride (POCl₃, 1.96 mL, 10 eq) were added thereto and the mixture was stirred for 30 minutes. After the reaction was carried out at room temperature for 12 hours, the reaction mixture was heated to 85° C. to proceed with the reaction. Acidification was performed with saturated CH₃COONa (aq) at 50° C. and the resulting solution was cooled to room temperature. An extraction process was performed with chloroform, and MgSO₄ was used to remove moisture from the extract. Column chromatography (chloroform) was performed to obtain Intermediate 2-3 as a yellow solid (yield=85%).

¹H NMR (500 MHz, CDCl₃) δ 9.74 (s, 1H), 7.36 (s, 1H), 7.33-7.28 (t, 2H), 7.24-7.23 (d, 2H), 7.18-7.16 (m, 4H), 6.75-6.74 (d, 1H), 2.03 (s, 6H), 1.99 (s, 6H).

### Synthesis of Compound 2

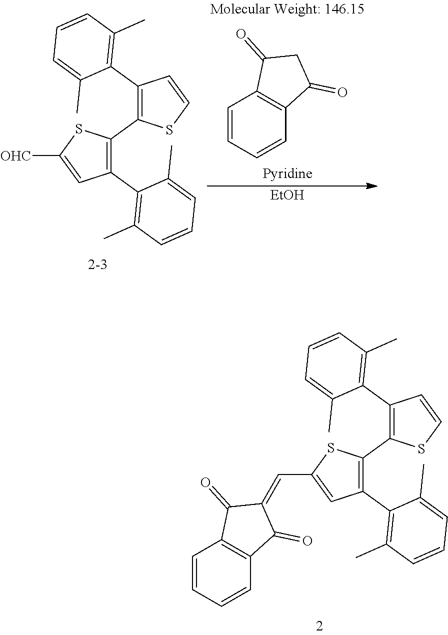

Intermediate 2-3 (0.4 g, 1 eq) and 1H-indene-1,3(2H)-dione (290.43 mg, 2 eq) were dissolved in 79 mL of ethanol in a 250 mL round bottom flask (RBF) under nitrogen conditions. 1.5 mL of pyridine was added to the solution, and the reaction was carried out at 80° C. for 12 hours. The resulting solution was filtered through filter paper, and washing was performed using ethanol. An extraction process was performed with chloroform and distilled water, and MgSO₄ was used to remove moisture from the extract. Column chromatography (chloroform) was performed to obtain Compound 2 (2-((3,3′-bis(2,6-dimethylphenyl)-[2,2′-bithiophen]-5-yl)methylene)-1H-indene-1,3(2H)-dione) as a purple solid (Yield=65%).

¹H NMR (500 MHz, CDCl₃) δ 8.29 (s, 1H), 7.92-7.89 (m, 2H), 7.75-7.73 (m, 2H), 7.62 (s, 1H), 7.40-7.37 (t, 1H), 7.33-7.30 (t, 1H), 7.27 (s, 1H), 7.24-7.23 (d, 2H) 7.18-7.16 (d, 2H), 6.79-6.78 (d, 1H), 2.04-2.03 (d, 12H).

### Synthesis Example 2 (Synthesis of Compound 7)

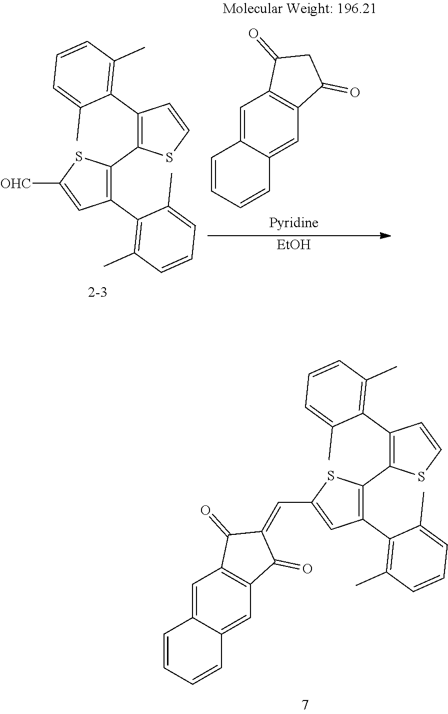

Compound 7 (2-((3,3′-bis(2,6-dimethylphenyl)-[2,2′-bithiophen]-5-yl)methylene)-1H-cyclopenta[b]naphthalene-1,3(2H)-dione) was synthesized using the same method as for the synthesis of Compound 2, except that 1H-cyclopenta[b]naphthalene-1,3(2H)-dione (389.91 mg, 2 eq) was used instead of 1H-indene-1,3(2H)-dione (Yield=30%).

¹H NMR (500 MHz, CDCl₃) δ 8.42 (s, 1H), 8.38 (s, 1H), 8.07 (m, 2H), 7.72 (s, 1H), 7.68-7.65 (m, 2H) 7.43-7.40 (t, 2H), 7.34-7.31 (t, 2H), 7.30-7.28 (s, 1H), 7.19-7.18 (d, 2H), 6.81-6.80 (d, 2H), 2.05-2.04 (d, 12H).

### Synthesis Example 3 (Synthesis of Compound 12)

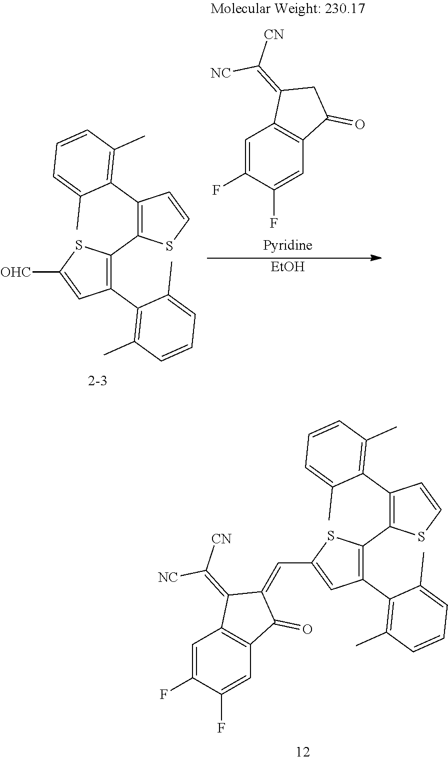

Compound 12 ((Z)-2-(2-((3,3′-bis(2,6-dimethylphenyl)-[2,2′-bithiophen]-5-yl)methylene)-5,6-difluoro-3-oxo-2,3-dihydro-1H-inden-1-ylidene)malononitrile) was synthesized using the same method as for the synthesis of Compound 2, except that 2-(5,6-difluoro-3-oxo-2,3-dihydro-1H-inden-1-ylidene)malononitrile (457.40 mg, 2 eq) was used instead of 1H-indene-1,3(2H)-dione (Yield=40%).

¹H NMR (500 MHz, CDCl₃) δ 8.61 (s, 1H), 8.51-8.48 (m, 1H), 7.66 (s, 1H), 7.65-7.62 (t, 1H), 7.41-7.38 (t, 1H), 7.36-7.35 (d, 1H), 7.34-7.31 (t, 2H), 7.27 (s, 1H), 7.18-7.17 (d, 2H), 6.84-6.83 (d, 1H), 2.03-2.05 (d, 12H).

### Synthesis Example 4 (Synthesis of Compound 20)

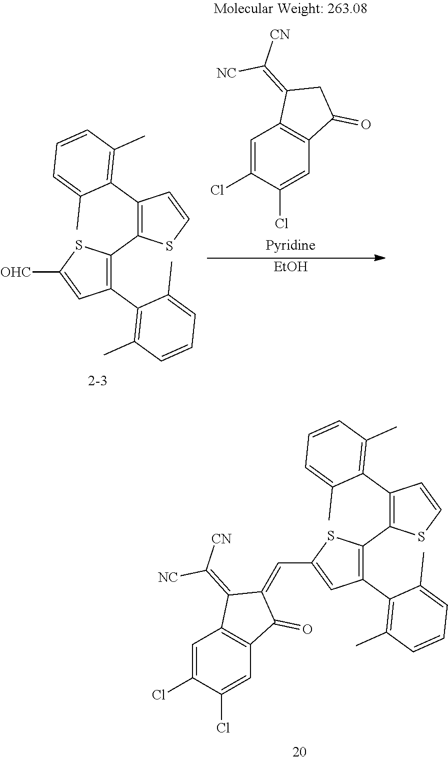

Compound 20 ((Z)-2-(2-((3,3′-bis(2,6-dimethylphenyl)-[2,2′-bithiophen]-5-yl)methylene)-5,6-dichloro-3-oxo-2,3-dihydro-1H-inden-1-ylidene)malononitrile) was synthesized using the same method as for the synthesis of Compound 2, except that 2-(5,6-dichloro-3-oxo-2,3-dihydro-1H-inden-1-ylidene)malononitrile (523 mg, 2 eq) was used instead of 1H-indene-1,3(2H)-dione (Yield=70%).

¹H NMR (500 MHz, CDCl₃) δ 8.73 (s, 1H), 8.64 (s, 1H), 7.89 (s, 1H), 7.66 (s, 1H), 7.43-7.40 (t, 1H), 7.37-7.36 (d, 1H), 7.34-7.31 (t, 1H), 7.28-7.27 (d, 2H), 7.19-7.17 (d, 2H), 6.85-6.84 (d, 1H), 2.05-2.03 (d, 12H).

### Synthesis Example 5 (Synthesis of Compound 33)

### Synthesis of Intermediate 33-1 ((3,3′-bis(2,6-dimethylphenyl)-[2,2′-bithiophen]-5-yl)trimethylstannane)

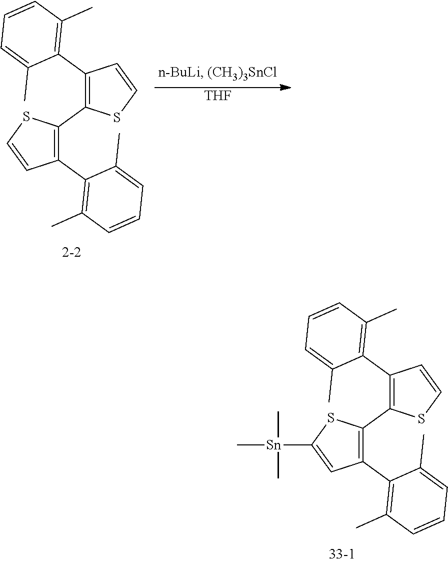 [SMILES: Cc1cccc(C)c1-c1ccsc1-c1sccc1-c1c(C)cccc1C ; Cc1cccc(C)c1-c1ccsc1-c1s[c]([Sn]([CH3])([CH3])[CH3])cc1-c1c(C)cccc1C ; "THF"]

Intermediate 2-2 (100 mg, 1 eq) was added to an anhydrous THE solvent under nitrogen conditions. The solution was cooled to −40° C., and 2 M n-BuLi (0.28 mL, 1.05 eq) was added dropwise thereto. The mixture was stirred at −40° C. for 1 hour and heated to room temperature. The reaction was carried out for 30 minutes, and the resulting solution was cooled to −40° C. and stirred for 1 hour. 1 M Me₃SnCl (0.29 mL, 1.1 eq) was added thereto, and the reaction was carried out for 12 hours. Water was added to the mixture to complete the reaction, and an extraction process was performed with DCM. MgSO₄ was used to remove the remaining moisture from the extracted solution, and vacuum drying was performed to obtain Intermediate 33-1 as a yellow solid. (Yield=86%).

¹H NMR (500 MHz, CDCl₃) δ 7.24-7.20 (m, 2H), 7.14-7.13 (d, 1H), 7.13-7.08 (m, 4H), 6.70 (s, 1H), 6.68-6.67 (d, 2H), 1.96-2.00 (d, 12H), 0.31-0.20 (m, 9H).

### Synthesis of Intermediate 33-2 (3″,4′-bis(2,6-dimethylphenyl)-[2,2′:5′,2″-terthiophene]-5-carbaldehyde)

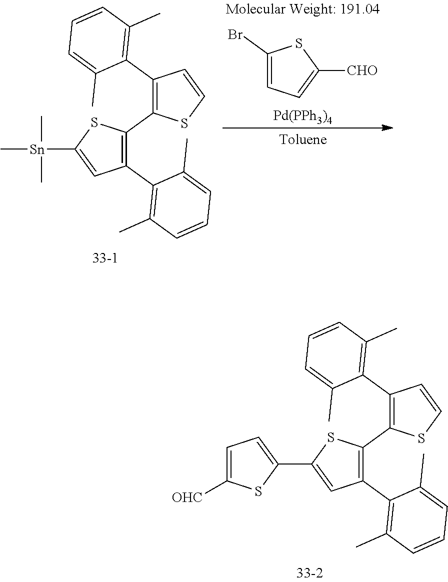 [SMILES: Cc1cccc(C)c1-c1ccsc1-c1s[c]([Sn]([CH3])([CH3])[CH3])cc1-c1c(C)cccc1C ; O=Cc1ccc(Br)s1 ; Cc1cccc(C)c1-c1ccsc1-c1sc(-c2ccc(C=O)s2)cc1-c1c(C)cccc1C ; "Pd(PPh3)4"]

Intermediate 33-1 (380 mg, 1 eq), 5-bromothiophene-2-carbaldehyde (162 mg, 1.2 eq), and Pd(PPh₃)₄ (81.7 mg, 0.1 eq) were dissolved in 14 mL of an anhydrous toluene in a microwave vial, and the reaction was carried out at 80° C. for 12 hours. An extraction process was performed with ether, and MgSO₄ was used to remove moisture from the extract. Purification was performed by column chromatography (Hex:DCM=1:1) to obtain Intermediate 33-2 as a yellow solid (Yield=86%).

¹H NMR (500 MHz, CDCl₃) δ 9.80 (s, 1H), 7.59-7.58 (d, 1H), 7.32-7.30 (t, 2H), 7.18-7.14 (m, 4H), 7.14 (s, 1H), 7.00-6.99 (d, 1H), 6.99 (s, 1H), 6.73-6.72 (d, 1H), 2.06-2.02 (d, 12H).

### Synthesis of Compound 33

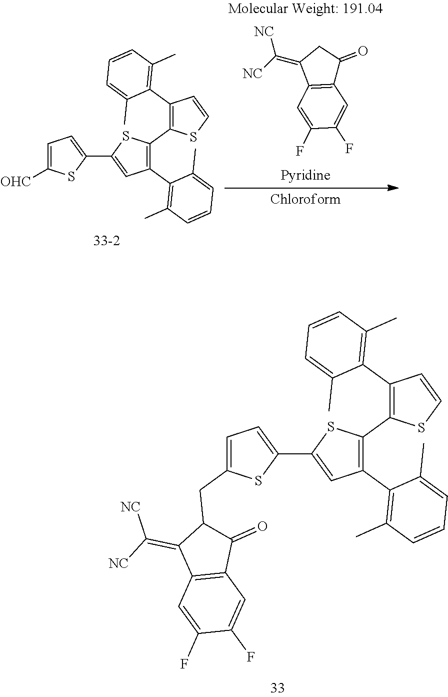 [SMILES: Cc1cccc(C)c1-c1ccsc1-c1sc(-c2ccc(C=O)s2)cc1-c1c(C)cccc1C ; N#CC(C#N)=C1CC(=O)c2cc(F)c(F)cc21 ; Cc1cccc(C)c1-c1ccsc1-c1sc(-c2ccc(CC3C(=O)c4cc(F)c(F)cc4C3=C(C#N)C#N)s2)cc1-c1c(C)cccc1C]

Under nitrogen conditions, Intermediate 33-2 (180 mg, 1 eq) and 2-(5,6-difluoro-3-oxo-2,3-dihydro-1H-inden-1-ylidene)malononitrile (170.25 mg, 2 eq) were dissolved in 166 mL of ethanol in a round-bottom flask. 2.8 mL of pyridine was added to the solution, and the reaction was carried out at 80° C. for 12 hours. When the reaction was complete, an extraction process was performed with chloroform, and MgSO₄ was used to remove moisture from the extract. Column chromatography (chloroform) was performed to obtain Compound 33 ((Z)-2-(2-((3″,4′-bis(2,6-dimethylphenyl)-[2,2′:5′,2″-terthiophen]-5-yl)methylene)-5,6-difluoro-3-oxo-2,3-dihydro-1H-inden-1-ylidene)malononitrile) as a yellow solid (Yield=68%).

¹H NMR (500 MHz, CDCl₃) δ 8.78 (s, 1H), 8.54-8.51 (m, 1H), 7.72-7.71 (d, 1H), 7.67-7.64 (t, 1H), 7.36-7.30 (m, 1H), 7.23 (s, 1H), 7.21-7.19 (m, 4H), 7.17 (s, 1H), 7.04-7.03 (d, 2H), 6.76-6.75 (d, 1H), 2.07-2.03 (d, 12H).

### Synthesis Example 6 (Synthesis of Compound 54)

### Synthesis of Intermediate 54-1 (5-bromo-3,3′-bis(2,6-dimethylphenyl)-2,2′-bithiophene)

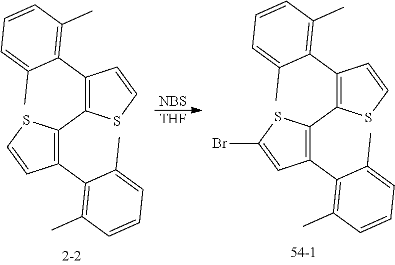

Intermediate 2-2 (500 mg, 1 eq) was dissolved in THE (200 mL) under nitrogen conditions, N-bromosuccinimide (NBS, 285.10 mg, 1.2 eq) was added thereto at room temperature and in the dark, and the mixture was reacted for 12 hours. After the reaction was completed, the solvent was evaporated under vacuum, and an extraction process was performed with DCM and saturated NaCl (aq). After MgSO₄ was used to remove moisture from the extract, column chromatography (hexane) was performed to obtain Intermediate 54-1 as a solid (Yield=40%).

¹H NMR (500 MHz, (CD₃)₂CO) δ 6.57-6.56 (d, 1H), 6.50-6.49 (m, 2H), 6.40-6.37 (m, 4H), 6.02 (s, 1H), 5.95-5.93 (d, 1H), 1.23 (s, 6H), 1.19 (s, 6H).

### Synthesis of Intermediate 54-2 (3,3′-bis(2,6-dimethylphenyl)-5-(selenophen-2-yl)-2,2′-bithiophene)

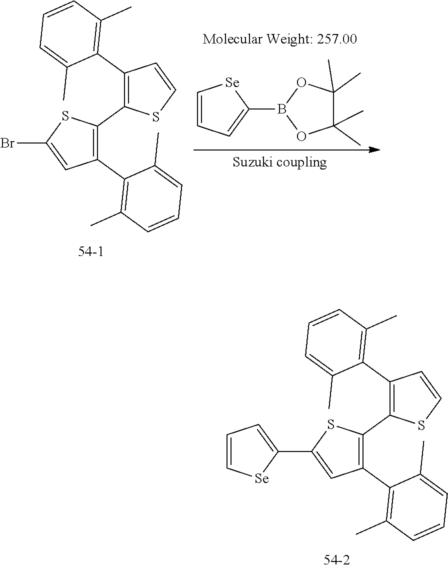

Intermediate 54-1 (150 mg, 1 eq), 4,4,5,5-tetramethyl-2-(selenophen-2-yl)-1,3,2-dioxaborolane (340.06 mg, 4 eq), and 1 drop of Aliquat 336 were placed in a microwave vial, and Pd(PPh₃)₄ (382.25 mg, 0.12 eq) was added thereto in a glovebox. The mixture was dissolved in toluene (8 mL) and 2 M CsCO₃ (4 mL) in a nitrogen atmosphere, reacted at 80° C. for 12 hours, and cooled to room temperature. An extraction process was performed with ether and distilled water, and MgSO₄ was used to remove moisture from the extract. Column chromatography (hexane) was performed to obtain Intermediate 54-2 as a white solid (Yield=54%).

¹H NMR (500 MHz, CDCl₃) δ 7.80-7.79 (d, 1H), 7.29-7.28 (m, 1H), 7.16-7.14 (m, 4H), 7.10 (m, 1H), 7.08-7.07 (m, 1H), 6.75 (s, 1H), 6.70-6.69 (d, 1H), 2.08 (s, 6H), 2.03 (s, 6H).

### Synthesis of Intermediate 54-3 (5-(3,3′-bis(2,6-dimethylphenyl)-[2,2′-bithiophen]-5-yl)selenophene-2-carbaldehyde)

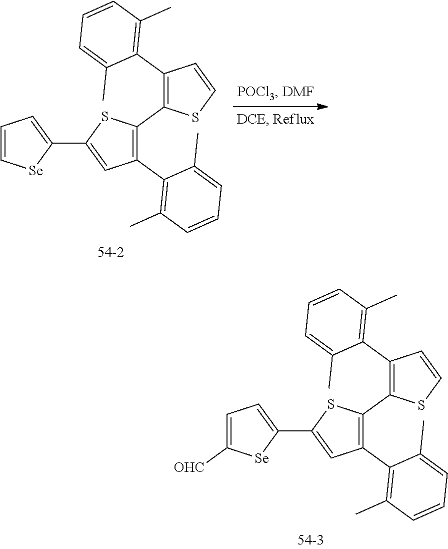 [SMILES: Cc1cccc(C)c1-c1ccsc1-c1sc(-c2ccc[se]2)cc1-c1c(C)cccc1C ; Cc1cccc(C)c1-c1ccsc1-c1sc(-c2ccc(C=O)[se]2)cc1-c1c(C)cccc1C]

Intermediate 54-2 (100 mg, 1 eq) was placed in a flask which was connected to a condenser in a nitrogen atmosphere. At 0° C., DCE (10 mL), DMF (0.015 mL, 1 eq), and POCl₃ (0.019 mL, 0.85 eq) was added thereto and stirred for 30 minutes. After the reaction was carried out at room temperature for 12 hours, the reaction mixture was heated to 90° C. to continue the reaction. Acidification was performed with saturated CH₃COONa (aq) at 50° C., and the resulting solution was cooled to room temperature. An extraction process was performed with chloroform, and MgSO₄ was used to remove moisture from the extract. Column chromatography (chloroform) was performed to obtain Intermediate 54-3 as a yellow solid (Yield=80%).

¹H NMR (500 MHz, (CD₃)₂CO) δ 9.76 (s, 1H), 8.06-8.05 (d, 1H), 7.43-7.42 (d, 1H), 7.33-7.32 (t, 2H), 7.30-7.28 (d, 1H), 7.22-7.20 (m, 4H), 7.17 (s, 1H), 6.80-6.79 (d, 1H), 2.05 (s, 6H), 2.00 (s, 6H).

### Synthesis of Compound 54

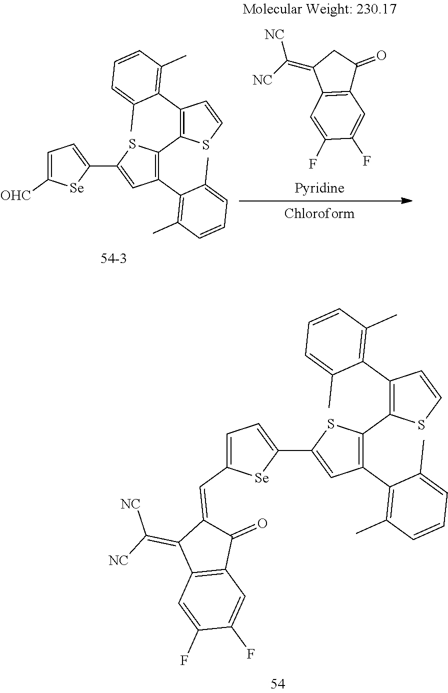 [SMILES: Cc1cccc(C)c1-c1ccsc1-c1sc(-c2ccc(C=O)[se]2)cc1-c1c(C)cccc1C ; N#CC(C#N)=C1CC(=O)c2cc(F)c(F)cc21 ; Cc1cccc(C)c1-c1ccsc1-c1sc(-c2ccc(/C=C3\C(=O)c4cc(F)c(F)cc4C3=C(C#N)C#N)[se]2)cc1-c1c(C)cccc1C]

Compound 54 ((Z)-2-(2-((5-(3,3′-bis(2,6-dimethylphenyl)-[2,2′-bithiophen]-5-yl)selenophen-2-yl)methylene)-5,6-difluoro-3-oxo-2,3-dihydro-1H-inden-1-ylidene)malononitrile) was synthesized using the same method as for the synthesis of Compound 33, except that Intermediate 54-3 was used instead of Intermediate 33-2 (Yield=61%).

¹H NMR (500 MHz, CDCl₃) δ 8.88 (s, 1H), 8.53-8.50 (m, 1H), 7.90-7.89 (d, 1H), 7.66-7.63 (t, 1H), 7.35-7.30 (m, 3H), 7.22-7.20 (m, 4H), 7.19 (s, 1H), 7.17 (s, 1H), 6.76-6.75 (d, 1H), 2.08-2.03 (d, 12H).

For the compounds synthesized in Synthesis Examples 1 to 6, ¹H NMR and high-resolution mass (HR-MS) were measured, and the results are shown in Table 1:

TABLE 1

| | | MS/FAB | |
|---|---|---|---|
| Compound | ¹H NMR (CDCl₃, 400 MHz) | found | calc. |
| 2 | 8.29 (s, 1H), 7.92-7.89 (m, 2H), 7.75-7.73 (m, 2H), 7.62 (s, | 530.7000 | 530.1374 |
| | 1H), 7.40-7.37 (t, 1H), 7.33-7.30 (t, 1H), 7.27 (s, 1H), 7.24- | | |
| | 7.23 (d, 2H) 7.18-7.16 (d, 2H), 6.79-6.78 (d, 1H), 2.04-2.03 | | |
| | (d, 12H). | | |
| 7 | 8.42 (s, 1H), 8.38 (s, 1H), 8.07 (m, 2H), 7.72 (s, 1H), 7.68- | 580.7600 | 580.1531 |
| | 7.65 (m, 2H) 7.43-7.40 (t, 2H), 7.34-7.31 (t, 2H), 7.30-7.28 | | |
| | (s, 1H), 7.19-7.18 (d, 2H), 6.81-6.80 (d, 2H), 2.05-2.04 (d, | | |
| | 12H). | | |
| 12 | 8.61 (s, 1H), 8.51-8.48 (m, 1H), 7.66 (s, 1H), 7.65-7.62 (t, | 614.7288 | 614.1298 |
| | 1H), 7.41-7.38 (t, 1H), 7.36-7.35 (d, 1H), 7.34-7.31 (t, 2H), | | |
| | 7.27 (s, 1H), 7.18-7.17 (d, 2H), 6.84-6.83 (d, 1H), 2.03-2.05 | | |
| | (d, 12H). | | |
| 20 | 8.73 (s, 1H), 8.64 (s, 1H), 7.89 (s, 1H), 7.66 (s, 1H), 7.43- | 647.6320 | 646.0707 |
| | 7.40 (t, 1H), 7.37-7.36 (d, 1H), 7.34-7.31 (t, 1H), 7.28-7.27 | | |
| | (d, 2H), 7.19-7.17 (d, 2H), 6.85-6.84 (d, 1H), 2.05-2.03 | | |
| 33 | 8.78 (s, 1H), 8.54-8.51 (m, 1H), 7.72-7.71 (d, 1H), 7.67-7.64 | 696.8488 | 696.1175 |
| | (t, 1H), 7.36-7.30 (m, 1H), 7.23 (s, 1H), 7.21-7.19 (m, 4H), | | |
| | 7.17 (s, 1H), 7.04-7.03 (d, 2H), 6.76-6.75 (d, 1H), 2.07-2.03 | | |
| | (d, 12H). | | |
| 54 | 8.88 (s, 1H), 8.53-8.50 (m, 1H), 7.90-7.89 (d, 1H), 7.66-7.63 | 744.0620 | 743.7488 |
| | (t, 1H), 7.35-7.30 (m, 3H), 7.22-7.20 (m, 4H), 7.19 (s, 1H), | | |
| | 7.17 (s, 1H), 6.76-6.75 (d, 1H), 2.08-2.03 (d, 12H). | | |

### Evaluation Example 1

The molecular weight, decomposition temperature, maximum absorption wavelength, highest occupied molecular orbital (HOMO) energy level, lowest unoccupied molecular orbital (LUMO) energy level, and optical band gap of each of the organic compounds synthesized according to Synthesis Examples 1 to 6 and Comparative Compounds CE1 to CE5 were measured according to the methods in Table 2, and the results are shown in Table 3.

TABLE 2

| | |
|---|---|
| Molecular weight | Calculated by adding up the standard atomic weights of the atoms that |
| evaluation method | make up each compound. |
| Decomposition | The sample was heated and the temperature at which the mass of the |
| temperature | substance decreased by 5% was determined as the decomposition |
| evaluation method | temperature by using a thermogravimetric analyzer. |
| Maximum | Wavelength-specific spectral data for the absorption region may be |
| absorption | obtained through measurement or simulation after synthesis of the |
| wavelength (λₘₐₓ) | molecular structure, and the wavelength exhibiting the maximum |
| | absorbance in the spectrum was obtained and calculated. |
| | Light of various wavelengths was emitted from a light source of |
| | Ultraviolet-visible spectroscopy and the intensity of light according to |
| | each wavelength was measured before and after it passed through the |
| | sample to identify the wavelength that exhibits maximum absorbance. |
| HOMO energy | A potential (V)-current (A) graph of each compound was obtained by |
| level evaluation | using cyclic voltammetry (CV) (electrolyte: 0.1M Bu₄NPF₆/solvent: |
| method | CH₃CN (acetonitrile)/electrode: 3 electrode system (working electrode: |
| | GC, reference electrode: Ag/AgNO₃, auxiliary electrode: Pt)), and from |
| | oxidation onset of the graph, a HOMO energy level of the compound |
| | was calculated. |
| LUMO energy level | The LUMO energy level of each compound was obtained by calculation |
| evaluation method | using the HOMO value obtained through CV and the optical band gap. |
| Optical band gap | The optical band gap was measured through the onset value of the |
| evaluation method | absorption wavelength of a film. |

TABLE 3

| | | | Maximum | | | |
|---|---|---|---|---|---|---|
| | | Decomposition | absorption | | | Optical |
| Organic | Molecular | temperature | wavelength | HOMO | LUMO | band gap |
| compound | weight | (° C.) | (λₘₐₓ) | (eV) | (eV) | (eV) |
| Compound 2 | 530.70 | 325 | 500 | −5.58 | −3.27 | 2.31 |
| Compound 7 | 580.76 | 313 | 521 | −5.59 | −3.39 | 2.20 |
| Compound 12 | 614.73 | 332 | 537 | −5.66 | −3.72 | 1.94 |
| Compound 20 | 647.63 | 348 | 547 | −5.82 | −3.90 | 1.92 |
| Compound 33 | 696.85 | 323 | 614 | −5.60 | −3.98 | 1.62 |
| Compound 54 | 743.75 | 300 | 627 | −5.54 | −3.96 | 1.58 |
| Comparative | 547.64 | 276 | 626 | −5.80 | −3.32 | 2.48 |
| Compound CE1 | | | | | | |
| Comparative | 646.6 | 318 | 589 | −6.35 | −3.73 | 2.62 |
| Compound CE2 | | | | | | |
| Comparative | 478.54 | 229 | 505 | −6.01 | −3.38 | 2.63 |
| Compound CE3 | | | | | | |
| Comparative | 979.31 | 342 | 596 | −6.10 | −3.84 | 2.26 |
| Compound CE4 | | | | | | |
| Comparative | 1473.96 | 348 | 632 | −6.26 | −3.61 | 2.65 |
| Compound CE5 | | | | | | |

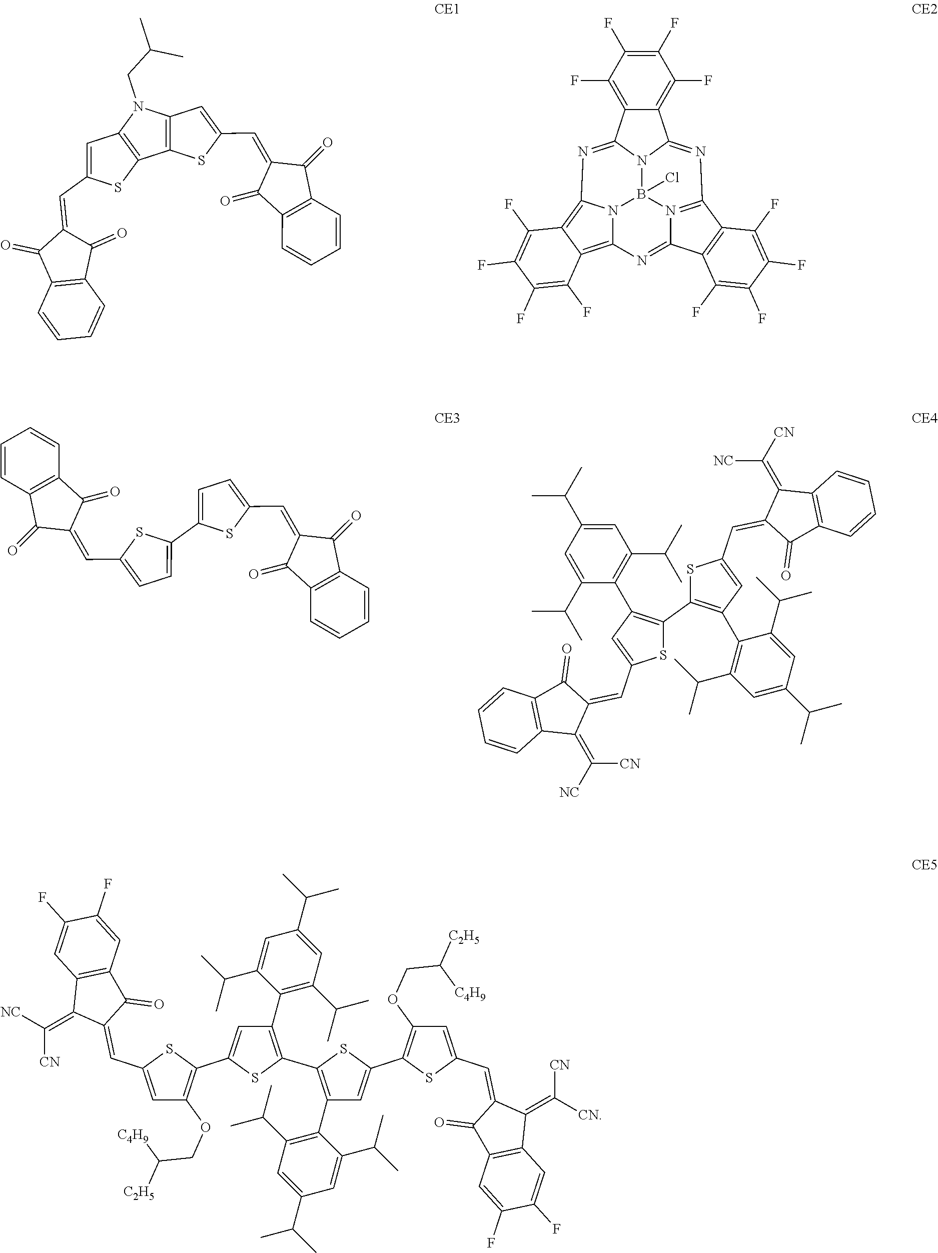

From Table 3, it can be confirmed that Comparative Compounds CE4 and CE5 have excessively large molecular weights, which leads to the understanding that Comparative Compounds CE4 and CE5 have excessively high deposition temperatures. Comparative Compounds CE4 and CE5 have decomposition temperatures that are lower than the deposition temperature, making it difficult to form layers through a deposition process. Therefore, compounds with relatively large molecular weights, such as Comparative Compounds CE4 and CE5, are unsuitable for the deposition process. When a layer including Comparative Compounds CE4 and/or CE5 is formed via a solution process, degeneration may occur upon exposure to oxygen, nitrogen, and/or moisture.

It can be confirmed that Compounds 2, 7, 12, 20, 33, and 54 and Comparative Compounds CE1 to CE3 have relatively small molecular weights. Among these, Compounds 2, 7, 12, 20, 33, and 54 were found to have relatively small optical band gaps of equal to or less than about 2.4 eV.

### Example 1

As an anode, a glass substrate (product of Corning Inc.) with a 15 Ω/cm² (1,200 Å) ITO formed thereon was cut to a size of 50 mm×50 mm×0.7 mm, sonicated by using isopropyl alcohol and pure water each for 5 minutes, washed by irradiation of ultraviolet rays and exposure of ozone thereto for 30 minutes, and mounted on a vacuum deposition apparatus.

2-TNATA was vacuum-deposited on the anode to form a hole injection layer having a thickness of 600 Å. 4,4′-bis[N-(1-naphthyl)-N-phenylamino]biphenyl (hereinafter, referred to as NPB) was vacuum-deposited on the hole injection layer to form a hole transport layer having a thickness of 300 Å. An emission auxiliary layer having a thickness of 300 Å was formed on the hole transport layer.

Compound 33 was deposited on the emission auxiliary layer to form a first layer (p-type optical activation layer), and Compound N36 was deposited to form a second layer (n-type optical activation layer), thereby forming an optical activation layer having a total thickness of 500 Å.

Alq₃ was vacuum-deposited on the optical activation layer to form an electron transport layer having a thickness of 300 Å. LiF was vacuum-deposited on the electron transport layer to form an electron injection layer having a thickness of 10 Å. Al was vacuum-deposited on the electron injection layer to form a cathode having a thickness of 3,000 Å, thereby completing the manufacture of an optoelectronic device.

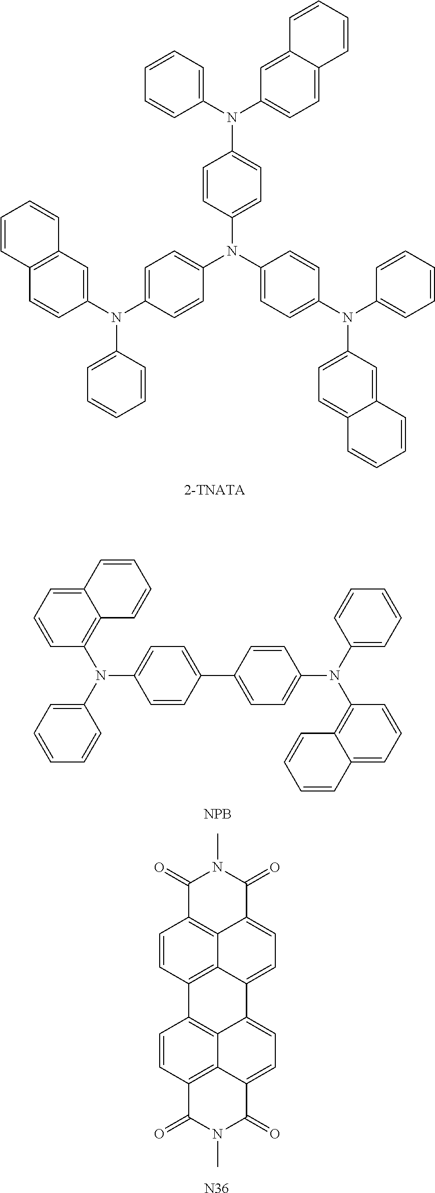

### Example 2 and Comparative Examples 1 to 3

An optoelectronic device was manufactured in the same manner as in Example 1, except that the compounds shown in Table 4 were used when forming the first layer of the optical activation layer.

### Comparative Examples 4 and 5

To form the first layer of the optical activation layer, deposition was attempted using Comparative Compounds CE4 and CE5, but Comparative Compounds CE4 and CE5 had decomposition temperatures lower than the deposition temperature, making deposition impossible, as shown in Table 4 below.

### Evaluation Example 2

The results of measuring the external quantum efficiency (EQE) of each of the optoelectronic devices manufactured in Examples 1 and 2 and Comparative Examples 1 to 3 and the deposition temperature during formation of the optical activation layer are shown in Table 4. External quantum efficiency refers to the ratio of electrical energy generated from the incident optical energy.

Light was irradiated onto the optoelectronic device by using a Xenon lamp, and the converted current during light irradiation was measured by using a current meter (Keithley, Tektronix, USA). The external quantum efficiency (EQE) was calculated by using the irradiated light and measured current through an external quantum efficiency meter (K3100, Mcscience Inc., Korea).

TABLE 4

| | | Deposition | |
|---|---|---|---|
| | Organic compound | temperature | EQE |
| No. | (p-type compound) | (° C.) | (%) |
| Example 1 | Compound 33 | 300 | 28 |
| Example 2 | Compound 54 | 280 | 33 |
| Comparative | Comparative | 285 | 12 |
| Example 1 | Compound CE1 | | |
| Comparative | Comparative | 312 | 8 |
| Example 2 | Compound CE2 | | |
| Comparative | Comparative | 188 | 0.8 |
| Example 3 | Compound CE3 | | |
| Comparative | Comparative | Non- | Non- |
| Example 4 | Compound CE4 | depositable | depositable |
| Comparative | Comparative | Non- | Non- |
| Example 5 | Compound CE5 | depositable | depositable |

As can be seen in Tables 3 and 4, when Comparative Compounds CE4 and CE5, each having a relatively large molecular weight, were employed, the deposition temperature was higher than the decomposition temperature of each of Comparative Compounds CE4 and CE5, so it was not possible to manufacture an optical activation layer through a deposition process. Therefore, Comparative Compounds CE4 and CE5 are not suitable for the deposition process and are not suitable as materials for forming an optical activation layer because degeneration may occur upon exposure to oxygen, nitrogen, and/or moisture when manufacturing an optical activation layer through a solution process.

In Examples 1 and 2, which use compounds having relatively low molecular weights, the optoelectronic device may be readily manufactured through a deposition process. In the manufacture of an electronic apparatus including a light-emitting device manufactured by a deposition process in addition to components of the optoelectronic device (a hole transport region or an electron transport region) excluding the optical activation layer and the optoelectronic device, the organic compound represented by Formula 1 is suitable for being used in the optical activation layer.

It can be confirmed that the optoelectronic devices according to Examples 1 and 2 have effectively superior EQEs than the optoelectronic devices according to Comparative Examples 1 to 3.

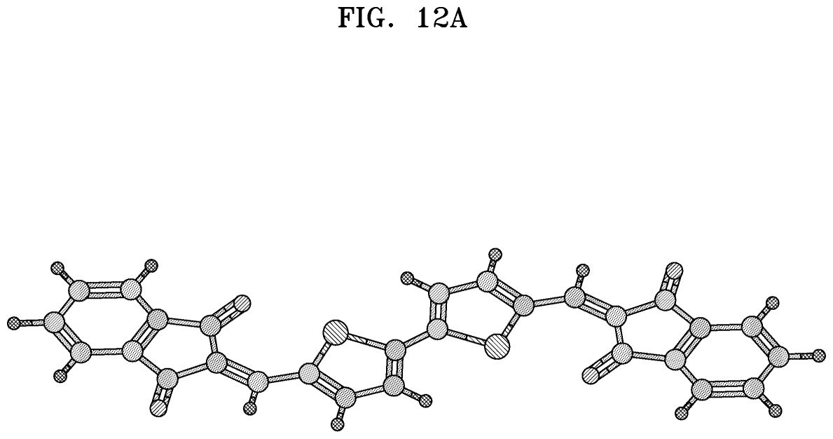

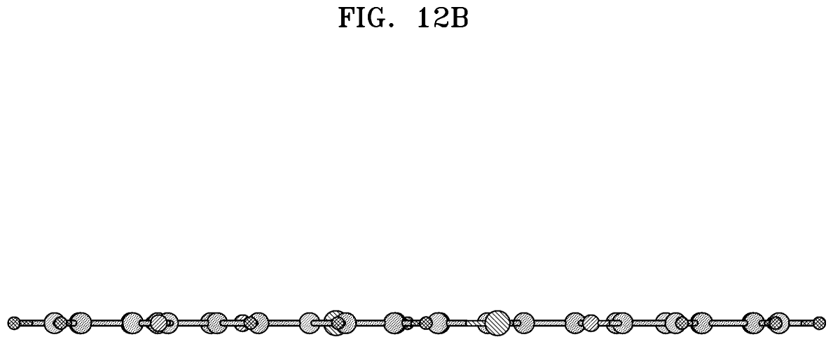

FIG. 12A is a schematic planar view of the structure of Comparative Compound CE3, and FIG. 12B is a schematic profile view of the structure of Comparative Compound CE3. Referring to FIGS. 12A and 12B, Comparative Compound CE3 has high planarity because, unlike the organic compounds of Examples 1 and 2, no benzene group (for example, dimethylphenyl) is bonded to the two thiophene rings. Thus, it can be predicted that the EQE of Comparative Example 3 was reduced due to direct contact between the emission auxiliary layer of the hole transport region and the second layer of the optical activation layer by aggregation of Comparative Compound CE3.

An organic compound having a structure of donor-(spacer)-acceptor (D-A) rather than a structure of acceptor-(spacer)-donor-(spacer)-acceptor (A-D-A), which is represented by Formula 1, has a relatively small molecular weight and may therefore be used in a deposition process at a relatively low deposition temperature. Since the deposition temperature of the organic compound is lower than the decomposition temperature of the organic compound, it can have excellent thermal stability without decomposing during the deposition process. Since the organic compound has a structure with low planarity and does not aggregate with itself, the interface characteristics of the optical activation layer may be improved. Therefore, when applying an optoelectronic device employing the organic compound to an electronic apparatus including a light-emitting device, both the light-emitting device and the optoelectronic device may be readily manufactured by a deposition process.

Embodiments have been disclosed herein, and although terms are employed, they are used and are to be interpreted in a generic and descriptive sense only and not for purposes of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. An optoelectronic device comprising:
a first electrode;
a second electrode facing the first electrode;
an optical activation layer between the first electrode and the second electrode; and
an organic compound represented by Formula 1: 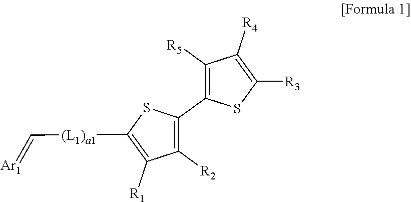
wherein in Formula 1,
R₁ to R₅ are each independently hydrogen, deuterium, a C₁-C₁₅ alkyl group unsubstituted or substituted with at least one R₀, a C₁-C₁₅ alkoxy group unsubstituted or substituted with at least one R₀, or a C₆-C₁₅ aryl group unsubstituted or substituted with at least one R₀,
R₀ is deuterium, a C₁-C₁₅ alkyl group, a C₁-C₁₅ alkoxy group, or a C₆-C₁₅ aryl group,
L₁ is a C₃-C₁₅ carbocyclic group unsubstituted or substituted with at least one R₁₀ₐ or a C₁-C₁₅ heterocyclic group unsubstituted or substituted with at least one R₁₀ₐ,
a1 is an integer from 0 to 2,
when a1 is 0, (L₁)ₐ₁ is a single bond,
when a1 is 2, two of L₁ are identical to or different from each other, and
Ar₁ is a group represented by one of Formulae A1 to A3: 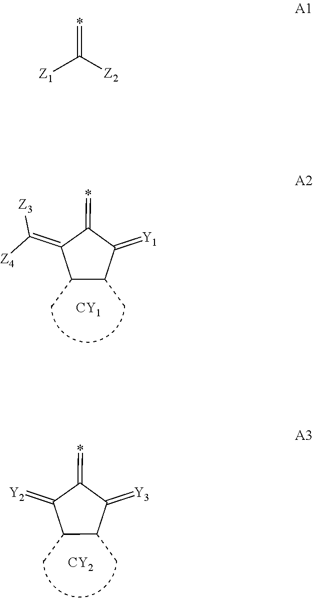
wherein in Formulae A1 to A3,
ring CY₁ and ring CY₂ are each independently a C₃-C₁₅ carbocyclic group unsubstituted or substituted with at least one R₁₀ₐ or a C₁-C₁₅ heterocyclic group unsubstituted or substituted with at least one R₁₀ₐ,
Z₁ to Z₄ are each independently a cyano group, —F, —Cl, —Br, or —I,
Y₁ to Y₃ are each independently O or S,
* indicates a binding site to a neighboring atom, and
R₁₀ₐ is:
deuterium, —F, —Cl, —Br, —I, a hydroxyl group, a cyano group, or a nitro group;
a C₁-C₁₅ alkyl group, a C₂-C₁₅ alkenyl group, a C₂-C₁₅ alkynyl group, or a C₁-C₁₅ alkoxy group, each unsubstituted or substituted with deuterium, —F, —Cl, —Br, —I, a hydroxyl group, a cyano group, a nitro group, a C₃-C₁₅ carbocyclic group, a C₁-C₁₅ heterocyclic group, a C₆-C₁₅ aryloxy group, a C₆-C₁₅ arylthio group, a C₇-C₁₅ arylalkyl group, a C₂₋₁₅ heteroarylalkyl group, or a combination thereof; or
a C₃-C₁₅ carbocyclic group, a C₁-C₁₅ heterocyclic group, a C₆-C₁₅ aryloxy group, a C₆-C₁₅ arylthio group, a C₇-C₁₅ arylalkyl group, or a C₂-C₁₅ heteroarylalkyl group, each unsubstituted or substituted with deuterium, —F, —Cl, —Br, —I, a hydroxyl group, a cyano group, a nitro group, a C₁-C₁₅ alkyl group, a C₂-C₁₅ alkenyl group, a C₂-C₁₅ alkynyl group, a C₁-C₁₅ alkoxy group, a C₃-C₁₅ carbocyclic group, a C₁-C₁₅ heterocyclic group, a C₆-C₁₅ aryloxy group, a C₆-C₁₅ arylthio group, a C₇-C₁₅ arylalkyl group, a C₂-C₁₅ heteroarylalkyl group, or a combination thereof.

2. The optoelectronic device of claim 1, further comprising:
a first compound that is different from the organic compound, wherein
the first compound is not a fullerene-based compound.

3. The optoelectronic device of claim 2, wherein the optical activation layer comprises the organic compound and the first compound.

4. The optoelectronic device of claim 2, wherein
the optical activation layer comprises:
a first layer adjacent to the first electrode; and
a second layer adjacent to the second electrode,
the first layer comprises the organic compound, and
the second layer comprises the first compound.

5. The optoelectronic device of claim 1, wherein the optical activation layer absorbs light having a wavelength in a range of about 400 nm to about 1,000 nm.

6. The optoelectronic device of claim 2, wherein the first compound is represented by one of Formulae 2-1 to 2-6: 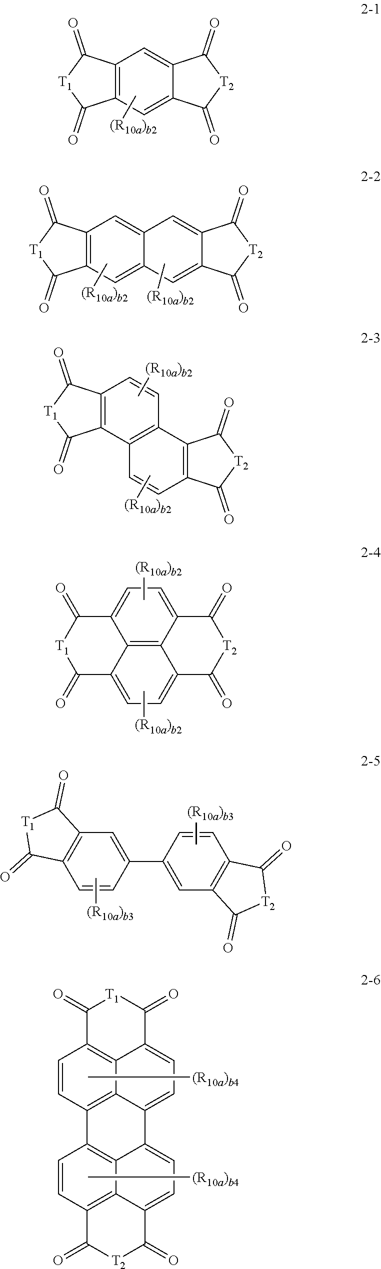
wherein in Formulae 2-1 to 2-6,
T₁ is O, S, N(R₆₁), C(R₆₁)(R₆₂), C(═O), C(═S), or C═C(R₆₁)(R₆₂),
T₂ is O, S, N(R₆₃), C(R₆₃)(R₆₄), C(═O), C(═S), or C═C(R₆₃)(R₆₄),
R₆₁ to R₆₄ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ arylalkyl group, a C₂-C₆₀ heteroarylalkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
R₁₀ₐ is:
deuterium, —F, —Cl, —Br, —I, a hydroxyl group, a cyano group, or a nitro group;
a C₁-C₁₅ alkyl group, a C₂-C₁₅ alkenyl group, a C₂-C₁₅ alkynyl group, or a C₁-C₁₅ alkoxy group, each unsubstituted or substituted with deuterium, —F, —Cl, —Br, —I, a hydroxyl group, a cyano group, a nitro group, a C₃-C₁₅ carbocyclic group, a C₁-C₁₅ heterocyclic group, a C₆-C₁₅ aryloxy group, a C₆-C₁₅ arylthio group, a C₇-C₁₅ arylalkyl group, a C₂₋₁₅ heteroarylalkyl group, or a combination thereof; or
a C₃-C₁₅ carbocyclic group, a C₁-C₁₅ heterocyclic group, a C₆-C₁₅ aryloxy group, a C₆-C₁₅ arylthio group, a C₇-C₁₅ arylalkyl group, or a C₂-C₁₅ heteroarylalkyl group, each unsubstituted or substituted with deuterium, —F, —Cl, —Br, —I, a hydroxyl group, a cyano group, a nitro group, a C₁-C₁₅ alkyl group, a C₂-C₁₅ alkenyl group, a C₂-C₁₅ alkynyl group, a C₁-C₁₅ alkoxy group, a C₃-C₁₅ carbocyclic group, a C₁-C₁₅ heterocyclic group, a C₆-C₁₅ aryloxy group, a C₆-C₁₅ arylthio group, a C₇-C₁₅ arylalkyl group, a C₂-C₁₅ heteroarylalkyl group, or a combination thereof,
Q₁ to Q₃ are each independently:
hydrogen, deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, or a C₁-C₆₀ alkoxy group; or
a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or a combination thereof,
b2 is an integer from 0 to 2,
b3 is an integer from 0 to 3, and
b4 is an integer from 0 to 4.

7. The optoelectronic device of claim 2, wherein the first compound is one of Compounds N1 to N43:

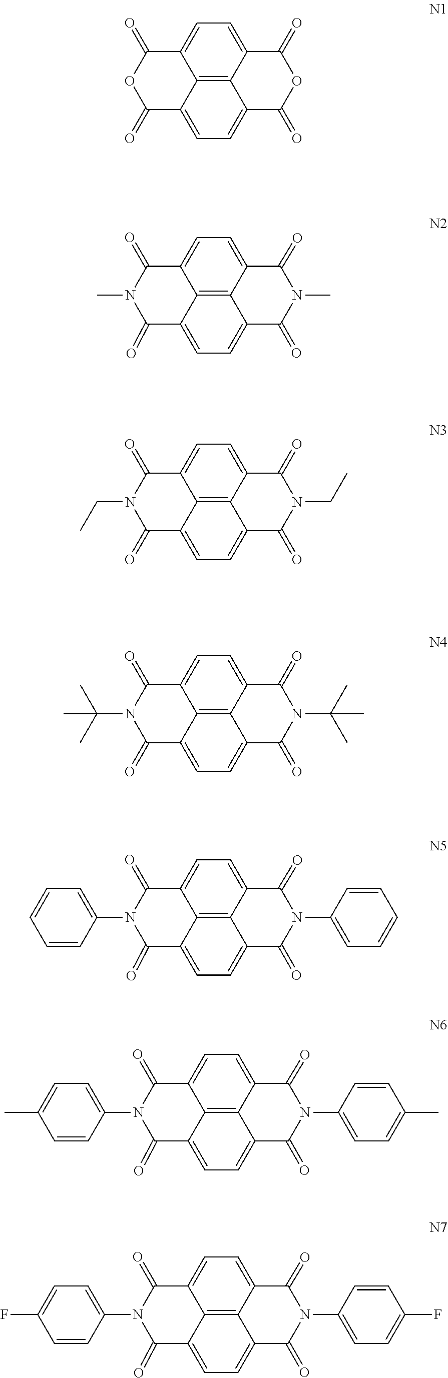

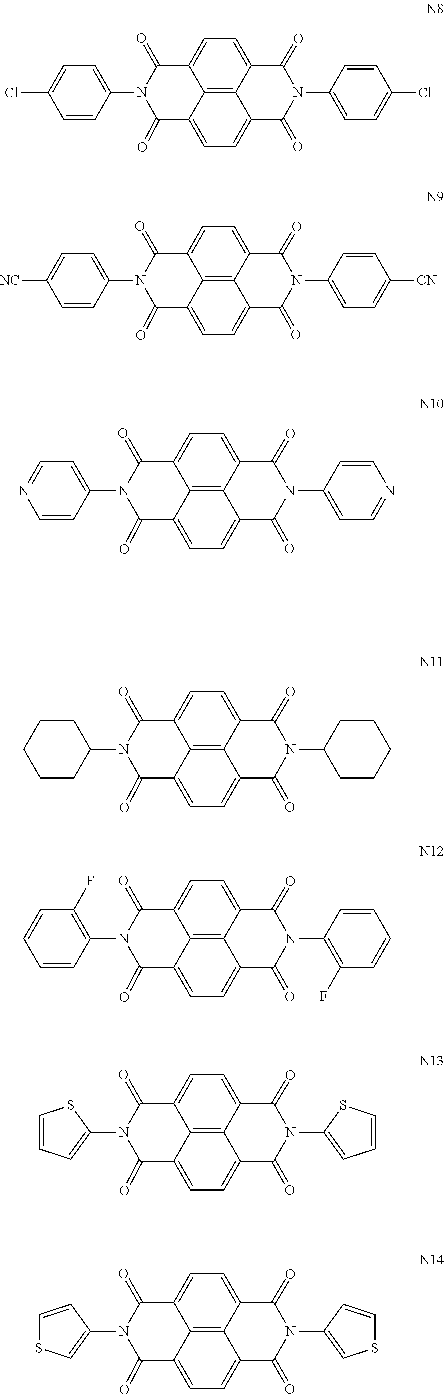

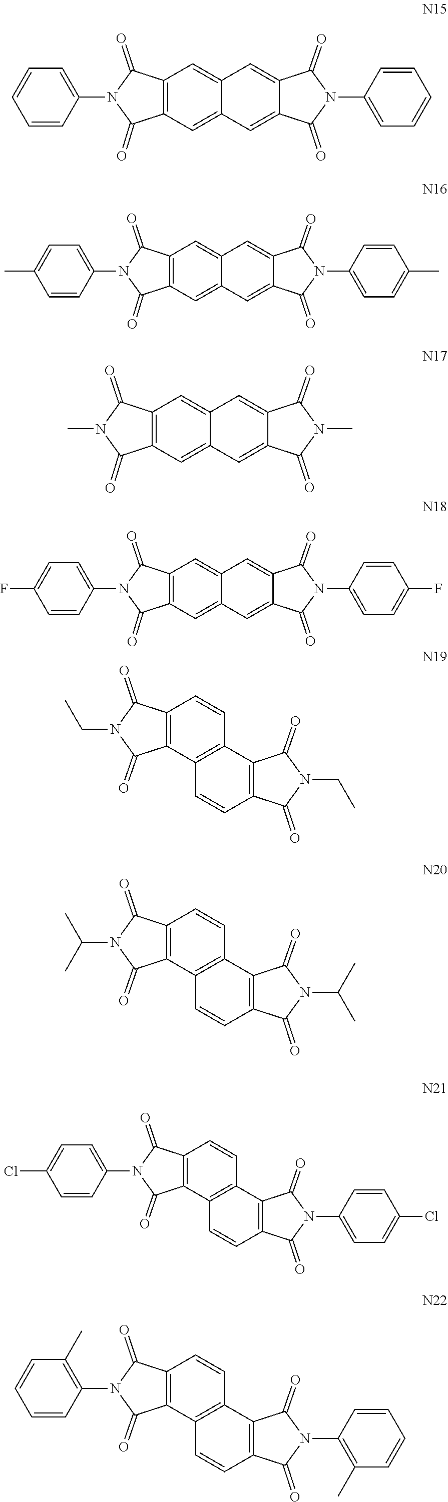

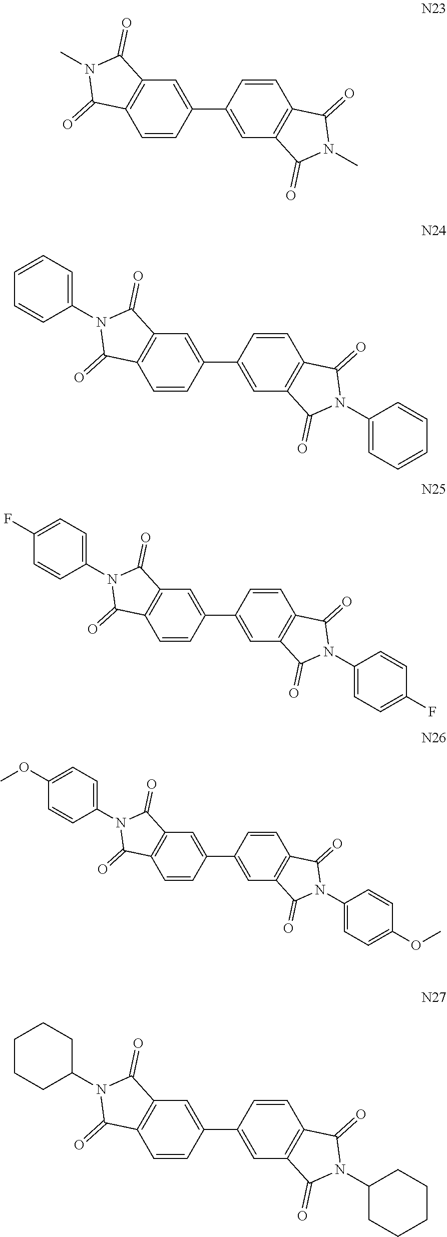

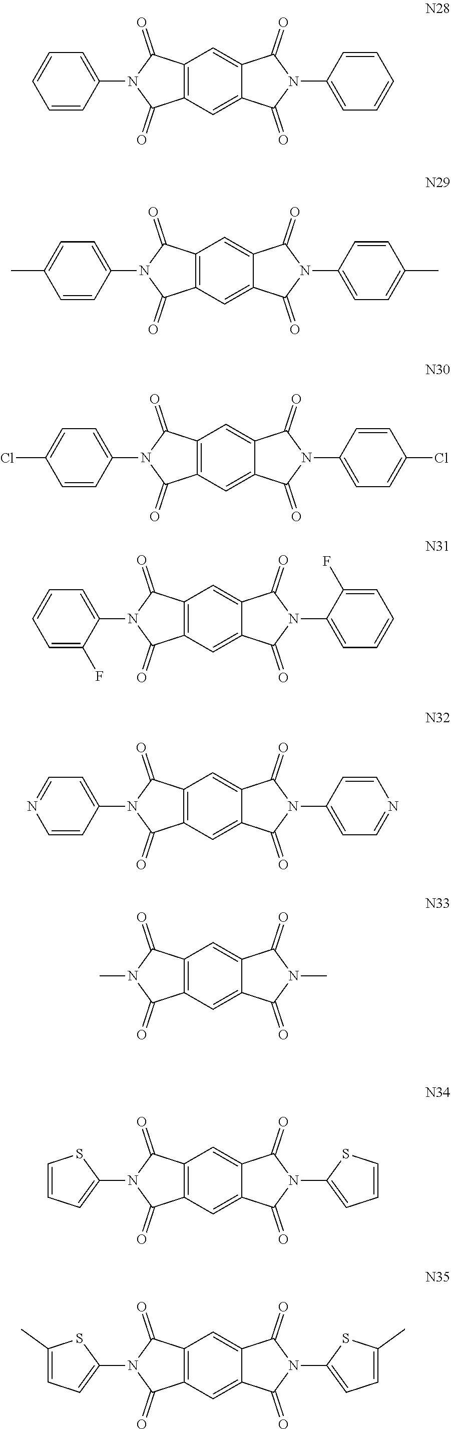

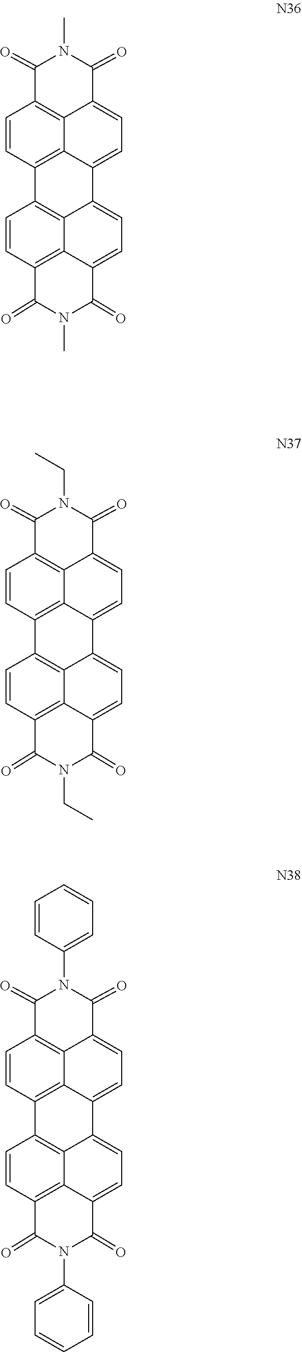 [SMILES: CN1C(=O)c2ccc3c4ccc5c6c(ccc(c7ccc(c2c37)C1=O)c64)C(=O)N(C)C5=O ; CCN1C(=O)c2ccc3c4ccc5c6c(ccc(c7ccc(c2c37)C1=O)c64)C(=O)N(CC)C5=O ; O=C1c2ccc3c4ccc5c6c(ccc(c7ccc(c2c37)C(=O)N1c1ccccc1)c64)C(=O)N(c1ccccc1)C5=O]

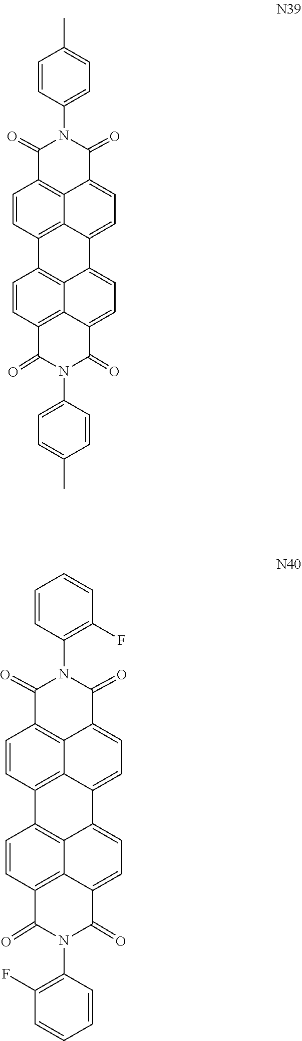 [SMILES: Cc1ccc(N2C(=O)c3ccc4c5ccc6c7c(ccc(c8ccc(c3c48)C2=O)c75)C(=O)N(c2ccc(C)cc2)C6=O)cc1 ; O=C1c2ccc3c4ccc5c6c(ccc(c7ccc(c2c37)C(=O)N1c1ccccc1F)c64)C(=O)N(c1ccccc1F)C5=O]

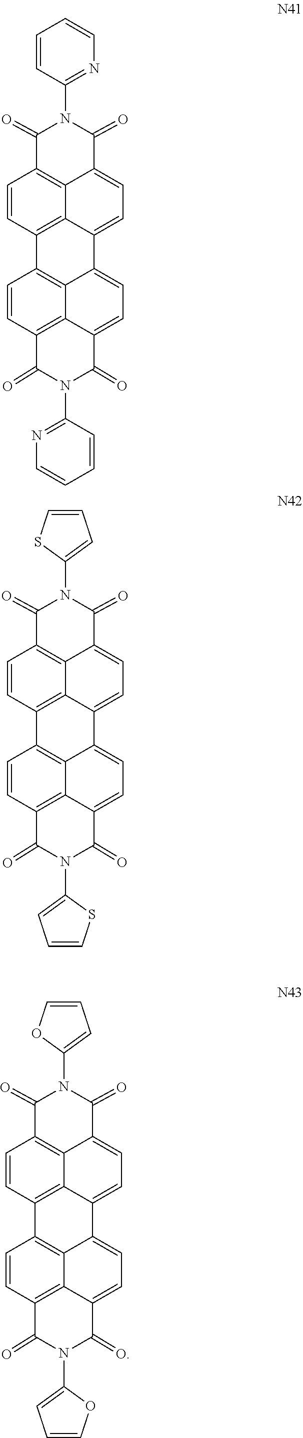

8. An electronic apparatus comprising:
the optoelectronic device of claim 1; and
a light-emitting device comprising an emission layer that does not overlap the optical activation layer.

9. An electronic equipment comprising:
the electronic apparatus of claim 8; and
a processor for transmitting a signal to the electronic apparatus.

10. The electronic equipment of claim 9, wherein the electronic equipment is a flat panel display, a curved display, a computer monitor, a medical monitor, a television, a billboard, an indoor light, an outdoor light, a signal light, a head-up display, a fully transparent display, a partially transparent display, a flexible display, a rollable display, a foldable display, a stretchable display, smart glasses, a head-mounted display, a smart watch, a laser printer, a telephone, a mobile phone, a tablet computer, a phablet, a personal digital assistant (PDA), a wearable device, a laptop computer, a digital camera, a camcorder, a viewfinder, a micro display, a three-dimensional (3D) display, a virtual reality display, an augmented reality display, a vehicle, a vehicle dashboard, a center information display (CID) for a vehicle, a rearview mirror display, a video wall with multiple displays tiled together, a theater screen, a stadium screen, a phototherapy device, or a signboard.

11. An organic compound represented by Formula 1: 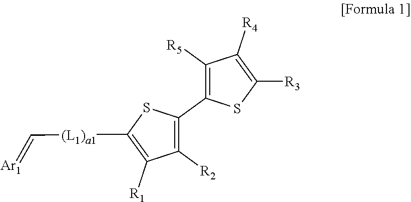
wherein in Formula 1,
R₁ to R₅ are each independently hydrogen, deuterium, a C₁-C₁₅ alkyl group unsubstituted or substituted with at least one R₀, a C₁-C₁₅ alkoxy group unsubstituted or substituted with at least one R₀, or a C₆-C₁₅ aryl group unsubstituted or substituted with at least one R₀,
R₀ is deuterium, a C₁-C₁₅ alkyl group, a C₁-C₁₅ alkoxy group, or a C₆-C₁₅ aryl group,
L₁ is a C₃-C₁₅ carbocyclic group unsubstituted or substituted with at least one R₁₀ₐ or a C₁-C₁₅ heterocyclic group unsubstituted or substituted with at least one R₁₀ₐ,
a1 is an integer from 0 to 2,
when a1 is 0, (L₁)ₐ₁ is a single bond,
when a1 is 2, two of L₁ are identical to or different from each other, and
Ar₁ is a group represented by one of Formulae A1 to A3: 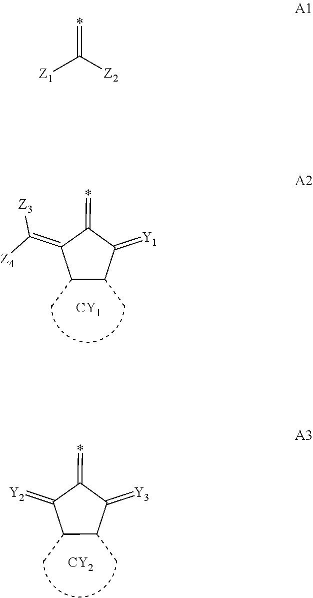
wherein in Formulae A1 to A3,
ring CY₁ and ring CY₂ are each independently a C₃-C₁₅ carbocyclic group unsubstituted or substituted with at least one R₁₀ₐ or a C₁-C₁₅ heterocyclic group unsubstituted or substituted with at least one R₁₀ₐ,
Z₁ to Z₄ are each independently a cyano group, —F, —Cl, —Br, or —I,
Y₁ to Y₃ are each independently O or S,
* indicates a binding site to a neighboring atom, and
R₁₀ₐ is:
deuterium, —F, —Cl, —Br, —I, a hydroxyl group, a cyano group, or a nitro group;
a C₁-C₁₅ alkyl group, a C₂-C₁₅ alkenyl group, a C₂-C₁₅ alkynyl group, or a C₁-C₁₅ alkoxy group, each unsubstituted or substituted with deuterium, —F, —Cl, —Br, —I, a hydroxyl group, a cyano group, a nitro group, a C₃-C₁₅ carbocyclic group, a C₁-C₁₅ heterocyclic group, a C₆-C₁₅ aryloxy group, a C₆-C₁₅ arylthio group, a C₇-C₁₅ arylalkyl group, a C₂₋₁₅ heteroarylalkyl group, or a combination thereof; or
a C₃-C₁₅ carbocyclic group, a C₁-C₁₅ heterocyclic group, a C₆-C₁₅ aryloxy group, a C₆-C₁₅ arylthio group, a C₇-C₁₅ arylalkyl group, or a C₂-C₁₅ heteroarylalkyl group, each unsubstituted or substituted with deuterium, —F, —Cl, —Br, —I, a hydroxyl group, a cyano group, a nitro group, a C₁-C₁₅ alkyl group, a C₂-C₁₅ alkenyl group, a C₂-C₁₅ alkynyl group, a C₁-C₁₅ alkoxy group, a C₃-C₁₅ carbocyclic group, a C₁-C₁₅ heterocyclic group, a C₆-C₁₅ aryloxy group, a C₆-C₁₅ arylthio group, a C₇-C₁₅ arylalkyl group, a C₂-C₁₅ heteroarylalkyl group, or a combination thereof.

12. The organic compound of claim 11, wherein a molecular weight of the organic compound is equal to or less than about 1,000 g/mol.

13. The organic compound of claim 11, wherein a decomposition temperature of the organic compound is equal to or greater than about 200° C.

14. The organic compound of claim 11, wherein in Formula 1, R₁ to R₅ are each independently:
hydrogen, deuterium, a C₁-C₄ alkyl group, a C₁-C₄ alkoxy group, a phenyl group, or a naphthyl group;
a C₁-C₄ alkyl group substituted with at least one deuterium;
a C₁-C₄ alkoxy group substituted with at least one deuterium; or
a phenyl group or a naphthyl group, each unsubstituted or substituted with deuterium, a C₁-C₄ alkyl group, a C₁-C₄ alkoxy group, or a combination thereof.

15. The organic compound of claim 11, wherein at least one of R₁ to R₅ is each independently a C₆-C₁₅ aryl group unsubstituted or substituted with at least one R₀.

16. The organic compound of claim 11, wherein the organic compound is represented by Formula 1-1: 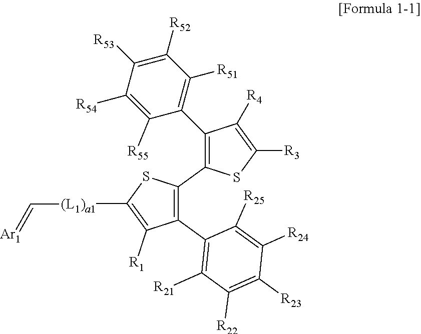
wherein in Formula 1-1,
R₁, R₃, R₄, L₁, a1, and Ar₁ are each the same as defined in Formula 1,
R₂₁ to R₂₅ are each independently the same as described in connection with R₂ in Formula 1, and
R₅₁ to R₅₅ are each independently the same as described in connection with R₅ in Formula 1.

17. The organic compound of claim 11, wherein:
a1 is 0; or
a1 is 1, and L₁ is a benzene group unsubstituted or substituted with at least one R₁₀ₐ, a pyrrole group unsubstituted or substituted with at least one R₁₀ₐ, a furan group unsubstituted or substituted with at least one R₁₀ₐ, a thiophene group unsubstituted or substituted with at least one R₁₀ₐ, or a selenophene group unsubstituted or substituted with at least one R₁₀ₐ.

18. The organic compound of claim 11, wherein
in Formulae A2 and A3, ring CY₁ and ring CY₂ are each independently:
a substituted or unsubstituted 5-membered ring;
a substituted or unsubstituted 6-membered ring;
a substituted or unsubstituted condensed ring in which two 5-membered rings are condensed with each other;
a substituted or unsubstituted condensed ring in which a 5-membered ring and a 6-membered ring are condensed with each other; or
a condensed ring in which two 6-membered rings are condensed with each other,
the 5-membered ring is a pyrrole group, a furan group, a thiophene group, an imidazole group, a pyrazole group, an oxazole group, an isoxazole group, or a thiazole group, and
the 6-membered ring is a benzene group, a pyridine group, a pyrimidine group, or a triazine group.

19. The organic compound of claim 11, wherein in Formulae A2 and A3, ring CY₁ and ring CY₂ are each independently a group represented by one of Formulae R1 to R5: 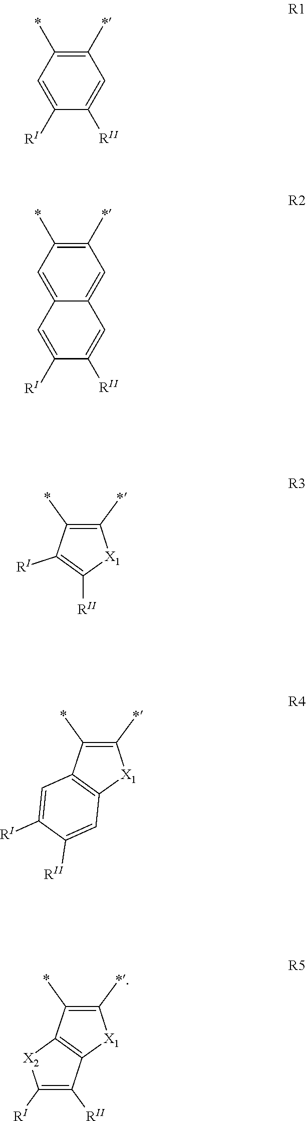
wherein in Formulae R1 to R5,
X₁ is O, S, N(R^{III}), or C(R^{III})(R^{IV}),
X₂ is O, S, N(R^{V}), or C(R^{V})(R^{VI}),
R^{I} to R^{VI} are each independently hydrogen, deuterium, —F, —Cl, —Br, —I, or a cyano group, and
* and *′ each indicate a binding site that is condensed with a moiety excluding ring CY₁ and ring CY₂ in Formulae A2 and A3.

20. The organic compound of claim 11, wherein the organic compound is one of Compounds 1 to 84: 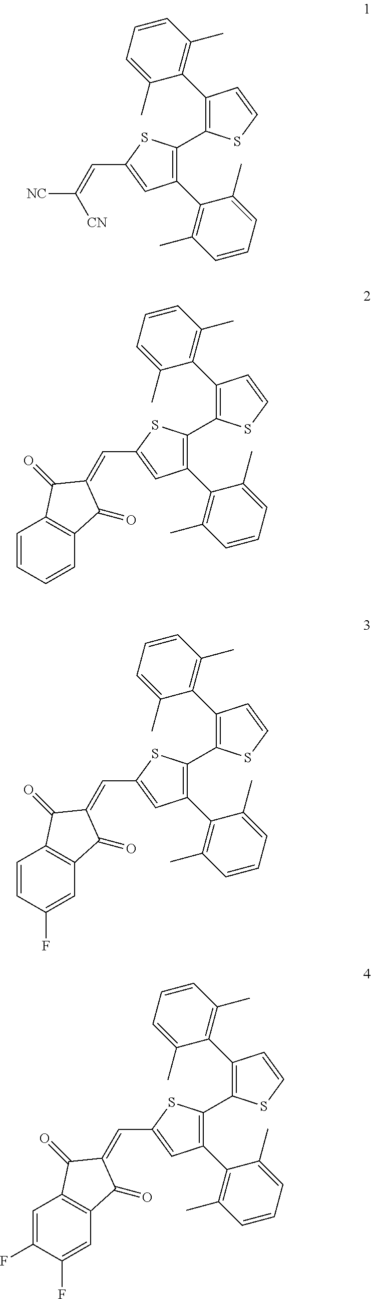 [SMILES: Cc1cccc(C)c1-c1ccsc1-c1sc(C=C(C#N)C#N)cc1-c1c(C)cccc1C ; Cc1cccc(C)c1-c1ccsc1-c1sc(C=C2C(=O)c3ccccc3C2=O)cc1-c1c(C)cccc1C ; Cc1cccc(C)c1-c1ccsc1-c1sc(/C=C2/C(=O)c3ccc(F)cc3C2=O)cc1-c1c(C)cccc1C ; Cc1cccc(C)c1-c1ccsc1-c1sc(C=C2C(=O)c3cc(F)c(F)cc3C2=O)cc1-c1c(C)cccc1C] 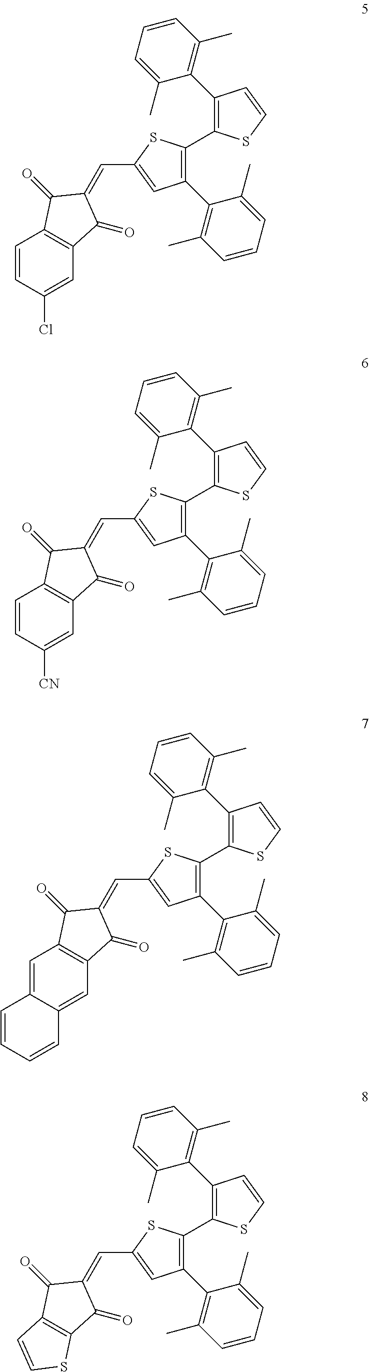 [SMILES: Cc1cccc(C)c1-c1ccsc1-c1sc(/C=C2/C(=O)c3ccc(Cl)cc3C2=O)cc1-c1c(C)cccc1C ; Cc1cccc(C)c1-c1ccsc1-c1sc(/C=C2/C(=O)c3ccc(C#N)cc3C2=O)cc1-c1c(C)cccc1C ; Cc1cccc(C)c1-c1ccsc1-c1sc(C=C2C(=O)c3cc4ccccc4cc3C2=O)cc1-c1c(C)cccc1C ; Cc1cccc(C)c1-c1ccsc1-c1sc(/C=C2/C(=O)c3ccsc3C2=O)cc1-c1c(C)cccc1C] 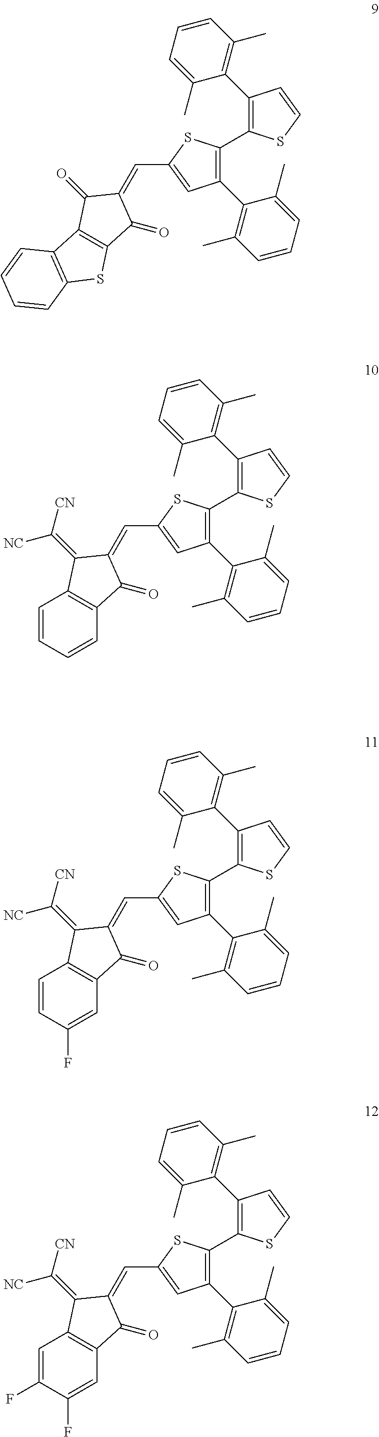 [SMILES: Cc1cccc(C)c1-c1ccsc1-c1sc(/C=C2\C(=O)c3sc4ccccc4c3C2=O)cc1-c1c(C)cccc1C ; Cc1cccc(C)c1-c1ccsc1-c1sc(/C=C2\C(=O)c3ccccc3C2=C(C#N)C#N)cc1-c1c(C)cccc1C ; Cc1cccc(C)c1-c1ccsc1-c1sc(/C=C2\C(=O)c3cc(F)ccc3C2=C(C#N)C#N)cc1-c1c(C)cccc1C ; Cc1cccc(C)c1-c1ccsc1-c1sc(/C=C2\C(=O)c3cc(F)c(F)cc3C2=C(C#N)C#N)cc1-c1c(C)cccc1C] 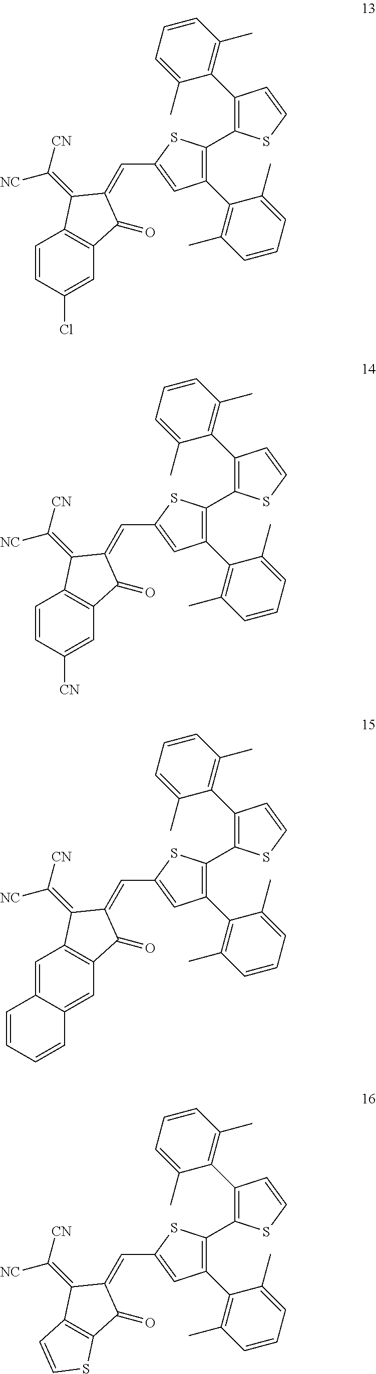 [SMILES: Cc1cccc(C)c1-c1ccsc1-c1sc(/C=C2\C(=O)c3cc(Cl)ccc3C2=C(C#N)C#N)cc1-c1c(C)cccc1C ; Cc1cccc(C)c1-c1ccsc1-c1sc(/C=C2\C(=O)c3cc(C#N)ccc3C2=C(C#N)C#N)cc1-c1c(C)cccc1C ; Cc1cccc(C)c1-c1ccsc1-c1sc(/C=C2\C(=O)c3cc4ccccc4cc3C2=C(C#N)C#N)cc1-c1c(C)cccc1C ; Cc1cccc(C)c1-c1ccsc1-c1sc(/C=C2\C(=O)c3sccc3C2=C(C#N)C#N)cc1-c1c(C)cccc1C] 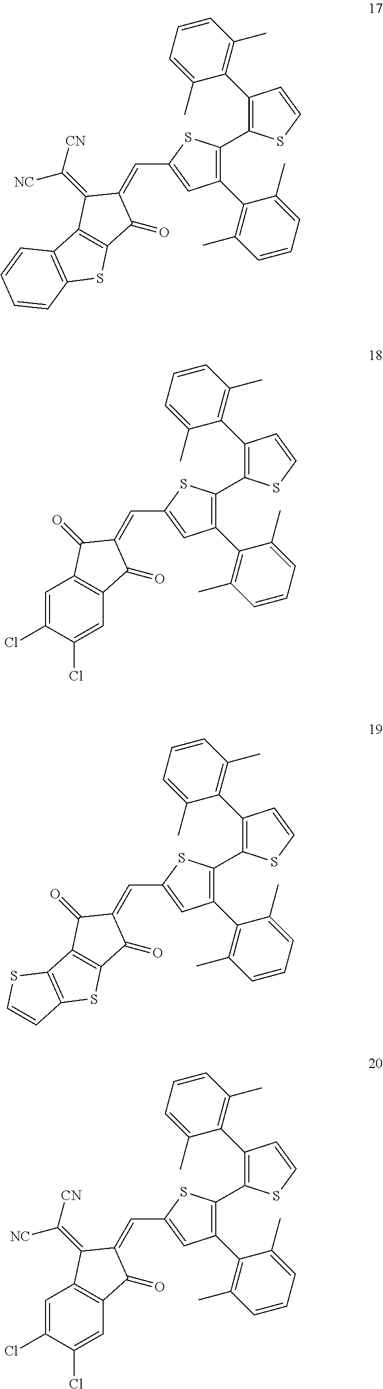 [SMILES: Cc1cccc(C)c1-c1ccsc1-c1sc(/C=C2\C(=O)c3sc4ccccc4c3C2=C(C#N)C#N)cc1-c1c(C)cccc1C ; Cc1cccc(C)c1-c1ccsc1-c1sc(C=C2C(=O)c3cc(Cl)c(Cl)cc3C2=O)cc1-c1c(C)cccc1C ; Cc1cccc(C)c1-c1ccsc1-c1sc(/C=C2\C(=O)c3sc4ccsc4c3C2=O)cc1-c1c(C)cccc1C ; Cc1cccc(C)c1-c1ccsc1-c1sc(/C=C2\C(=O)c3cc(Cl)c(Cl)cc3C2=C(C#N)C#N)cc1-c1c(C)cccc1C] 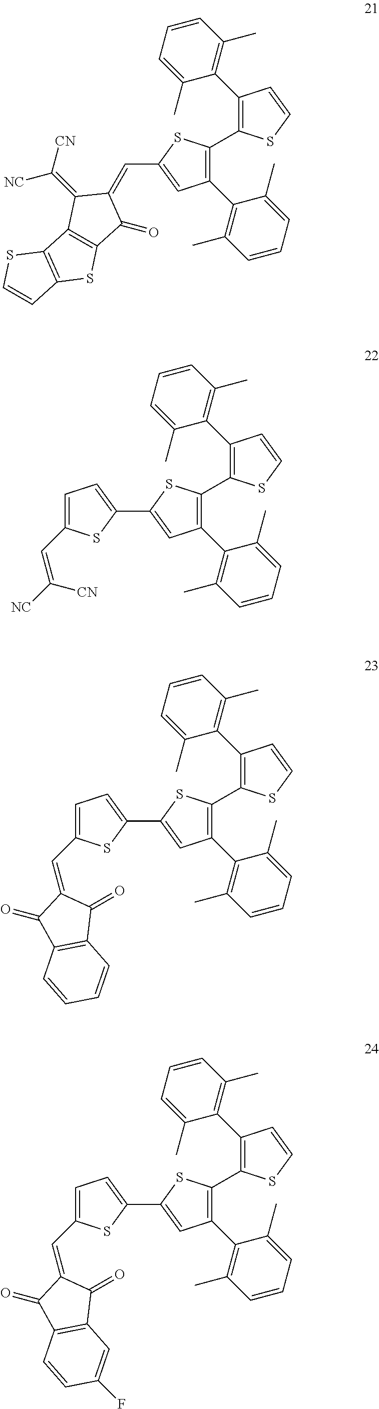 [SMILES: Cc1cccc(C)c1-c1ccsc1-c1sc(/C=C2\C(=O)c3sc4ccsc4c3C2=C(C#N)C#N)cc1-c1c(C)cccc1C ; Cc1cccc(C)c1-c1ccsc1-c1sc(-c2ccc(C=C(C#N)C#N)s2)cc1-c1c(C)cccc1C ; Cc1cccc(C)c1-c1ccsc1-c1sc(-c2ccc(C=C3C(=O)c4ccccc4C3=O)s2)cc1-c1c(C)cccc1C ; Cc1cccc(C)c1-c1ccsc1-c1sc(-c2ccc(/C=C3/C(=O)c4ccc(F)cc4C3=O)s2)cc1-c1c(C)cccc1C] 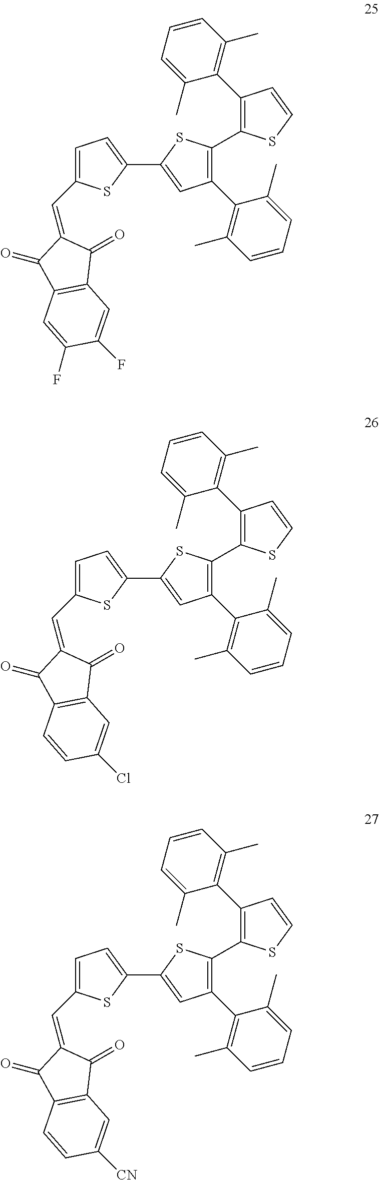 [SMILES: Cc1cccc(C)c1-c1ccsc1-c1sc(-c2ccc(C=C3C(=O)c4cc(F)c(F)cc4C3=O)s2)cc1-c1c(C)cccc1C ; Cc1cccc(C)c1-c1ccsc1-c1sc(-c2ccc(/C=C3/C(=O)c4ccc(Cl)cc4C3=O)s2)cc1-c1c(C)cccc1C ; Cc1cccc(C)c1-c1ccsc1-c1sc(-c2ccc(/C=C3/C(=O)c4ccc(C#N)cc4C3=O)s2)cc1-c1c(C)cccc1C] 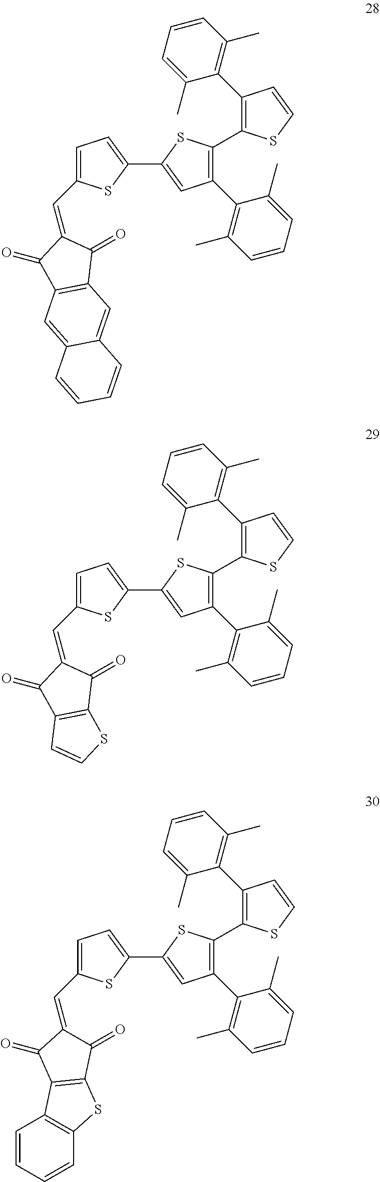 [SMILES: Cc1cccc(C)c1-c1ccsc1-c1sc(-c2ccc(C=C3C(=O)c4cc5ccccc5cc4C3=O)s2)cc1-c1c(C)cccc1C ; Cc1cccc(C)c1-c1ccsc1-c1sc(-c2ccc(/C=C3/C(=O)c4ccsc4C3=O)s2)cc1-c1c(C)cccc1C ; Cc1cccc(C)c1-c1ccsc1-c1sc(-c2ccc(/C=C3\C(=O)c4sc5ccccc5c4C3=O)s2)cc1-c1c(C)cccc1C] 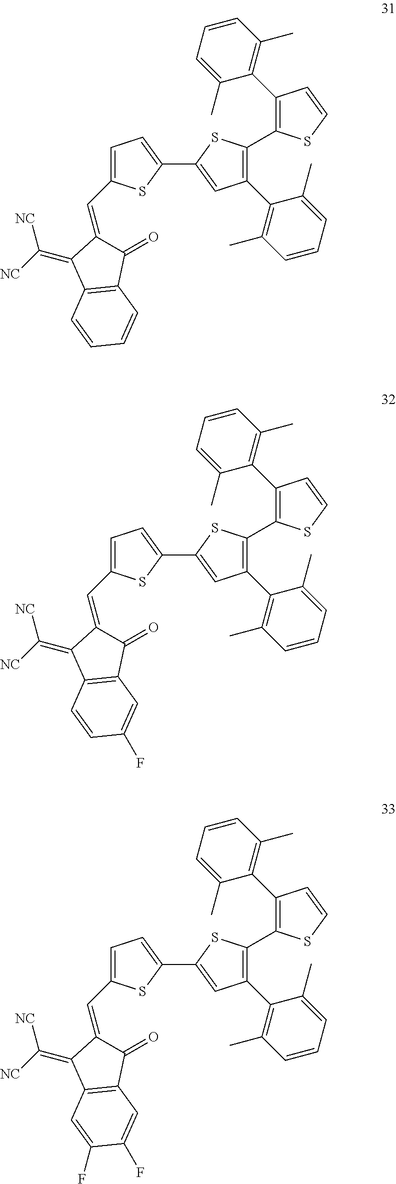 [SMILES: Cc1cccc(C)c1-c1ccsc1-c1sc(-c2ccc(/C=C3\C(=O)c4ccccc4C3=C(C#N)C#N)s2)cc1-c1c(C)cccc1C ; Cc1cccc(C)c1-c1ccsc1-c1sc(-c2ccc(/C=C3\C(=O)c4cc(F)ccc4C3=C(C#N)C#N)s2)cc1-c1c(C)cccc1C ; Cc1cccc(C)c1-c1ccsc1-c1sc(-c2ccc(/C=C3\C(=O)c4cc(F)c(F)cc4C3=C(C#N)C#N)s2)cc1-c1c(C)cccc1C] 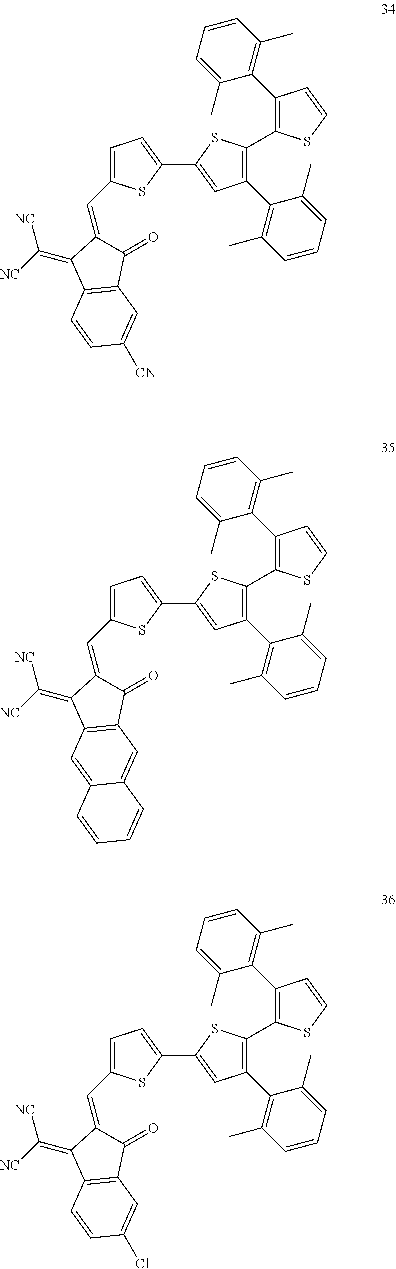 [SMILES: Cc1cccc(C)c1-c1ccsc1-c1sc(-c2ccc(/C=C3\C(=O)c4cc(C#N)ccc4C3=C(C#N)C#N)s2)cc1-c1c(C)cccc1C ; Cc1cccc(C)c1-c1ccsc1-c1sc(-c2ccc(/C=C3\C(=O)c4cc5ccccc5cc4C3=C(C#N)C#N)s2)cc1-c1c(C)cccc1C ; Cc1cccc(C)c1-c1ccsc1-c1sc(-c2ccc(/C=C3\C(=O)c4cc(Cl)ccc4C3=C(C#N)C#N)s2)cc1-c1c(C)cccc1C] 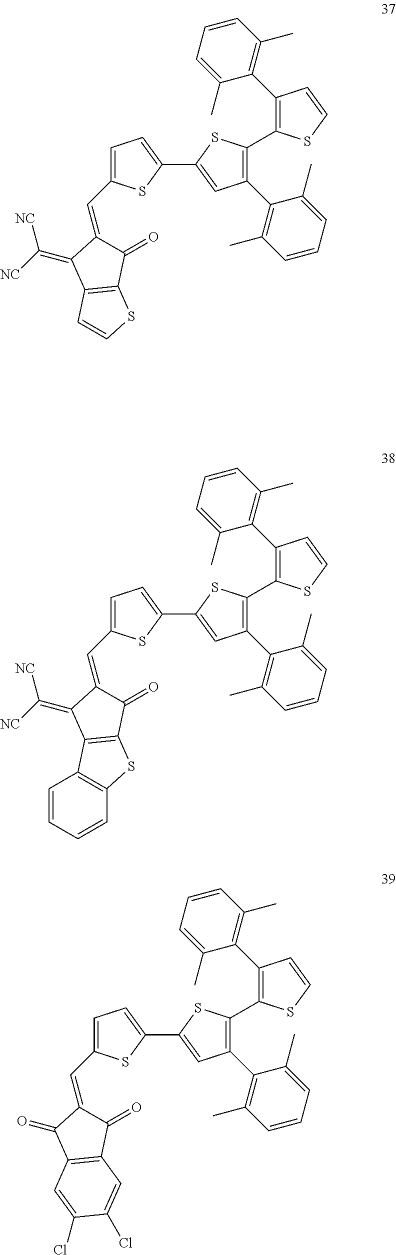 [SMILES: Cc1cccc(C)c1-c1ccsc1-c1sc(-c2ccc(/C=C3\C(=O)c4sccc4C3=C(C#N)C#N)s2)cc1-c1c(C)cccc1C ; Cc1cccc(C)c1-c1ccsc1-c1sc(-c2ccc(/C=C3\C(=O)c4sc5ccccc5c4C3=C(C#N)C#N)s2)cc1-c1c(C)cccc1C ; Cc1cccc(C)c1-c1ccsc1-c1sc(-c2ccc(C=C3C(=O)c4cc(Cl)c(Cl)cc4C3=O)s2)cc1-c1c(C)cccc1C] 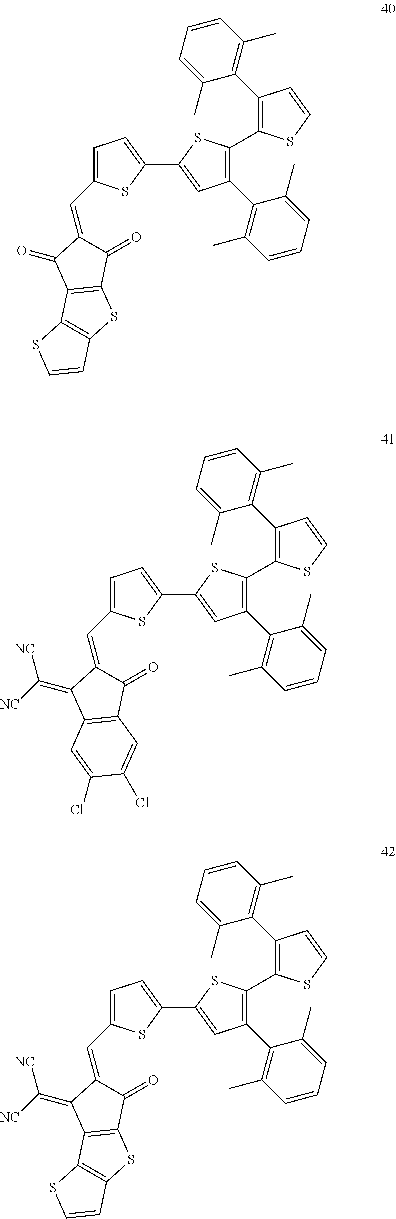 [SMILES: Cc1cccc(C)c1-c1ccsc1-c1sc(-c2ccc(/C=C3\C(=O)c4sc5ccsc5c4C3=O)s2)cc1-c1c(C)cccc1C ; Cc1cccc(C)c1-c1ccsc1-c1sc(-c2ccc(/C=C3\C(=O)c4cc(Cl)c(Cl)cc4C3=C(C#N)C#N)s2)cc1-c1c(C)cccc1C ; Cc1cccc(C)c1-c1ccsc1-c1sc(-c2ccc(/C=C3\C(=O)c4sc5ccsc5c4C3=C(C#N)C#N)s2)cc1-c1c(C)cccc1C] 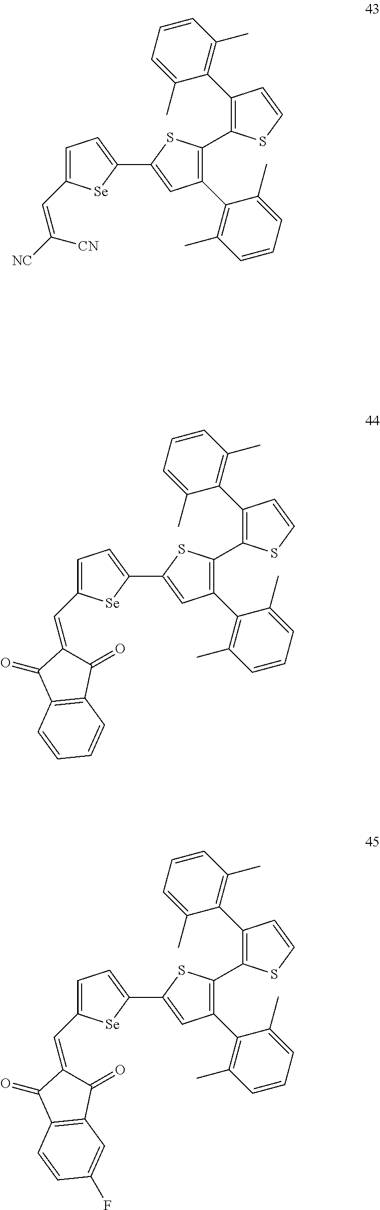 [SMILES: Cc1cccc(C)c1-c1ccsc1-c1sc(-c2ccc(C=C(C#N)C#N)[se]2)cc1-c1c(C)cccc1C ; Cc1cccc(C)c1-c1ccsc1-c1sc(-c2ccc(C=C3C(=O)c4ccccc4C3=O)[se]2)cc1-c1c(C)cccc1C ; Cc1cccc(C)c1-c1ccsc1-c1sc(-c2ccc(/C=C3/C(=O)c4ccc(F)cc4C3=O)[se]2)cc1-c1c(C)cccc1C] 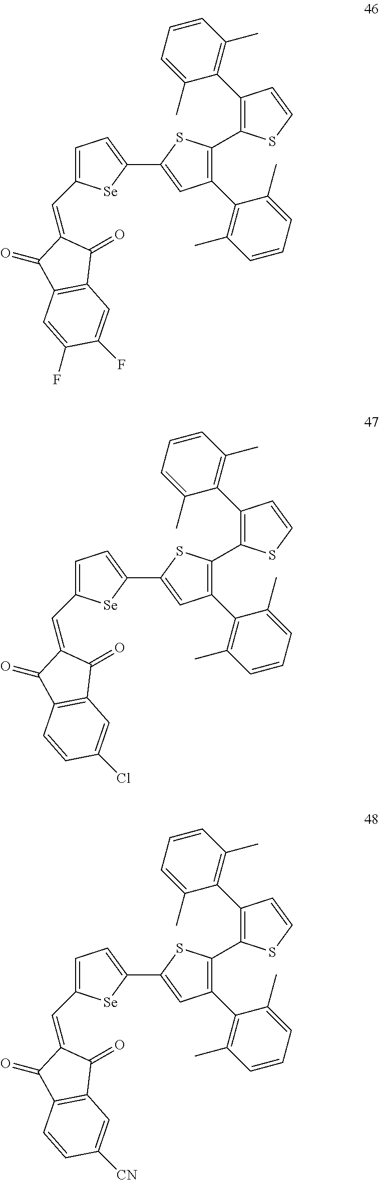 [SMILES: Cc1cccc(C)c1-c1ccsc1-c1sc(-c2ccc(C=C3C(=O)c4cc(F)c(F)cc4C3=O)[se]2)cc1-c1c(C)cccc1C ; Cc1cccc(C)c1-c1ccsc1-c1sc(-c2ccc(/C=C3/C(=O)c4ccc(Cl)cc4C3=O)[se]2)cc1-c1c(C)cccc1C ; Cc1cccc(C)c1-c1ccsc1-c1sc(-c2ccc(/C=C3/C(=O)c4ccc(C#N)cc4C3=O)[se]2)cc1-c1c(C)cccc1C] 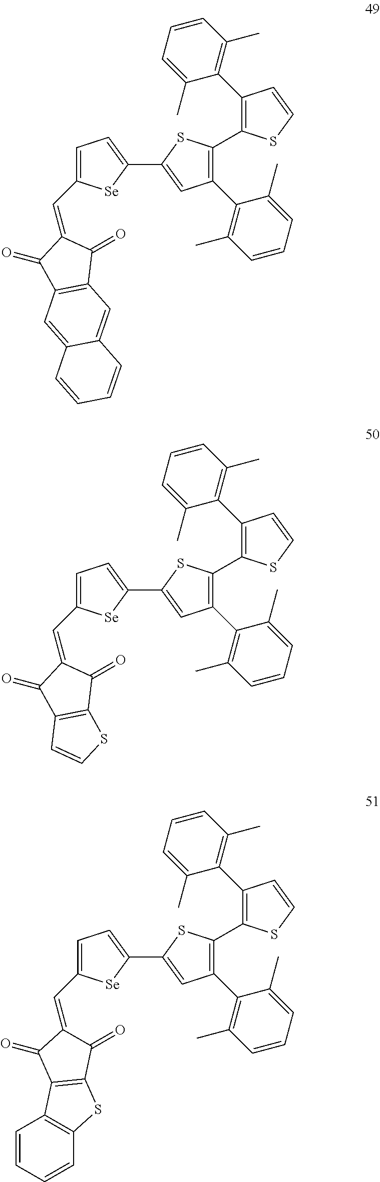 [SMILES: Cc1cccc(C)c1-c1ccsc1-c1sc(-c2ccc(C=C3C(=O)c4cc5ccccc5cc4C3=O)[se]2)cc1-c1c(C)cccc1C ; Cc1cccc(C)c1-c1ccsc1-c1sc(-c2ccc(/C=C3/C(=O)c4ccsc4C3=O)[se]2)cc1-c1c(C)cccc1C ; Cc1cccc(C)c1-c1ccsc1-c1sc(-c2ccc(/C=C3\C(=O)c4sc5ccccc5c4C3=O)[se]2)cc1-c1c(C)cccc1C] 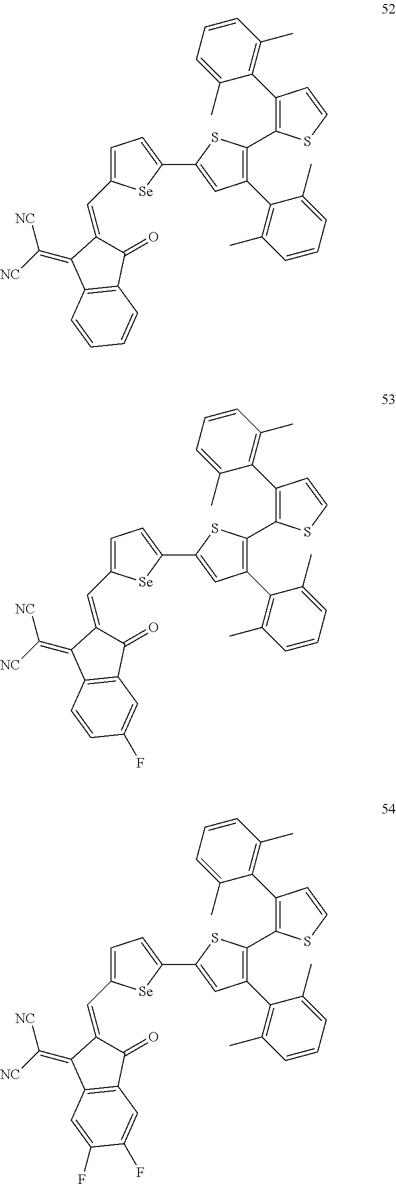 [SMILES: Cc1cccc(C)c1-c1ccsc1-c1sc(-c2ccc(/C=C3\C(=O)c4ccccc4C3=C(C#N)C#N)[se]2)cc1-c1c(C)cccc1C ; Cc1cccc(C)c1-c1ccsc1-c1sc(-c2ccc(/C=C3\C(=O)c4cc(F)ccc4C3=C(C#N)C#N)[se]2)cc1-c1c(C)cccc1C ; Cc1cccc(C)c1-c1ccsc1-c1sc(-c2ccc(/C=C3\C(=O)c4cc(F)c(F)cc4C3=C(C#N)C#N)[se]2)cc1-c1c(C)cccc1C] 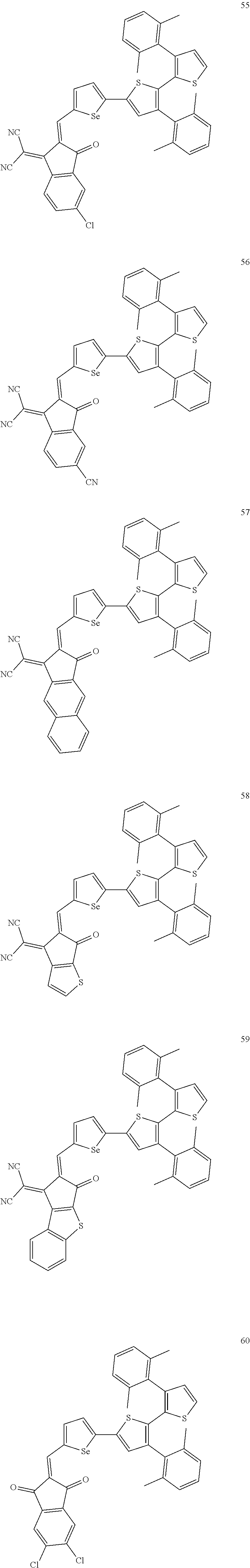 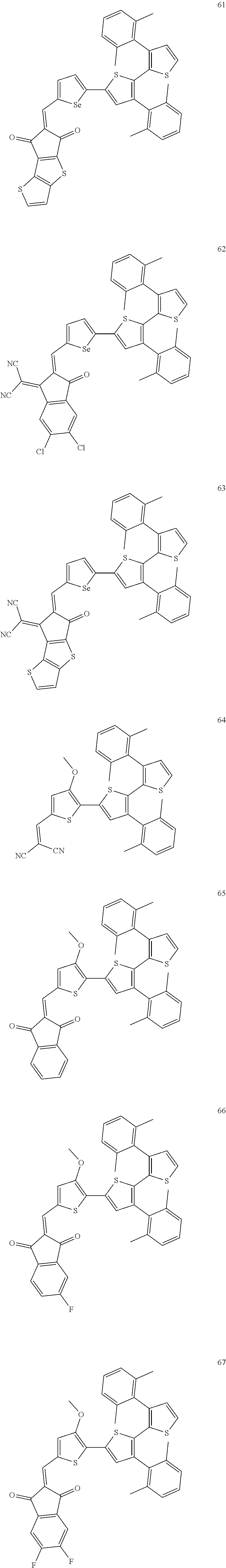 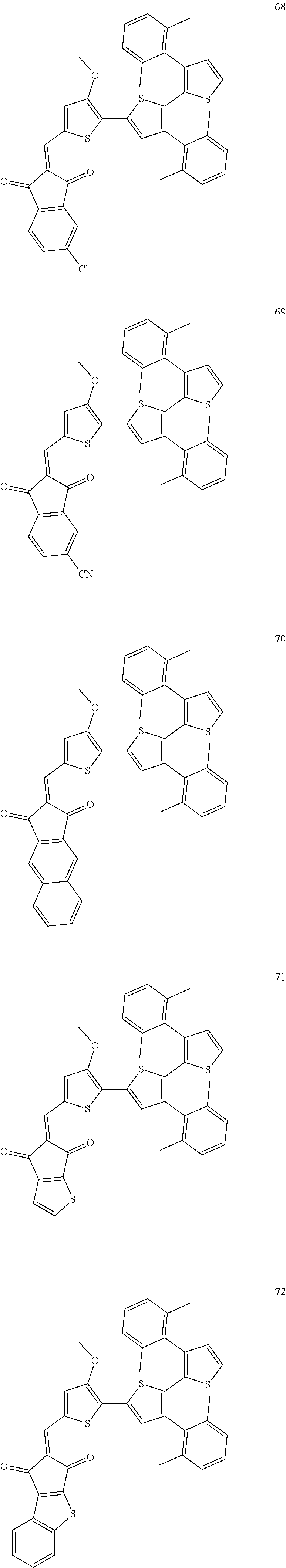 [SMILES: COc1cc(/C=C2/C(=O)c3ccc(Cl)cc3C2=O)sc1-c1cc(-c2c(C)cccc2C)c(-c2sccc2-c2c(C)cccc2C)s1 ; COc1cc(/C=C2/C(=O)c3ccc(C#N)cc3C2=O)sc1-c1cc(-c2c(C)cccc2C)c(-c2sccc2-c2c(C)cccc2C)s1 ; COc1cc(C=C2C(=O)c3cc4ccccc4cc3C2=O)sc1-c1cc(-c2c(C)cccc2C)c(-c2sccc2-c2c(C)cccc2C)s1 ; COc1cc(/C=C2/C(=O)c3ccsc3C2=O)sc1-c1cc(-c2c(C)cccc2C)c(-c2sccc2-c2c(C)cccc2C)s1 ; COc1cc(/C=C2\C(=O)c3sc4ccccc4c3C2=O)sc1-c1cc(-c2c(C)cccc2C)c(-c2sccc2-c2c(C)cccc2C)s1] 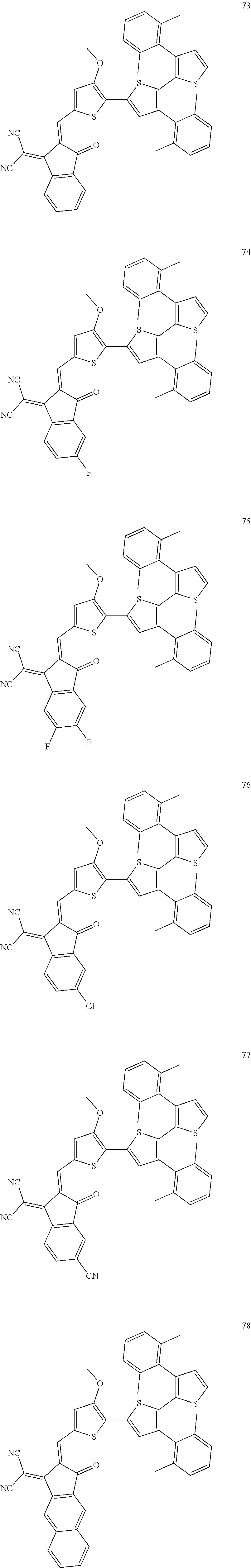 [chemical structure]
